(19) United States
(12) Patent Application Publication
(10) Pub. No.: US 2025/0376549 A1
(43) Pub. Date: Dec. 11, 2025

(54) RESIST UNDERLAYER FILM-FORMING COMPOSITION

(71) Applicant: NISSAN CHEMICAL CORPORATION, Tokyo (JP)

(72) Inventors: Hikaru TOKUNAGA, Toyama-shi (JP); Yuki MITSUTAKE, Toyama-shi (JP); Jun KOSAI, Toyama-shi (JP)

(73) Assignee: NISSAN CHEMICAL CORPORATION, Tokyo (JP)

(21) Appl. No.: 18/876,085

(22) PCT Filed: Jun. 2, 2023
(86) PCT No.: PCT/JP2023/020570

§ 371 Date: Dec. 17, 2024

(30) Foreign Application Priority Data
Jun. 17, 2022 (JP) 2022-098109
Oct. 11, 2022 (JP) 2022-163049

(51) Int. Cl. C08F 34/00; C08F 38/00; G03F 7/095; H01L 21/311

(52) U.S. Cl. CPC C08F 34/00; C08F 38/00; G03F 7/095; H01L 21/31144

(57) ABSTRACT

A resist underlayer film-forming composition exhibits a satisfactory etching resistance and heat resistance, and satisfies various other properties, e.g., curability, amount of sublimate generation, in-plane uniformity of film thickness, planarization, embeddability, and so forth; the resist underlayer film-forming composition contains a novolac resin and a solvent, and the novolac resin contains an aromatic ring-bearing unit structure A; this unit structure A is represented by formula (A): and contains a single species or two or more species of bis(azaaryl condensed ring) structural units, which are a structural unit in which two azaaryl condensed rings are bonded via a linker group L. A method forms a resist pattern using this composition and a method produces a semiconductor device using this composition.

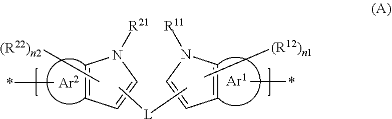

### TECHNICAL FIELD

The present invention relates to a resist underlayer film-forming composition suited for lithographic processing of semiconductor substrates, a resist underlayer film obtained from the resist underlayer film-forming composition, a method for forming a resist pattern using the resist underlayer film-forming composition, and a method for manufacturing a semiconductor device using the composition.

### BACKGROUND ART

The recent rapid advancements in semiconductor manufacturing processes have led to a strong demand for higher quality and enhanced characteristics of resist underlayer films.

For example, Patent Literature 1 discloses a polymer that includes a structural unit containing a specific heteroaromatic ring-containing divalent group having an indole skeleton as part of its structure, and an aryl-substituted divalent group, such as an aryl-substituted methylene group. According to the disclosure, the polymer can give a material enhanced in film density and etching resistance. The literature mentions but does not substantiate flattening properties.

Furthermore, Patent Literature 2 discloses that a polymer obtained by the reaction of an indole derivative with a mixture of specific aromatic aldehyde compounds is enhanced in solubility (applicability) and can further ensure etching resistance and heat resistance of a hard mask layer using the polymer.

Furthermore, Patent Literature 3 discloses a hard mask-forming composition that contains a resin having a specific diarylaminobenzyl alcohol derivative as a partial structure. The literature reports that the composition can give an organic film having high etching resistance and excellent solvent resistance and heat resistance.

Furthermore, Patent Literature 4 discloses a resist underlayer film-forming composition that includes a polymer having a unit structure containing a 2-arylindole derivative/analog structure and an aryl-substituted methylene group. The literature reports that the composition can give a resist underlayer film that does not undergo intermixing between a top portion of the resist underlayer film and a layer applied thereon and allows for forming a good resist pattern shape.

Furthermore, Patent Literature 5 discloses a resist underlayer film-forming composition that includes a compound having a specific bis(polycyclic aryl)fluorene derivative/analog structure as a structural unit. The literature reports that the composition gives a resist underlayer film material having high etching resistance, high heat resistance, and high solubility (applicability).

However, the quality and characteristics of resist underlayer films that are to be enhanced are not limited to etching resistance and heat resistance but also include other numerous characteristics, such as, for example, curability, the amount of sublimates generated, in-plane uniformity of film thickness, flattening properties, and gap-filling properties. The techniques described above still have room for improvement when these characteristics are taken into account.

### CITATION LIST

### Patent Literature

Patent Literature 1: JP 2016-151024 A
Patent Literature 2: JP 2020-105513 A
Patent Literature 3: JP 2021-81686 A
Patent Literature 4: WO 2013/146670 (A1)
Patent Literature 5: WO 2018/198960 (A1)

### SUMMARY OF INVENTION

### Technical Problem

Objects of the present invention are therefore to provide a resist underlayer film-forming composition that satisfies not only etching resistance and heat resistance but also other numerous characteristics, such as curability, the amount of sublimates generated, in-plane uniformity of film thickness, flattening properties, and gap-filling properties, and to provide a method for forming a resist pattern using the resist underlayer film-forming composition, and a method for manufacturing a semiconductor device using the composition.

### Solution to Problem

The present invention includes the following aspects.

[1]

A resist underlayer film-forming composition comprising a novolac resin and a solvent, wherein
the novolac resin comprises a unit structure A having an aromatic ring, and the unit structure A includes one, or two or more kinds of bis(azaaryl fused ring) structural units represented by formula (A) below in which two azaaryl fused rings are connected to each other by a linking group L,

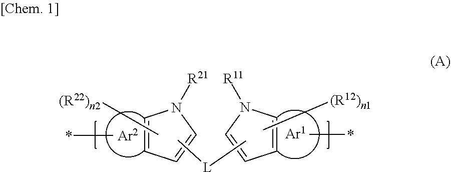

in the formula (A),
L denotes a divalent linking group between two carbon atoms each constituting the respective azaaryl fused rings and is not a single bond,
R¹¹ and R²¹ are the same as or different from each other and each independently denote:
(i) a hydrogen atom or a methylol group,
(ii) a C6-C30 aryl group, or
(iii) a C2-C20 linear, branched, or cyclic alkoxymethyl group; a C1-C20 linear, branched, or cyclic alkyl group; a C2-C10 alkenyl group; or a C2-C10 alkynyl group;
R¹² and R²² are the same as or different from each other and each independently denote an optional substituent on a carbon atom constituting the azaaryl fused ring,
the groups mentioned in (ii) and (iii) are optionally further substituted with an oxygen atom-containing substituent, a sulfur atom-containing substituent, a nitrogen atom-containing substituent, an aryl group, or a halo group, and the groups mentioned in (iii) optionally further have a hydrocarbon chain moiety interrupted by an oxygen atom-containing substituent, a sulfur atom-containing substituent, a nitrogen atom-containing substituent, or an arylene group,
n1 and n2 are the same as or different from each other and independently indicate the number of the substituents R¹² and the number of the substituents R²², respectively, each being optionally 0,
Ar¹ and Ar² are the same as or different from each other, and each independently denote a benzene ring or a fused ring composed of 2 or 3 benzene rings and each independently form a fused ring with the pyrrole ring moiety in the formula (A), and
* denotes a valence bond.
   [2]

The resist underlayer film-forming composition according to [1], wherein the novolac resin comprises composite unit structures A-B represented by formula (AB) below:

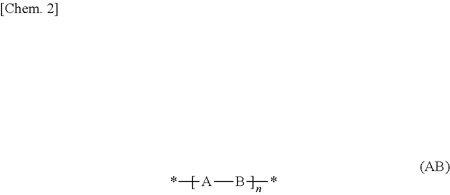

in the formula (AB)
n indicates the number of the composite unit structures A-B,
the unit structures A are represented by the formula (A) described in claim 1,
the unit structures B indicate one, or two or more kinds of unit structures including a structure represented by formula (B1), (B2), or (B3) below, and
* denotes a valence bond,

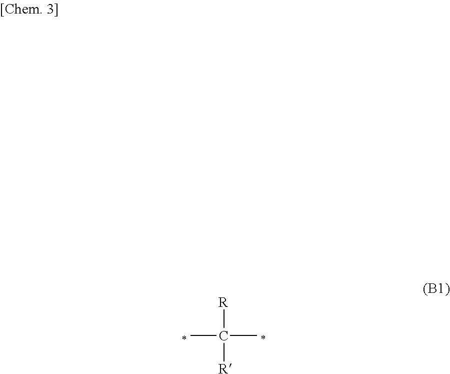

[in the formula (B1),
R and R′ each independently denote a hydrogen atom, an optionally substituted C6-C30 aromatic ring residue, an optionally substituted C3-C30 heterocyclic ring residue, or an optionally substituted C10 or lower linear, branched, or cyclic alkyl group, and
* denotes a valence bond]

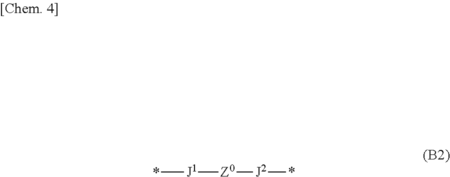

[in the formula (B2),
Z⁰ denotes an optionally substituted C6-C30 aromatic ring residue, aliphatic ring residue, or organic group including two aromatic ring residues or aliphatic ring residues connected to each other via a single bond,
J¹ and J² each independently denote a direct bond or an optionally substituted divalent organic group, and
* denotes a valence bond]

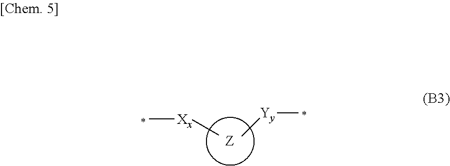

[in the formula (B3),
Z is an optionally substituted C4-C25 monocyclic ring or bicyclic, tricyclic, or tetracyclic fused ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic fused ring is optionally further condensed with one or more aromatic rings to form a pentacyclic or higher fused ring,
X and Y denote identical or different —CR³¹R³²— groups, R³¹ and R³² are the same as or different from each other and each denote a hydrogen atom or a C1-C6 hydrocarbon group,
x and y indicate the numbers of X and Y, respectively, and are each independently 0 or 1,

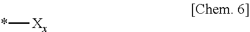

is bonded to any carbon atom (referred to as “carbon atom 1”) constituting any of the non-aromatic monocyclic rings in Z (when x=1) or extends from the carbon atom 1 (when x=0),

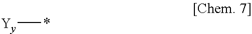

is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond].
   [3]

The resist underlayer film-forming composition according to [1], wherein the linking group L is selected from the group consisting of —O—, —S—, —SO₂—, —CO—, —CONH—, —COO—, —NH—, —(CR¹R²)m¹-, —(Ar)m²-, —CH₂—(Ar)m²-CH₂—, and -(cyclo-R)—,
R¹ and R² are the same as or different from each other and each independently denote a hydrogen atom, a C1-C5 hydrocarbon group, or a C6-C30 aryl group, m¹ denotes an integer of 1 to 10,
Ar denotes a C6-C30 arylene group, m² denotes an integer of 1 to 3 and indicates the number of aromatic ring(s) bonded to one another through a single bond, and
cyclo-R denotes a 5- to 8-membered divalent alicyclic hydrocarbon group optionally forming a fused ring with one or two benzene rings or naphthalene rings.
   [4]

The resist underlayer film-forming composition according to [3], wherein cyclo-R denotes a 6- to 8-membered divalent alicyclic hydrocarbon group optionally forming a fused ring with one or two benzene rings or naphthalene rings.

[5]

The resist underlayer film-forming composition according to [1], wherein at least part of the occurrences of R¹¹ and R²¹ denotes a substituent:

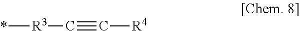

[wherein
* denotes a valence bond,
R³ is a single bond or a C1-C20 divalent organic group, and
R⁴ is a hydrogen atom or a C1-C20 monovalent organic group].
   [6]

The resist underlayer film-forming composition according to [1], wherein the solvent comprises a solvent having a boiling point of 160° C. or above.

[7]

The resist underlayer film-forming composition according to any one of [1] to [6], further comprising an acid and/or a salt thereof, and/or an acid generator.

[8]

The resist underlayer film-forming composition according to any one of [1] to [7], further comprising a crosslinking agent.

[9]

The resist underlayer film-forming composition according to [8], wherein the crosslinking agent is an aminoplast crosslinking agent or a phenoplast crosslinking agent.

[10]

The resist underlayer film-forming composition according to any one of [1] to [9], further comprising a surfactant.

[11]

A resist underlayer film on a semiconductor substrate, comprising a baked product of a coating film comprising the resist underlayer film-forming composition described in any one of [1] to [10].

[12]

A method for forming a resist pattern used in semiconductor manufacturing, the method comprising a step of applying the resist underlayer film-forming composition described in any one of [1] to [10] onto a semiconductor substrate, and baking the resist underlayer film-forming composition to form a resist underlayer film.

[13]

A method for manufacturing a semiconductor device, comprising:
a step of forming on a semiconductor substrate a resist underlayer film from the resist underlayer film-forming composition described in any one of [1] to [10];
a step of forming a resist film on the resist underlayer film;
a step of forming a resist pattern by irradiation of the resist film with light or electron beam followed by development;
a step of etching the resist underlayer film through the resist pattern; and
a step of processing the semiconductor substrate through the resist underlayer film having been patterned.
   [14]

A method for manufacturing a semiconductor device, comprising:
a step of forming on a semiconductor substrate a resist underlayer film from the resist underlayer film-forming composition described in any one of [1] to [10];
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned; and
a step of processing the semiconductor substrate through the resist underlayer film having been patterned.
   [15]

A method for manufacturing a semiconductor device, comprising:
a step of forming on a semiconductor substrate a resist underlayer film from the resist underlayer film-forming composition described in any one of [1] to [10];
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.
   [16]

A method for manufacturing a semiconductor device, comprising:
a step of forming on a semiconductor substrate a resist underlayer film from the resist underlayer film-forming composition described in any one of [1] to [10];
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been etched;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.
   [17]

The method for manufacturing a semiconductor device according to any one of [14] to [16], wherein the hard mask is formed by applying a composition comprising an inorganic substance or by depositing an inorganic substance.

[18]

The method for manufacturing a semiconductor device according to any one of [13] to [16], wherein the resist film is patterned by a nanoimprinting method or by using a self-assembled film.

[19]

The method for manufacturing a semiconductor device according to [15] or [16], wherein the hard mask is removed by etching or with an alkaline chemical solution.

### Advantageous Effects of Invention

The novolac resin that has a bis(azaaryl fused ring) derivative [typically a bis(indole) derivative] of the formula (A) as a structural unit has high heat resistance as compared to conventional novolac resins having an indole compound as a structural unit. Thus, the resist underlayer film-forming composition containing the novolac resin generates less sublimates at the time of high-temperature baking and gives a film having superior in-plane uniformity of thickness and also having high etching resistance. Furthermore, the composition exhibits good applicability to various deposition-coated substrates and achieves good flattening properties and gap-filling properties. Furthermore, the above characteristics, in particular, the resistance during etching processing, can be controlled by adding additional dissimilar monomers. Optical constants appropriate for eliminating or reducing reflection at the time of exposure can also be controlled by the addition of such monomers.

Furthermore, in a more preferred embodiment, alkylene groups, such as propargyl groups, are introduced into the novolac resin having a bis(azaaryl fused ring) derivative of the formula (A) as a structural unit. The resist underlayer film-forming composition containing such a novolac resin can attain, in addition to the characteristics described above, curability without a crosslinking agent or an acid catalyst, that is, self-crosslinkability, and can exhibit sufficient curability not only in air atmosphere but also in nitrogen atmosphere.

Furthermore, in the preferred embodiment in which alkylene groups, such as propargyl groups, are introduced into the novolac resin having a bis(azaaryl fused ring) derivative of the formula (A) as a structural unit, the alkylene groups serve as crosslinking groups. The resist underlayer film-forming composition containing such a novolac resin in combination with an acid catalyst and/or a crosslinking agent can give films that are enhanced in physical hardness compared to the usual level and thereby attain enhanced patterning characteristics at the time of etching processing.

### DESCRIPTION OF EMBODIMENTS

### I. Definitions of Terms

The definitions of the main terms in the present specification related to novolac resins constituting an aspect of the present invention will be described below. Unless otherwise specified separately, the terms related to novolac resins are based on the following definitions.

### (I-1) “Novolac Resins”

The term “novolac resins” refers not only to narrowly defined phenol-formaldehyde resins (so-called novolac-type phenol resins) and aniline-formaldehyde resins (so-called novolac-type aniline resins) but also to a broad range of general polymers formed by the formation of covalent bonds (such as a substitution reaction, an addition reaction, a condensation reaction, or an addition condensation reaction) between an organic compound that has a functional group enabling covalent bonding to an aromatic ring in the presence of an acid catalyst or under similar reaction conditions [such as, for example, an aldehyde group, a ketone group, an acetal group, a ketal group; a hydroxyl or alkoxy group bonded to a secondary or tertiary carbon; a hydroxyl, alkoxy, or halo group bonded to an α-carbon atom in an alkylaryl group (such as a benzylic carbon atom); or a carbon-carbon unsaturated bond, such as divinylbenzene or dicyclopentadiene], and an aromatic ring in an aromatic ring-containing compound (preferably having, on the aromatic ring, a substituent containing a heteroatom, such as an oxygen atom, a nitrogen atom, or a sulfur atom).

Thus, the novolac resins referred to in the present specification are polymers in which an organic compound that contains a carbon atom derived from the above functional group (sometimes written as the “linking carbon atom”) connects a plurality of molecules of an aromatic ring-containing compound by forming, via the linking carbon atoms, covalent bonds with the aromatic rings in the molecules of the aromatic ring-containing compound.

In the present specification, the unit structures constituting a “novolac resin” are written as unit structures A, unit structures B, and unit structures C. The unit structure A is a unit structure derived from an aromatic ring-containing compound. The unit structure B is a unit structure derived from a compound having a functional group enabling covalent bonding to an aromatic ring in the unit structure A. The unit structure C is a unit structure that is equivalent, in bonding mode, to a composite unit structure A-B, and is derived from a compound having an aromatic ring and also having a functional group enabling covalent bonding to an aromatic ring in the unit structure A. Due to the identicalness in bonding mode, the unit structure C may be replaced with the composite unit structure A-B.

### (I-2) “Residues”

The term “residue” indicates an organic group that has a valence bond in place of a hydrogen atom bonded to a carbon atom or a heteroatom (such as a nitrogen atom, an oxygen atom, or a sulfur atom) and may be a monovalent group or a polyvalent group. For example, the substitution of one hydrogen atom with one valence bond results in a monovalent organic group, and the substitution of two hydrogen atoms with valence bonds yields a divalent organic group.

### (I-3) “Aromatic Rings” (Aromatic Groups, Aryl Groups, Arylene Groups)

The concept of “aromatic rings” comprehends aromatic hydrocarbon rings, aromatic heterocyclic rings, and residues thereof [also written as “aromatic groups”, “aryl groups” (in the case of monovalent groups), or “arylene groups” (in the case of divalent groups)], and the rings may be monocyclic (aromatic monocyclic rings) or polycyclic (aromatic polycyclic rings). In the case of polycyclic rings, at least one monocyclic ring is an aromatic monocyclic ring, but the remaining monocyclic ring or rings that form the fused ring with that aromatic monocyclic ring may be monocyclic heterocyclic rings (heteromonocyclic rings) or monocyclic alicyclic hydrocarbons (alicyclic monocyclic rings).

Examples of the aromatic rings include, but are not limited to, aromatic hydrocarbon rings, such as benzene, indene, naphthalene, azulene, styrene, toluene, xylene, mesitylene, cumene, anthracene, phenanthrene, triphenylene, benzanthracene, pyrene, chrysene, fluorene, biphenyl, corannulene, perylene, fluoranthene, benzo[k]fluoranthene, benzo[b]fluoranthene, benzo[ghi]perylene, coronene, dibenzo[g,p]chrysene, acenaphthylene, acenaphthene, naphthacene, pentacene, and cyclooctatetraene, more typically, aromatic hydrocarbon rings such as benzene, naphthalene, anthracene, and pyrene; and aromatic heterocyclic rings, such as furan, pyran, thiophene, pyrrole, N-alkylpyrrole, N-arylpyrrole, imidazole, pyridine, pyrimidine, pyrazine, triazine, thiazole, indole, phenylindole, bisindolefluorene, bisindolebenzofluorene, bisindoledibenzofluorene, purine, quinoline, isoquinoline, chromene, thianthrene, phenothiazine, phenoxazine, xanthene, acridine, phenazine, carbazole, and indolocarbazole, more typically, furan, thiophene, pyrrole, indole, phenylindole, bisindolefluorene, phenothiazine, carbazole, indolocarbazole, imidazole, pyran, pyridine, pyrimidine, and pyrazine.

The aromatic rings (such as, for example, benzene ring or naphthalene ring) may optionally have a substituent. Examples of such substituents include halogen atoms; saturated or unsaturated, linear, branched, or cyclic hydrocarbon groups (—R) (the hydrocarbon chains may be interrupted with an oxygen atom one or more times; examples of R include alkyl groups, alkenyl groups, alkynyl groups, and propargyl group); alkoxy groups or aryloxy groups (—OR wherein R denotes the hydrocarbon group —R described above); alkylamino groups [—NHR or —NR₂ (the two groups R may be the same as or different from each other), wherein R denotes the hydrocarbon group —R described above and may be, for example, an alkyl group, an alkenyl group, an alkynyl group, or a propargyl group, and the hydrocarbon chains may be interrupted with an oxygen atom one or more times]; hydroxyl group; amino group (—NH₂); carboxyl group; cyano group; nitro group; ester groups (—CO₂R or —OCOR wherein R denotes the hydrocarbon group-R described above); amide groups (—NHCOR, —CONHR, —NRCOR (the two groups R may be the same as or different from each other), or —CONR₂ (the two groups R may be the same as or different from each other), wherein R denotes the hydrocarbon group —R described above); sulfonyl-containing groups (—SO₂R wherein R denotes the hydrocarbon group —R described above or the hydroxyl group —OH); thiol group (—SH); sulfide-containing groups (—SR wherein R denotes the hydrocarbon group —R described above); ether bond-containing organic groups [residues of an ether compound represented by R¹¹—O—R¹¹ (R¹¹ independently at each occurrence denotes a C1-C6 alkyl group, such as a methyl group or an ethyl group, or an aryl group, such as a phenyl group, a naphthyl group, an anthranyl group, or a pyrenyl group); for example, organic groups containing an ether bond as a methoxy group, an ethoxy group, or a phenoxy group]; and aryl groups.

Furthermore, the aromatic rings may be organic groups having a fused ring formed of one or more aromatic rings (such as benzene, naphthalene, anthracene, or pyrene) with one or more aliphatic rings or heterocyclic rings. Examples of the aliphatic rings here include cyclobutane, cyclobutene, cyclopentane, cyclopentene, cyclohexane, cyclohexene, methylcyclohexane, methylcyclohexene, cycloheptane, and cycloheptene. Examples of the heterocyclic rings include furan, thiophene, pyrrole, imidazole, pyran, pyridine, pyrimidine, pyrazine, pyrrolidine, piperidine, piperazine, and morpholine.

The aromatic rings may be organic groups having a structure in which two or more aromatic rings are connected via a divalent linking group, such as an alkylene group.

### (I-4) “Heterocyclic Rings”

The concept of “heterocyclic rings” comprehends both aliphatic heterocyclic rings and aromatic heterocyclic rings and includes not only monocyclic rings (heteromonocyclic rings) but also polycyclic rings (heteropolycyclic rings). In the case of polycyclic rings, at least one monocyclic ring is a heteromonocyclic ring, but the remaining monocyclic ring or rings may be aromatic hydrocarbon monocyclic rings or alicyclic monocyclic rings. Examples of the aromatic heterocyclic rings include those described in (I-3) above. Similarly to the aromatic rings in (I-3), the heterocyclic rings may have a substituent.

### (I-5) “Non-Aromatic Rings” (Aliphatic Rings)

The term “non-aromatic monocyclic rings” refers to monocyclic hydrocarbons that are not aromatic, and typically indicates monocyclic rings of alicyclic compounds. The rings may also be referred to as aliphatic monocyclic rings (including aliphatic heteromonocyclic rings) (the rings may contain an unsaturated bond as long as the rings do not belong to aromatic compounds). Similarly to the aromatic rings in (I-3), the non-aromatic monocyclic rings may have a substituent.

Examples of the non-aromatic monocyclic rings (aliphatic rings, aliphatic monocyclic rings) include cyclopropane, cyclobutane, cyclobutene, cyclopentane, cyclopentene, cyclohexane, methylcyclohexane, cyclohexene, methylcyclohexene, cycloheptane, and cycloheptene.

The term “non-aromatic polycyclic rings” refers to polycyclic hydrocarbons that are not aromatic, and typically indicates polycyclic rings of alicyclic compounds. The rings may also be referred to as aliphatic polycyclic rings [including aliphatic heteropolycyclic rings (at least one of the monocyclic rings constituting the polycyclic ring is an aliphatic heterocyclic ring) (the rings may contain an unsaturated bond as long as the rings do not belong to aromatic compounds)]. The non-aromatic polycyclic rings include non-aromatic bicyclic rings, non-aromatic tricyclic rings, and non-aromatic tetracyclic rings.

The term “non-aromatic bicyclic rings” refers to fused rings composed of two monocyclic hydrocarbons that are not aromatic, and typically indicates fused rings composed of two alicyclic compounds. In the present specification, the rings are also referred to as aliphatic bicyclic rings (including aliphatic heterobicyclic rings) (the rings may contain an unsaturated bond as long as the rings do not belong to aromatic compounds). Examples of the non-aromatic bicyclic rings include bicyclopentane, bicyclooctane, and bicycloheptene.

The term “non-aromatic tricyclic rings” refers to fused rings composed of three monocyclic hydrocarbons that are not aromatic, and typically indicates fused rings composed of three alicyclic compounds (that may be each a heterocyclic ring and may contain an unsaturated bond as long as the compound does not belong to aromatic compounds). Examples of the non-aromatic tricyclic rings include tricyclooctane, tricyclononane, and tricyclodecane.

The term “non-aromatic tetracyclic rings” refers to fused rings composed of four monocyclic hydrocarbons that are not aromatic, and typically indicates fused rings composed of four alicyclic compounds (that may be each a heterocyclic ring and may contain an unsaturated bond as long as the compound does not belong to aromatic compounds). Examples of the non-aromatic tetracyclic rings include hexadecahydropyrene.

(1-6)

The term “carbon atom constituting a ring (moiety)” means the carbon atom constituting a hydrocarbon ring (that may be any of an aromatic ring, an aliphatic ring, and a heterocyclic ring) in a substituent-free form.

(1-7)

The term “azaaryl fused rings” generally means fused rings formed between an azaaryl group (a nitrogen-containing aromatic heterocyclic ring) and an aromatic ring. In the present invention, in particular, the azaaryl group that is a nitrogen-containing aromatic heterocyclic ring is a pyrrole ring.

The term “bis(azaaryl fused ring) compounds” means compounds that include a structural unit having two azaaryl fused rings. In the present invention, in particular, the term means novolac resins including unit structures of formula (A) described later in (IIA-1).

### (I-8)

The term “hydrocarbon groups” refers to groups resulting from the removal of one, or two or more hydrogen atoms from a hydrocarbon. The hydrocarbons include saturated or unsaturated aliphatic hydrocarbons, saturated or unsaturated alicyclic hydrocarbons, and aromatic hydrocarbons.

(1-9)

In the chemical structural formulas showing unit structures of novolac resins in the present specification, valence bonds (indicated by *) are sometimes described for the purpose of convenience. Such valence bonds may be present at any possible bonding positions in the unit structures unless otherwise specified, and the bonding positions in the unit structures are not limited to those that are illustrated.

### II; Resist Underlayer Film-Forming Compositions

A resist underlayer film-forming composition according to an aspect of the present invention includes a specific novolac resin and a solvent.

### (IIA) Novolac Resins

### (IIA-1)

The specific novolac resin contained in the resist underlayer film-forming composition according to an aspect of the present invention includes a unit structure A having an aromatic ring, and the unit structure A includes one, or two or more kinds of bis(azaaryl fused ring) structural units represented by formula (A) below in which two azaaryl fused rings, preferably two indole rings (which may be substituted, such as, for example, 2-phenylindole) are connected to each other by a linking group L.

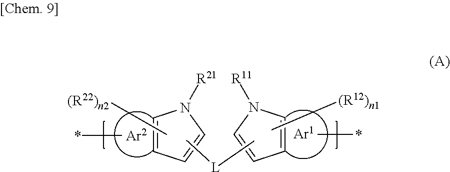

Unless otherwise specified, * as used hereinbelow indicates a valence bond.

In the formula (A), the valence bonds indicated by * extend from carbon atoms among the carbon atoms constituting the azaaryl fused rings, and preferably extend from carbon atoms constituting Ar¹ and Ar². However, this does not exclude that the valence bonds extend from the pyrrole ring moieties in the azaaryl fused rings or, when L has an aromatic ring, from the aromatic ring in L.

### (IIA-1-1)

In the formula (A), L is a divalent linking group and is not a single bond. The group L may bond to any carbon atoms constituting the respective azaaryl fused rings and may bond to aromatic carbon atoms in Ar¹ and Ar², that is, to aromatic carbon atoms in the azaaryl fused rings that constitute the following rings:

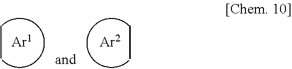

It is, however, preferable that L be bonded to carbon atoms constituting the pyrrole ring moieties in the azaaryl fused rings.

The linking group is preferably selected from the group consisting of —O—, —S—, —SO₂—, —CO—, —CONH—, —COO—, —NH—, —(CR¹R²)m¹-, —(Ar)m²-, —CH₂—(Ar)m²-CH₂—, and -(cyclo-R)—.

R¹ and R² are the same as or different from each other and each independently denote a hydrogen atom; a C1-C5 hydrocarbon group; or a C6-C30 aryl group; and m¹ denotes an integer of 1 to 10.

Ar denotes a C6-C30 arylene group; and m² denotes an integer of 1 to 3 and indicates the number of aromatic ring(s) bonded to one another through a single bond. Examples of such Ar include divalent benzene ring, naphthalene ring, anthracene ring, pyrene ring, biphenyl ring, and terphenyl ring.

cyclo-R denotes a 5- to 8-membered, preferably 6- to 8-membered, divalent alicyclic hydrocarbon group optionally forming a fused ring with one or two benzene rings or naphthalene rings. The two valence bonds of cyclo-R each extend from a carbon atom constituting the ring of the alicyclic hydrocarbon group (both preferably extend from the same carbon atom; there is no case where the valence bonds extend from carbon atoms belonging to the optional benzene ring(s) or naphthalene ring(s) that are condensed). The alicyclic hydrocarbon group may be a divalent monocyclic hydrocarbon group derived from, for example, cyclohexane or cyclopentane, or may be a divalent polycyclic hydrocarbon group derived from, for example, dicyclopentadiene. Examples of the alicyclic hydrocarbon groups forming a fused ring with a benzene ring(s) or a naphthalene ring(s) include divalent hydrocarbon groups derived from tetralin, 9,10-dihydroanthracene, 9,10-dihydrophenanthrene, indane, fluorene, benzocyclobutene, benzofluorene, dibenzofluorene, or acenaphthene. When the alicyclic hydrocarbon group is a 5-membered ring, that is, a divalent hydrocarbon group derived from cyclopentane, the number of benzene rings or naphthalene rings that should be condensed is preferably 0 to 2.

In an embodiment of the present invention, L in the formula (A) may be a structure except a fluorene ring.

In an embodiment of the present invention, it is preferable that when L in the formula (A) is a fluorene ring, at least part of the occurrences of R¹¹ and R²¹ denote an alkynyl group described later.

### (IIA-1-2)

Ar¹ and Ar² are the same as or different from each other, and each independently denote a benzene ring or a fused ring composed of 2 or 3 benzene rings and each independently form a fused ring (an azaaryl fused ring) with the pyrrole ring moiety in the formula (A). Examples of the fused rings composed of 2 or 3 benzene rings include naphthalene ring, anthracene ring, and phenanthrene ring. The rings may be substituted, with examples including biphenyl (benzene ring substituted with a phenyl group) and terphenyl (benzene ring substituted with a biphenyl group).

Ar¹ and Ar² are preferably benzene rings.

### (IIA-1-3)

R¹¹ and R²¹ are substituents on the nitrogen atoms in the azaaryl fused rings, specifically, substituents on the nitrogen atoms in the pyrrole ring moieties.

R¹¹ and R²¹ are the same as or different from each other and each independently denote:
(i) a hydrogen atom or a methylol group,
(ii) a C6-C30 aryl group, or
(iii) a C2-C20 linear, branched, or cyclic alkoxymethyl group (such as a methoxymethyl group); a C1-C20 linear, branched, or cyclic alkyl group; a C2-C10 alkenyl group; or a C2-C10 alkynyl group.

The groups mentioned in (ii) and (iii) are optionally further substituted with an oxygen atom-containing substituent (such as a hydroxyl group, an alkoxy group, an aryloxy group, a carboxyl group, or a carbonyl group), a sulfur atom-containing substituent (such as a sulfonic acid group, a sulfide-containing group, or a sulfonyl-containing group), a nitrogen atom-containing substituent (such as an amino group, a substituted amino group (a mono-substituted or di-substituted amino group, such as a monoalkylamine or a dialkylamine), an amide group, a nitro group, or a cyano group), an aryl group (preferably a C6-C15 aryl group, such as, for example, a phenyl group), or a halo group. The groups mentioned in (iii) optionally further have a hydrocarbon chain moiety interrupted by an oxygen atom-containing substituent (such as —O—, —C(O)—, —C(O)O—, or —OC(O)—), a sulfur atom-containing substituent (such as —S—), a nitrogen atom-containing substituent (such as —N(R)C(O)—, —C(O)N(R)—, —OC(O)N(R)—, —N(R)C(O)O—, —N(R)C(O)N(R)—, or —NR—), or an arylene group (such as a phenylene group). In the interrupting substituents, R independently at each occurrence denotes a C1-C30 hydrocarbon group, and the hydrocarbon groups that are denoted may be the same as or different from one another.

From the point of view of self-crosslinkability, it is preferable that at least part of the occurrences of R¹¹ and R²¹ denote an alkynyl group illustrated below:

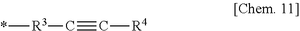

The phrase “at least part of the occurrences” means that the alkynyl groups are preferably introduced on 5 to 100% of the nitrogen atoms constituting the pyrrole ring moieties of the azaaryl fused rings. Here, the alkynyl group introduction ratio may be calculated by, for example, ¹H-NMR measurement or ¹³C-NMR. Where necessary, the introduction ratio may be calculated using an internal standard or the like.

Here, R³ is a single bond; or a C1-C20 divalent organic group, preferably an alkylene group, and more preferably a methylene group; and R⁴ is a hydrogen atom or a C1-C20 monovalent organic group, preferably an alkyl group, and more preferably a hydrogen atom.

Incidentally, the term organic group means a residue of an organic compound.

### (IIA-1-4)

R¹² and R²² are the same as or different from each other and each independently denote an optional substituent on a carbon atom constituting the azaaryl fused ring. The substituents may be present on carbon atoms constituting the pyrrole ring moieties or on carbon atoms constituting the aromatic ring moieties Ar¹ and Ar² condensed with the pyrrole ring moieties.

For example, R¹² and R²² may be each independently:
(iv) a hydroxyl group, a nitro group, a cyano group, a carboxyl group, a trifluoromethyl group, or a halo group,
(v) a C6-C15 aryloxy group, a C8-C15 arylalkoxycarbonyl group, a C7-C15 aryloxycarbonyl group, or a C6-C30 aryl group, or
(vi) a C1-C15 acyl group, a C1-C15 alkoxy group, a C7-C15 arylalkoxy group, a C1-C15 alkoxycarbonyl group, a C1-C10 linear, branched, or cyclic alkyl group, a C2-C20 alkenyl group, or a C2-C10 alkynyl group. The groups that are denoted may be the same as or different from one another.

The groups mentioned in (v) and (vi) are optionally further substituted with an oxygen atom-containing substituent, a sulfur atom-containing substituent, a nitrogen atom-containing substituent, an aryl group, or a halo group, similar to those described for the groups in (ii) and (iii) in (IIA-1-3); and the groups mentioned in (vi) optionally further have a hydrocarbon chain moiety interrupted by an oxygen atom-containing substituent, a sulfur atom-containing substituent, a nitrogen atom-containing substituent, or an arylene group (such as a phenylene group), similar to those described for the groups in (iii) in (IIA-1-3).

n1 and n2 are the same as or different from each other and independently indicate the number of the substituents R¹² and the number of the substituents R²², respectively, each being optionally 0.

### (IIA-1-5)

The resist underlayer film-forming composition according to an aspect of the present invention achieves enhanced etching resistance, less sublimates, high in-plane uniformity, good curability, and good flattening properties and gap-filling properties. Although not bound by theory, these advantageous effects probably stem from the following.

The novolac resin contained in the resist underlayer film-forming composition according to an aspect of the present invention includes bis(azaaryl fused ring) structural units (preferably bisindole structural units). At the time of baking, the bis(azaaryl fused ring) structural units are present very close to one another via the divalent linking group L that is not a single bond (the molecules tend to be fixed for entropy reasons), and consequently the structural units form fused rings during baking.

The following illustrates typical schemes of the fused ring formation upon baking that are expected when the bis(azaaryl fused ring) structural units are bis(indole) structural units [when Ar¹ and Ar² in the formula (A) are benzene rings].

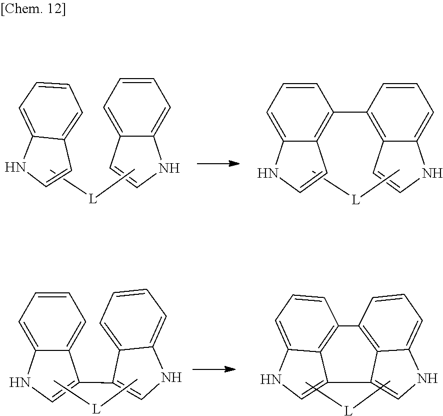

Fused rings will be formed in a similar manner also when Ar¹ and Ar² are fused rings composed of 2 or 3 benzene rings (for example, naphthalene rings or anthracene rings). When, however, the azaaryl fused rings are such that all the carbon atoms in the pyrrole ring moieties of the azaaryl groups are substituted (with aryl substituents, such as phenyl groups), as is the case in 2-phenylindole, the formation of a bond between the two pyrrole ring moieties connected via the linking group L illustrated in the above scheme is unlikely to occur. In this case, however, an additional bond will be formed between the two substituents, namely, phenyl groups, thereby forming a fused ring, and thus similar effects can be expected.

It is probable that the above formation of fused rings during baking reduces the amount of oxidation sites and increases the carbon content, thereby resulting in enhanced etching resistance. Furthermore, the fused ring formation probably also enhances heat resistance. As a result, the amount of sublimates generated is dramatically reduced and consequently the in-plane uniformity can be increased. Furthermore, the formation of fused rings will significantly lower the solubility in solvents after baking and thus curability is also improved.

Conventionally, it is generally known that higher flattening properties and higher gap-filling properties are exhibited with increasing flexibility of resins, and rigid molecules offer poor flattening properties and gap-filling properties. Thus, it was expected that gap-filling properties and flattening properties would be poor if use was made of condensed bis(azaaryl fused ring) skeletons already having additional fused rings that should be formed after baking. In addition, difficulties were expected in preparing such a resin into a solution in view of the knowledge that rigid structures exhibit extremely low solubility in solvents for resist underlayer films. In the present application, the resin before baking has a bis(azaaryl fused ring) structure and thus can be easily dissolved into a solvent for resist underlayer films, and the resultant solution can be applied to achieve good gap-filling properties and flattening properties. By being baked, the resin attains a bulky structure probably as illustrated in the above schemes and comes to have a rigid skeleton still ensuring gap-filling properties and flattening properties.

### (IIA-1-6)

Some typical examples of the bis(azaaryl fused ring) structural units are illustrated below.

Incidentally, the illustrations omit valence bonds from the structural units. While the typical examples below illustrate that hydrogen atoms are bonded to the nitrogen atoms on the azaaryl fused rings (indole rings), at least part thereof may be replaced with the substituents defined as R¹¹ and R²¹ defined in relation to the formula (A) in (IIA-1). Furthermore, the structural units may optionally have substituents illustrated as R¹² and R²² defined in relation to the formula (A) in (IIA-1).

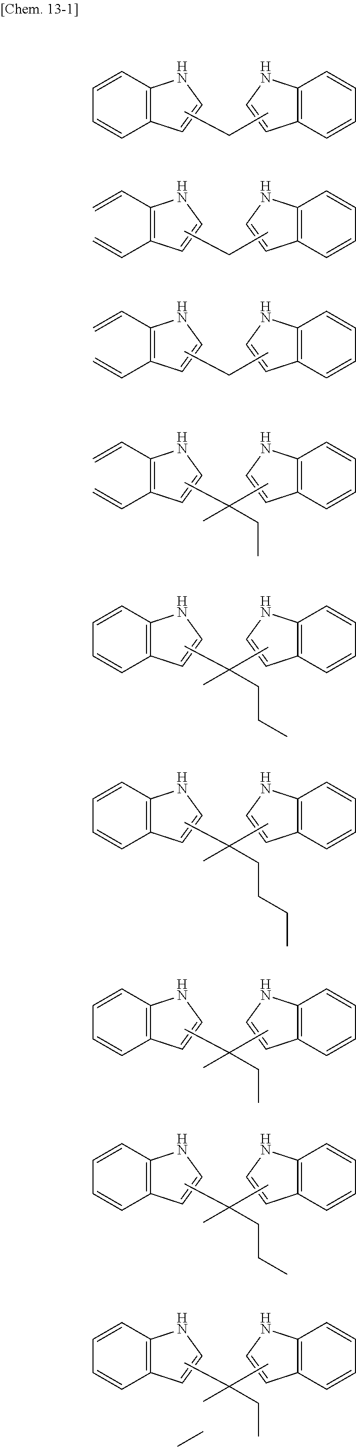

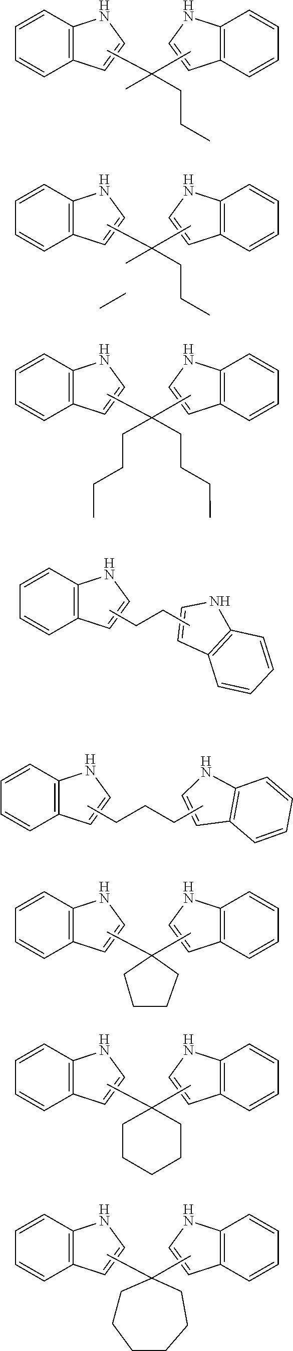

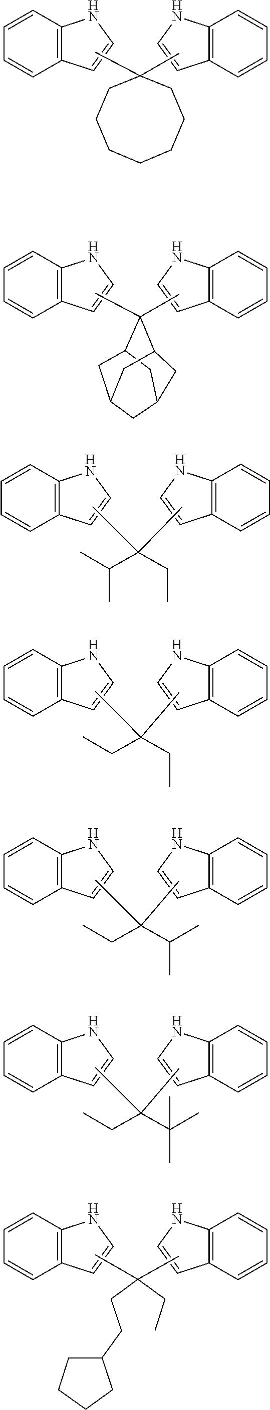

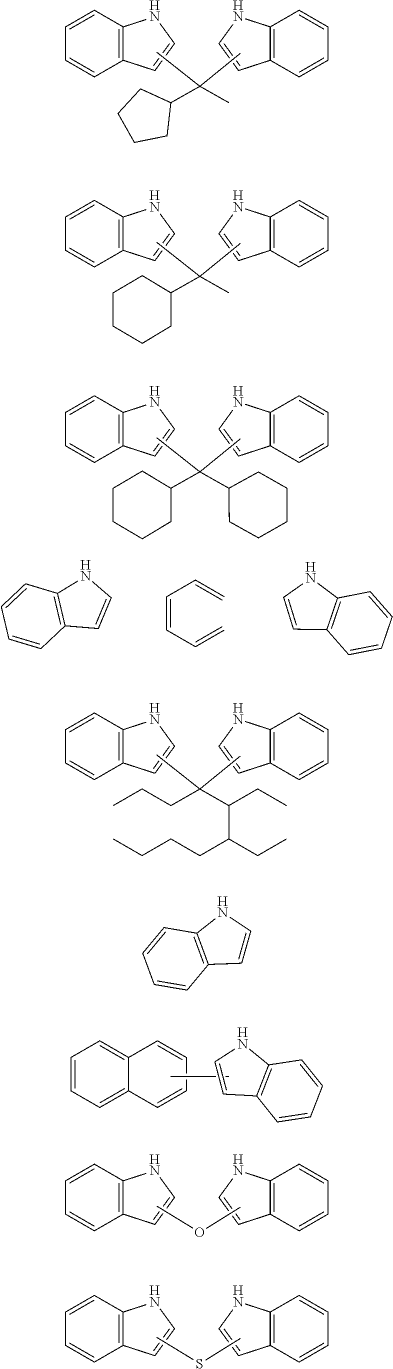

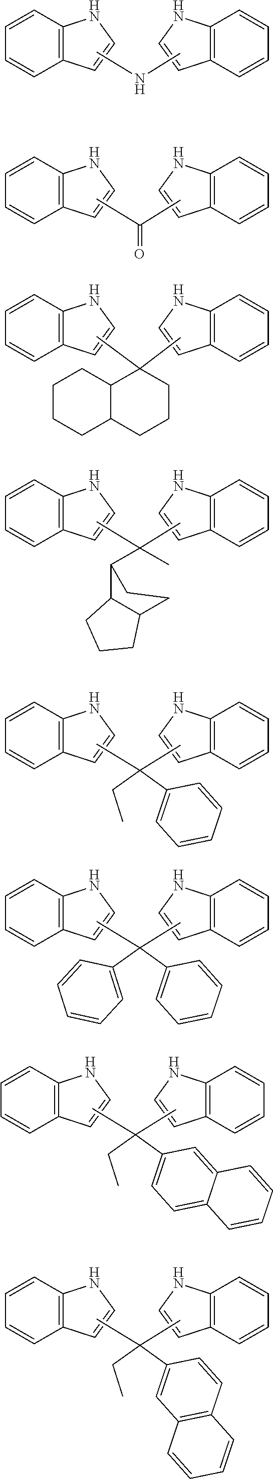

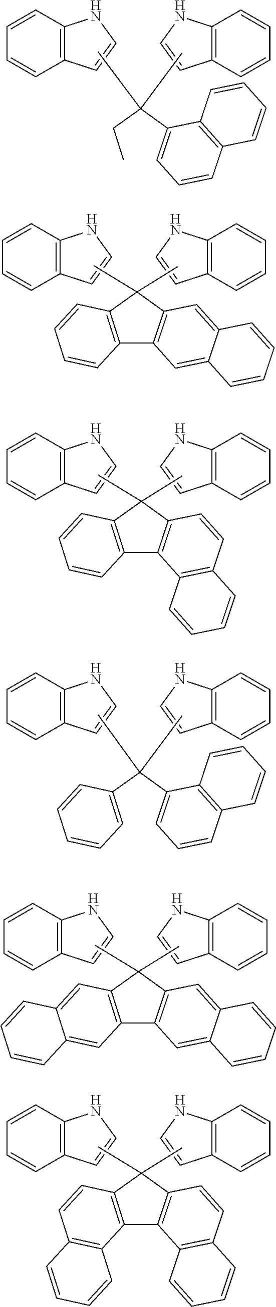

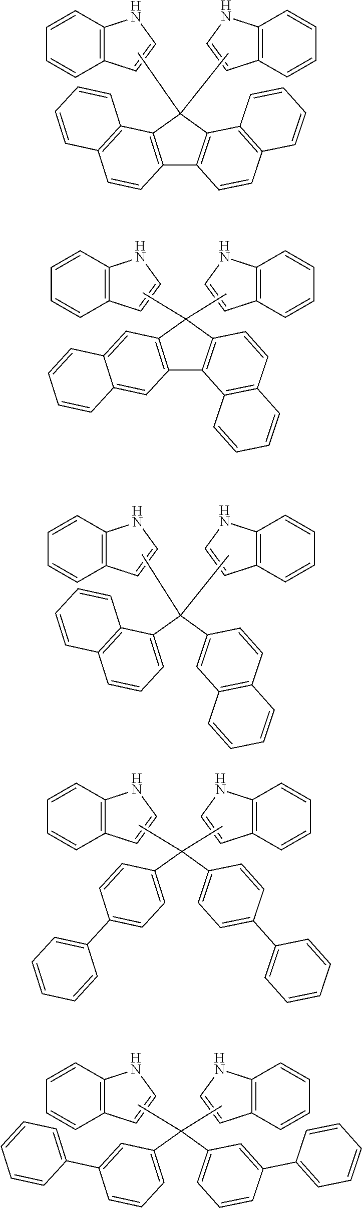

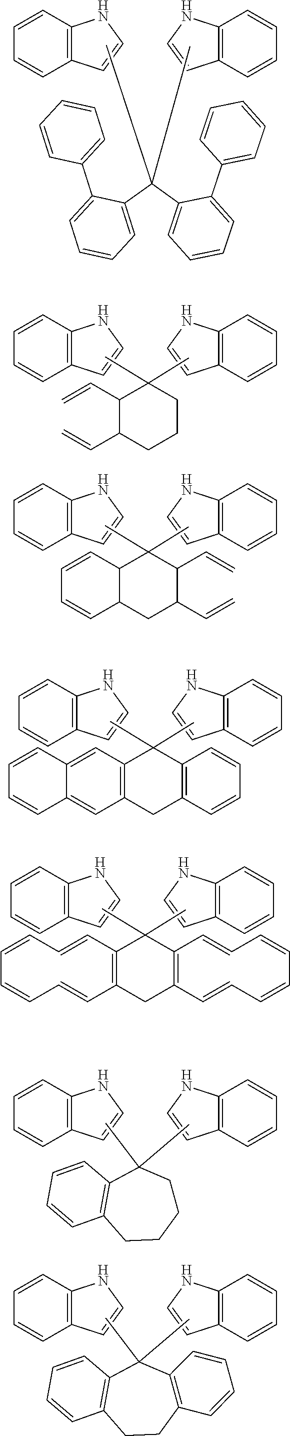

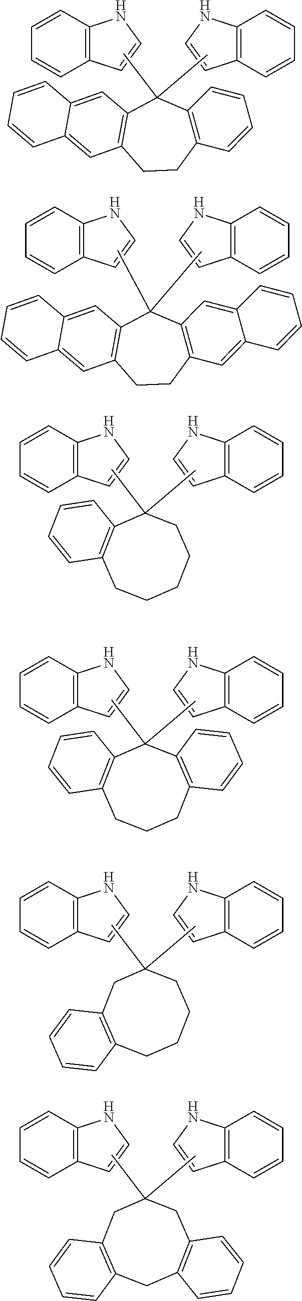

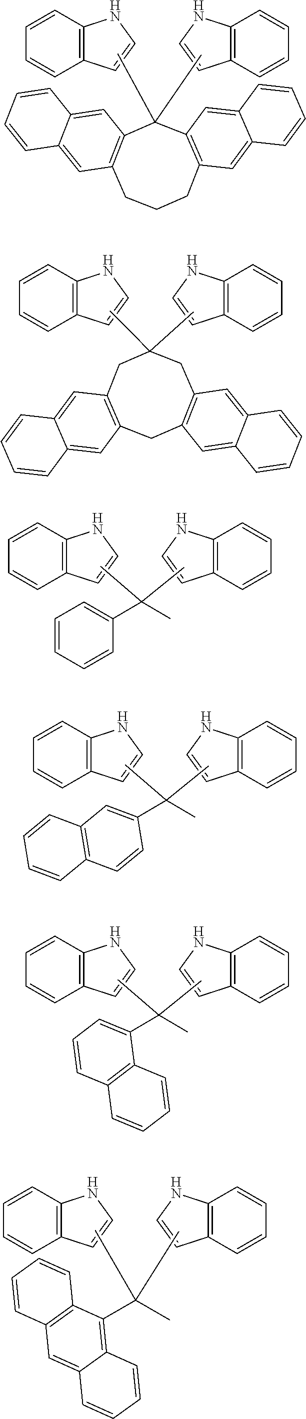

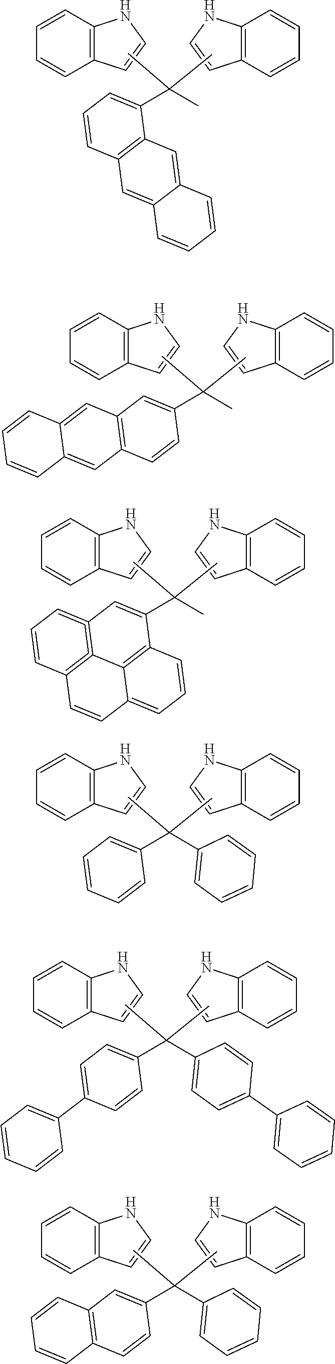

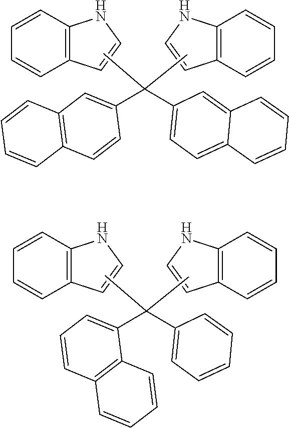

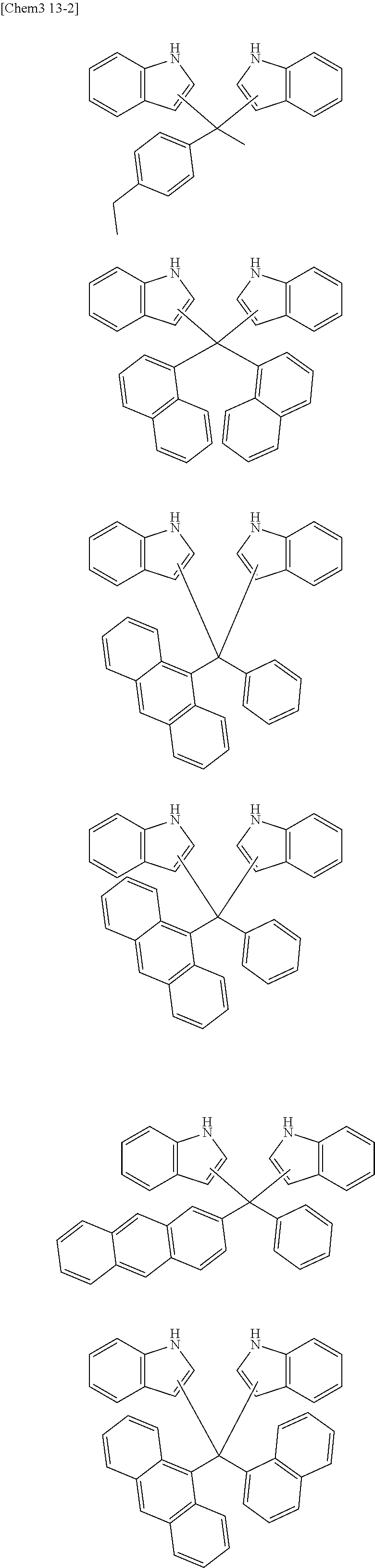

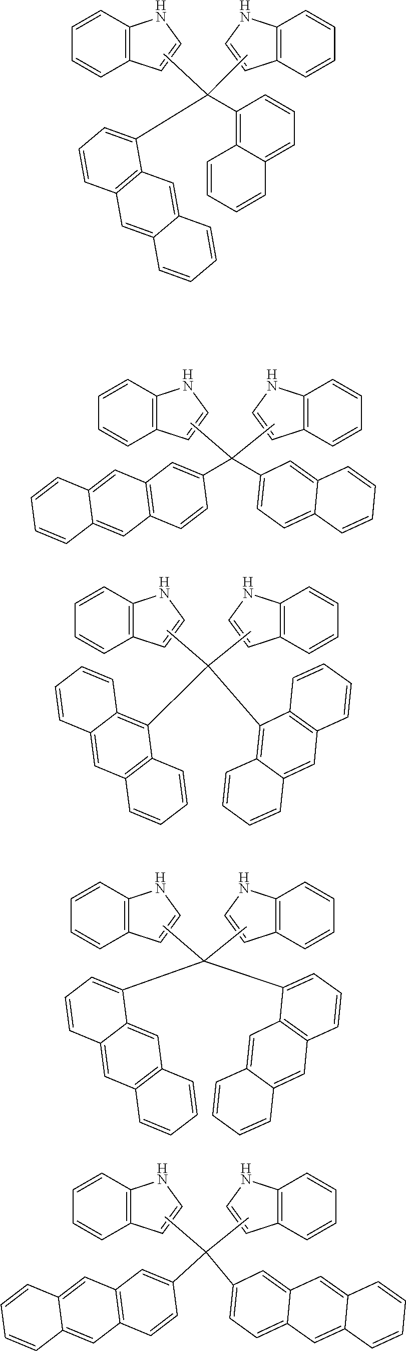

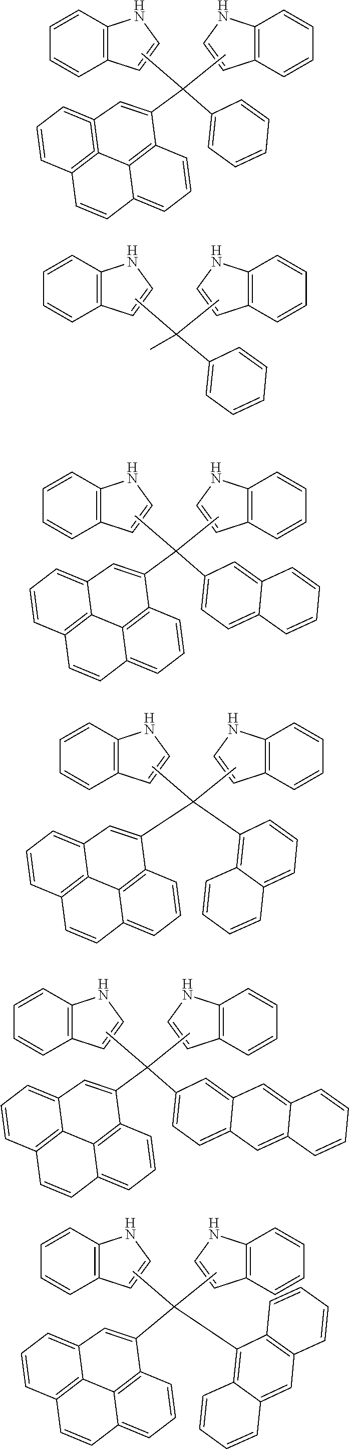

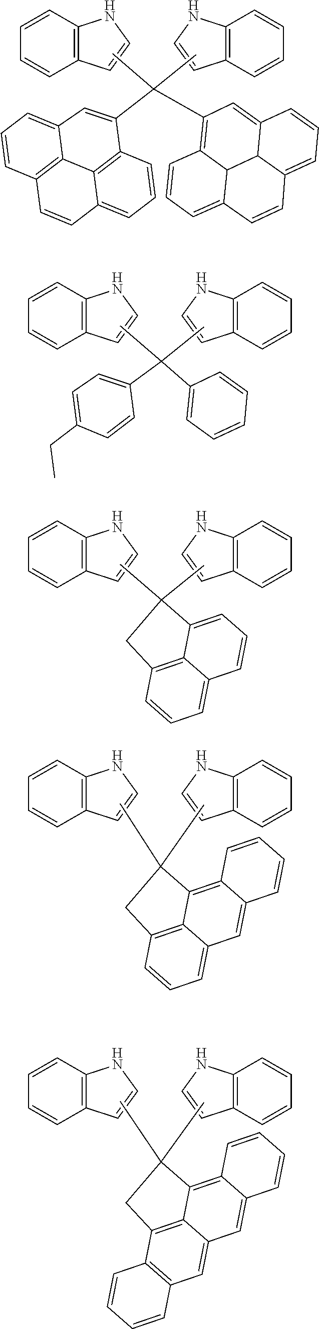

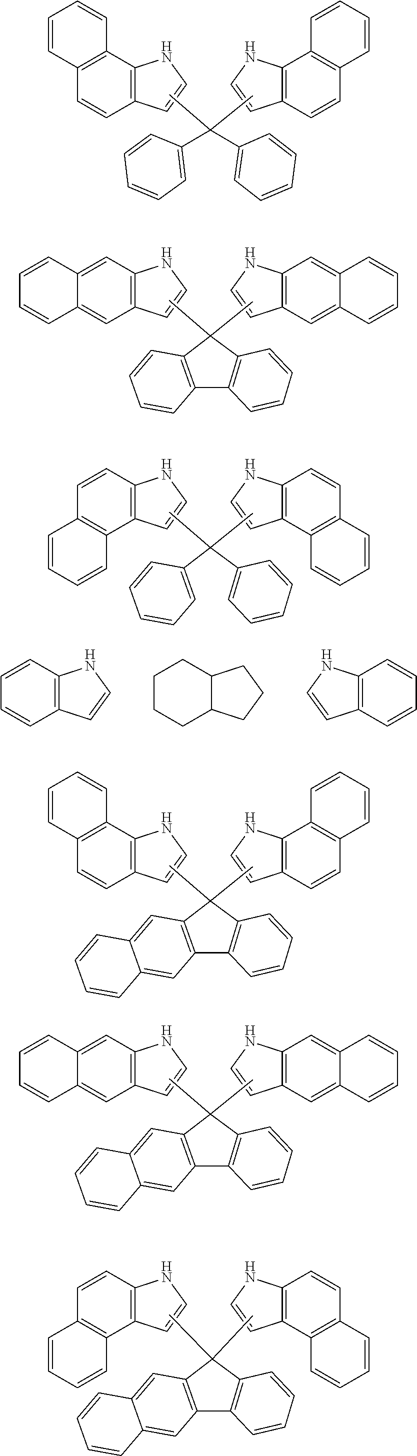

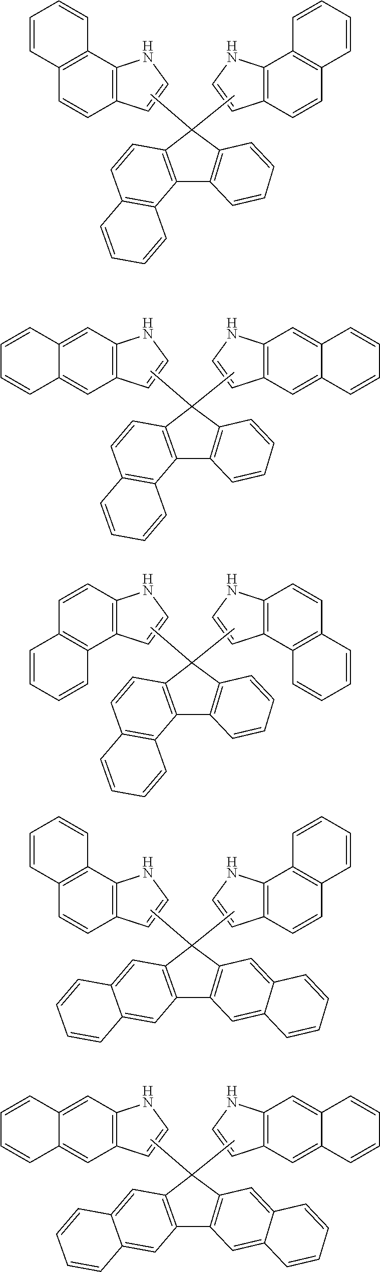

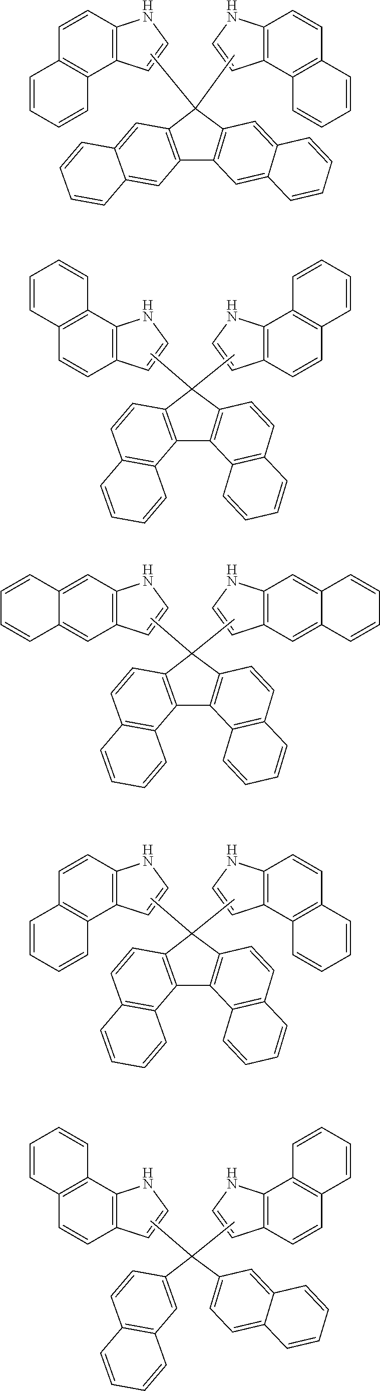

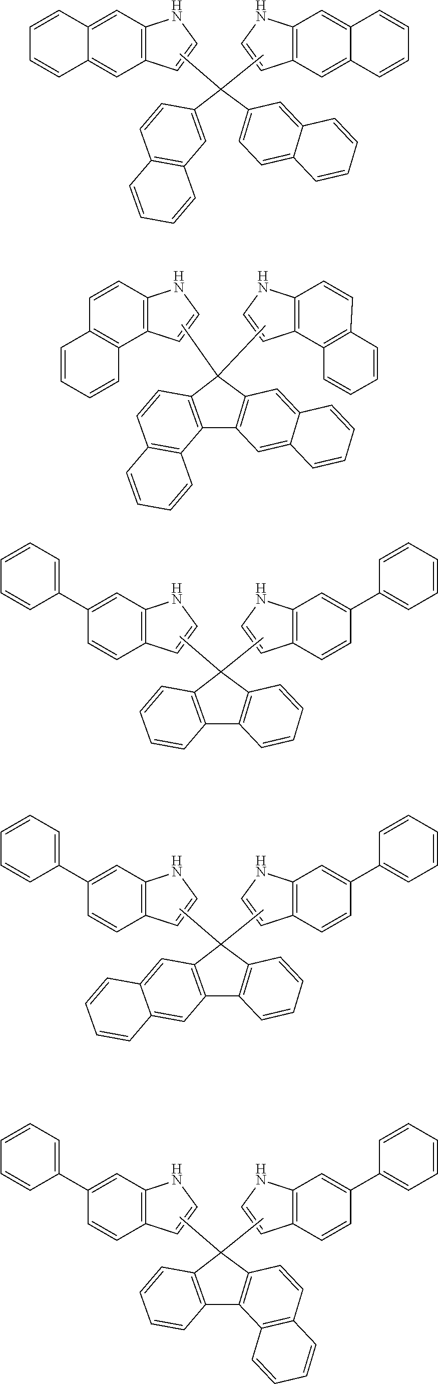

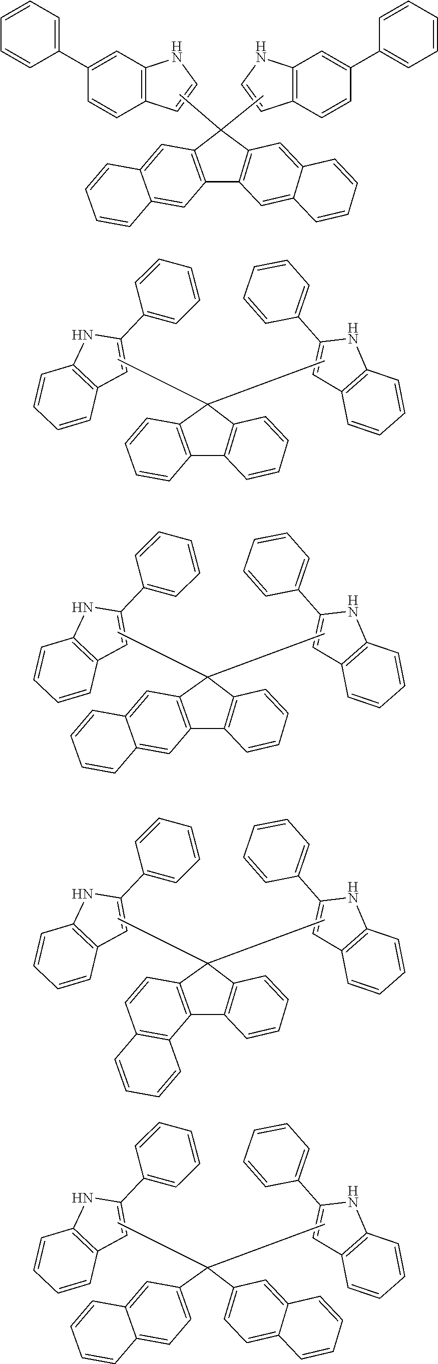

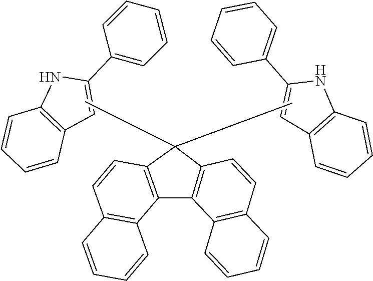

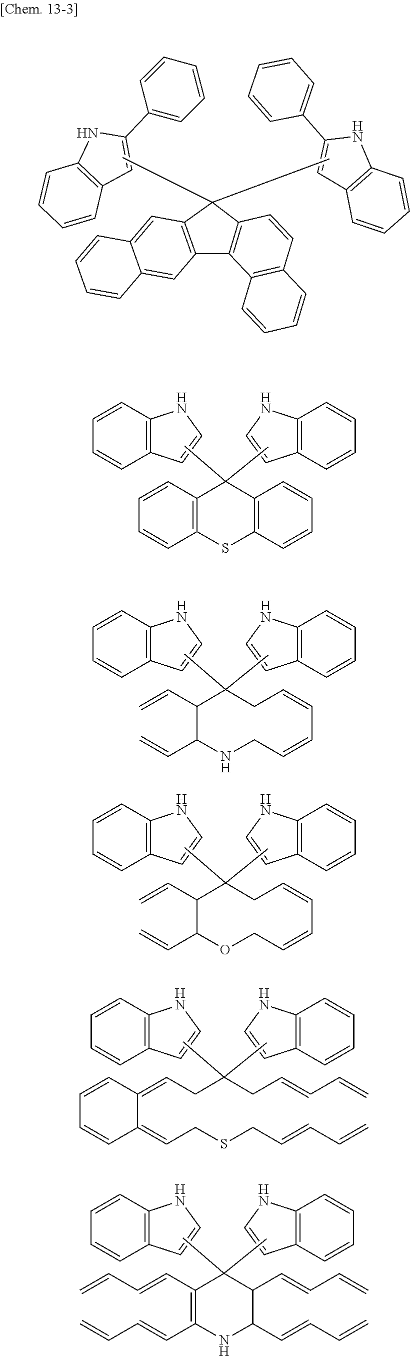

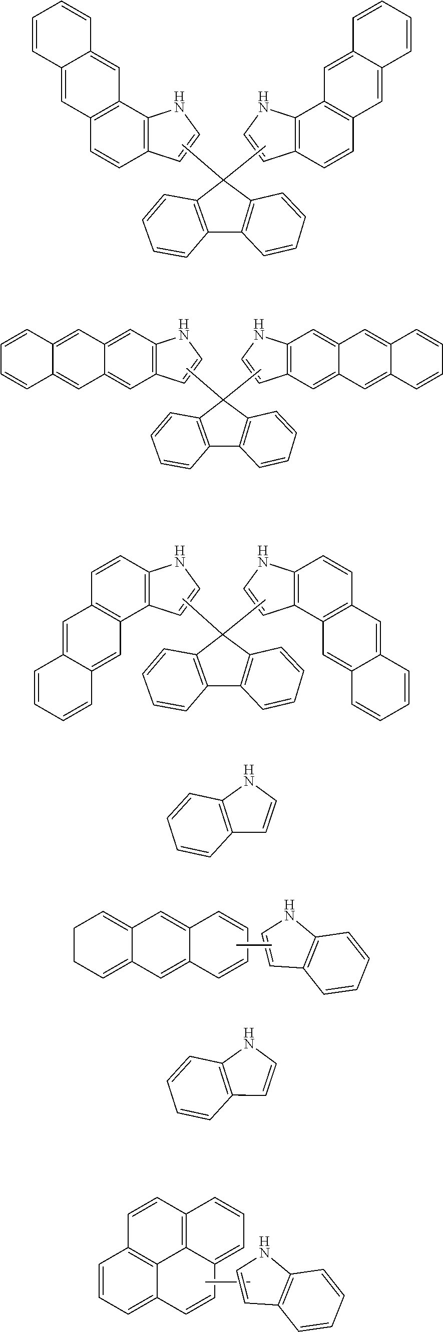

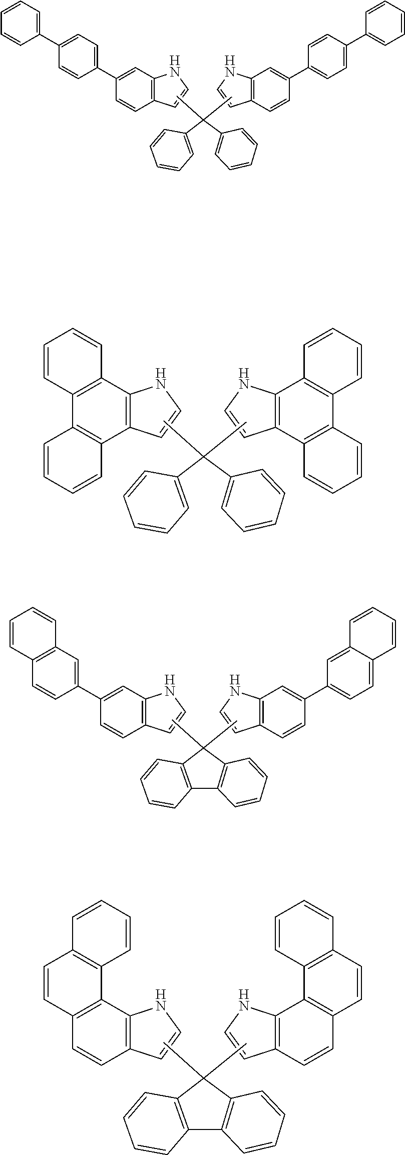

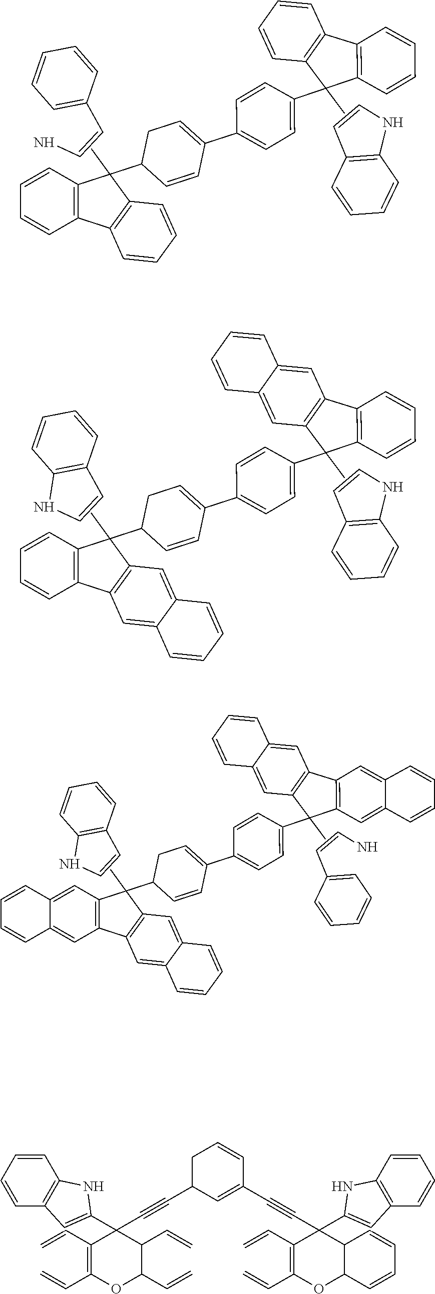

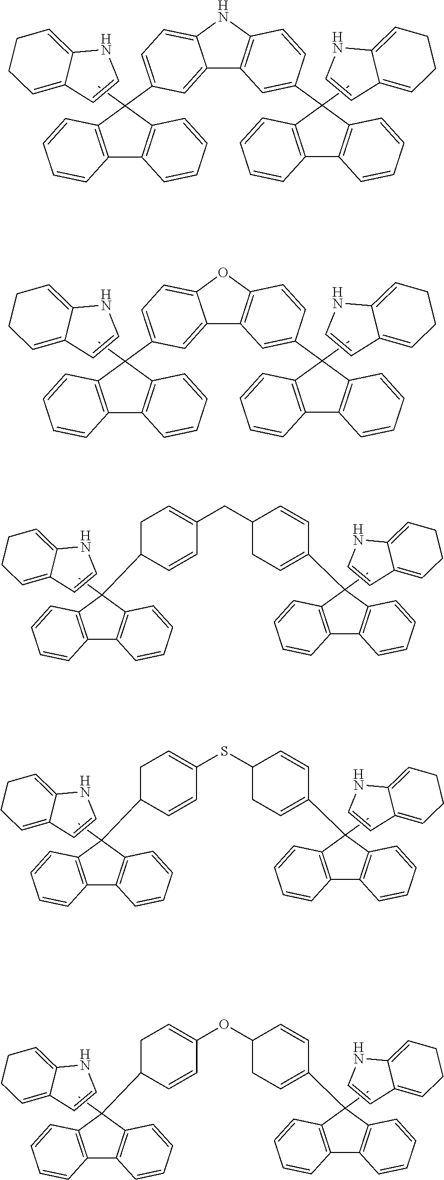

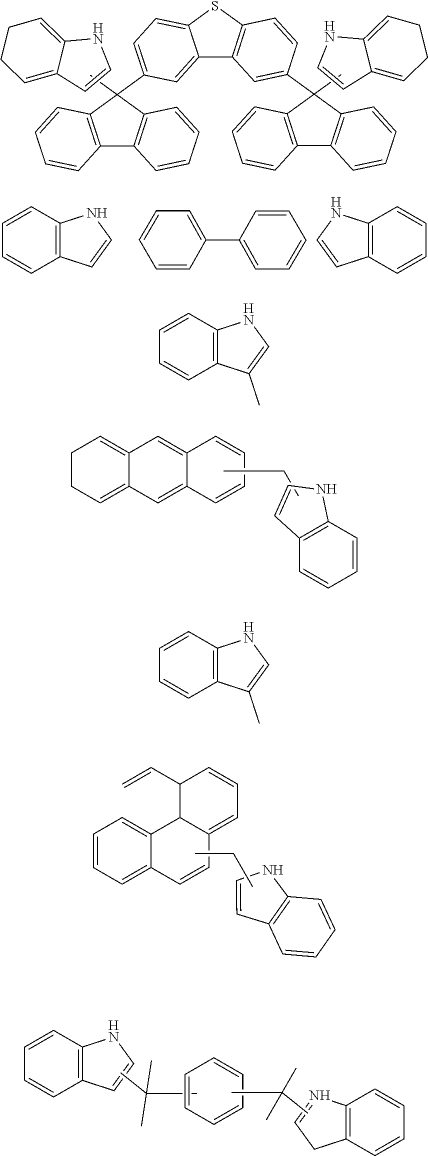

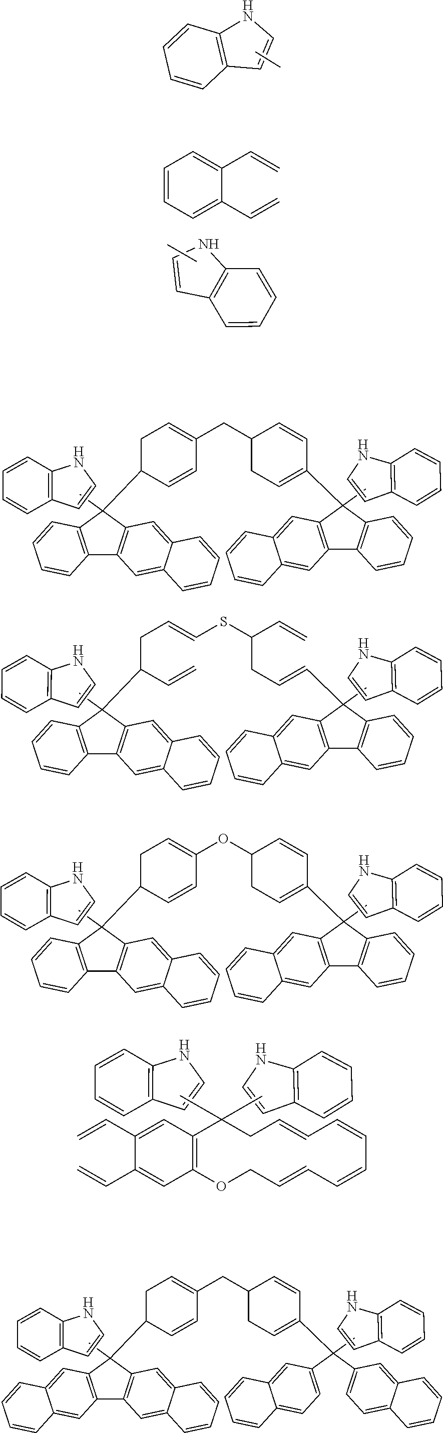

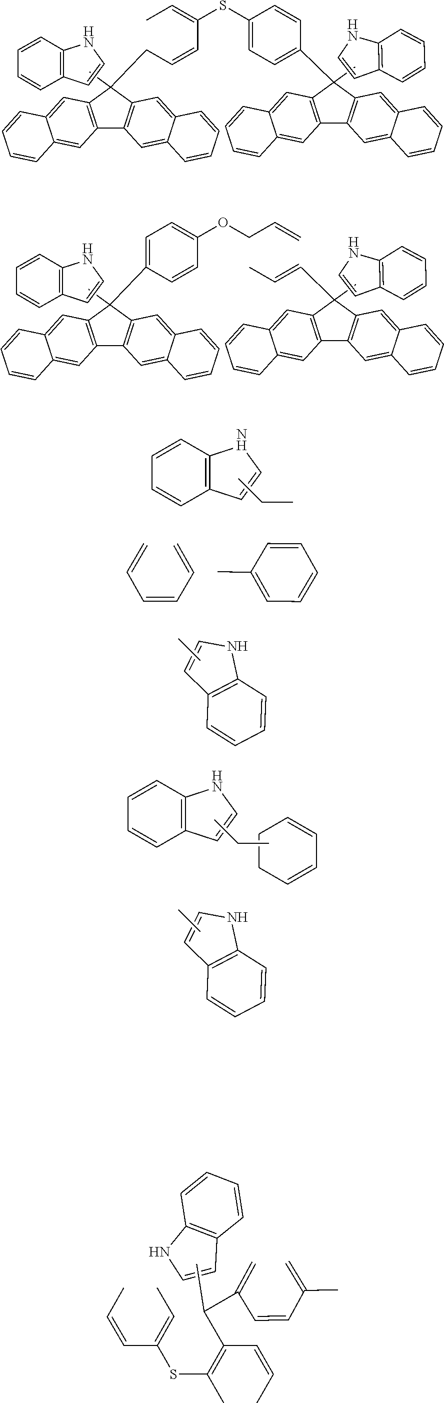

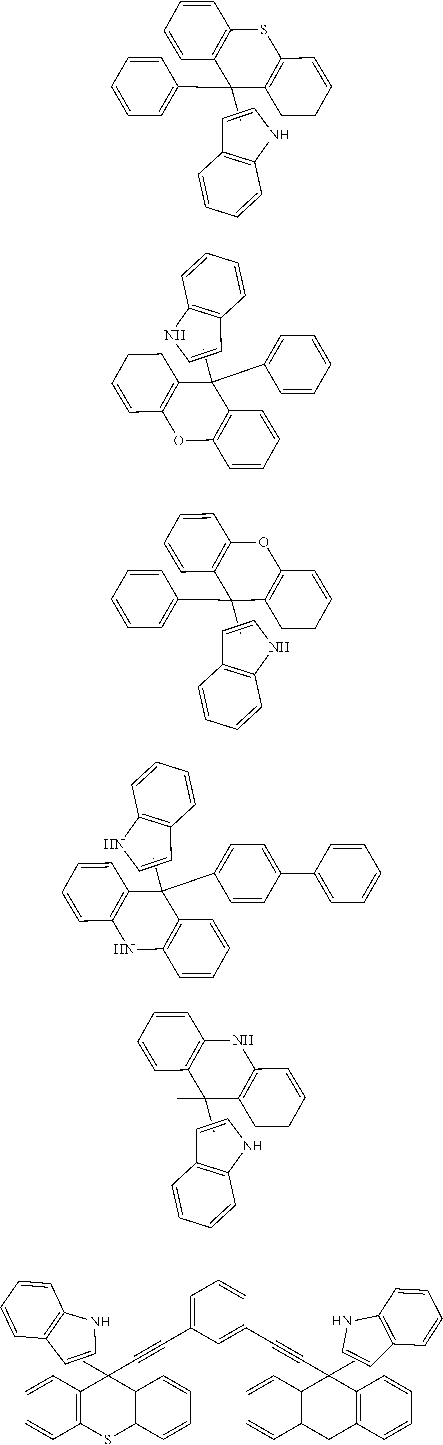

### (IIA-1-7)

The bis(azaaryl fused ring) that gives the unit structure A of the formula (A) may be synthesized by any known method. For example, such compounds may be synthesized using the following reactions.

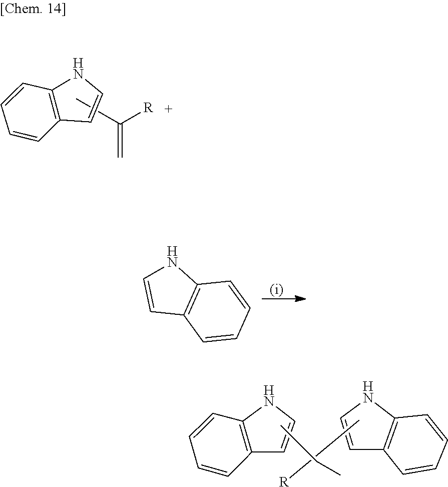

(i): Palladium (II) acetate (sodium triflate)

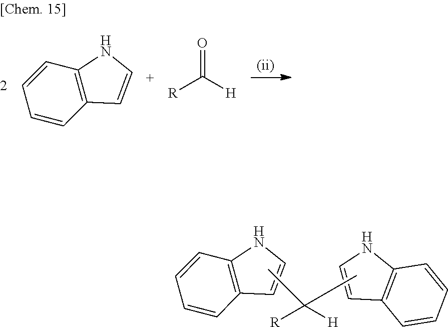

(ii): Sodium dodecyl sulfate, ytterbium triflate; or zirconium chloride

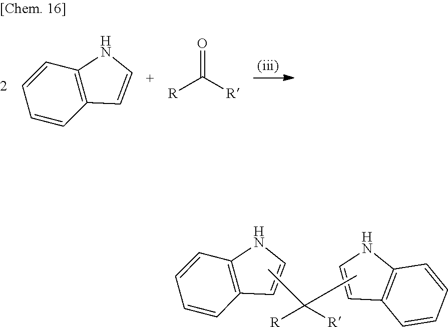

(iii): Trifluoroacetic acid or sulfuric acid

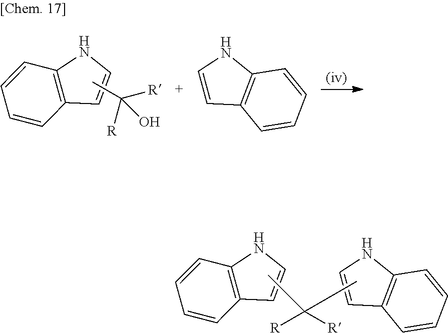

(iv): (S)-3,3′-bis(2,4,6-triisopropylphenyl)-1,1′-binaphthyl-2,2′-diyl hydrogen phosphate

### (IIA-1-8)

As long as the advantageous effects of the present invention are not impaired, the unit structures A may include one or more kinds of additional unit structures having an aromatic ring other than those of the formula (A) in (IIA-1).

The aromatic ring preferably has 6 to 30 carbon atoms, and more preferably 6 to 24 carbon atoms.

Preferably, the aromatic ring is one or more benzene, naphthalene, anthracene, or pyrene rings; or is a fused ring formed between a benzene ring, a naphthalene ring, an anthracene ring, or a pyrene ring and a heterocyclic ring or an aliphatic ring (such as a fluorene ring, a benzofluorene ring, a dibenzofluorene ring, an indole ring, a carbazole ring, or an indolocarbazole ring).

The aromatic ring may be optionally substituted, and the substituent preferably contains a heteroatom. The aromatic ring may include two or more aromatic rings connected to one another by a linking group, and the linking group preferably contains a heteroatom. Examples of the heteroatoms include an oxygen atom, a nitrogen atom, and a sulfur atom.

Preferably, the “aromatic ring” is a C6-C30 or C6-C24 organic group that contains at least one heteroatom selected from N, S, and O on the ring, within the ring, or between the rings.

Examples of the heteroatoms contained on the ring include a nitrogen atom contained in amino groups (for example, a propargylamino group) and in a cyano group; an oxygen atom contained in oxygen-containing substituents, such as a formyl group, a hydroxyl group, a carboxyl group, and alkoxy groups (for example, a propargyloxy group); and a nitrogen atom and oxygen atoms contained in a nitro group that is an oxygen-containing and nitrogen-containing substituent. Examples of the heteroatoms contained within the ring include an oxygen atom contained in xanthene and a nitrogen atom contained in carbazole. Examples of the heteroatoms contained in the linking group between two or more aromatic rings include nitrogen atoms, oxygen atoms, and sulfur atoms contained in —NH— bond, —NHCO— bond, —O— bond, —COO— bond, —CO— bond, —S— bond, —SS— bond, and —SO₂— bond. Preferably, the unit structure A is a unit structure that has an aromatic ring having an oxygen-containing substituent described above, a unit structure that has two or more aromatic rings connected to one another by —NH—, or a unit structure that has a fused ring formed between one or more aromatic hydrocarbon rings and one or more heterocyclic rings.

Examples of the skeletons that may be used in the unit structures A other than the formula (A) include the following skeletons. Unless otherwise specified, the compounds illustrated below may be substituted with substituents similar to the above-described substituents on the azaaryl groups. The number and the positions of hydroxyl groups in the compounds below are only illustrative, and any theoretically acceptable number of hydroxyl groups may be present at any positions where the substitution is theoretically possible.

### (Examples of Amine Skeletons)

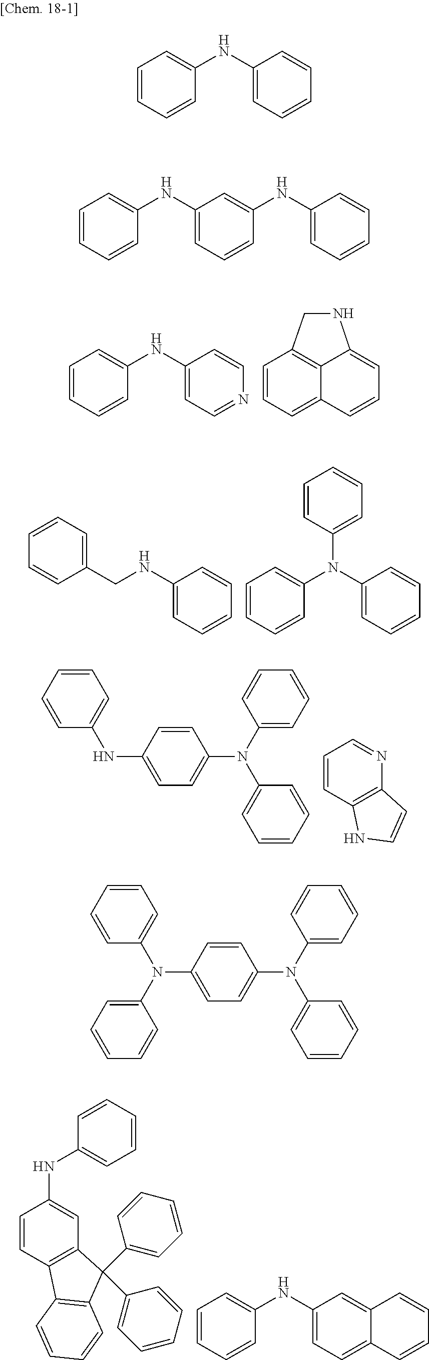

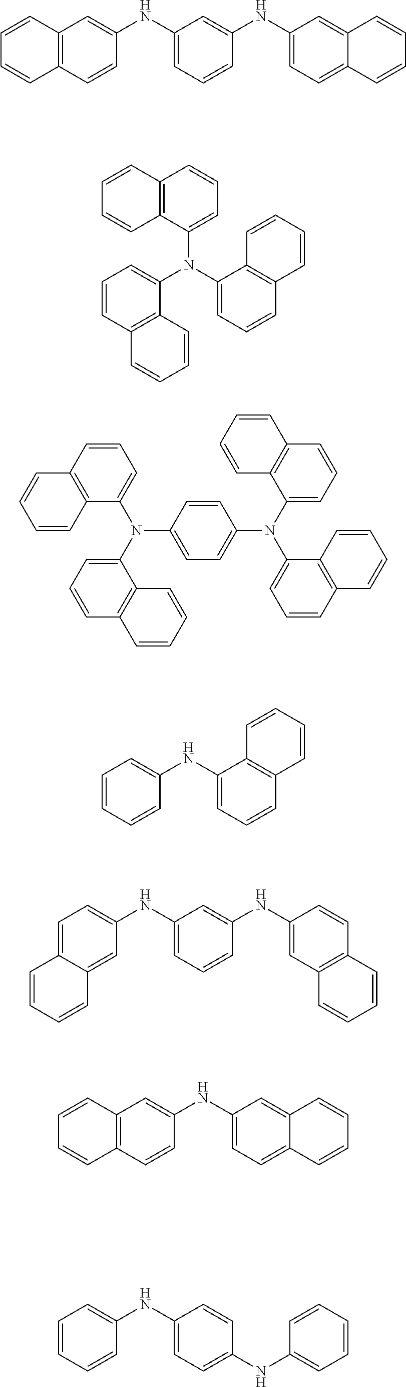

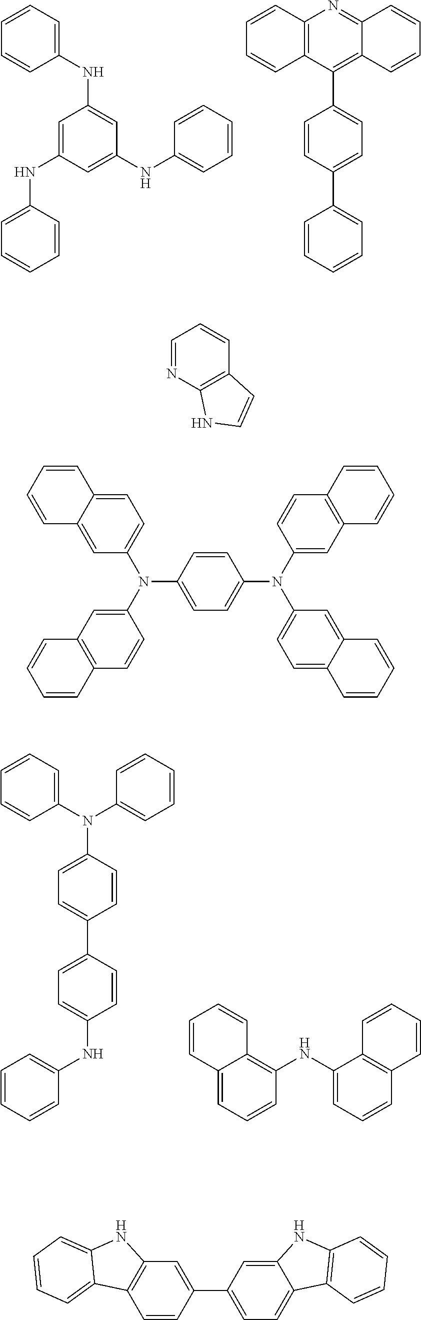

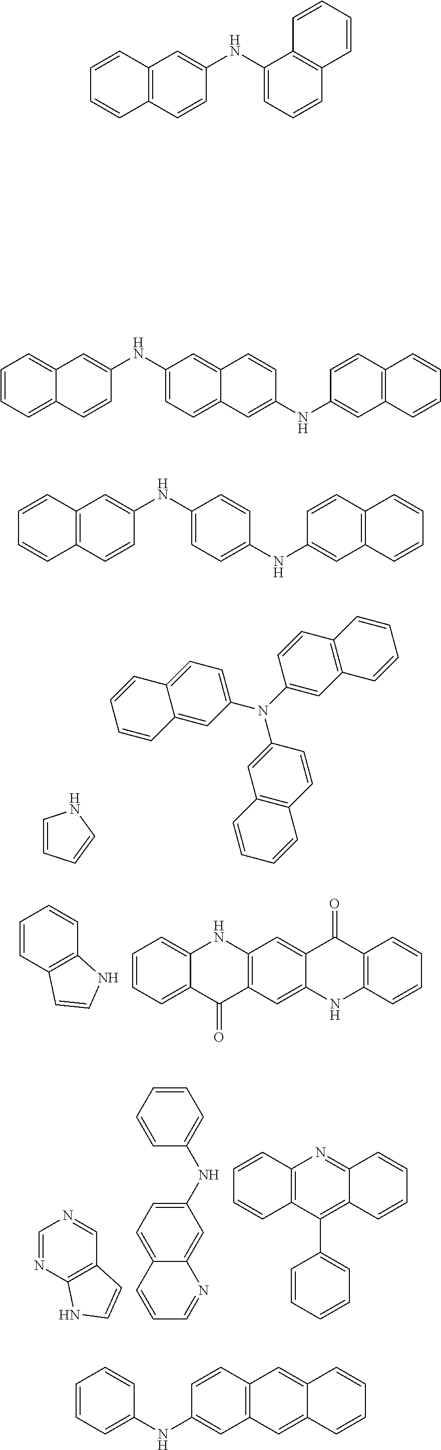

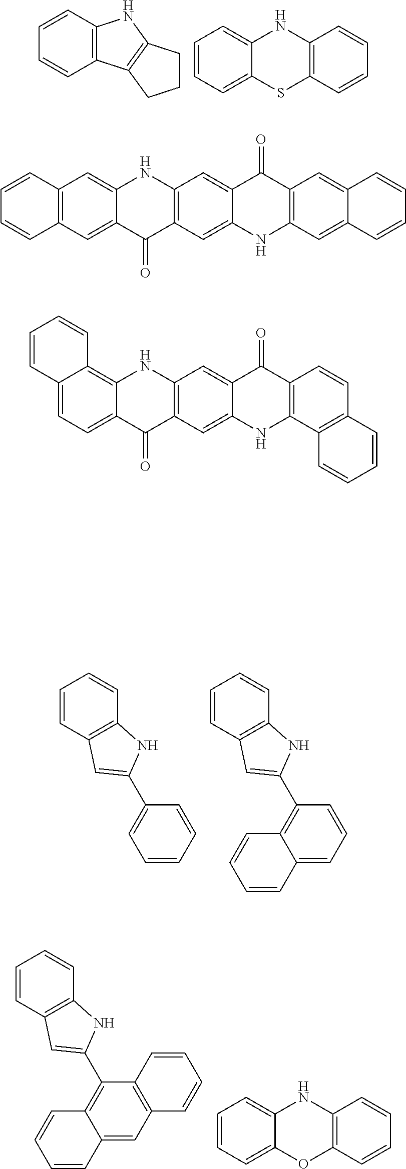

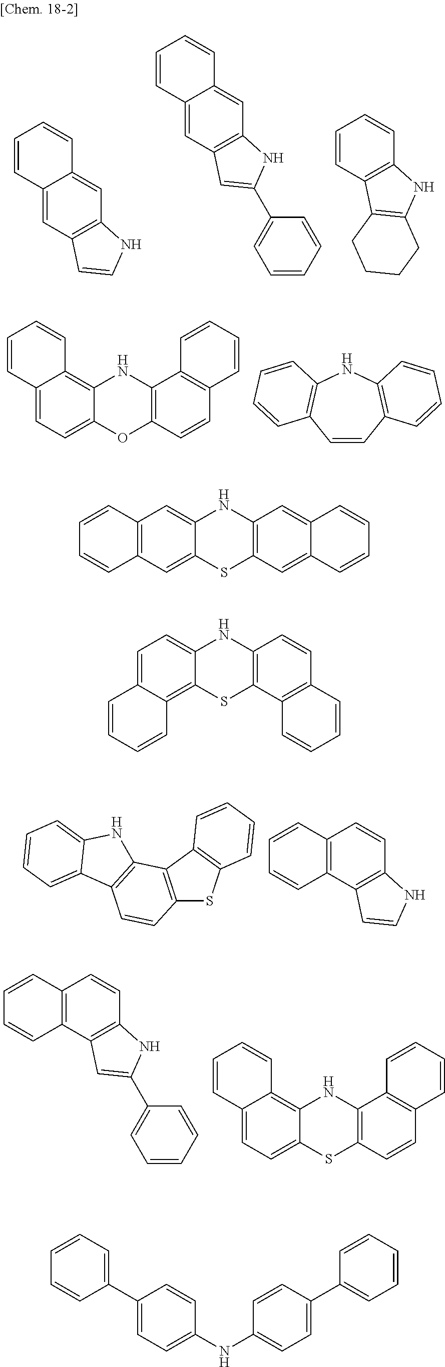

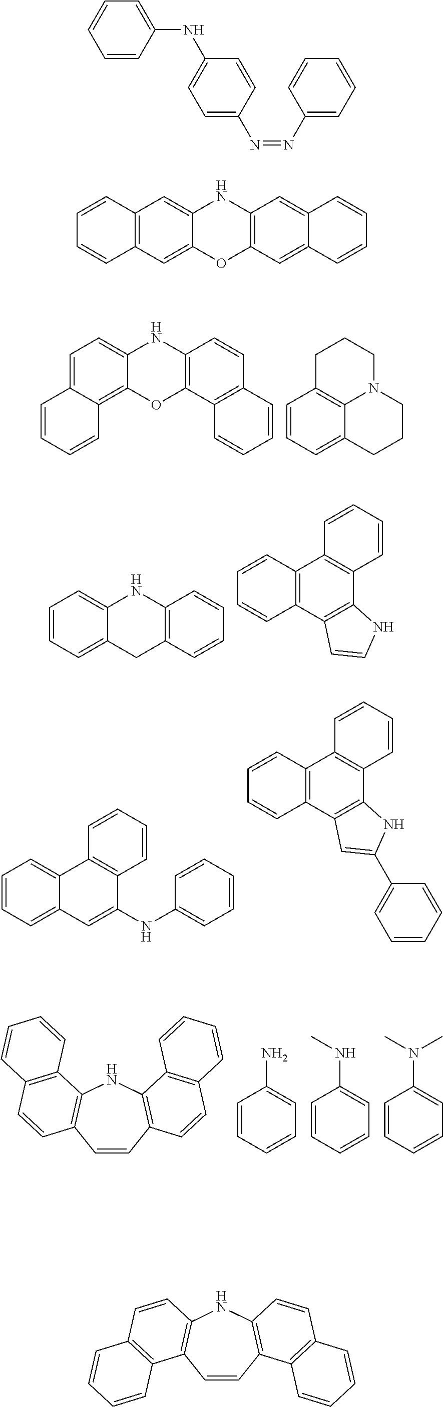

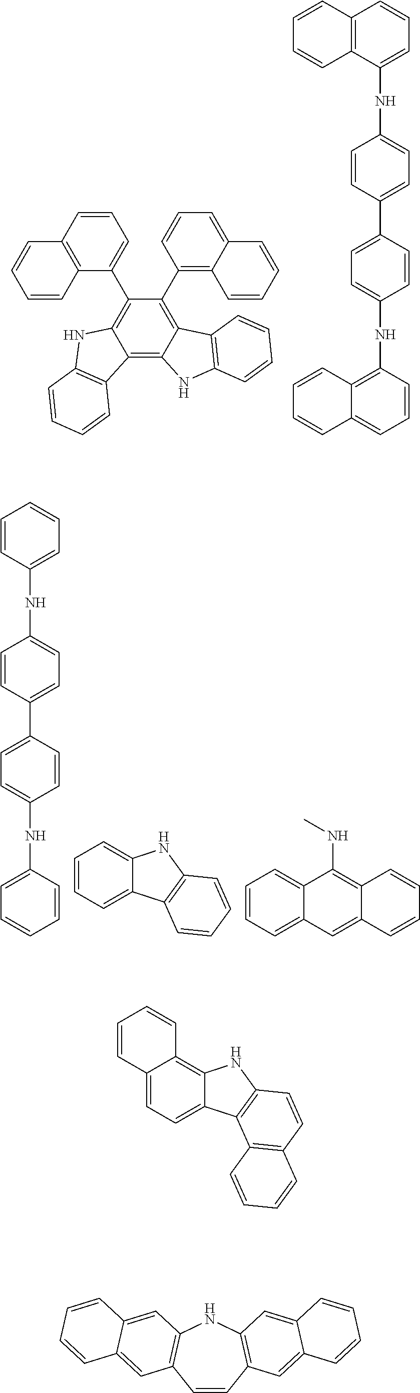

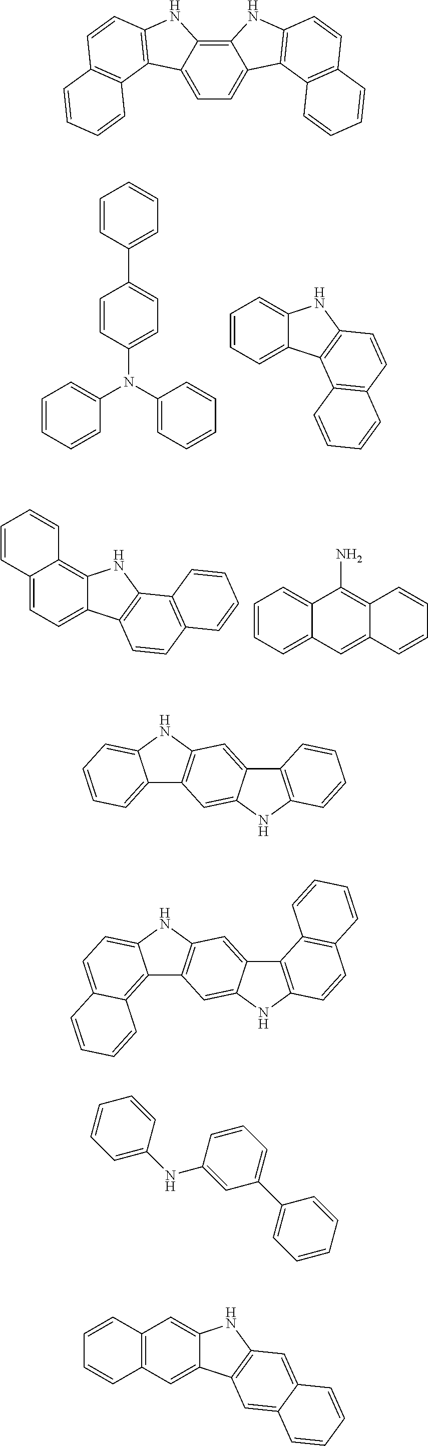

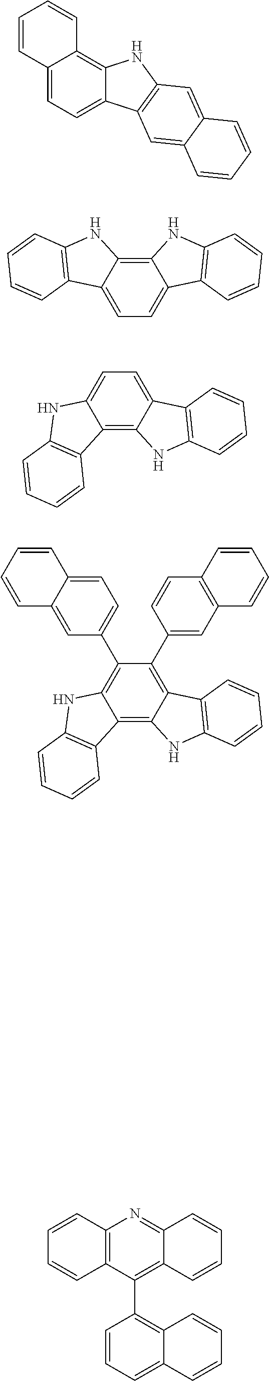

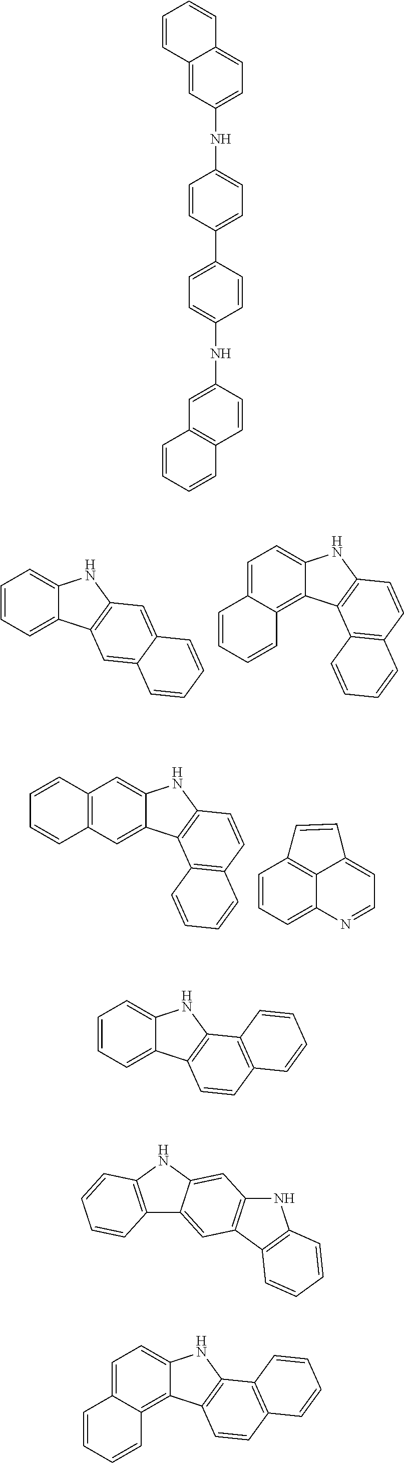

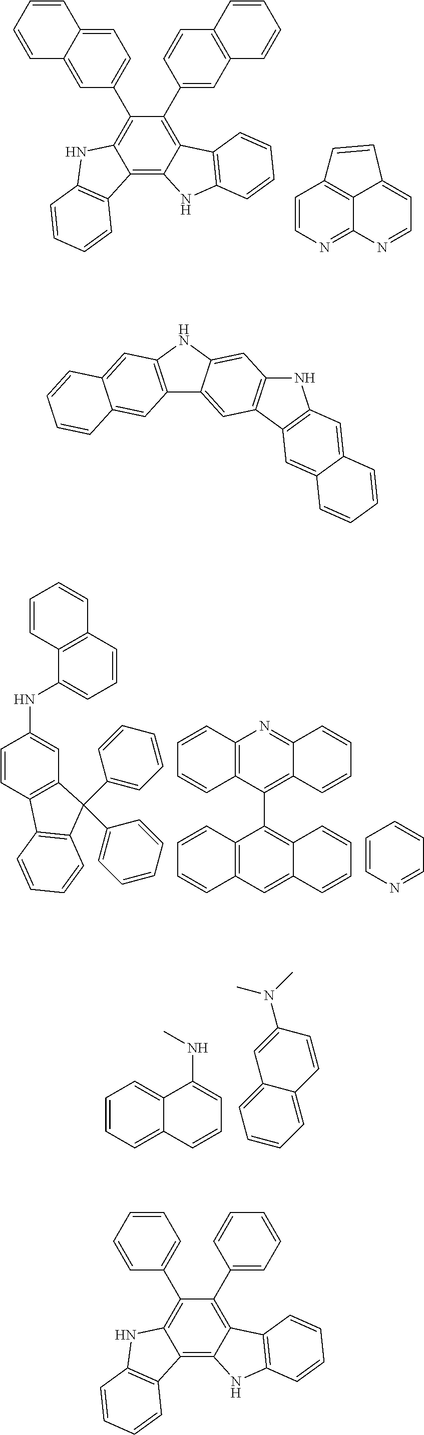

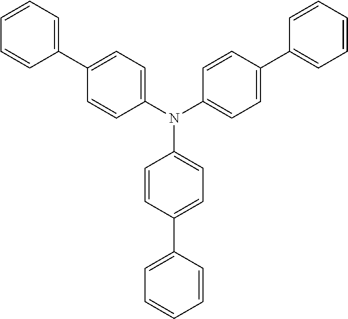 [SMILES: c1ccc(-c2ccc(N(c3ccc(-c4ccccc4)cc3)c3ccc(-c4ccccc4)cc3)cc2)cc1]

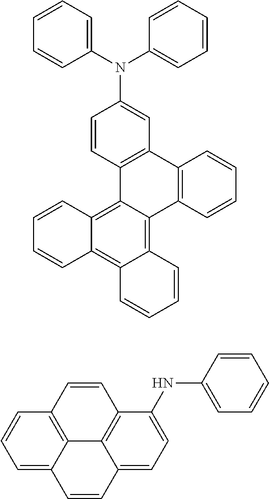 [SMILES: c1ccc(N(c2ccccc2)c2ccc3c(c2)c2ccccc2c2c4ccccc4c4ccccc4c32)cc1 ; c1ccc(Nc2ccc3ccc4cccc5ccc2c3c45)cc1]

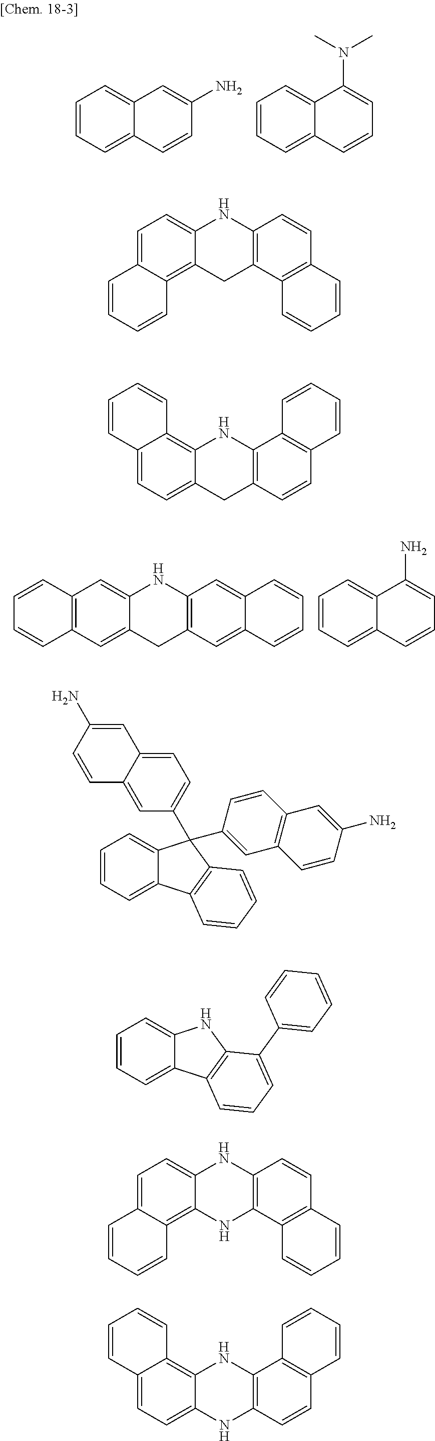

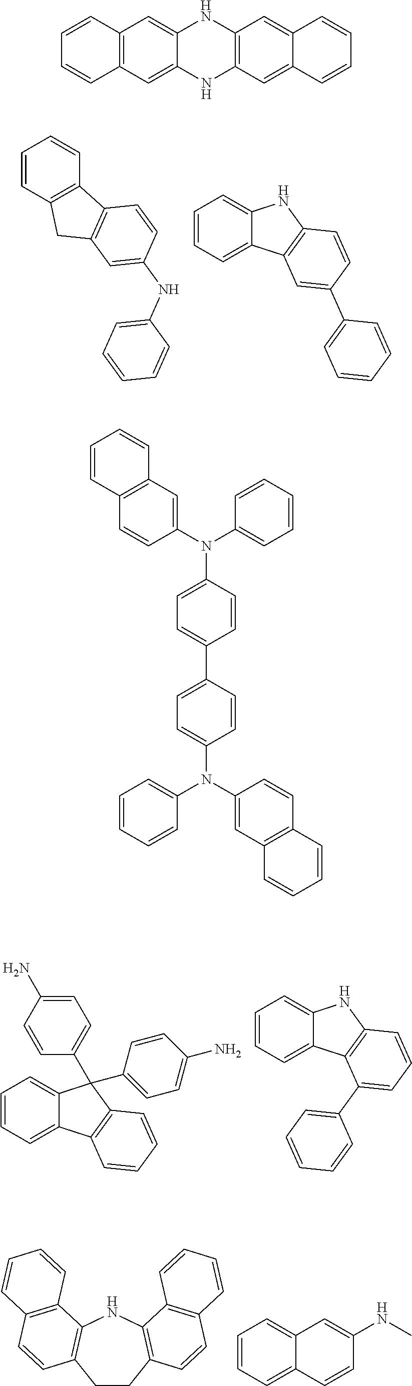

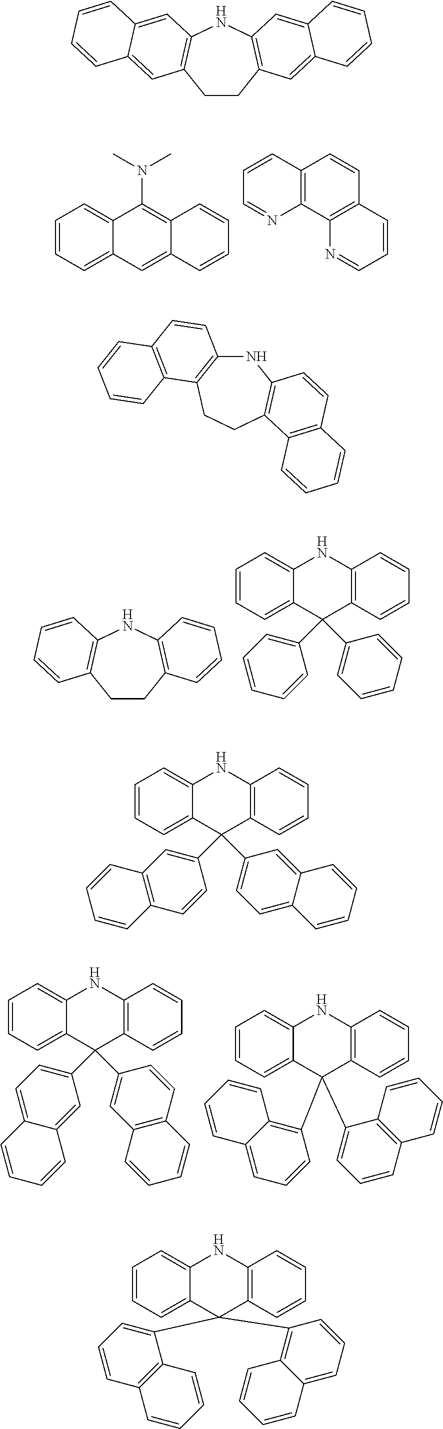

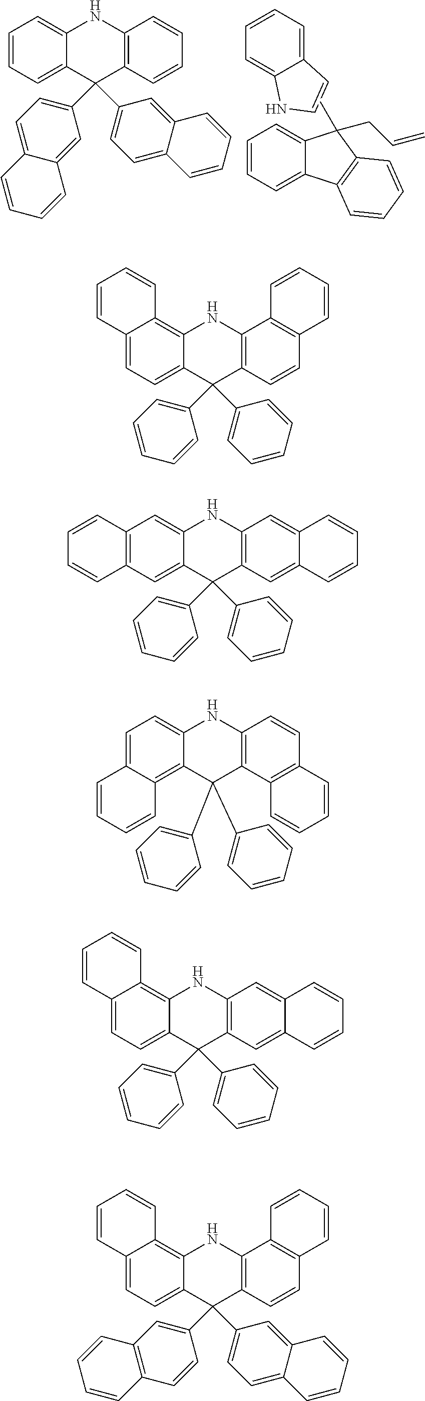

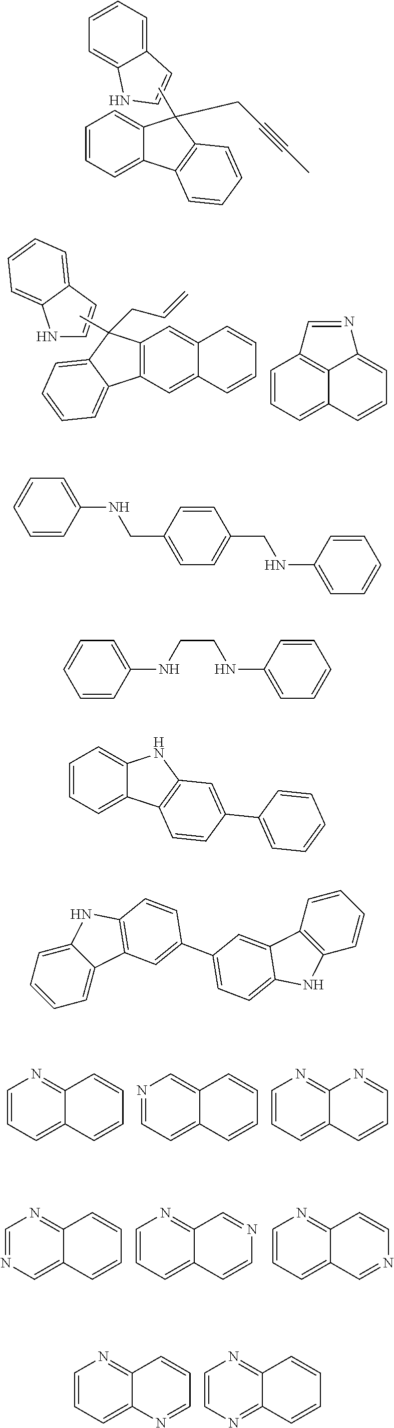

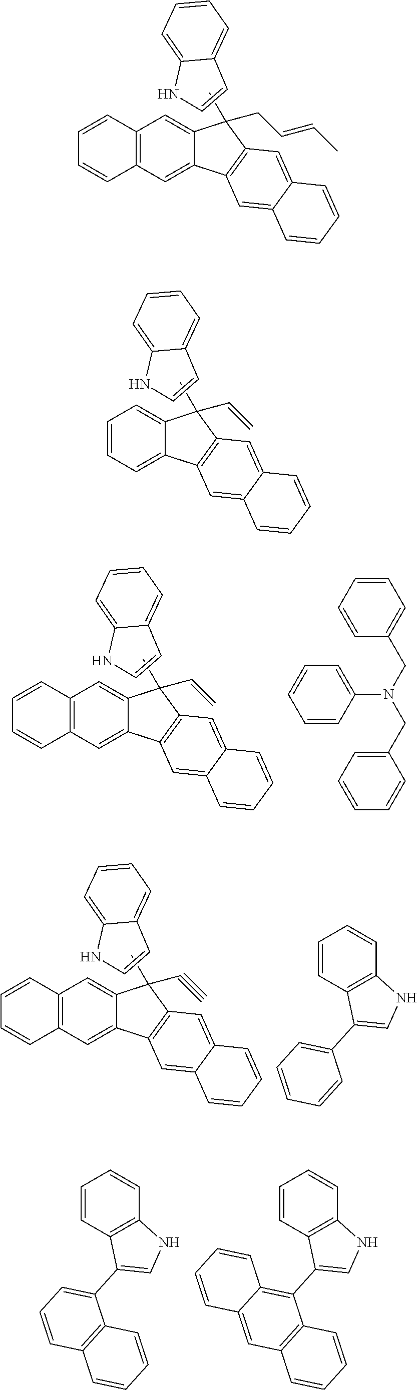

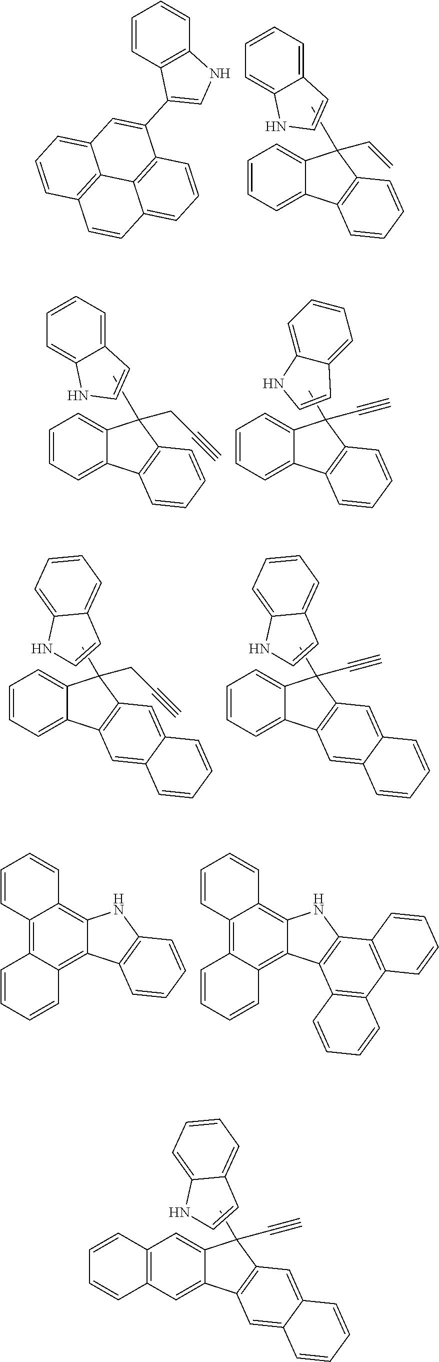

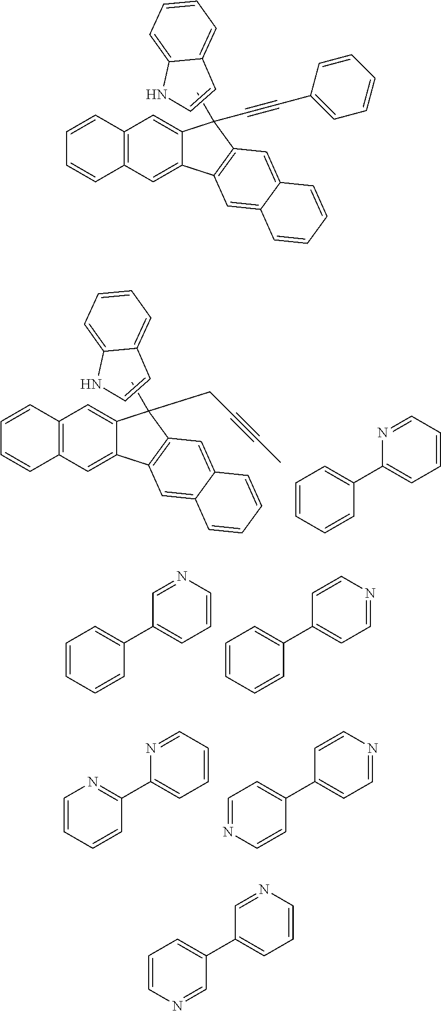

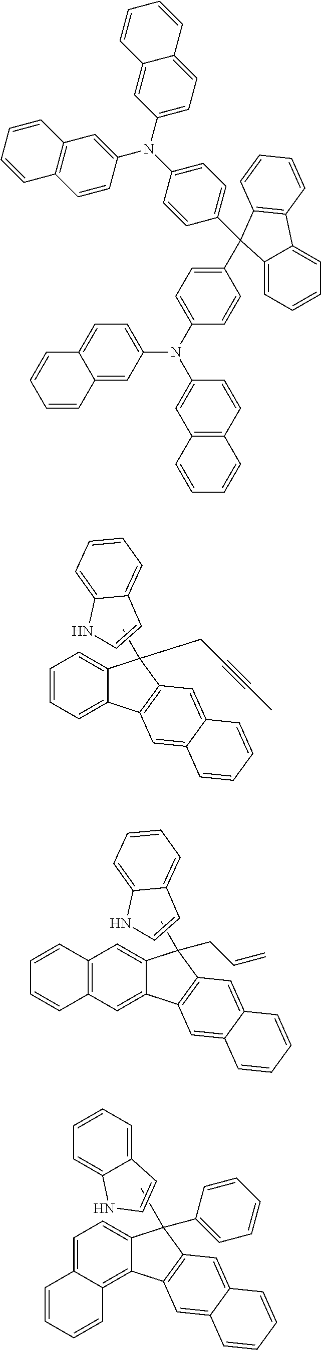

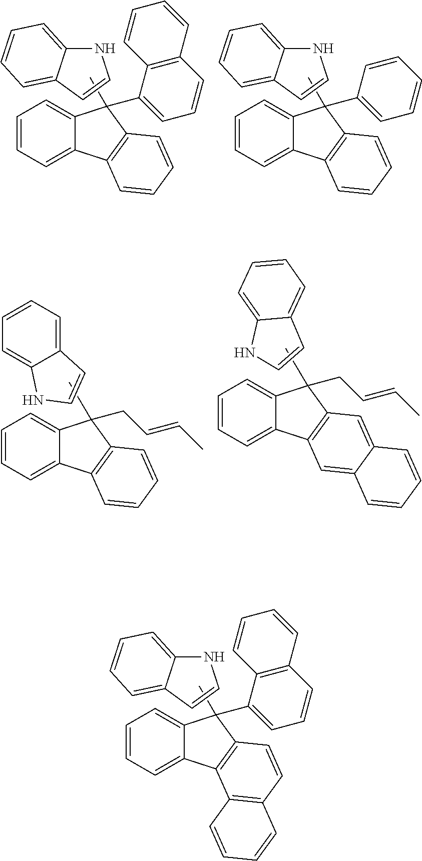

### (Examples of Phenol Skeletons)

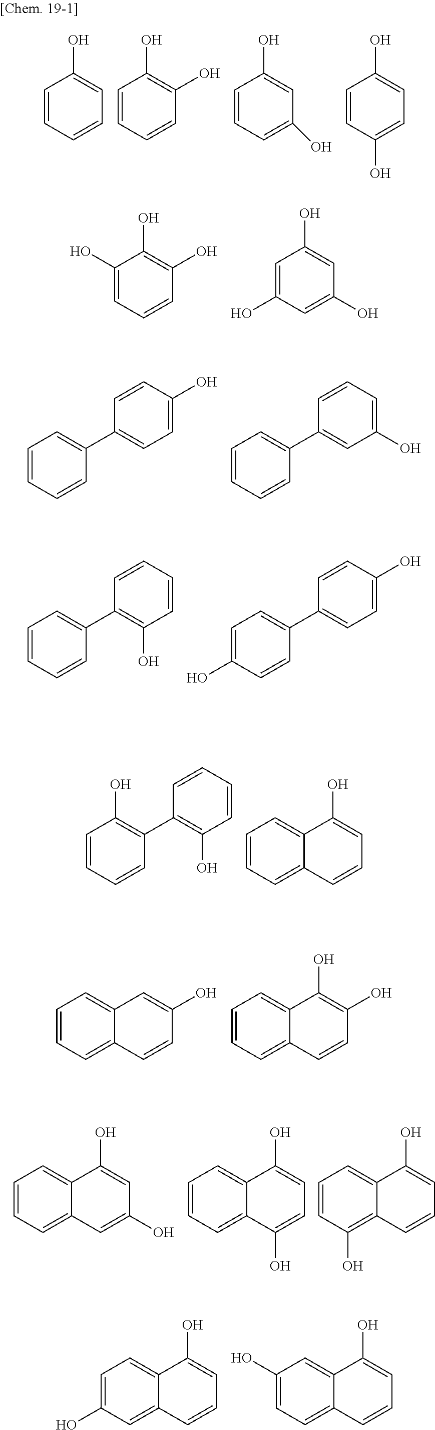

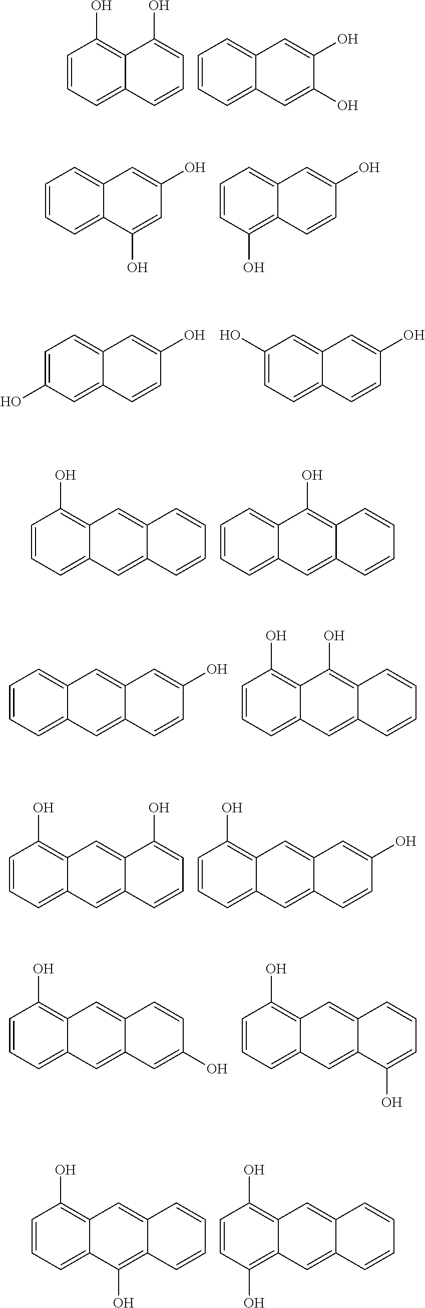

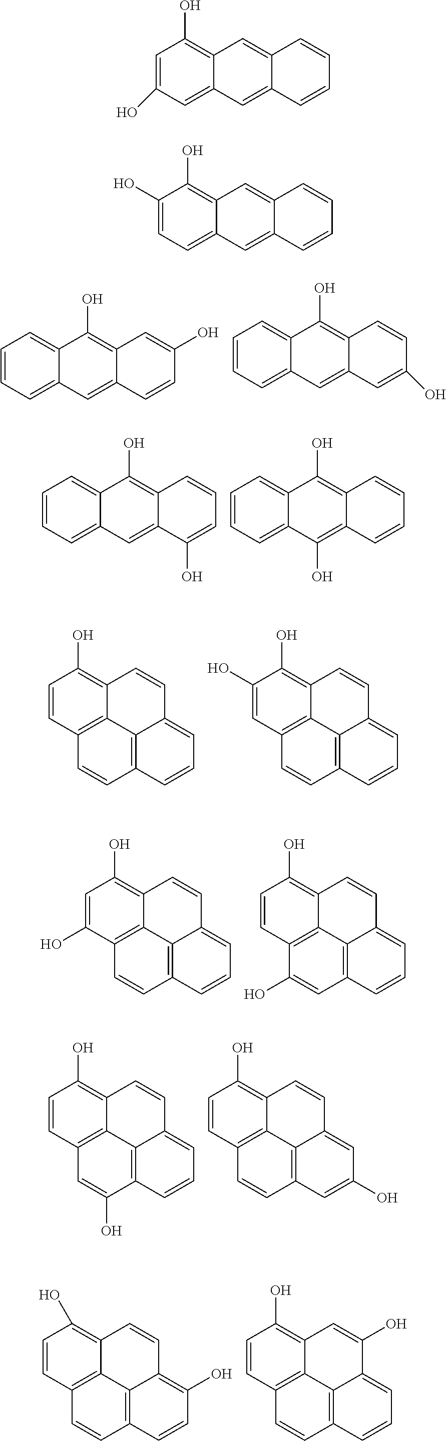

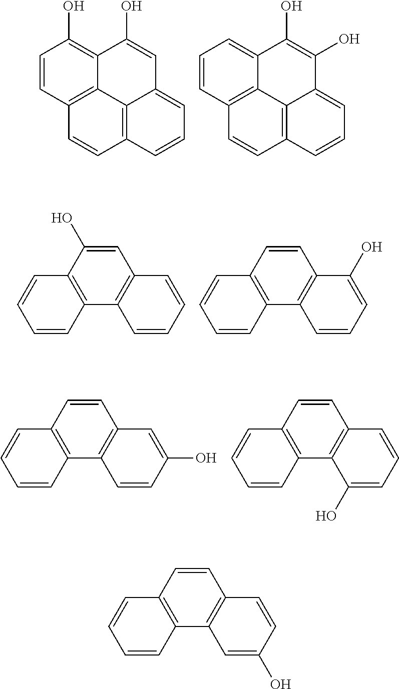

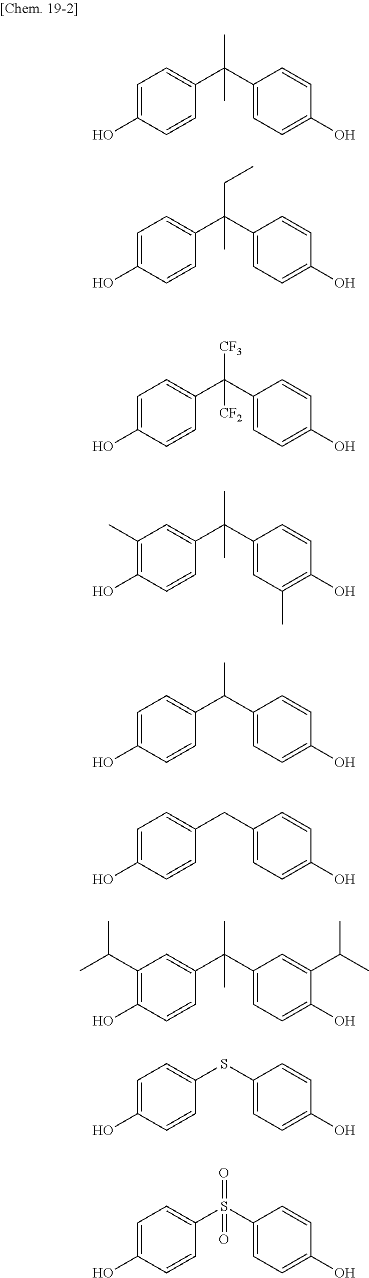

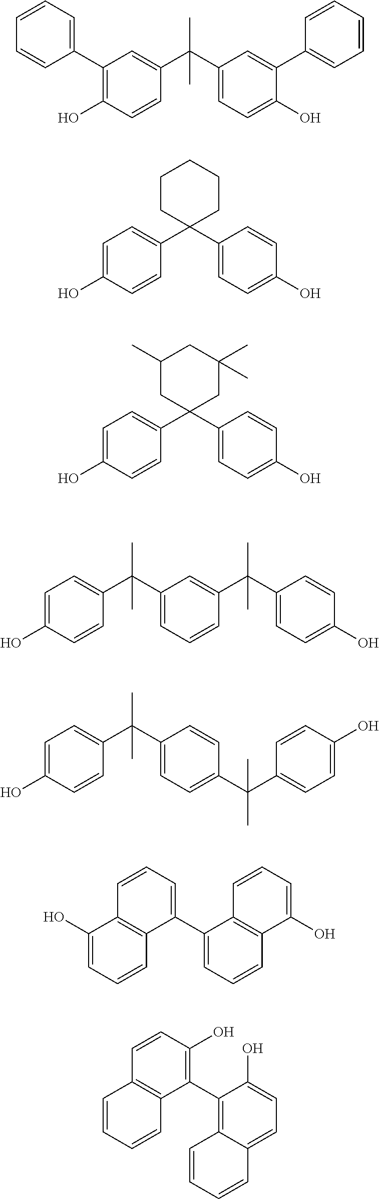

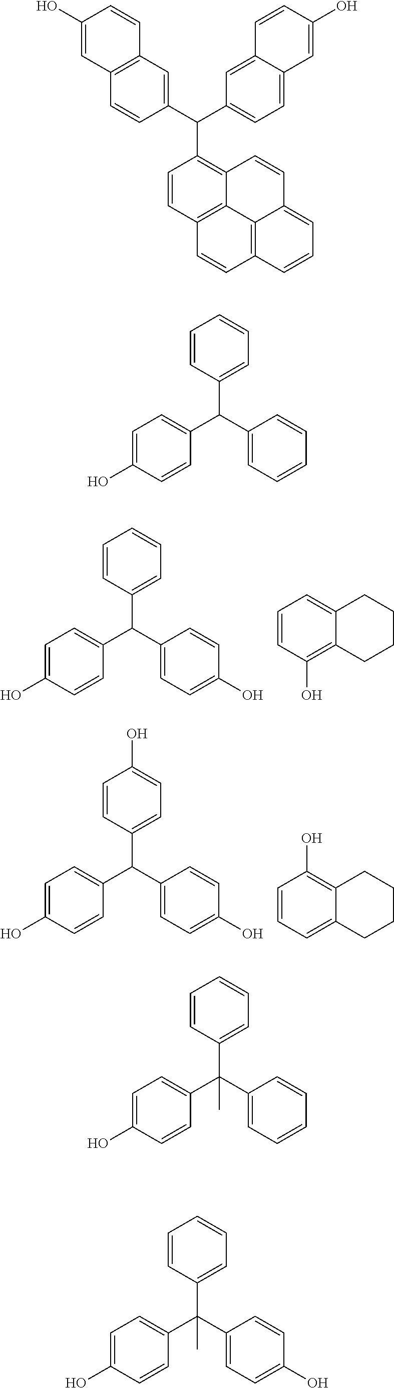

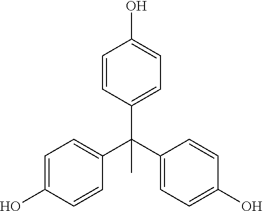 [SMILES: CC(c1ccc(O)cc1)(c1ccc(O)cc1)c1ccc(O)cc1]

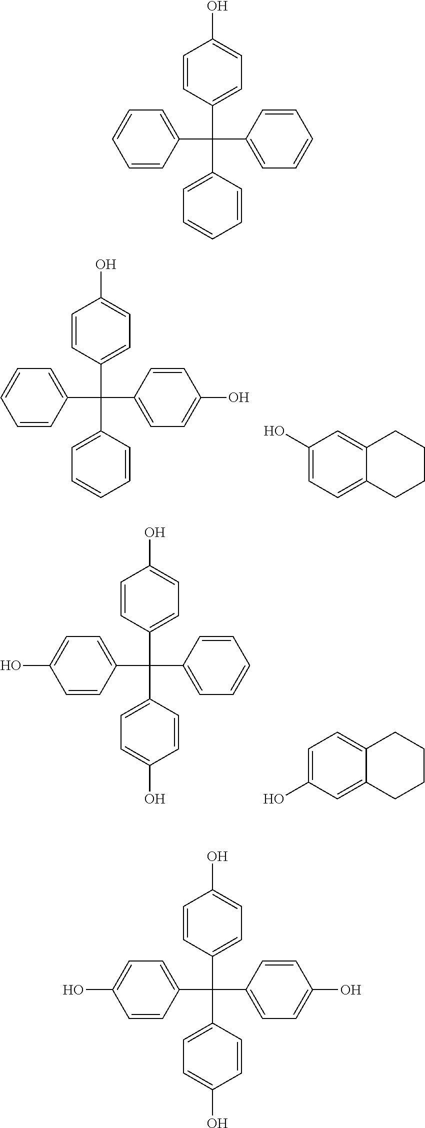 [SMILES: Oc1ccc(C(c2ccccc2)(c2ccccc2)c2ccccc2)cc1 ; Oc1ccc(C(c2ccccc2)(c2ccccc2)c2ccc(O)cc2)cc1 ; Oc1ccc2c(c1)CCCC2 ; Oc1ccc(C(c2ccccc2)(c2ccc(O)cc2)c2ccc(O)cc2)cc1 ; Oc1ccc2c(c1)CCCC2 ; Oc1ccc(C(c2ccc(O)cc2)(c2ccc(O)cc2)c2ccc(O)cc2)cc1]

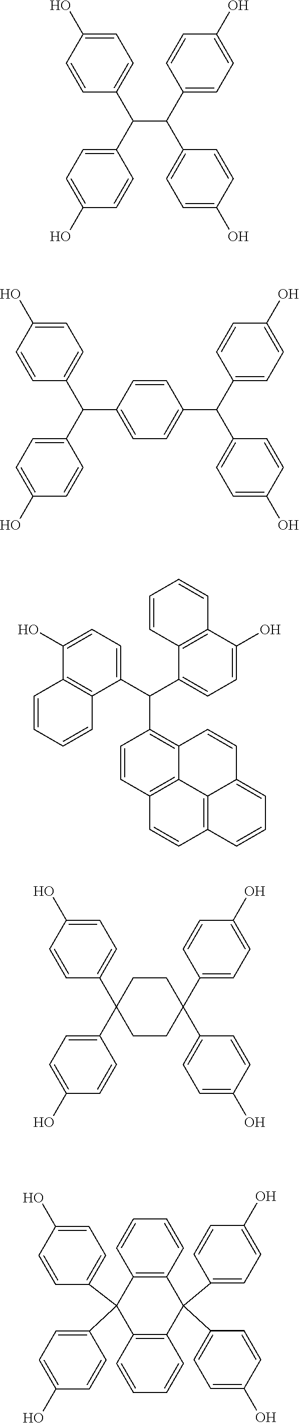 [SMILES: Oc1ccc(C(c2ccc(O)cc2)C(c2ccc(O)cc2)c2ccc(O)cc2)cc1 ; Oc1ccc(C(c2ccc(O)cc2)c2ccc(C(c3ccc(O)cc3)c3ccc(O)cc3)cc2)cc1 ; Oc1ccc(C(c2ccc(O)c3ccccc23)c2ccc3ccc4cccc5ccc2c3c45)c2ccccc12 ; Oc1ccc(C2(c3ccc(O)cc3)CCC(c3ccc(O)cc3)(c3ccc(O)cc3)CC2)cc1 ; Oc1ccc(C2(c3ccc(O)cc3)c3ccccc3C(c3ccc(O)cc3)(c3ccc(O)cc3)c3ccccc32)cc1]

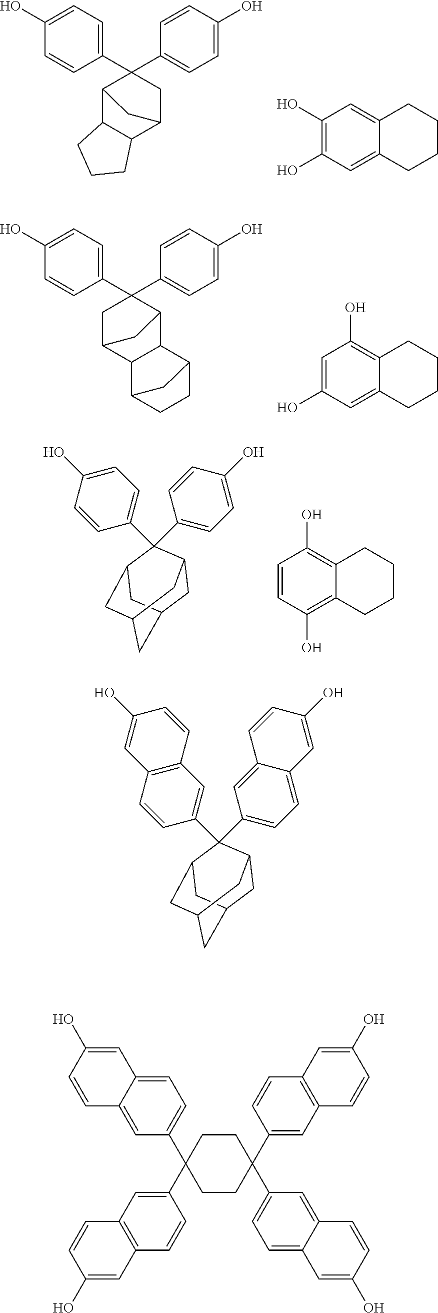

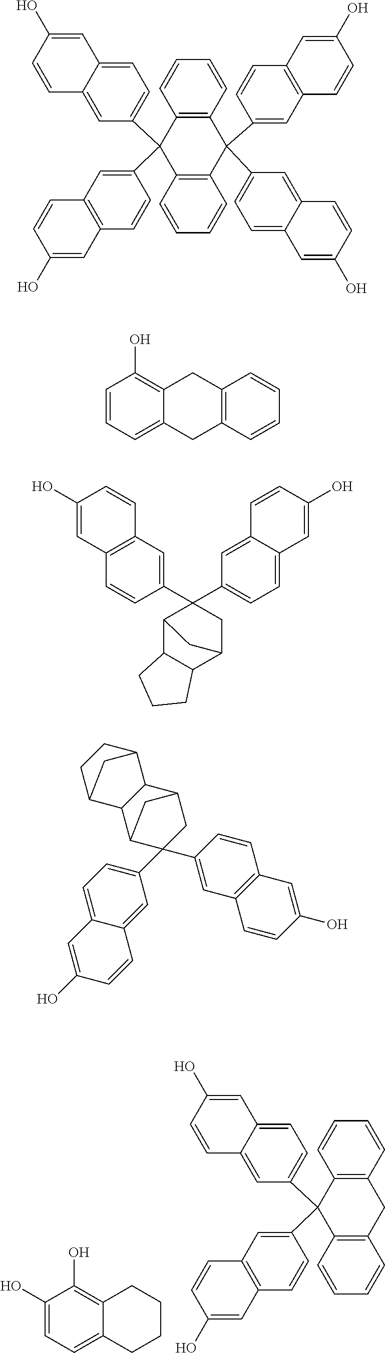

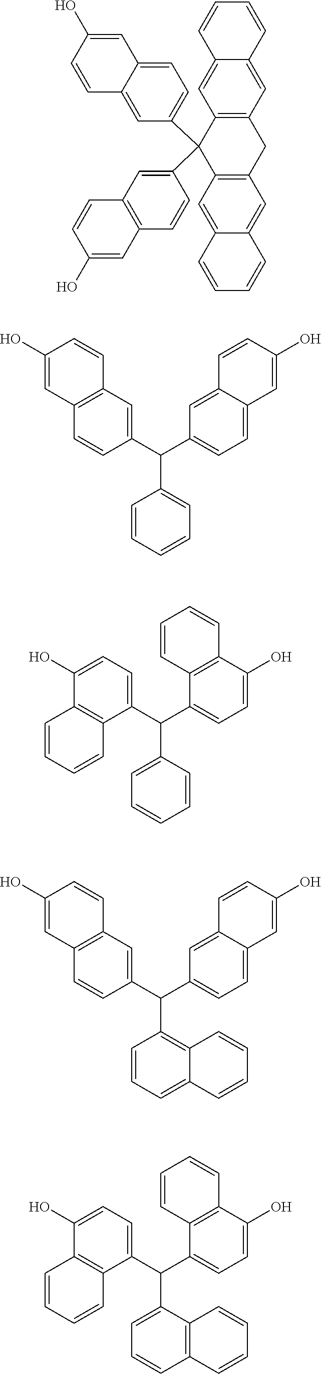 [SMILES: Oc1ccc2cc(C3(c4ccc5cc(O)ccc5c4)c4cc5ccccc5cc4Cc4cc5ccccc5cc43)ccc2c1 ; Oc1ccc2cc(C(c3ccccc3)c3ccc4cc(O)ccc4c3)ccc2c1 ; Oc1ccc(C(c2ccccc2)c2ccc(O)c3ccccc23)c2ccccc12 ; Oc1ccc2cc(C(c3ccc4cc(O)ccc4c3)c3cccc4ccccc34)ccc2c1 ; Oc1ccc(C(c2cccc3ccccc23)c2ccc(O)c3ccccc23)c2ccccc12]

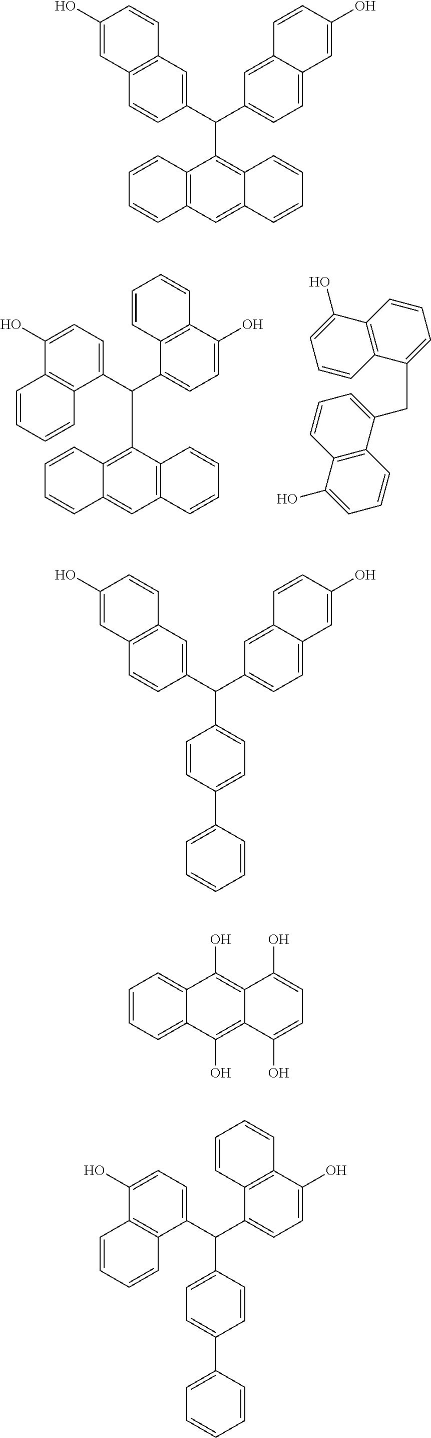 [SMILES: Oc1ccc2cc(C(c3ccc4cc(O)ccc4c3)c3c4ccccc4cc4ccccc34)ccc2c1 ; Oc1ccc(C(c2c3ccccc3cc3ccccc23)c2ccc(O)c3ccccc23)c2ccccc12 ; Oc1cccc2c(Cc3cccc4c(O)cccc34)cccc12 ; Oc1ccc2cc(C(c3ccc(-c4ccccc4)cc3)c3ccc4cc(O)ccc4c3)ccc2c1 ; Oc1ccc(O)c2c(O)c3ccccc3c(O)c12 ; Oc1ccc(C(c2ccc(-c3ccccc3)cc2)c2ccc(O)c3ccccc23)c2ccccc12]

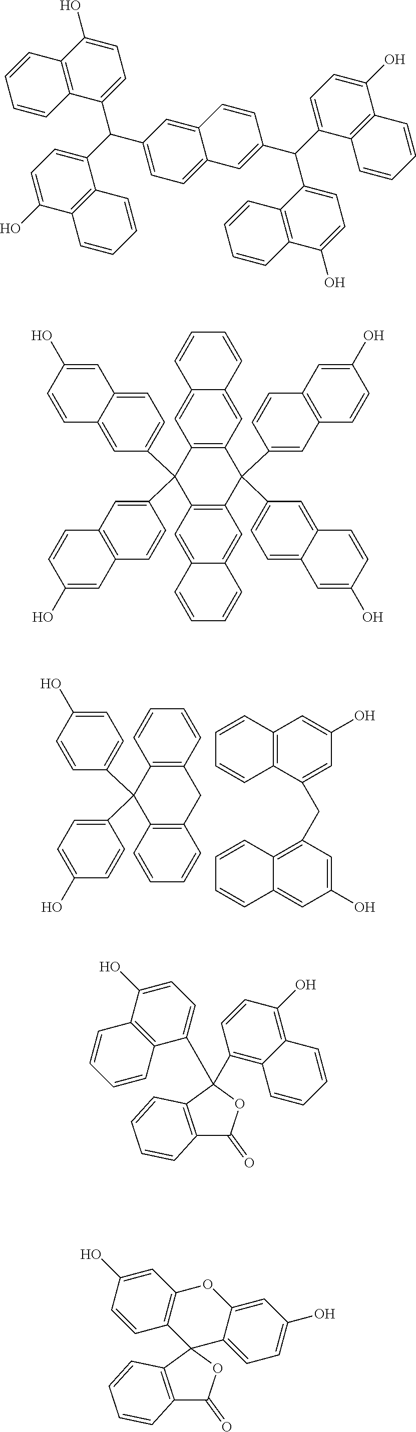

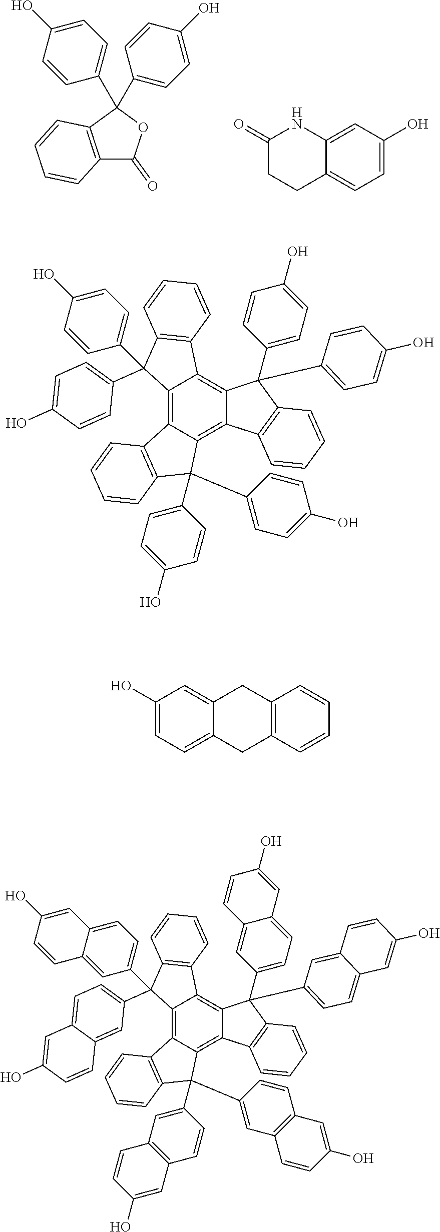 [SMILES: O=C1OC(c2ccc(O)cc2)(c2ccc(O)cc2)c2ccccc21 ; O=C1CCc2ccc(O)cc2N1 ; Oc1ccc(C2(c3ccc(O)cc3)c3ccccc3-c3c2c2c(c4c3C(c3ccc(O)cc3)(c3ccc(O)cc3)c3ccccc3-4)C(c3ccc(O)cc3)(c3ccc(O)cc3)c3ccccc3-2)cc1 ; Oc1ccc2c(c1)Cc1ccccc1C2 ; Oc1ccc2cc(C3(c4ccc5cc(O)ccc5c4)c4ccccc4-c4c3c3c(c5c4C(c4ccc6cc(O)ccc6c4)(c4ccc6cc(O)ccc6c4)c4ccccc4-5)C(c4ccc5cc(O)ccc5c4)(c4ccc5cc(O)ccc5c4)c4ccccc4-3)ccc2c1]

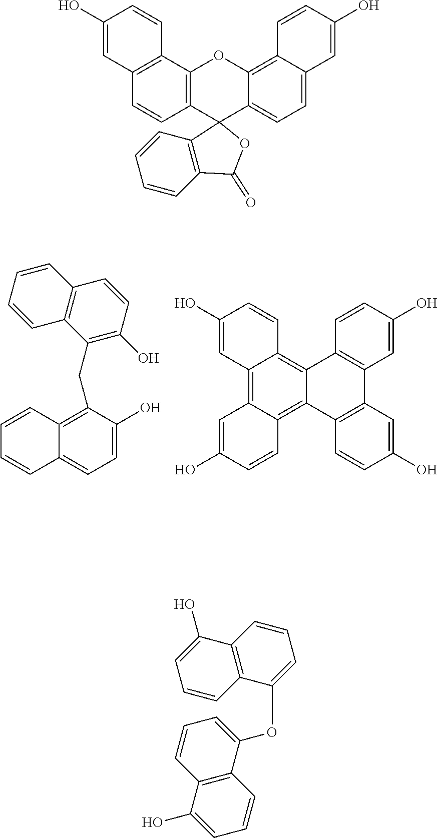 [SMILES: O=C1OC2(c3ccccc31)c1ccc3cc(O)ccc3c1Oc1c2ccc2cc(O)ccc12 ; Oc1ccc2ccccc2c1Cc1c(O)ccc2ccccc12 ; Oc1ccc2c(c1)c1cc(O)ccc1c1c3ccc(O)cc3c3cc(O)ccc3c21 ; Oc1cccc2c(Oc3cccc4c(O)cccc34)cccc12]

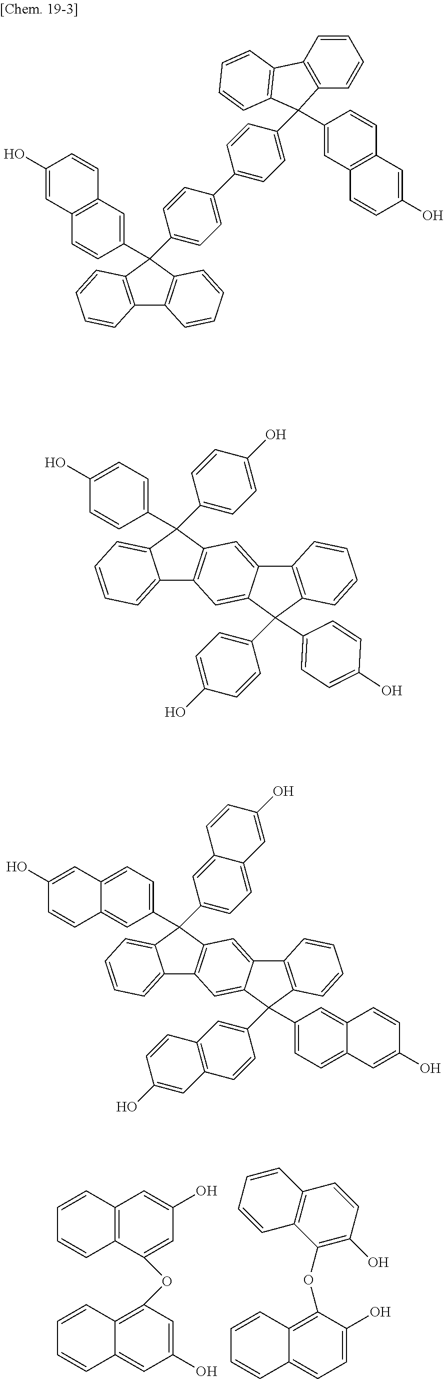

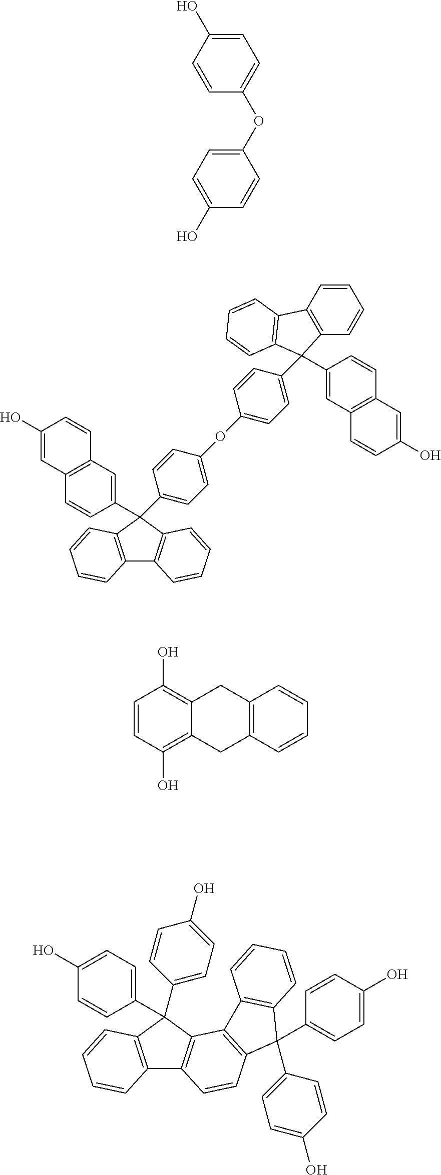 [SMILES: Oc1ccc(Oc2ccc(O)cc2)cc1 ; Oc1ccc2cc(C3(c4ccc(Oc5ccc(C6(c7ccc8cc(O)ccc8c7)c7ccccc7-c7ccccc76)cc5)cc4)c4ccccc4-c4ccccc43)ccc2c1 ; Oc1ccc(O)c2c1Cc1ccccc1C2 ; Oc1ccc(C2(c3ccc(O)cc3)c3ccccc3-c3c2ccc2c3C(c3ccc(O)cc3)(c3ccc(O)cc3)c3ccccc3-2)cc1]

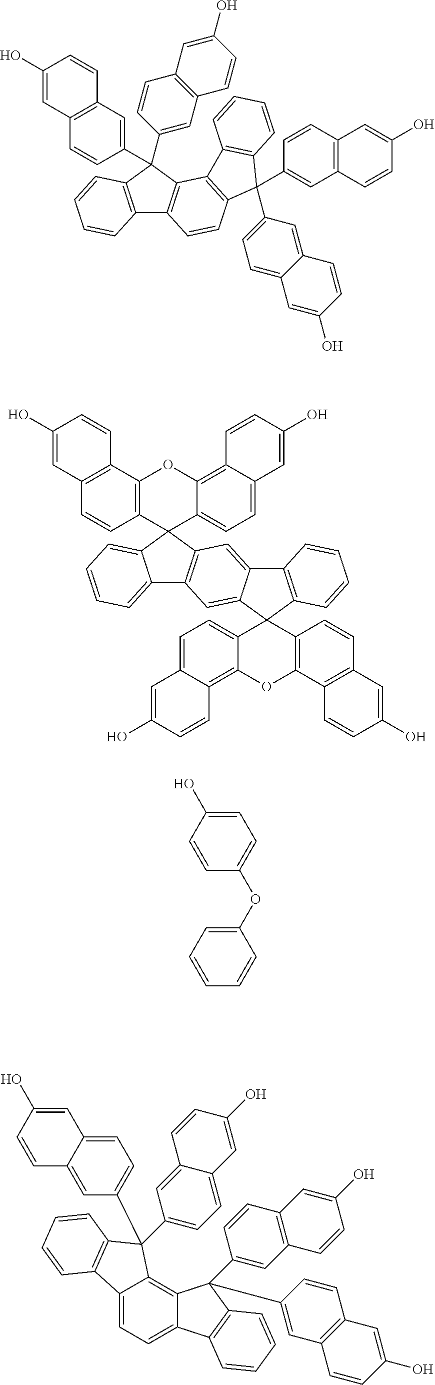 [SMILES: Oc1ccc2cc(C3(c4ccc5cc(O)ccc5c4)c4ccccc4-c4c3ccc3c4C(c4ccc5cc(O)ccc5c4)(c4ccc5cc(O)ccc5c4)c4ccccc4-3)ccc2c1 ; Oc1ccc2c3c(ccc2c1)C1(c2ccccc2-c2cc4c(cc21)-c1ccccc1C41c2ccc4cc(O)ccc4c2Oc2c1ccc1cc(O)ccc21)c1ccc2cc(O)ccc2c1O3 ; Oc1ccc(Oc2ccccc2)cc1 ; Oc1ccc2cc(C3(c4ccc5cc(O)ccc5c4)c4ccccc4-c4ccc5c(c43)C(c3ccc4cc(O)ccc4c3)(c3ccc4cc(O)ccc4c3)c3ccccc3-5)ccc2c1]

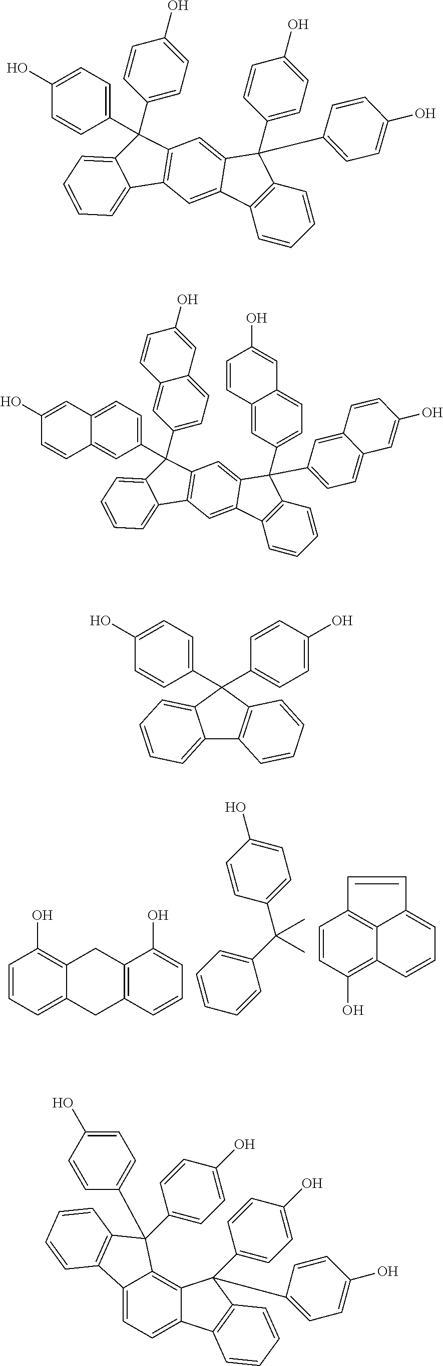

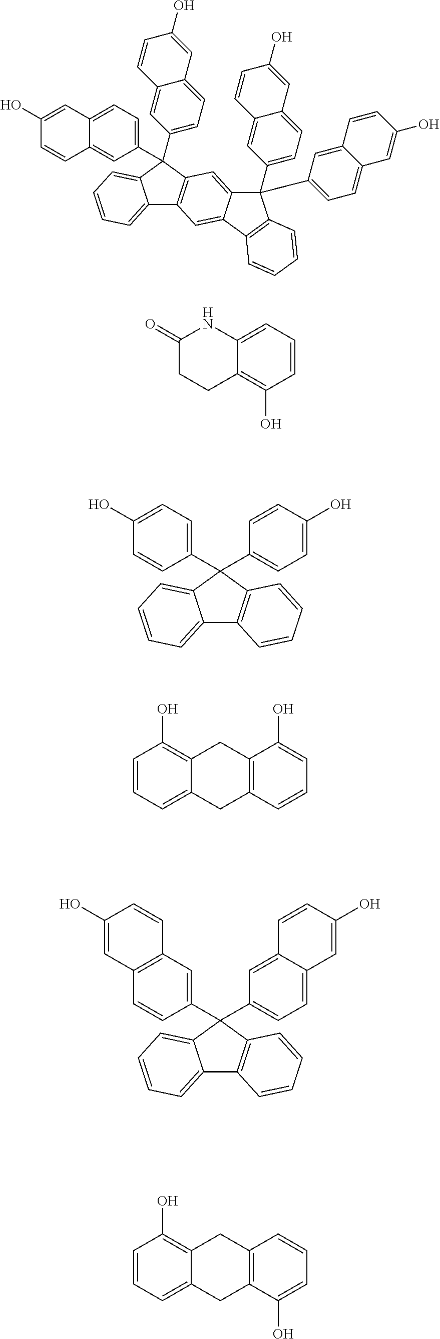 [SMILES: Oc1ccc2cc(C3(c4ccc5cc(O)ccc5c4)c4ccccc4-c4cc5c(cc43)C(c3ccc4cc(O)ccc4c3)(c3ccc4cc(O)ccc4c3)c3ccccc3-5)ccc2c1 ; O=C1CCc2c(O)cccc2N1 ; Oc1ccc(C2(c3ccc(O)cc3)c3ccccc3-c3ccccc32)cc1 ; Oc1cccc2c1Cc1c(O)cccc1C2 ; Oc1ccc2cc(C3(c4ccc5cc(O)ccc5c4)c4ccccc4-c4ccccc43)ccc2c1 ; Oc1cccc2c1Cc1cccc(O)c1C2]

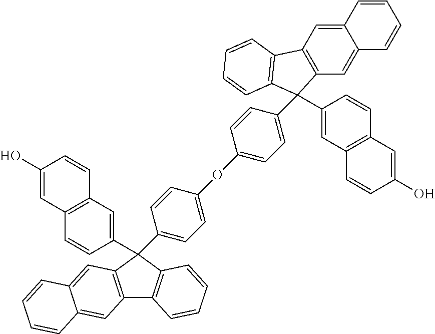 [SMILES: Oc1ccc2cc(C3(c4ccc(Oc5ccc(C6(c7ccc8cc(O)ccc8c7)c7ccccc7-c7cc8ccccc8cc76)cc5)cc4)c4ccccc4-c4cc5ccccc5cc43)ccc2c1]

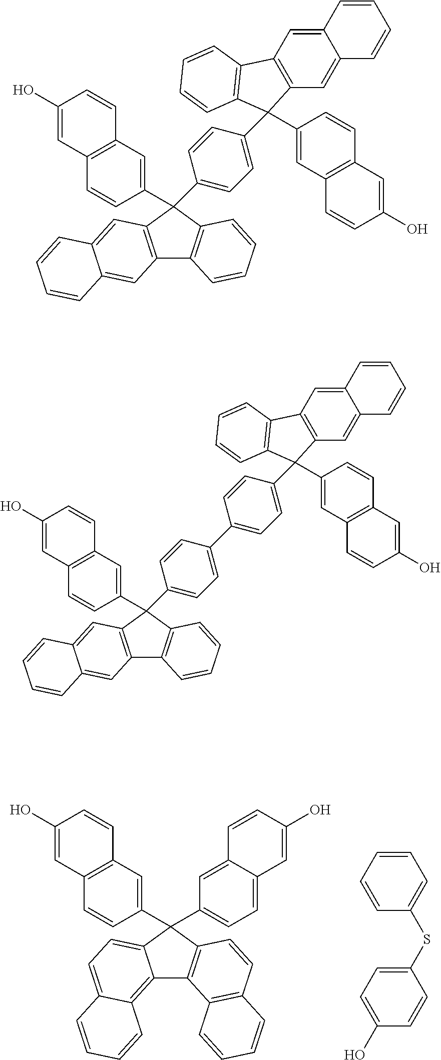 [SMILES: Oc1ccc2cc(C3(c4ccc(C5(c6ccc7cc(O)ccc7c6)c6ccccc6-c6cc7ccccc7cc65)cc4)c4ccccc4-c4cc5ccccc5cc43)ccc2c1 ; Oc1ccc2cc(C3(c4ccc(-c5ccc(C6(c7ccc8cc(O)ccc8c7)c7ccccc7-c7cc8ccccc8cc76)cc5)cc4)c4ccccc4-c4cc5ccccc5cc43)ccc2c1 ; Oc1ccc2cc(C3(c4ccc5cc(O)ccc5c4)c4ccc5ccccc5c4-c4c3ccc3ccccc43)ccc2c1 ; Oc1ccc(Sc2ccccc2)cc1]

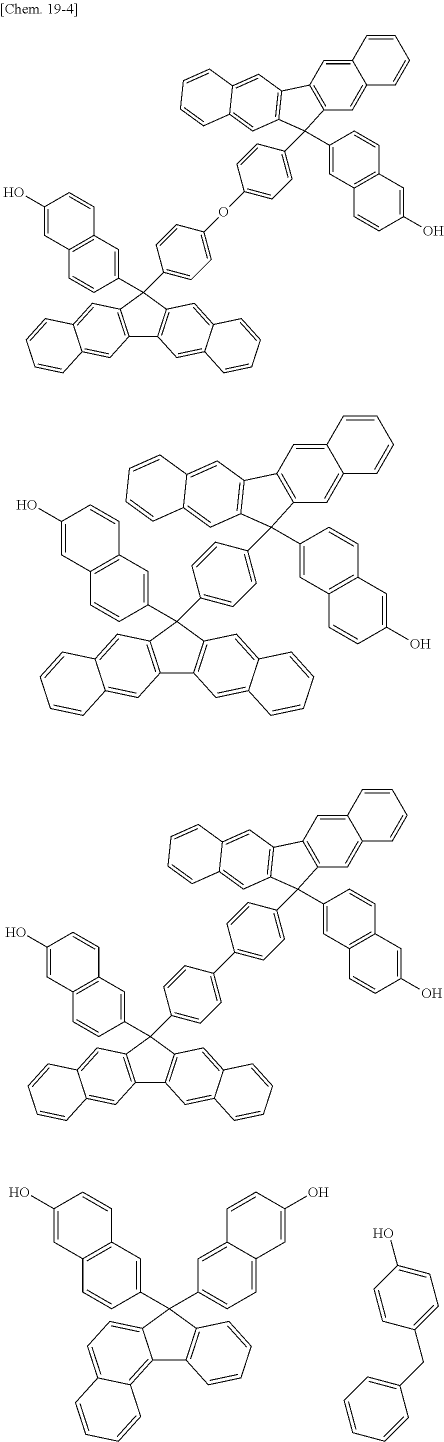 [SMILES: Oc1ccc2cc(C3(c4ccc(Oc5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1 ; Oc1ccc2cc(C3(c4ccc(C5(c6ccc7cc(O)ccc7c6)c6cc7ccccc7cc6-c6cc7ccccc7cc65)cc4)c4cc5ccccc5cc4-c4cc5ccccc5cc43)ccc2c1 ; Oc1ccc2cc(C3(c4ccc(-c5ccc(C6(c7ccc8cc(O)ccc8c7)c7cc8ccccc8cc7-c7cc8ccccc8cc76)cc5)cc4)c4cc5ccccc5cc4-c4cc5ccccc5cc43)ccc2c1 ; Oc1ccc2cc(C3(c4ccc5cc(O)ccc5c4)c4ccccc4-c4c3ccc3ccccc43)ccc2c1 ; Oc1ccc(Cc2ccccc2)cc1]

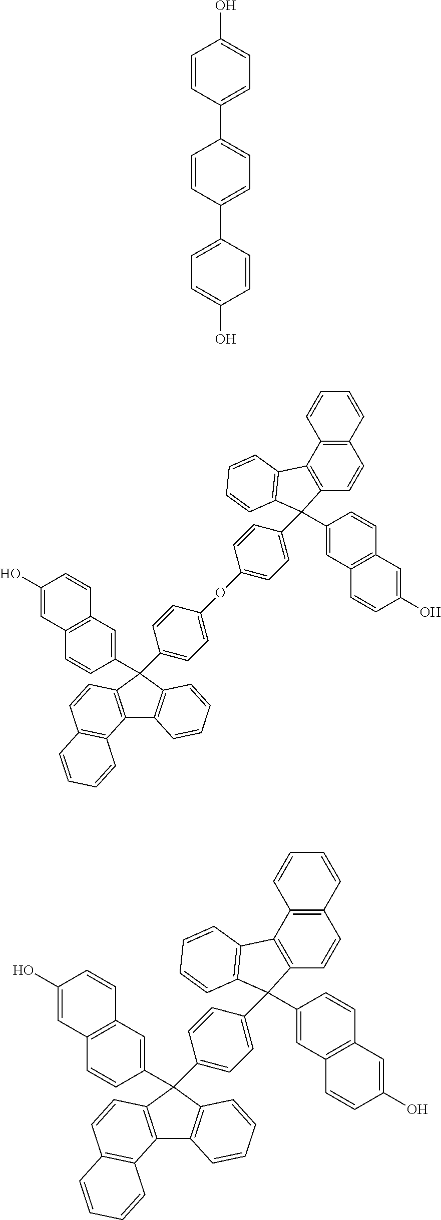 [SMILES: Oc1ccc(-c2ccc(-c3ccc(O)cc3)cc2)cc1 ; Oc1ccc2cc(C3(c4ccc(Oc5ccc(C6(c7ccc8cc(O)ccc8c7)c7ccccc7-c7c6ccc6ccccc76)cc5)cc4)c4ccccc4-c4c3ccc3ccccc43)ccc2c1 ; Oc1ccc2cc(C3(c4ccc(C5(c6ccc7cc(O)ccc7c6)c6ccccc6-c6c5ccc5ccccc65)cc4)c4ccccc4-c4c3ccc3ccccc43)ccc2c1]

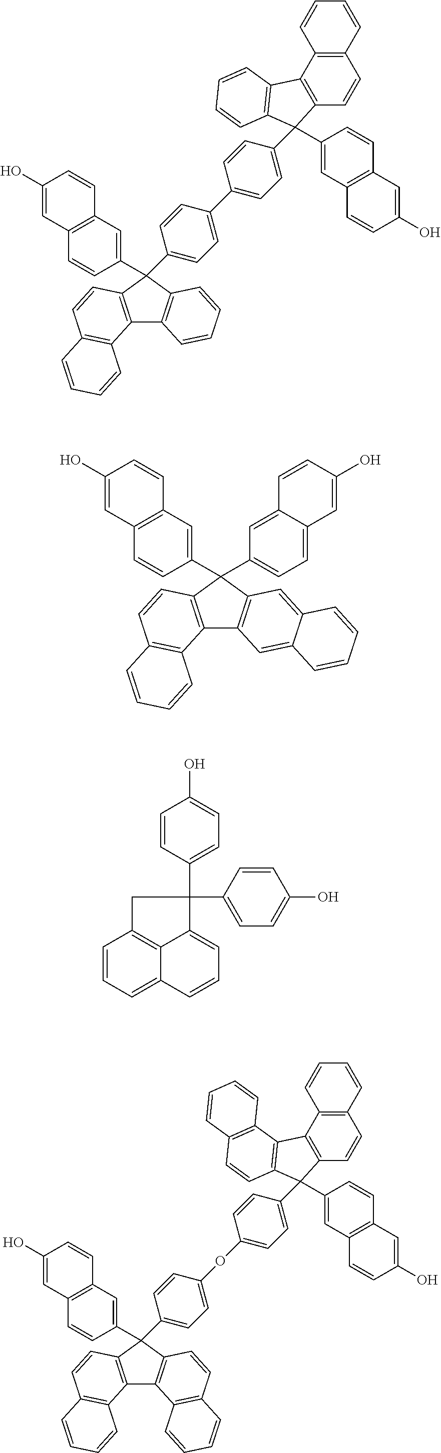 [SMILES: Oc1ccc2cc(C3(c4ccc(-c5ccc(C6(c7ccc8cc(O)ccc8c7)c7ccccc7-c7c6ccc6ccccc76)cc5)cc4)c4ccccc4-c4c3ccc3ccccc43)ccc2c1 ; Oc1ccc2cc(C3(c4ccc5cc(O)ccc5c4)c4cc5ccccc5cc4-c4c3ccc3ccccc43)ccc2c1 ; Oc1ccc(C2(c3ccc(O)cc3)Cc3cccc4cccc2c34)cc1 ; Oc1ccc2cc(C3(c4ccc(Oc5ccc(C6(c7ccc8cc(O)ccc8c7)c7ccc8ccccc8c7-c7c6ccc6ccccc76)cc5)cc4)c4ccc5ccccc5c4-c4c3ccc3ccccc43)ccc2c1]

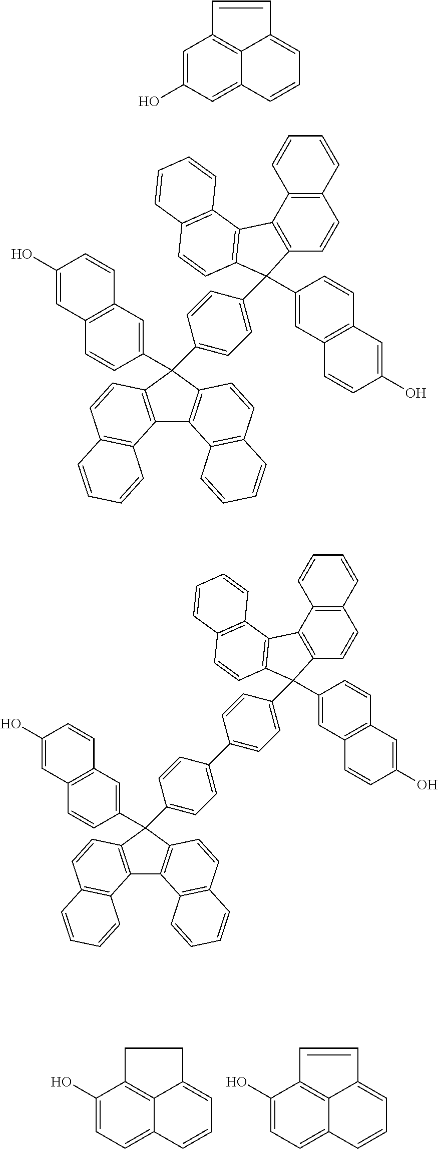

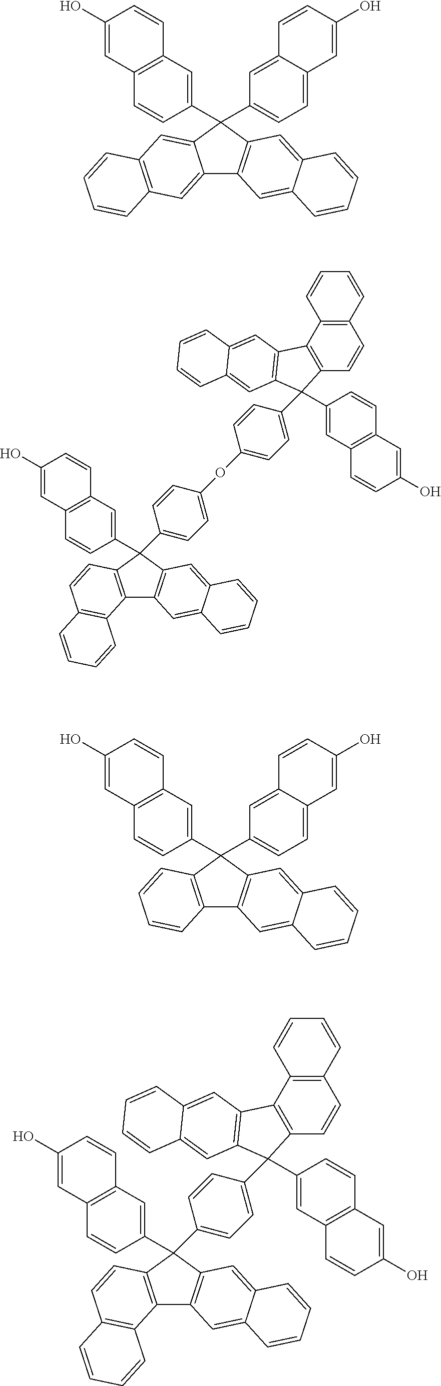 [SMILES: Oc1ccc2cc(C3(c4ccc5cc(O)ccc5c4)c4cc5ccccc5cc4-c4cc5ccccc5cc43)ccc2c1 ; Oc1ccc2cc(C3(c4ccc(Oc5ccc(C6(c7ccc8cc(O)ccc8c7)c7cc8ccccc8cc7-c7c6ccc6ccccc76)cc5)cc4)c4cc5ccccc5cc4-c4c3ccc3ccccc43)ccc2c1 ; Oc1ccc2cc(C3(c4ccc5cc(O)ccc5c4)c4ccccc4-c4cc5ccccc5cc43)ccc2c1 ; Oc1ccc2cc(C3(c4ccc(C5(c6ccc7cc(O)ccc7c6)c6cc7ccccc7cc6-c6c5ccc5ccccc65)cc4)c4cc5ccccc5cc4-c4c3ccc3ccccc43)ccc2c1]

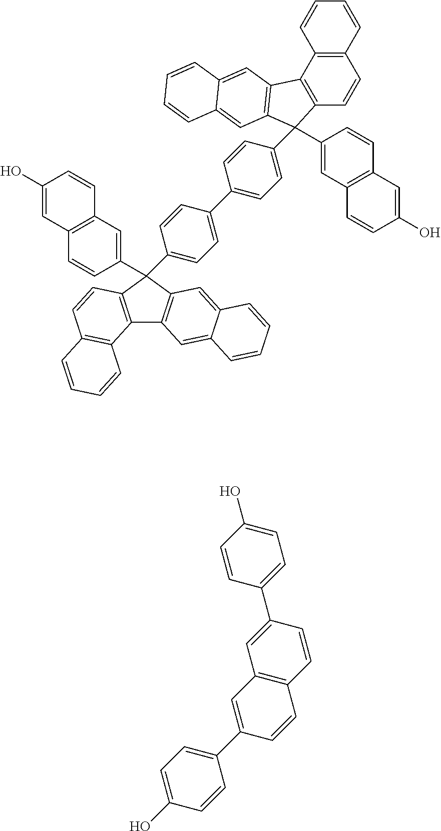 [SMILES: Oc1ccc2cc(C3(c4ccc(-c5ccc(C6(c7ccc8cc(O)ccc8c7)c7cc8ccccc8cc7-c7c6ccc6ccccc76)cc5)cc4)c4cc5ccccc5cc4-c4c3ccc3ccccc43)ccc2c1 ; Oc1ccc(-c2ccc3ccc(-c4ccc(O)cc4)cc3c2)cc1]

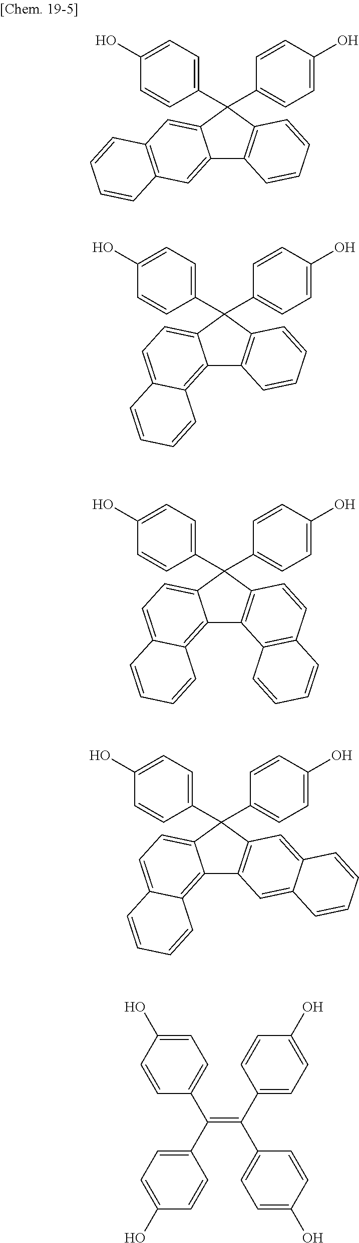 [SMILES: Oc1ccc(C2(c3ccc(O)cc3)c3ccccc3-c3cc4ccccc4cc32)cc1 ; Oc1ccc(C2(c3ccc(O)cc3)c3ccccc3-c3c2ccc2ccccc32)cc1 ; Oc1ccc(C2(c3ccc(O)cc3)c3ccc4ccccc4c3-c3c2ccc2ccccc32)cc1 ; Oc1ccc(C2(c3ccc(O)cc3)c3cc4ccccc4cc3-c3c2ccc2ccccc32)cc1 ; Oc1ccc(C(=C(c2ccc(O)cc2)c2ccc(O)cc2)c2ccc(O)cc2)cc1]

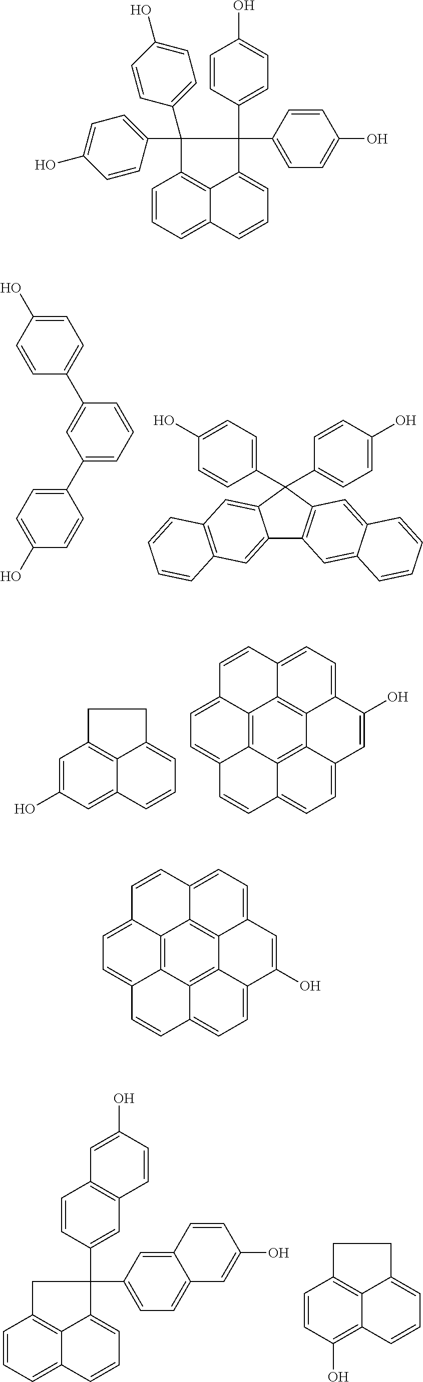

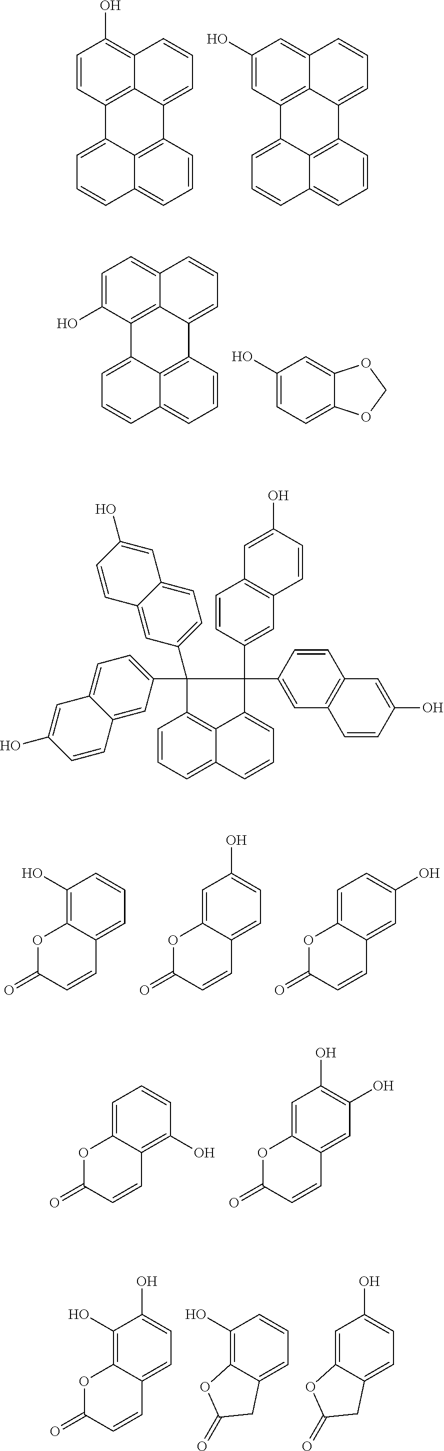

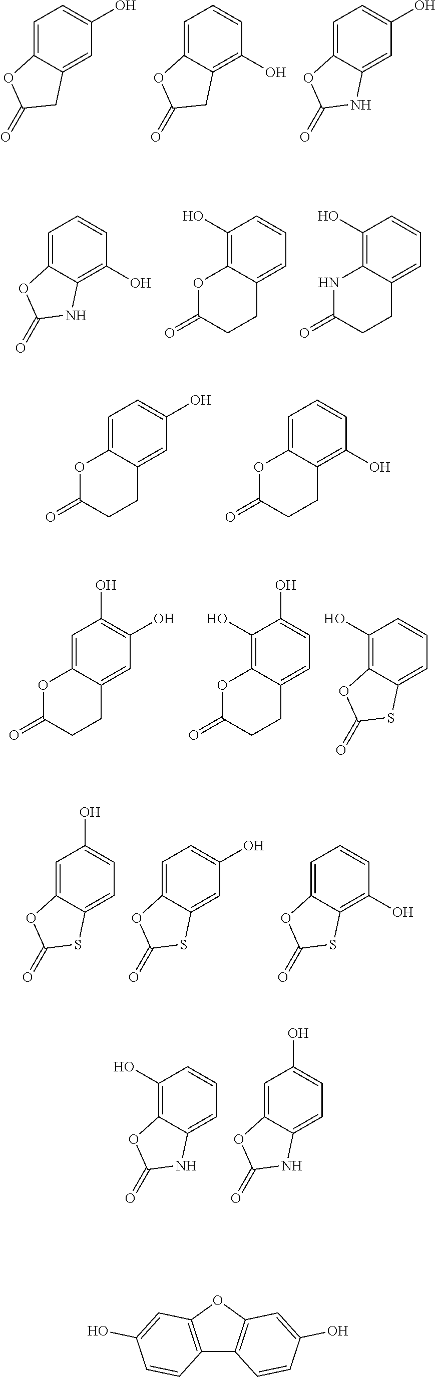

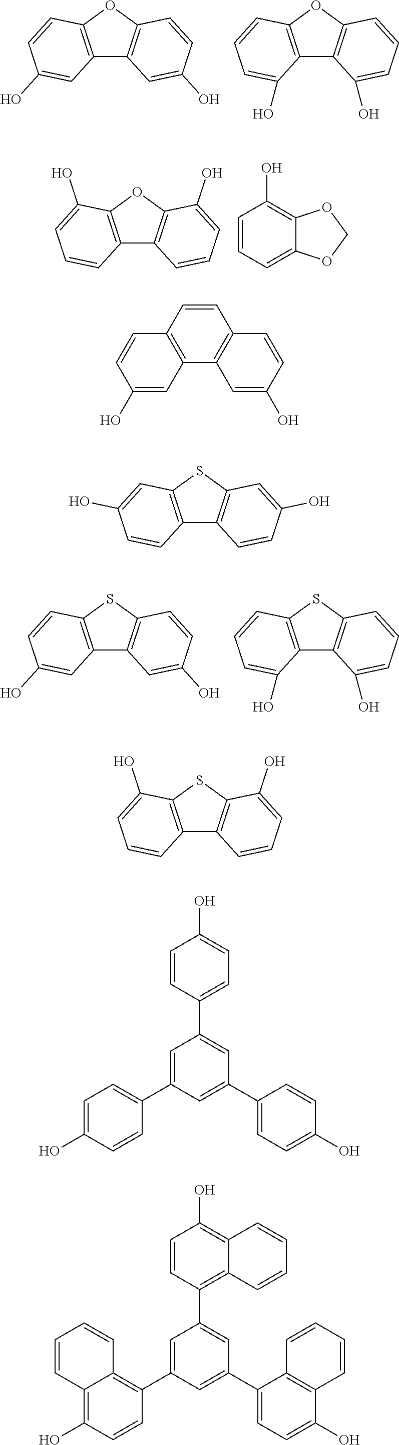

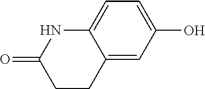 [SMILES: O=C1CCc2cc(O)ccc2N1]

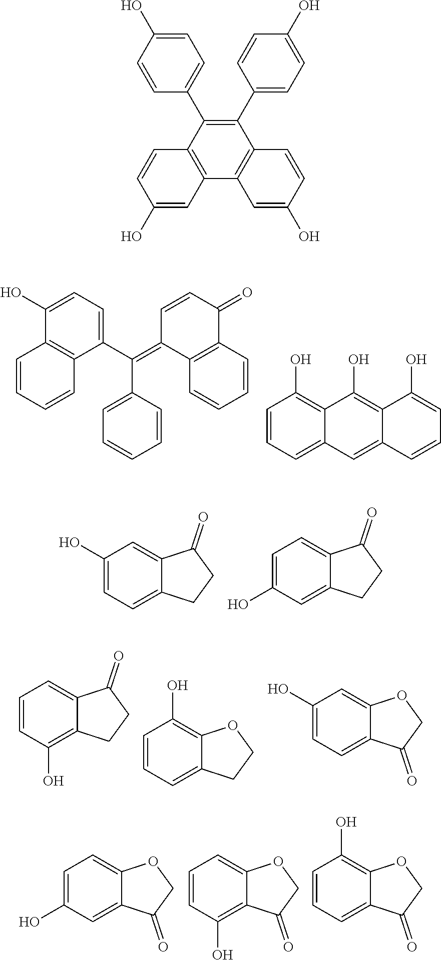

H of NH in the above amine skeletons and H of OH in the above phenol skeletons may be substituted with substituents illustrated below:

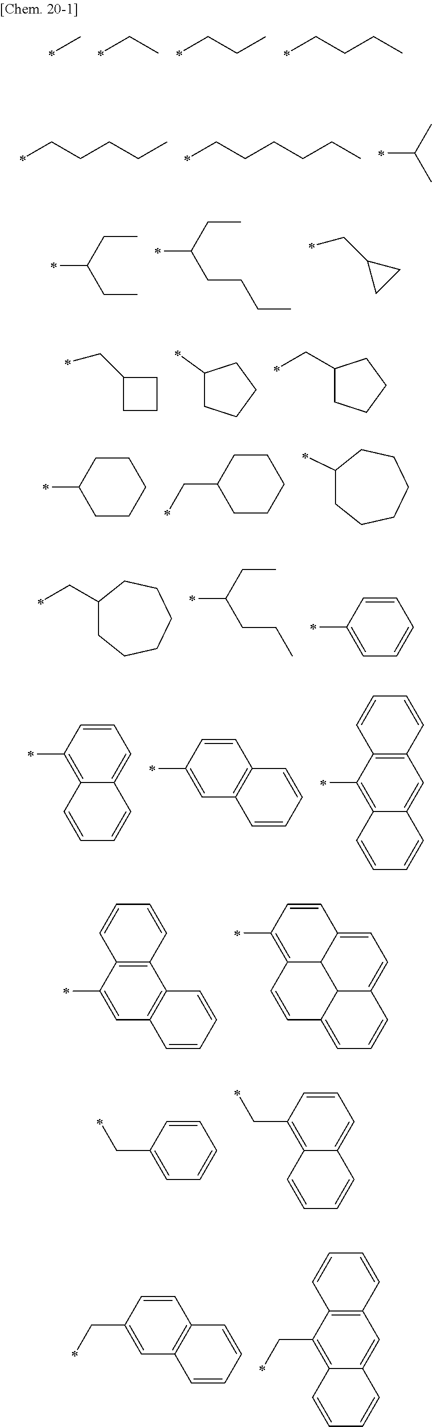

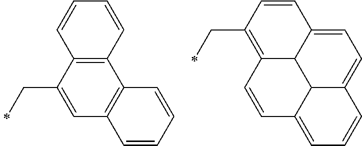

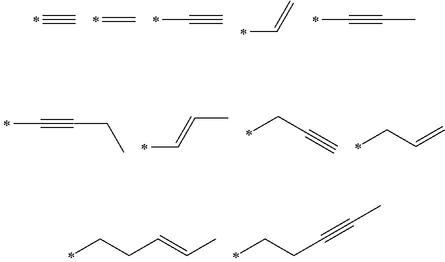

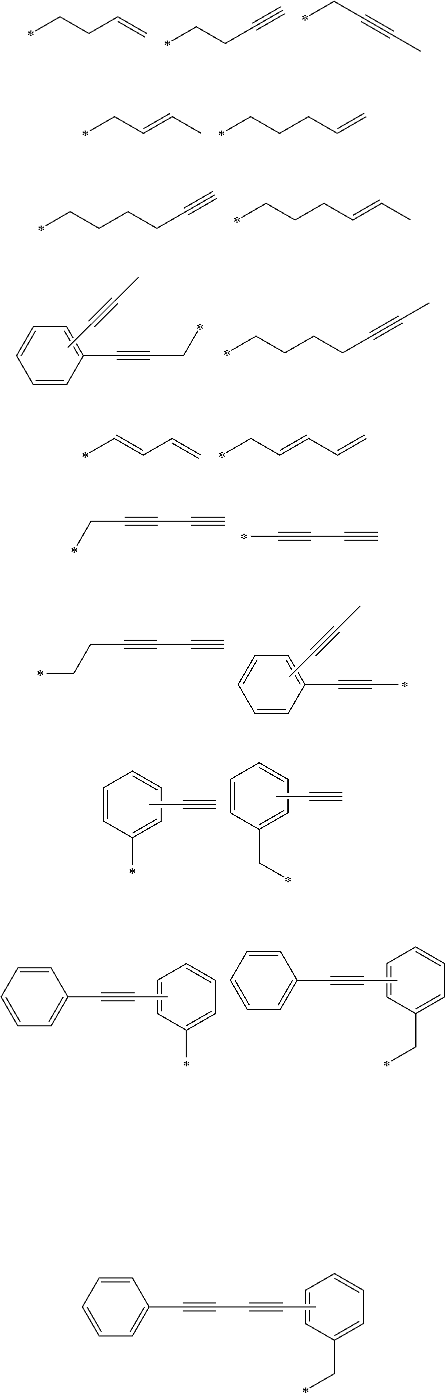

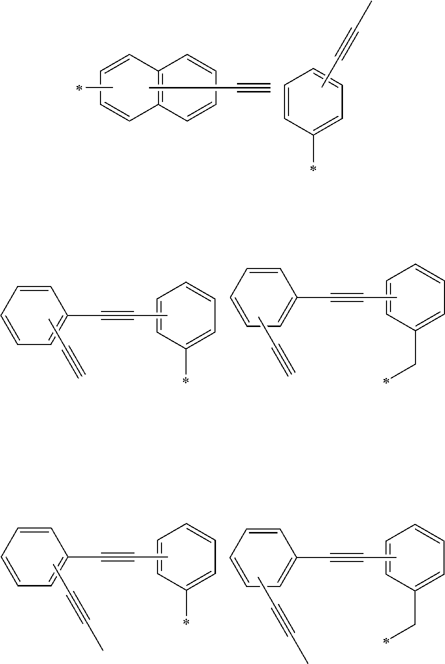

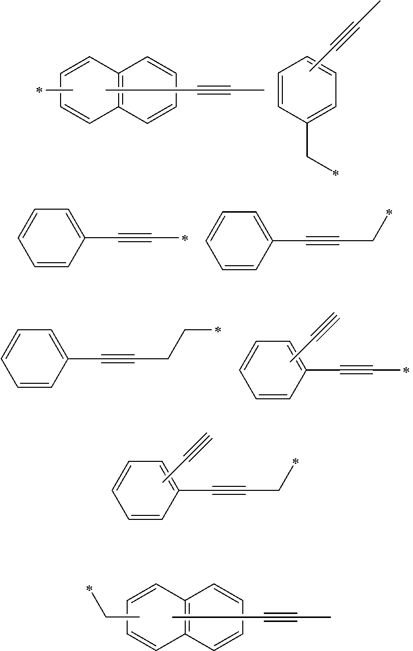

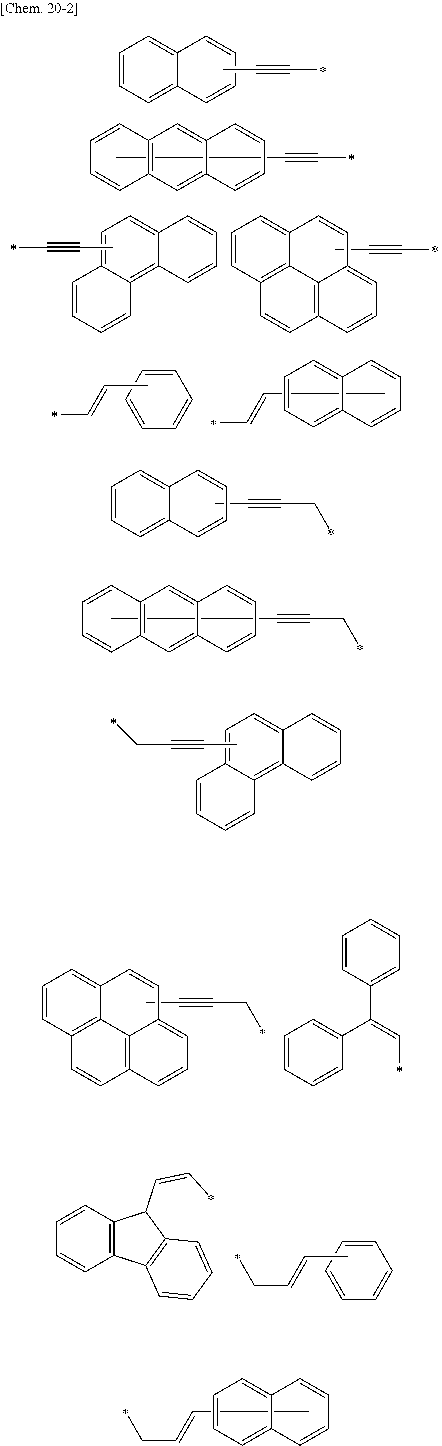

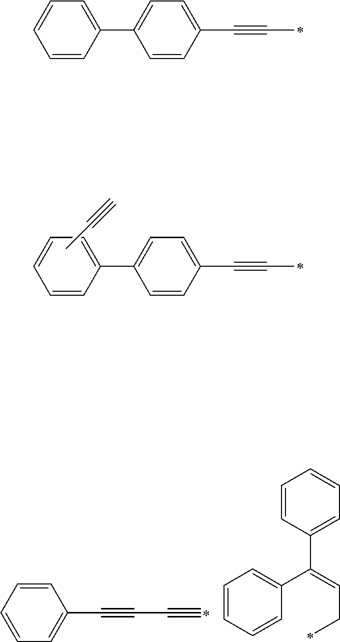

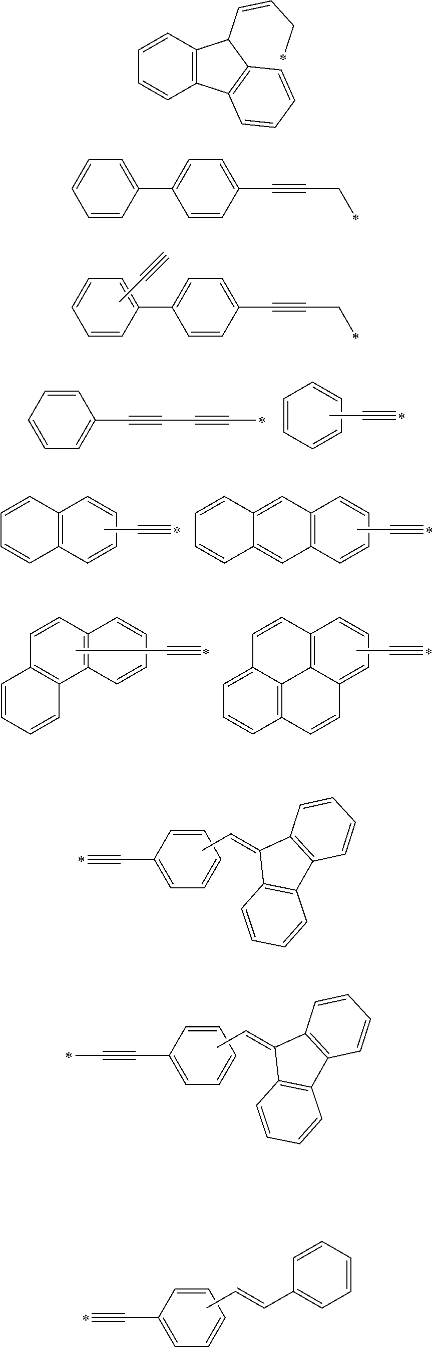

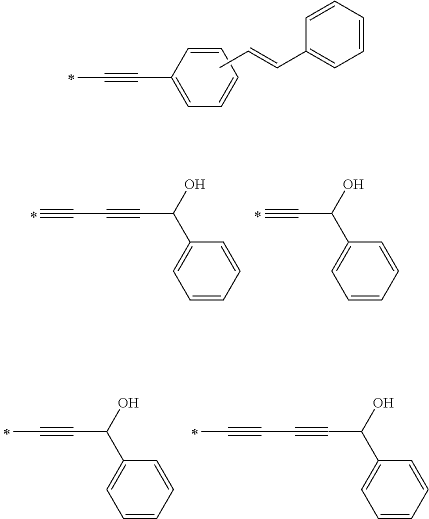

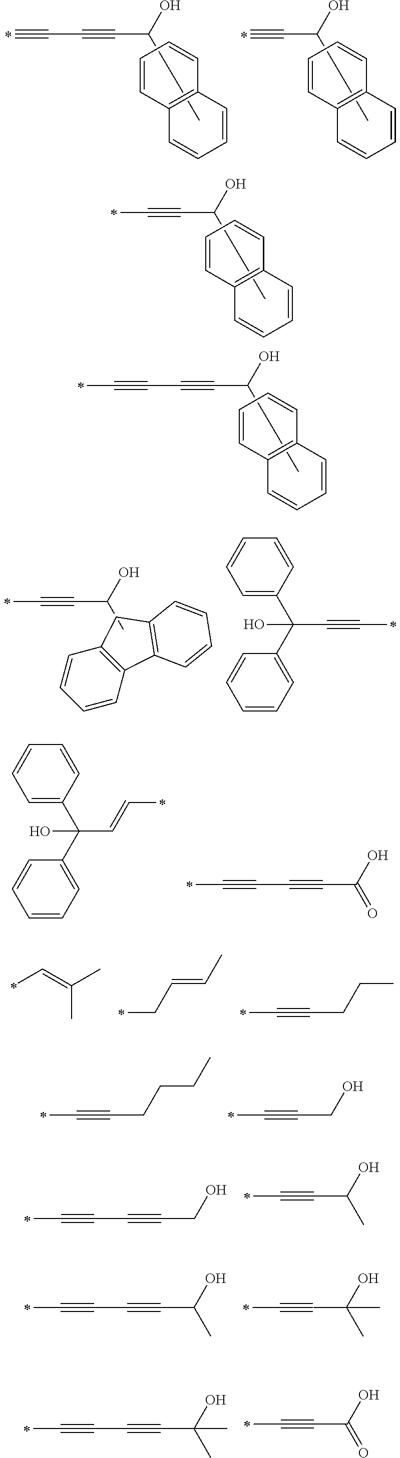

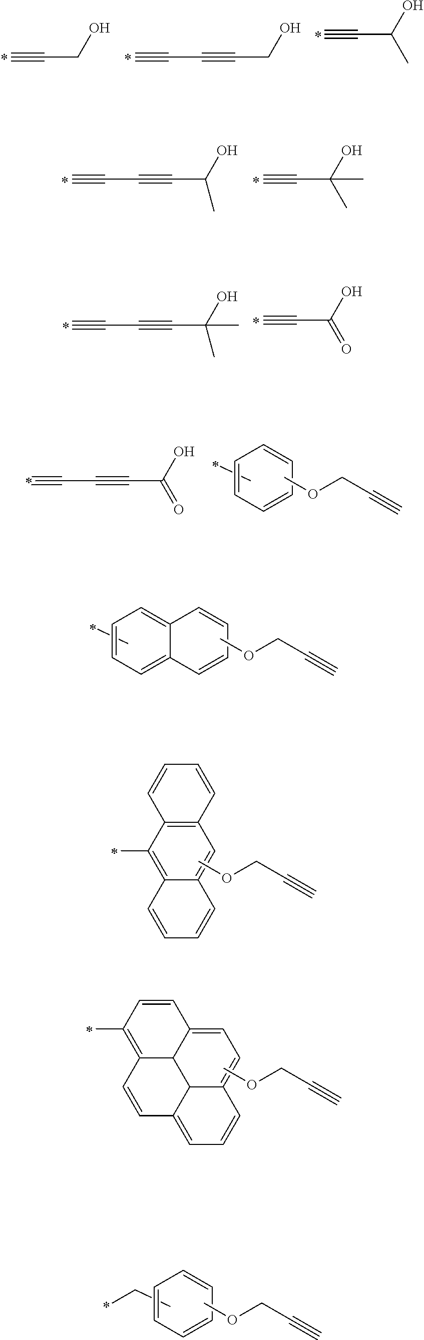

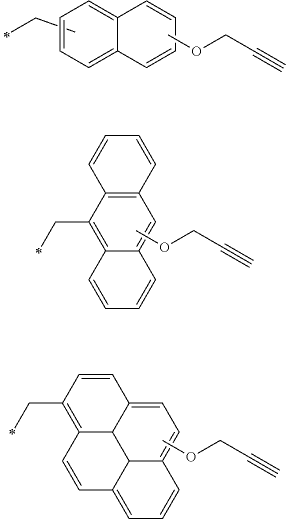

The unit structures A other than the formula (A) are preferably at least one kind of unit structures selected from the following. Incidentally, the positions of the two valence bonds in each of the unit structures below are only illustrative and are not limited thereto, and the valence bonds may each extend from any appropriate carbon atom.

(Examples of the Unit Structures Derived from a Heterocyclic Ring)

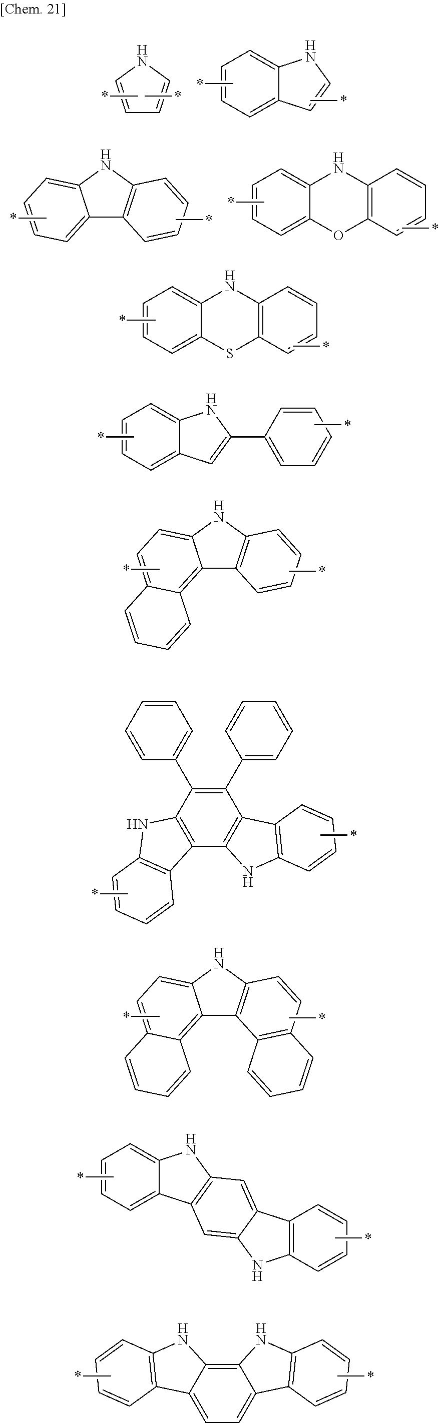

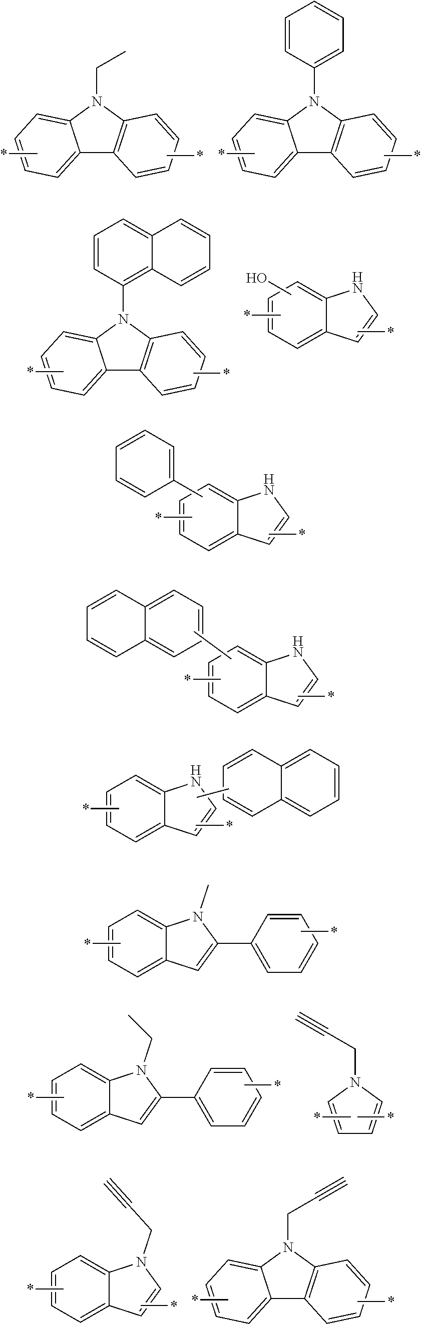

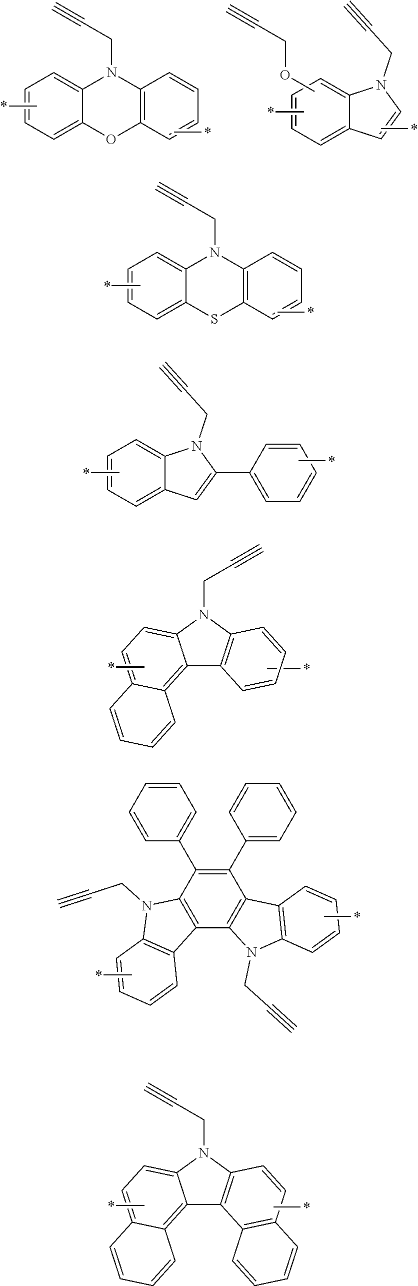

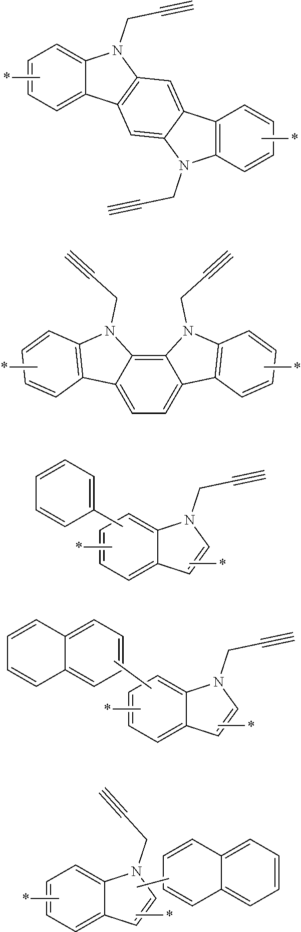

(Examples of the Unit Structures Derived from an Aromatic Hydrocarbon Having an Oxygen-Containing Substituent)

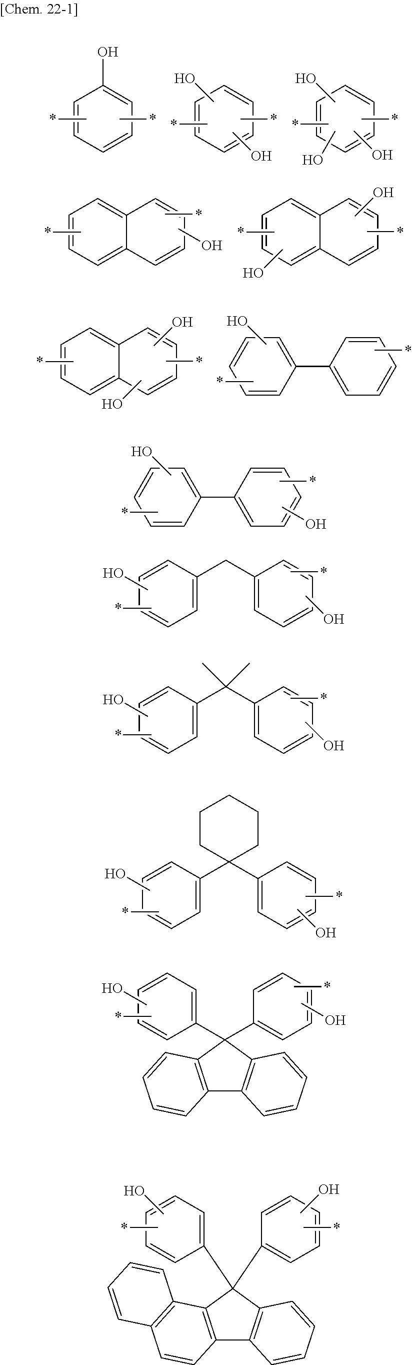

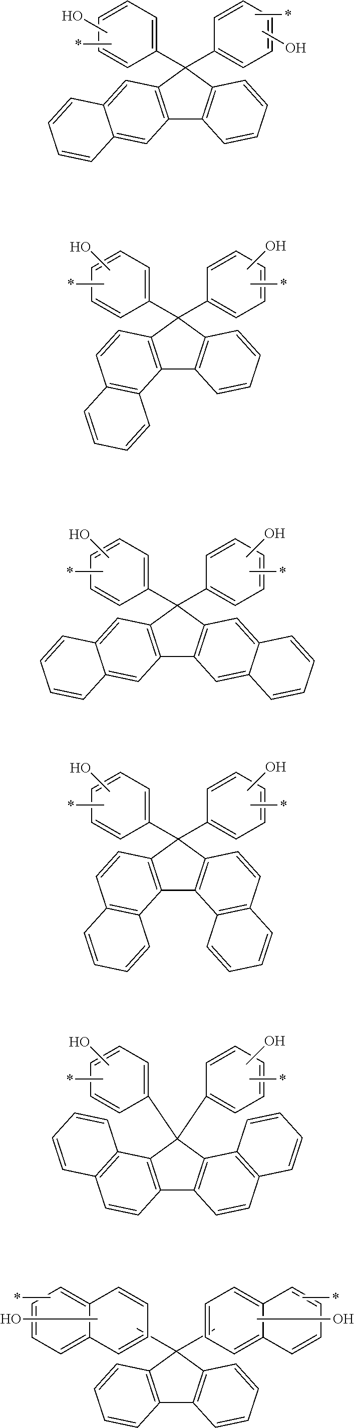

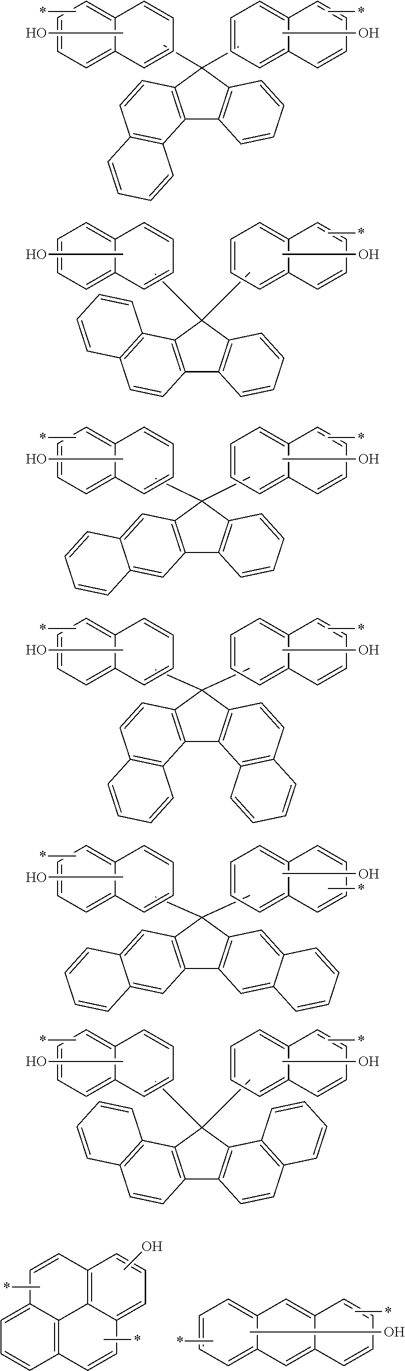

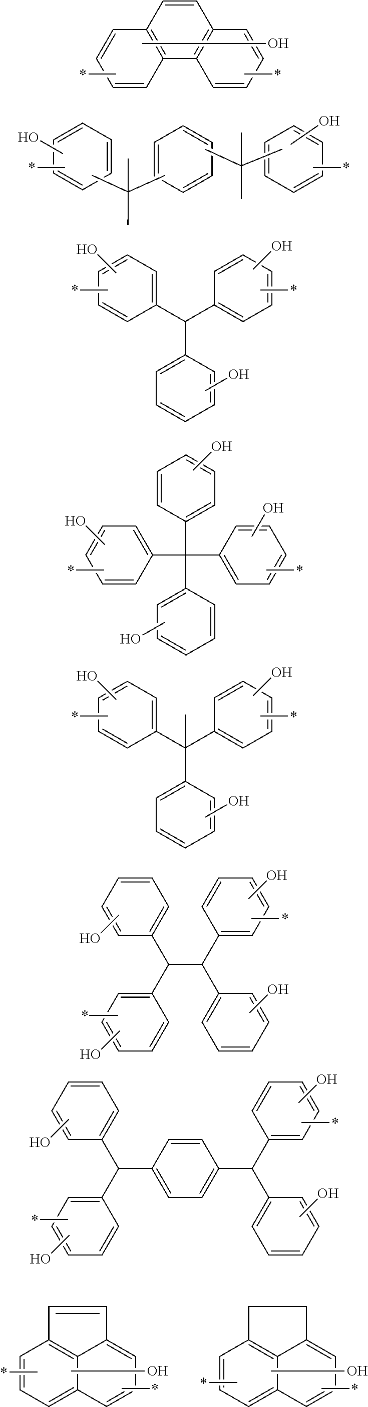

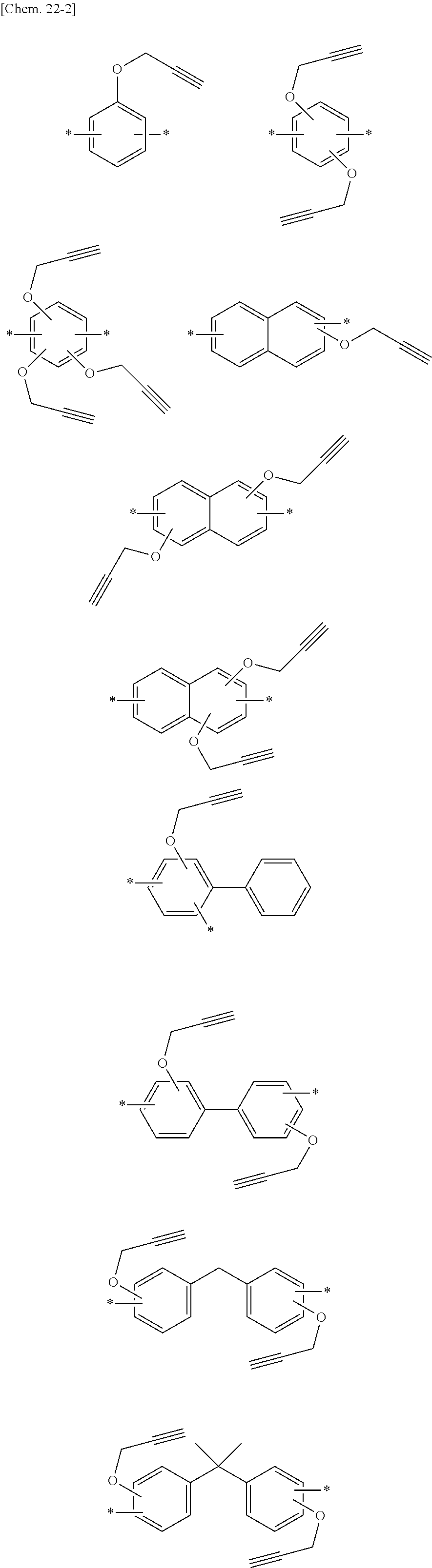

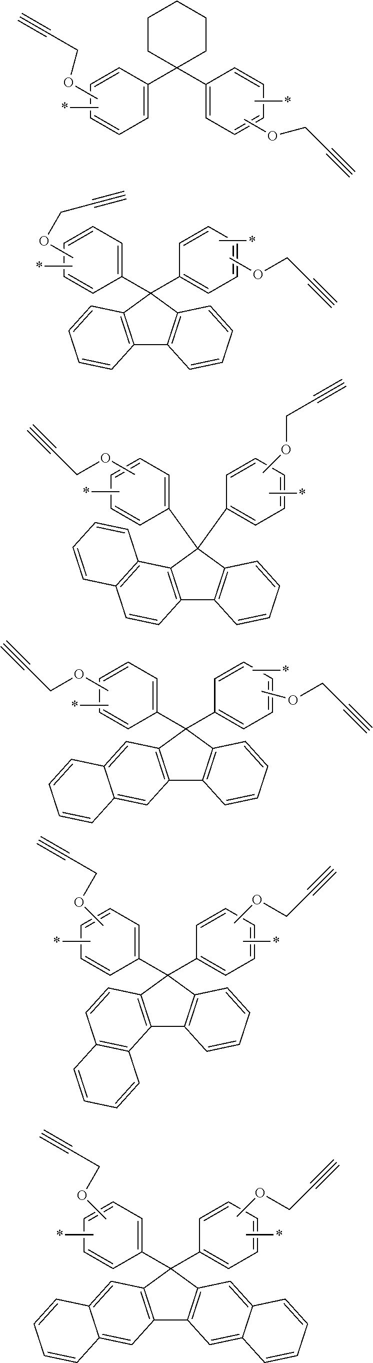

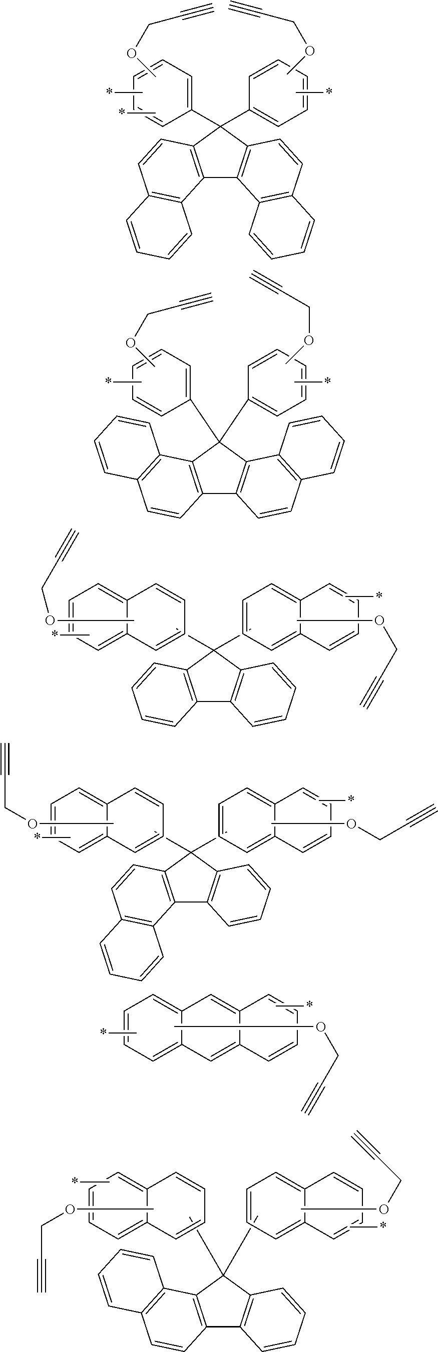

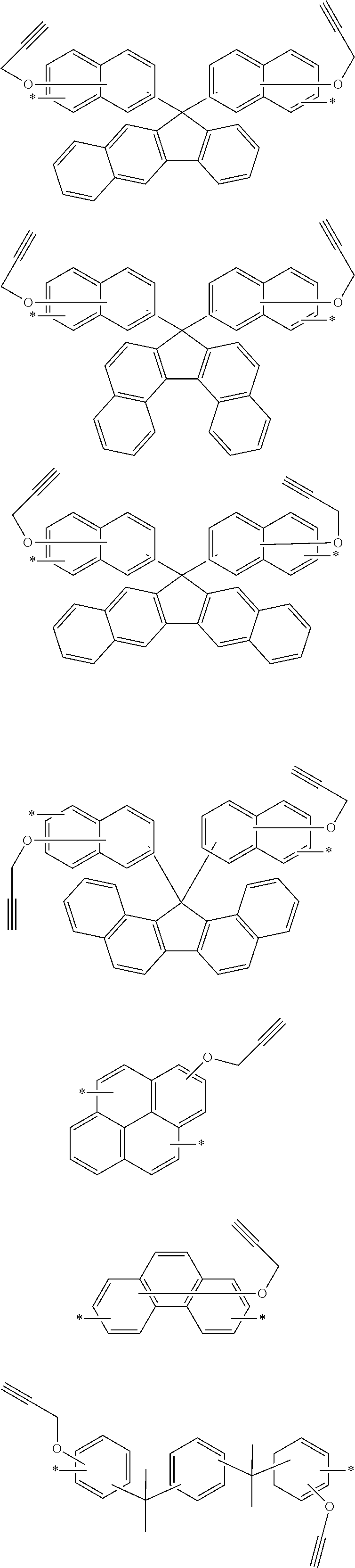

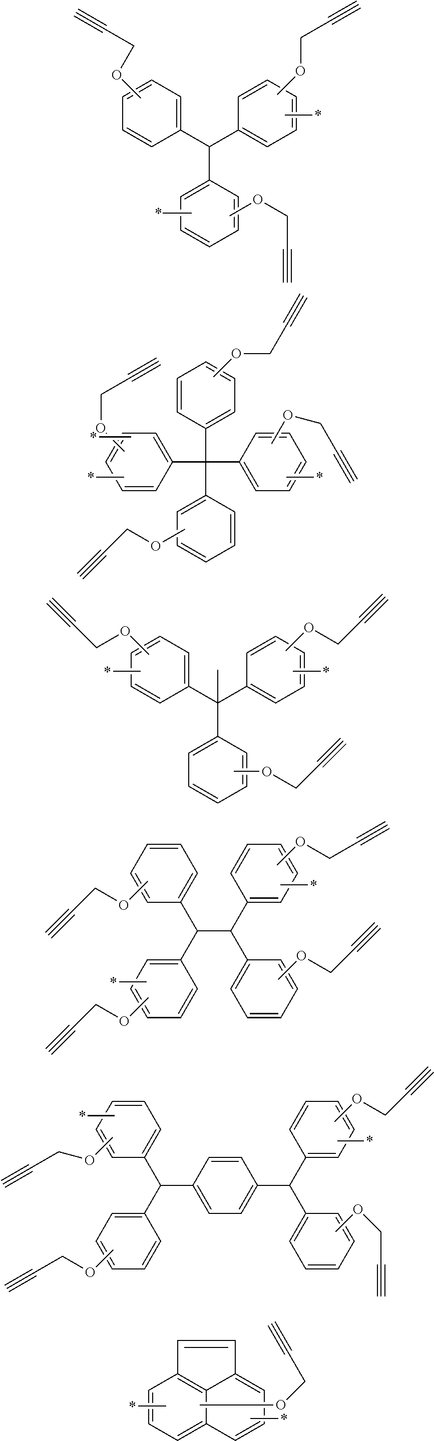

(Examples of the Unit Structures Derived from Aromatic Hydrocarbons Connected by —NH—)
Substituents may be present in place of the hydrogen atom on N in —NH—.

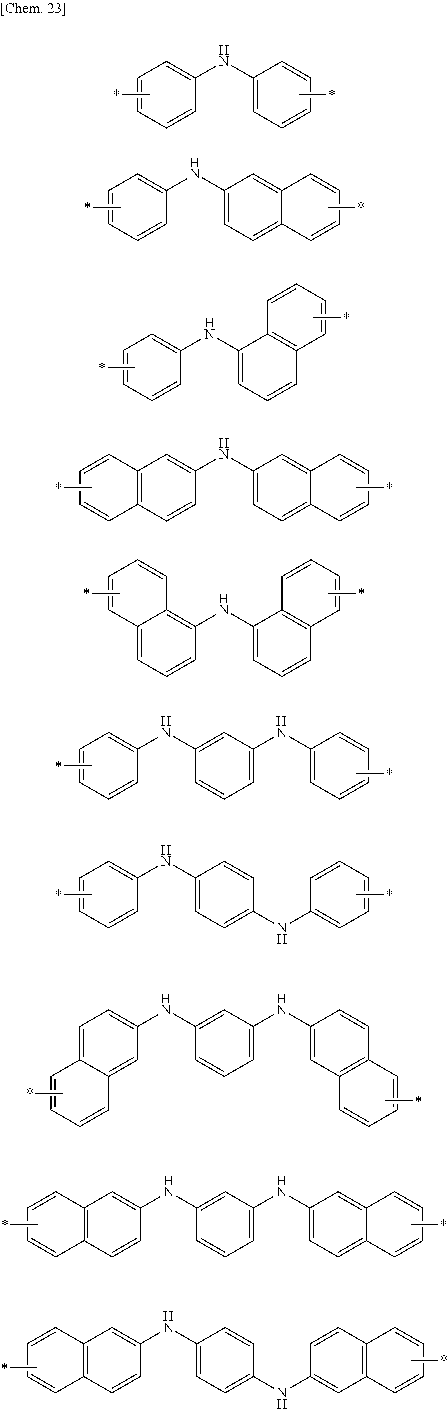

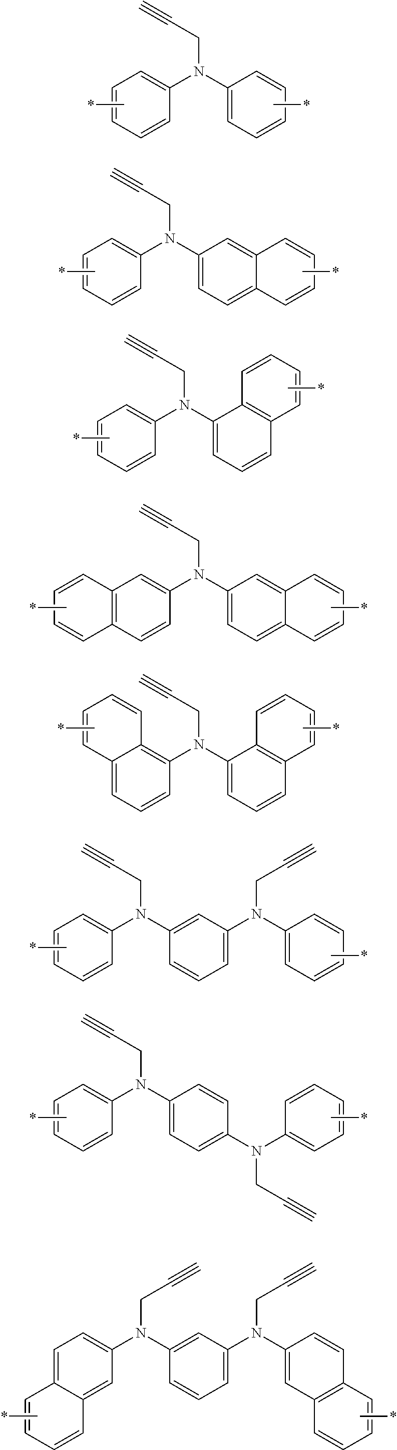

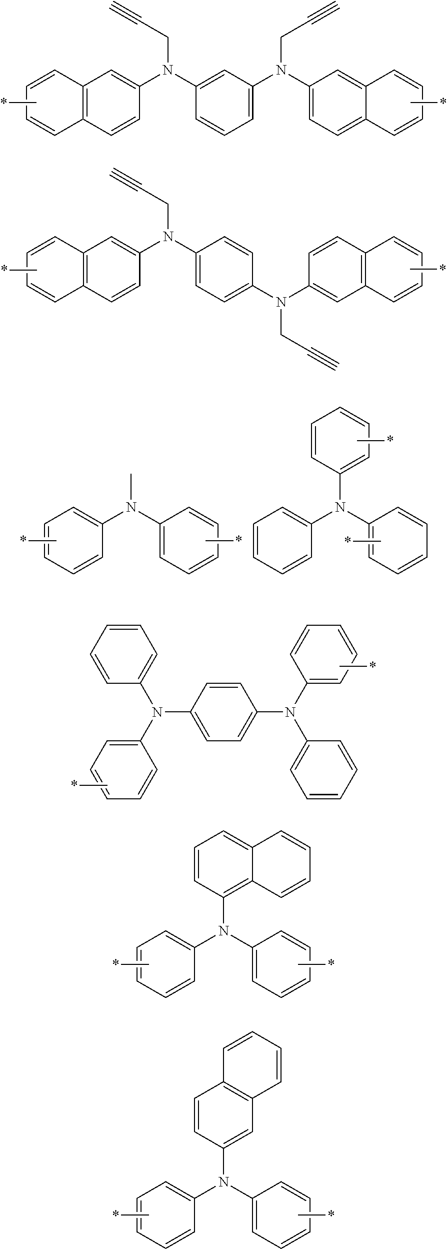

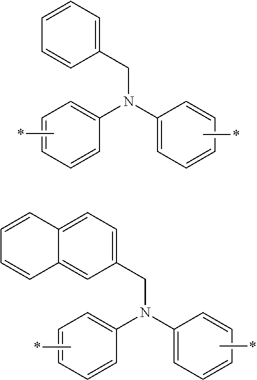

In an embodiment in which L in the formula (A) in (IIA-1) is a fluorene ring, the unit structures A preferably include one or more kinds of additional unit structures having an aromatic ring other than those of the formula (A).

For example, the skeletons that are used as such unit structures may be the amine skeletons and the phenol skeletons described above. Furthermore, the following unit structures are also preferable.

(Examples of Unit Structures Derived from an Aromatic Hydrocarbon Having an Oxygen-Containing Substituent)

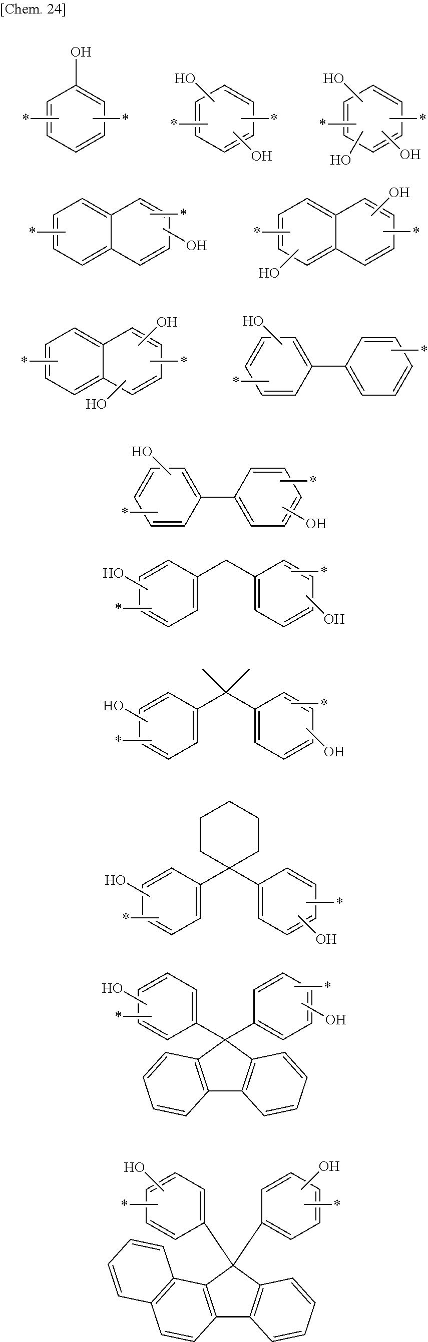

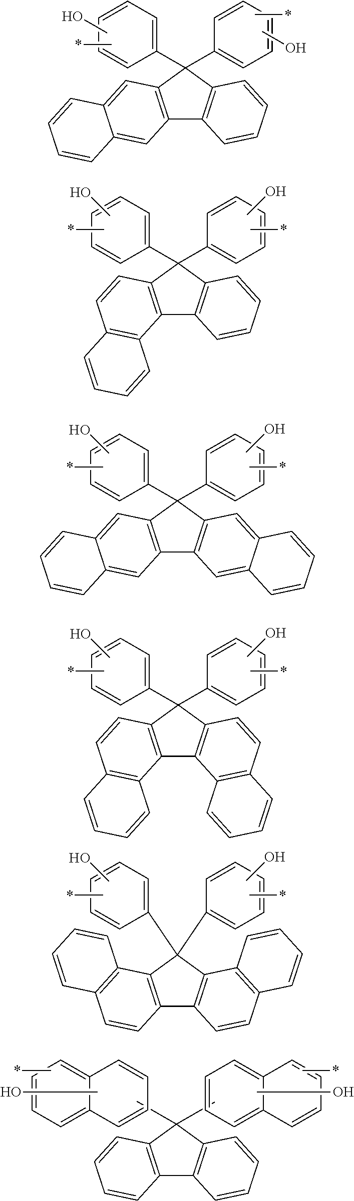

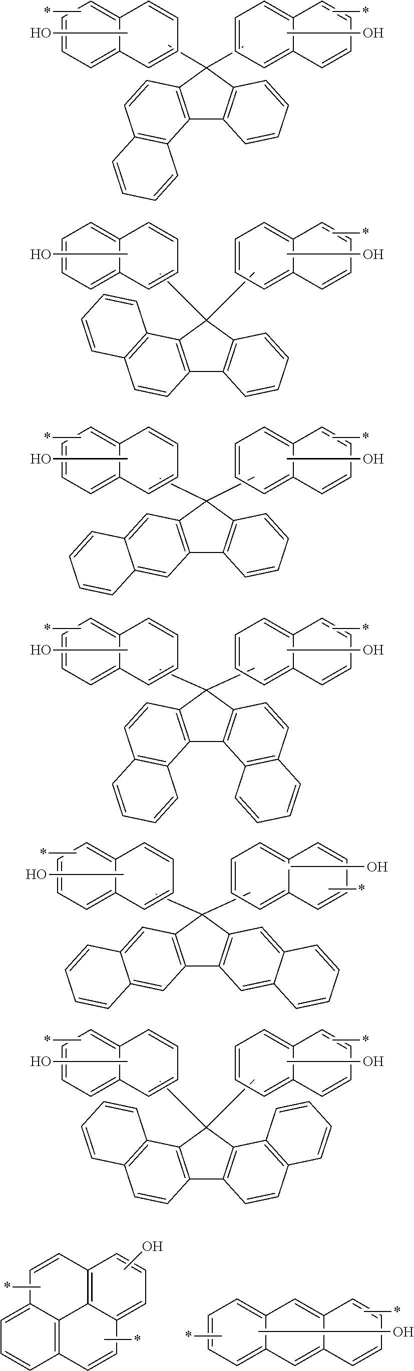

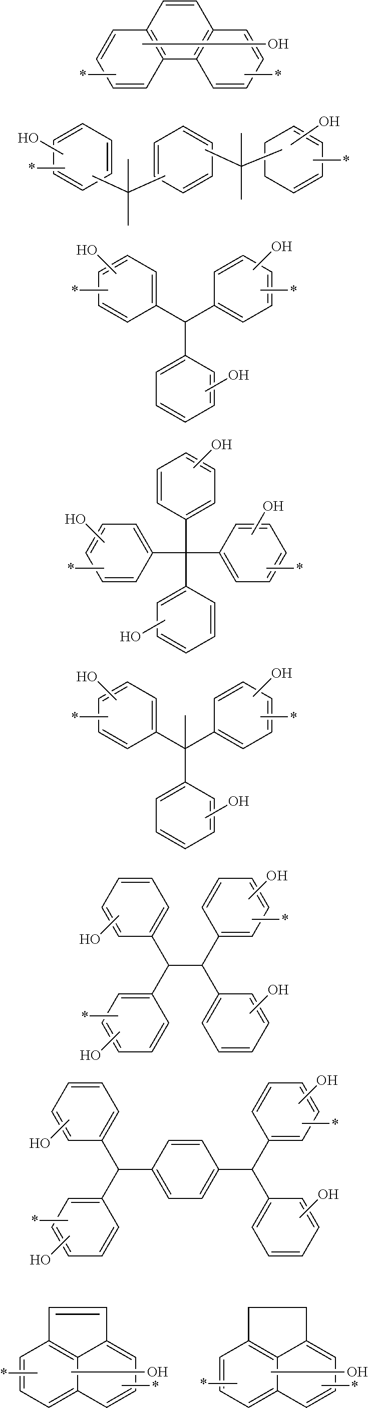

(Examples of Unit Structures Derived from a Heterocyclic Ring and Examples of Unit Structures Derived from Aromatic Hydrocarbons Connected by —NH—)

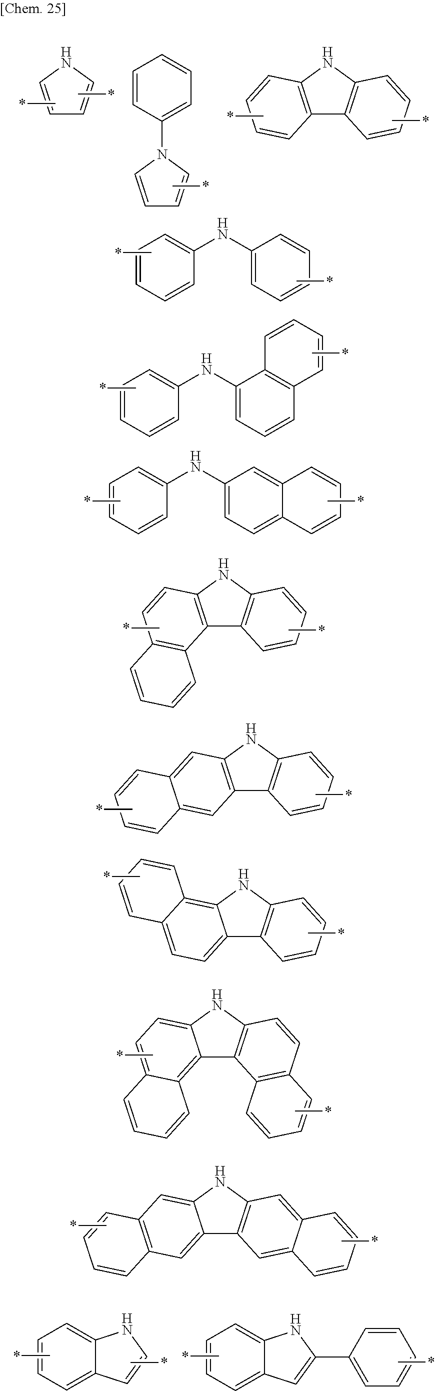

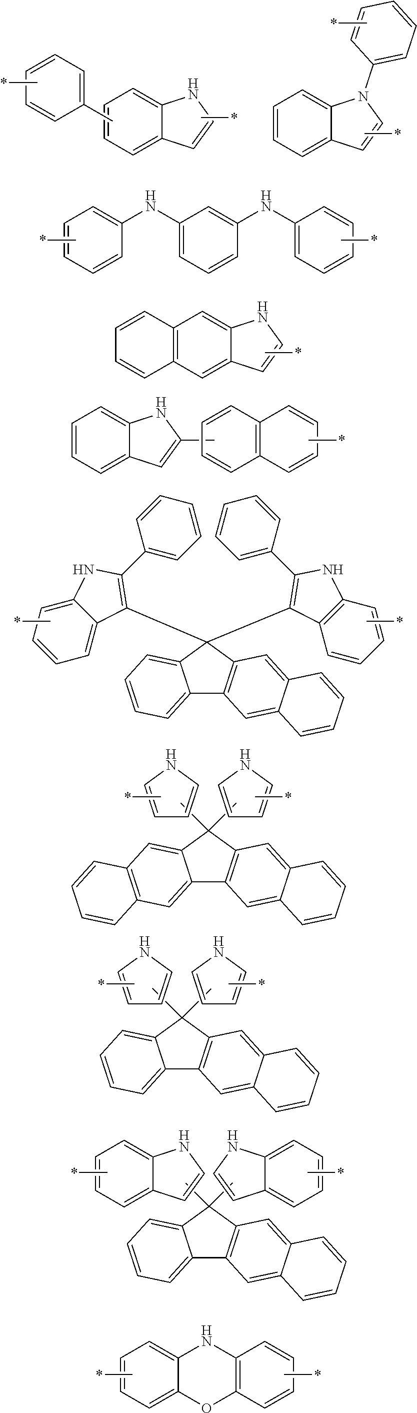

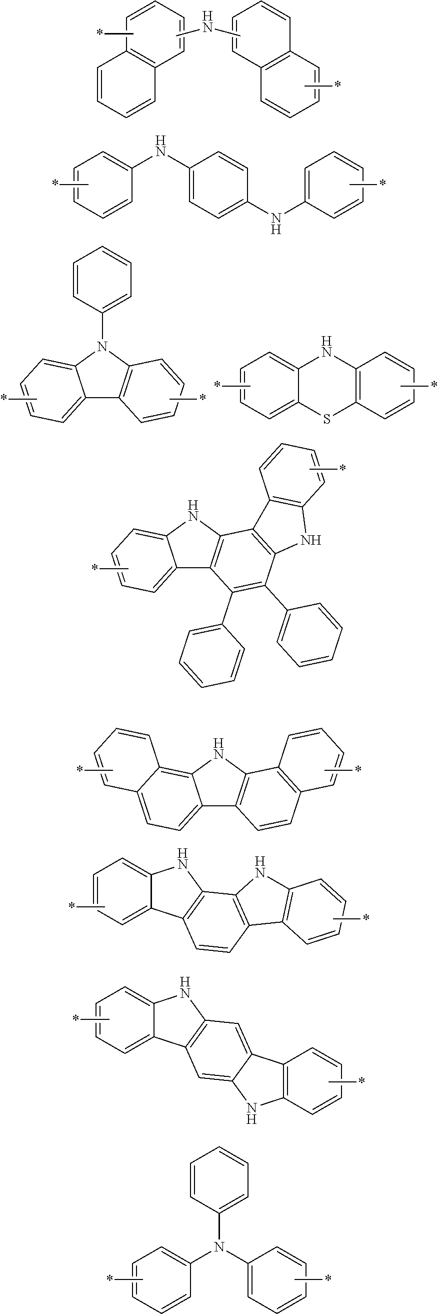

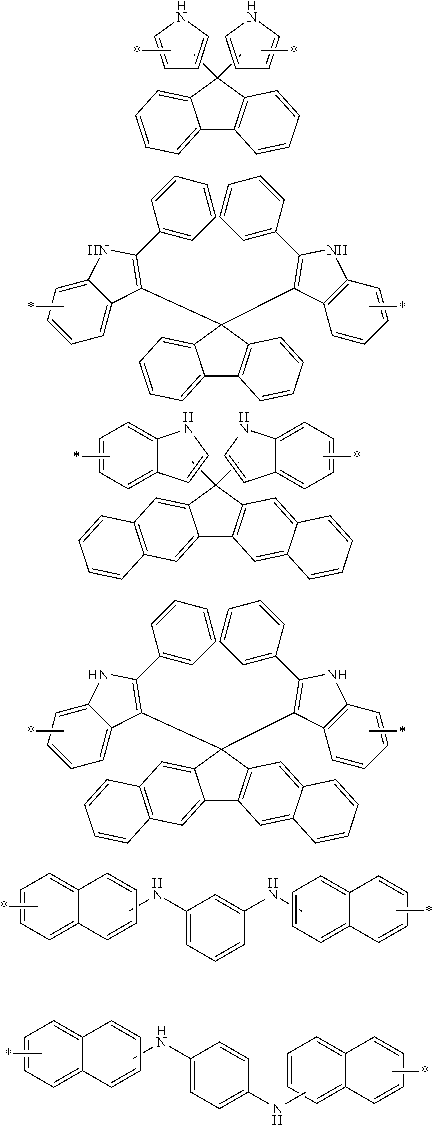

### (IIA-2)

The novolac resin preferably includes composite unit structures A-B represented by formula (AB) below:

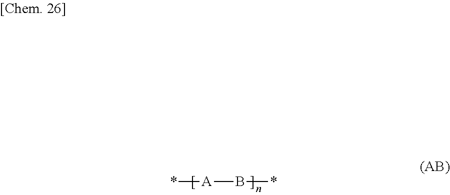

In the formula (AB), n indicates the number of the composite unit structures A-B, and the unit structures A are represented by the formula (A) described in (IIA-1) hereinabove.

### (IIA-2-1) Unit Structures B

The unit structures B are one, or two or more kinds of unit structures that contain a linking carbon atom [see (I-1)] bonded to an aromatic ring in the unit structure A; and include a structure represented by formula (B1), (B2), or (B3) described later in (IIA-2-2) to (IIA-2-4). The unit structure B can connect two unit structures A by covalently bonding to a carbon atom on the azaaryl fused ring of each unit structure A.

Furthermore, at least one composite unit structures A-B may be replaced with a single unit structure equivalent thereto, specifically, one, or two or more kinds of unit structures C that include structures represented by formulas (C1), (C2), and (C3) described later in (IIA-2-2-3), (IIA-2-3-2), and (IIA-2-4-3), respectively.

### (IIA-2-2) Formula (B1)

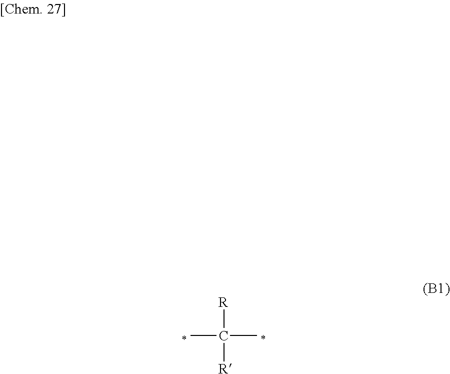

In the formula (B1),

R and R′ each independently denote a hydrogen atom, an optionally substituted C6-C30 aromatic ring, an optionally substituted C3-C30 heterocyclic ring, or an optionally substituted C10 or lower linear, branched, or cyclic alkyl group.

The two valence bonds in the formula (B1) can be covalently bonded to the aromatic rings in the unit structures A.

### (IIA-2-2-1)

In the definition of R and R′ in the formula (B1), the “aromatic ring” and the “heterocyclic ring” are as described in (I-3) and (I-4).

Examples of the “alkyl group” in the definition of R and R′ in the formula (B1) include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, n-heptyl group, n-octyl group, n-nonyl group, and n-decyl group.

Preferably, R and R′ are each independently phenyl, naphthalenyl, anthracenyl, phenanthrenyl, naphthacenyl, or pyrenyl.

### (IIA-2-2-2)

For example, the unit structures including a structure represented by the formula (B1) may include a structure in which two or three identical or differing structures of the formula (B1) are bonded to a divalent or trivalent linking group to form a dimer or trimer structure. In this case, as illustrated in formula (B11) below, one of the two valence bonds in each of the structures of the formula (B1) is bonded to the linking group.

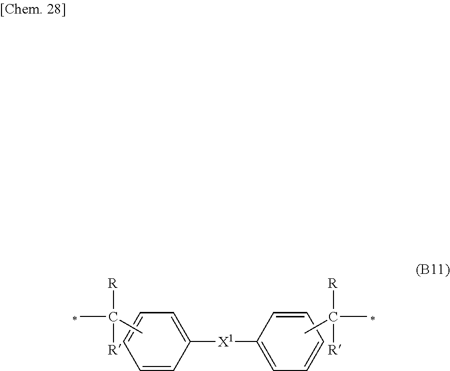

Examples of such linking groups include linking groups having two or three aromatic rings (corresponding to the unit structures A). Specific examples of the divalent or trivalent linking groups include the divalent linking groups (L1) below that are illustrated in formula (B11) above.

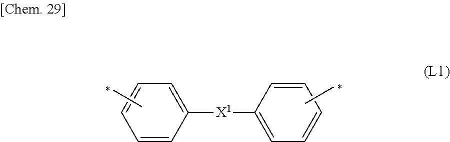

[X¹ denotes a single bond, a methylene group, an oxygen atom, a sulfur atom, or —N(R⁵)—, and R⁵ denotes a hydrogen atom or a C1-C20 hydrocarbon group (that may be a chain hydrocarbon or a cyclic hydrocarbon (that may be aromatic or non-aromatic))]. Examples further include divalent or trivalent linking groups of formulas (L2) and (L3) below.

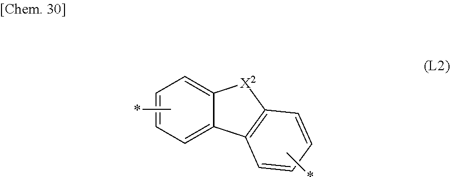

[X² denotes a methylene group, an oxygen atom, or —N(R⁶)—, and R⁶ denotes a hydrogen atom, a C1-C10 aliphatic hydrocarbon group, or a C5-C20 aromatic hydrocarbon group].

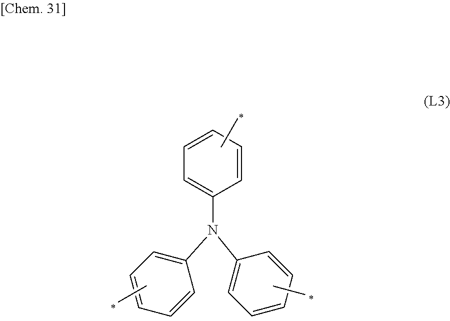

Examples further include a divalent linking group of formula (L4) below that can undergo an addition reaction of an acetylide with a ketone to form a covalent bond with the linking carbon atom.

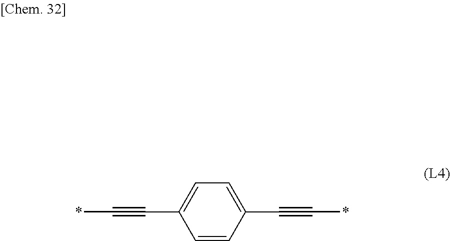 [SMILES: *C#Cc1ccc(C#C*)cc1]

### (IIA-2-2-3)

When at least one of R or R′ in the formula (B1) is an aromatic ring, the aromatic ring [see for example, Ar in formula (B12) below] may be additionally bonded to the other unit structure B.

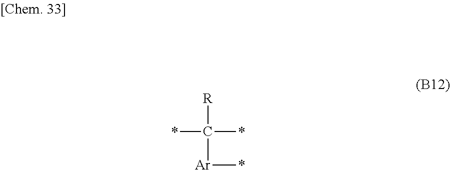

When, in the above case, one valence bond of the linking carbon atom is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in formula (C1) below, the unit structure may be regarded as a single unit structure C equivalent to a composite unit structure A-B and may replace at least one composite unit structure A-B.

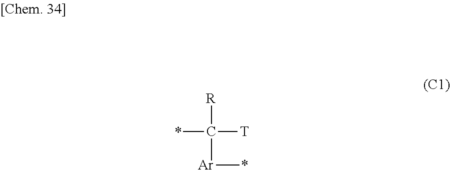

That is, the aromatic ring in the formula (C1) [Ar in the formula (C1)] may be bonded to the other unit structure B and the remaining valence bond of the linking carbon atom illustrated in the formula (C1) may be bonded to the aromatic ring in the unit structure A, thereby extending the polymer chain.

### (IIA-2-2-4)

Some specific examples of the unit structures B including a structure represented by the formula (B1) are illustrated below. * basically indicates a bonding site to the unit structure A. It is needless to mention that the illustrated structures may be part of the whole unit structure.

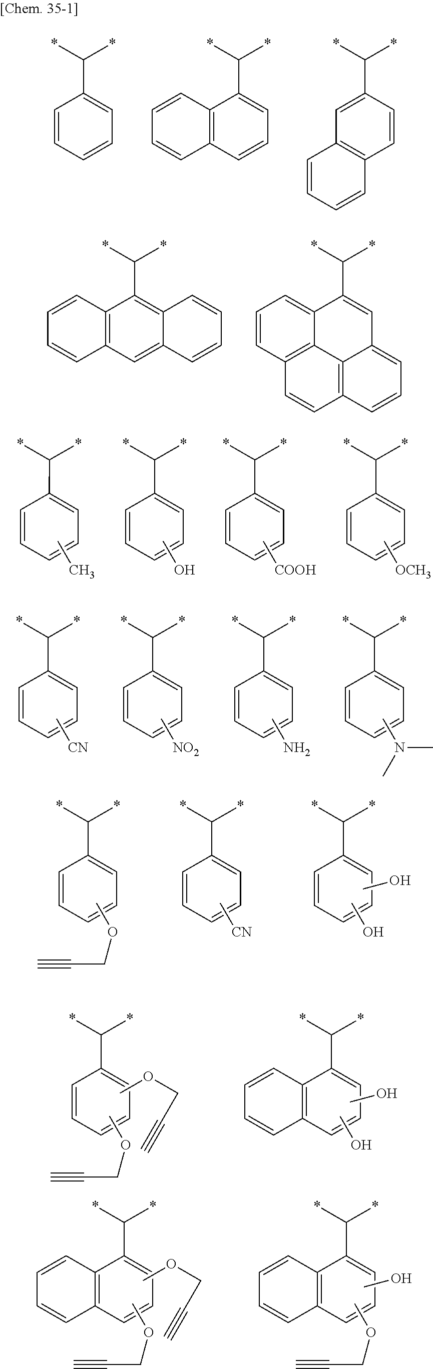

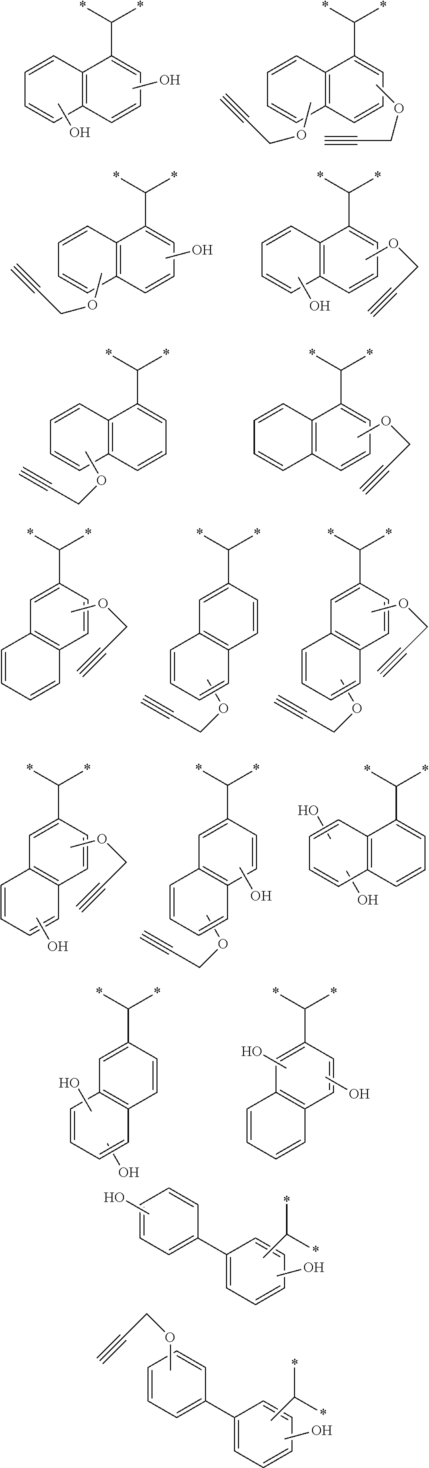

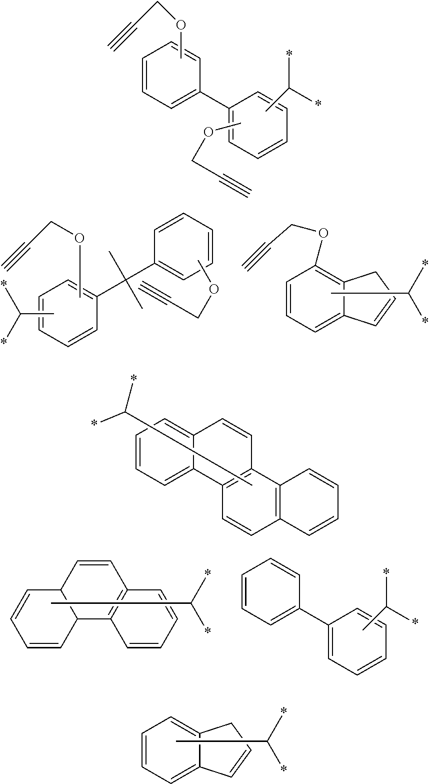

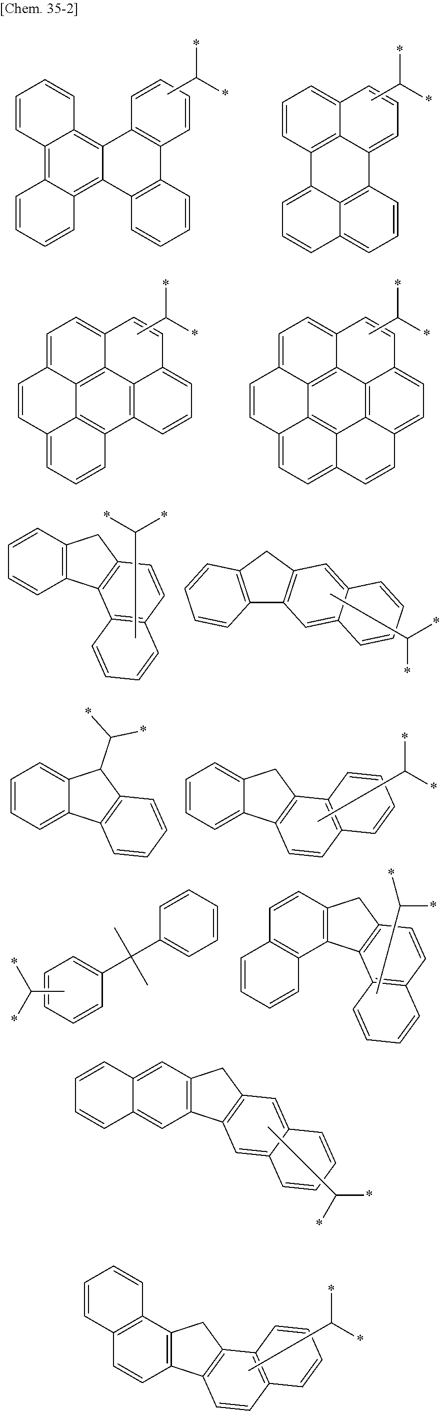

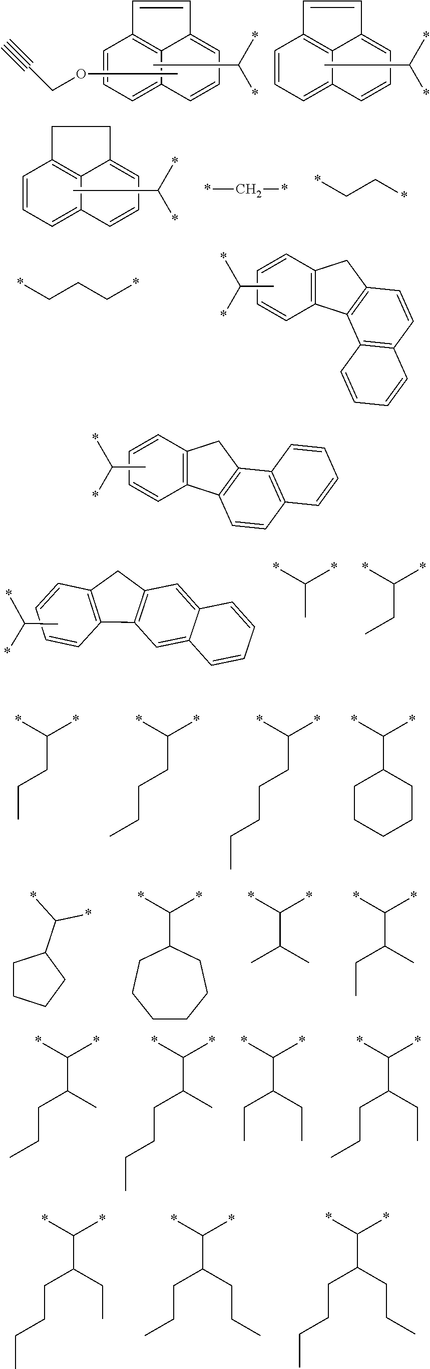

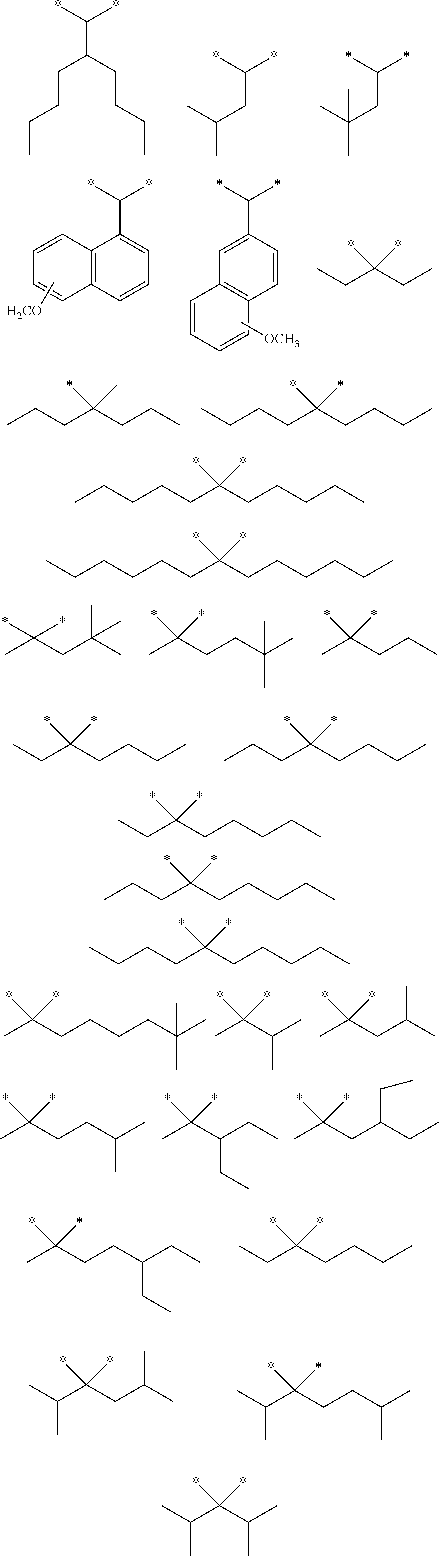

### (IIA-2-3)

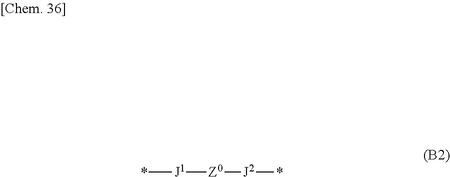

In the formula (B2),
Z⁰ denotes an optionally substituted C6-C30 aromatic ring residue, aliphatic ring residue, or organic group including two aromatic or aliphatic rings connected to each other via a single bond. Examples of the organic groups including two aromatic or aliphatic rings connected to each other via a single bond include divalent residues of, for example, biphenyl, cyclohexylphenyl, and bicyclohexyl.

J¹ and J² each independently denote a direct bond or an optionally substituted divalent organic group. The divalent organic group is preferably a C1-C6 linear or branched alkylene group optionally substituted with a substituent, such as a hydroxyl group, an aryl group (such as a phenyl group or a substituted phenyl group), or a halo group (for example, fluorine). Examples of the linear alkylene groups include methylene group, ethylene group, propylene group, butylene group, pentylene group, and hexylene group.

### (IIA-2-3-1)

Similarly to (IIA-2-2-2) regarding the formula (B1), the unit structures including a structure represented by the formula (B2) may include a structure in which two or three identical or differing structures of the formula (B2) are bonded to a divalent or trivalent linking group to form a dimer or trimer structure.

### (IIA-2-3-2)

Embodiments of the formula (B2) include one in which the unit structure contains an aromatic ring [Z⁰ in the formula (B2)]. Thus, similarly to (IIA-2-2-3) regarding the formula (B1), the aromatic ring [for example, the aromatic ring in Z⁰_{Ar} in formula (B21) below] may be additionally bonded to the other unit structure B [via the vertical valence bond in the formula (B21)].

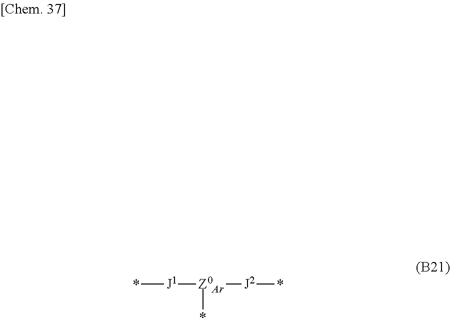

[In the formula (B21),
Z⁰_{Ar} is an optionally substituted C6-C30 aromatic ring residue or organic group including two aromatic rings or aliphatic rings connected to each other via a single bond, the organic group having at least one aromatic ring; the valence bond extending downward from Z⁰_{Ar} belongs to an aromatic ring in Z⁰_{Ar}; and
J¹ and J² are the same as defined in the formula (B2).]

When, in the above case, one valence bond of the linking carbon atom is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in formula (C2) below, the unit structure may be regarded as a single unit structure C equivalent to a composite unit structure A-B and may replace at least one composite unit structure A-B.

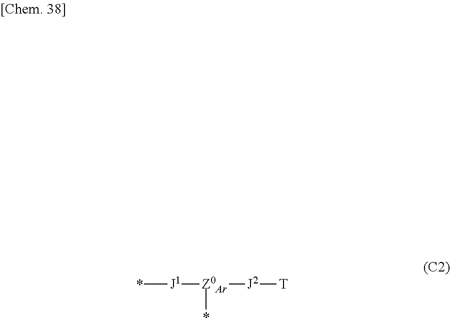

[In the formula (C2),
Z⁰_{Ar}, J¹, and J² are the same as defined in the formula (B21), and
T denotes the polymer terminal.]
   That is, the aromatic ring in the formula (C2) [the aromatic ring in Z⁰_{Ar} in the formula (C2)] may be bonded to the other unit structure B and the remaining valence bond of the linking carbon atom illustrated in the formula (C2) may be bonded to the aromatic ring in the unit structure A, thereby extending the polymer chain.

### (IIA-2-3-3)

Some specific examples of the unit structures including a structure represented by the formula (B2) are illustrated below. * indicates a bonding site to the unit structure A. It is needless to mention that the illustrated structures may be part of the whole unit structure.

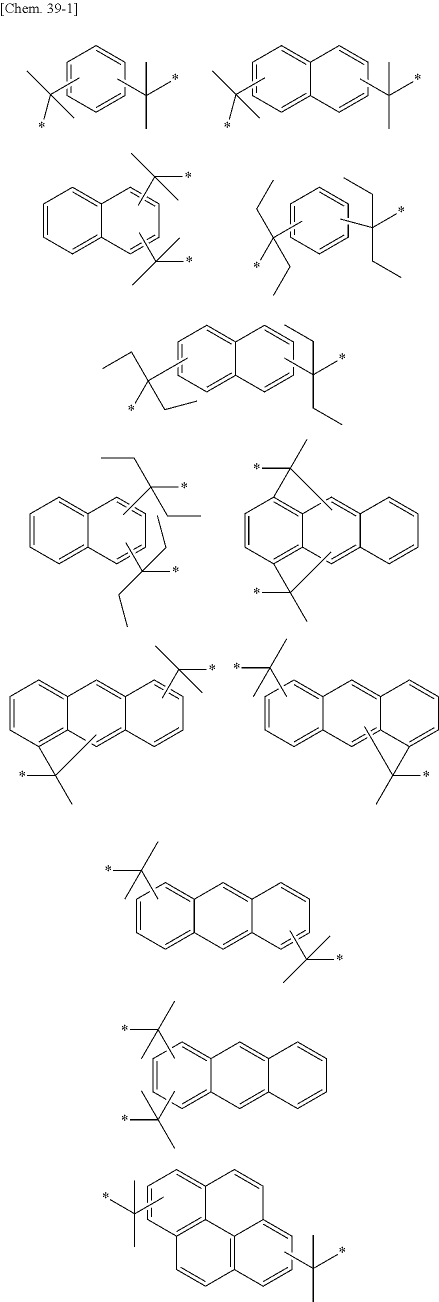

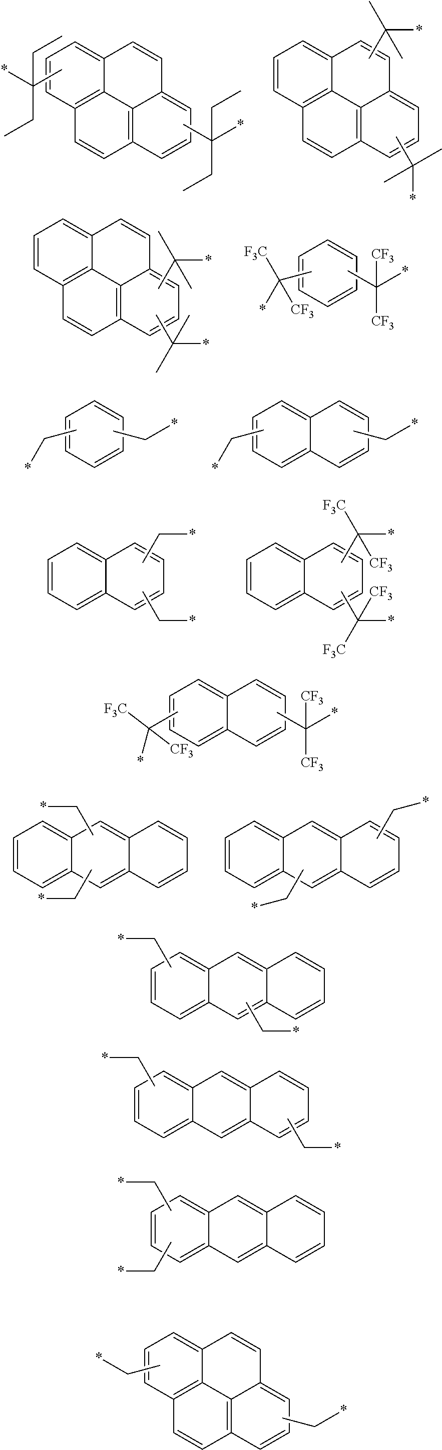

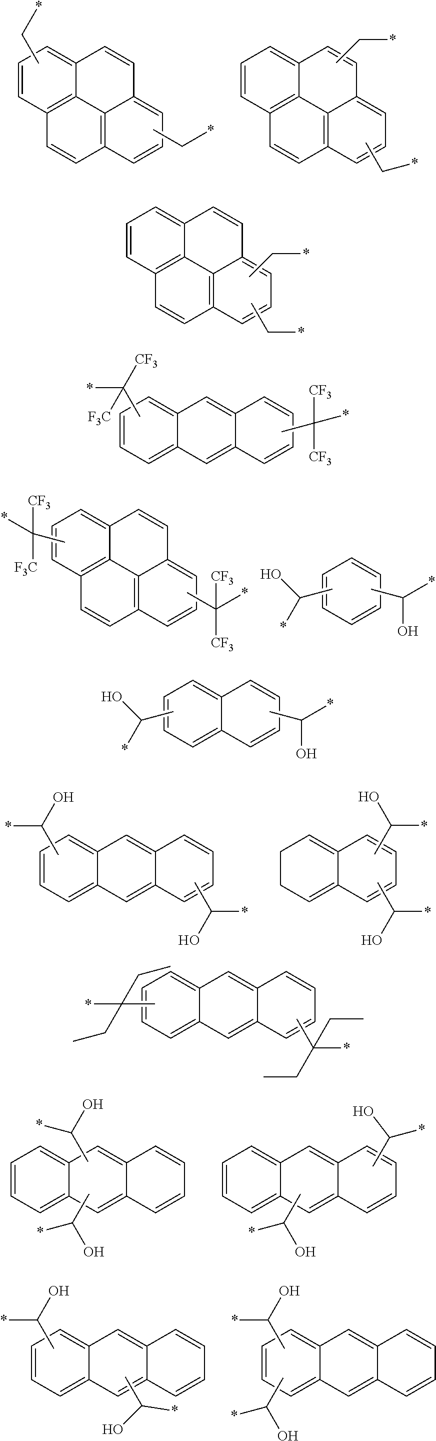

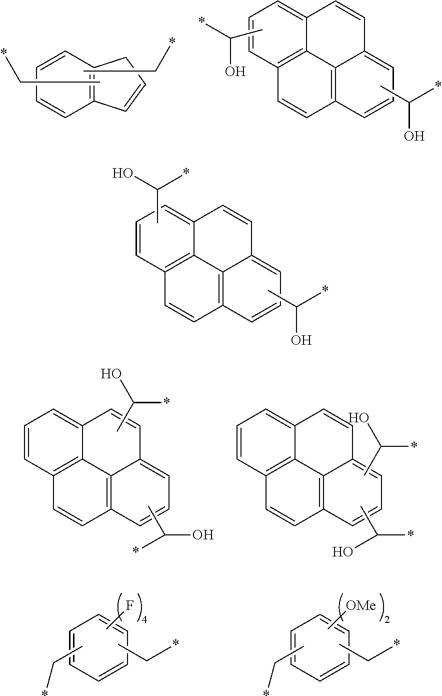

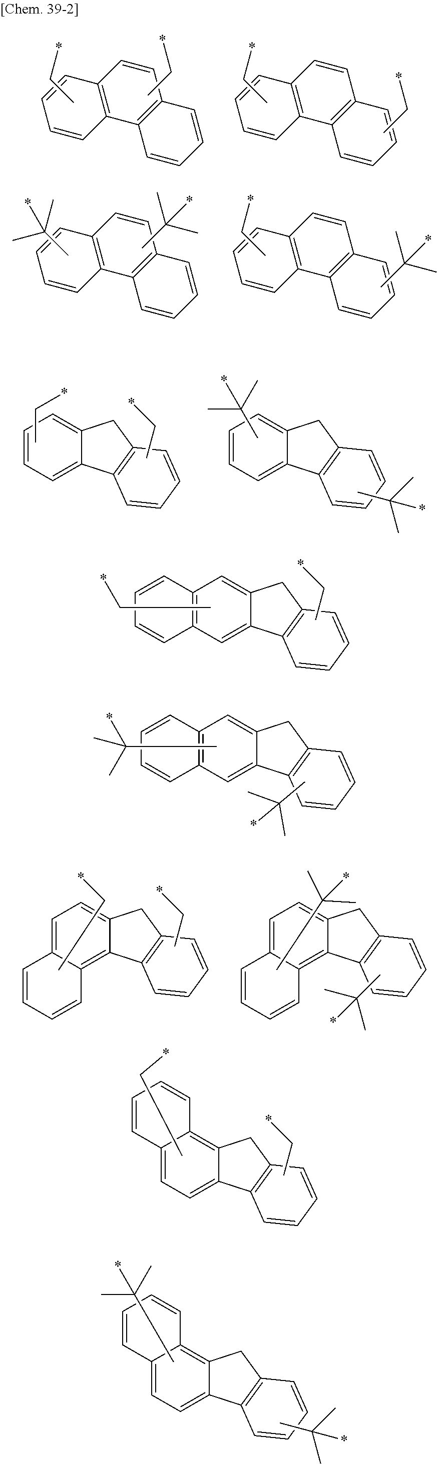

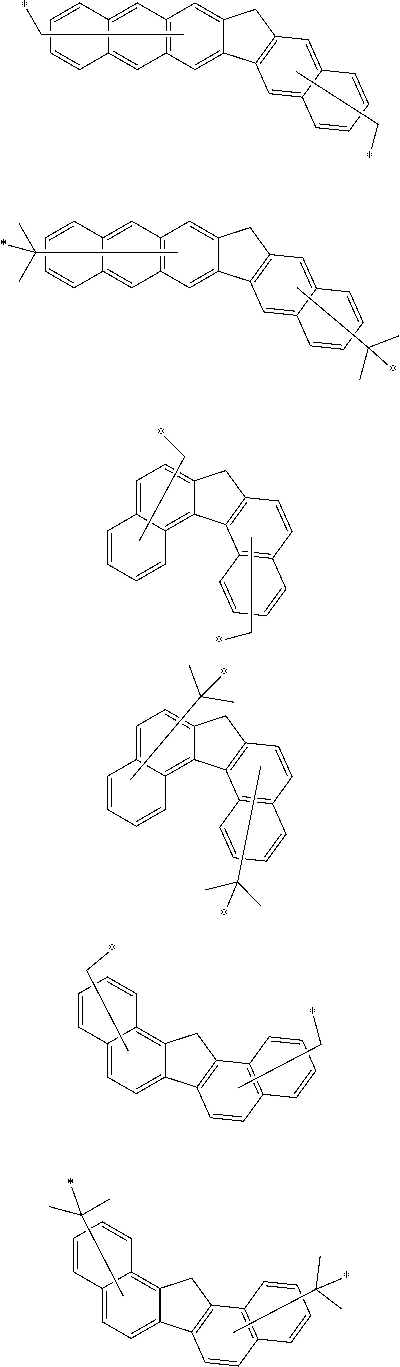

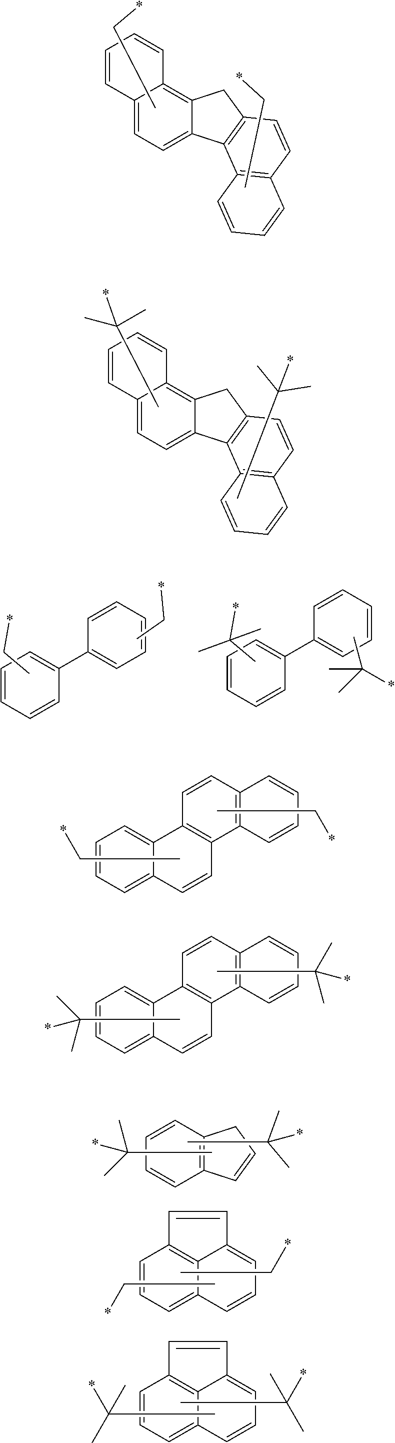

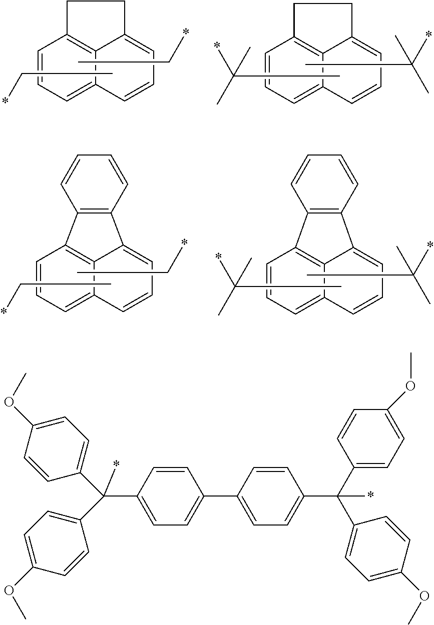

### (IIA-2-4) Formula (B3)

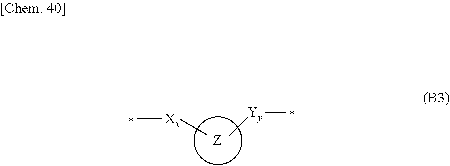

In the formula (B3),
Z is an optionally substituted C4-C25 monocyclic ring or bicyclic, tricyclic, or tetracyclic fused ring. Here, the number of carbon atoms indicates the number of carbon atoms constituting the ring skeleton of the monocyclic ring or the bicyclic, tricyclic, or tetracyclic fused ring except substituents. When the monocyclic ring or the fused ring is a heterocyclic ring, the number of carbon atoms does not include the number of heteroatoms constituting the heterocyclic ring.

The monocyclic ring is a non-aromatic monocyclic ring; and at least one of the monocyclic rings constituting the bicyclic, tricyclic, or tetracyclic ring is a non-aromatic monocyclic ring, and the remaining monocyclic ring or rings may be aromatic monocyclic rings or non-aromatic monocyclic rings.

The monocyclic ring or the bicyclic, tricyclic, or tetracyclic fused ring may be further condensed with one or more aromatic rings to form a pentacyclic or higher fused ring. The number of carbon atoms in the pentacyclic or higher fused ring is preferably 40 or less. The number of carbon atoms here indicates the number of carbon atoms constituting the ring skeleton of the pentacyclic or higher fused ring except substituents. When the pentacyclic or higher fused ring is a heterocyclic ring, the number of carbon atoms does not include the number of heteroatoms constituting the heterocyclic ring.

X and Y denote identical or different —CR³¹R³²— groups, and R³¹ and R³² are the same as or different from each other and each denote a hydrogen atom or a C1-C6 hydrocarbon group.

The letters x and y indicate the numbers of X and Y, respectively, and are each independently 0 or 1.

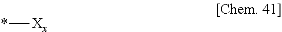

is bonded to any carbon atom (referred to as “carbon atom 1”) constituting the non-aromatic monocyclic ring in Z (when x=1) or extends from the carbon atom 1 (when x=0).

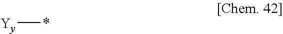

is bonded to any carbon atom (referred to as “carbon atom 2”) constituting the non-aromatic monocyclic ring in Z (when y=1) or extends from the carbon atom 2 (when y=0). The carbon atom 1 and the carbon atom 2 may be the same as or different from each other. The carbon atom 1 and the carbon atom 2 different from each other may belong to the same non-aromatic monocyclic ring or may belong to different non-aromatic monocyclic rings.

Furthermore, the formula (B3) may optionally contain a linking carbon atom other than the carbon atom 1 and the carbon atom 2 [see (IIA-2-4-2) described later].

When Z is a tricyclic or higher fused ring, the one or two non-aromatic monocyclic rings having the carbon atoms 1 and 2 in the formula (B3) may have any permutational positional relationship with the other monocyclic ring or rings in the fused ring. When the carbon atom 1 and the carbon atom 2 belong to different non-aromatic monocyclic rings (referred to as the “non-aromatic monocyclic ring 1” and the “non-aromatic monocyclic ring 2”, respectively), the permutational positional relationship between the non-aromatic monocyclic ring 1 and the non-aromatic monocyclic ring 2 in the fused ring is not limited.

### (IIA-2-4-1)

Similarly to (IIA-2-2-2) regarding the formula (B1), two or three identical or differing structures of the formula (B3) may be bonded to a divalent or trivalent linking group to form a dimer or trimer structure.

### (IIA-2-4-2)

Some specific examples of the organic groups including a structure represented by the formula (B3) are illustrated below. The bonding sites to the unit structures A are not particularly limited. It is needless to mention that the illustrated structures may be part of the whole unit structure.

In some of the following examples, the number of valence bonds (*) exceeds 2. The extra valence bonds may be used to, for example, form bonds to aromatic rings in other polymer chains to establish crosslinking.

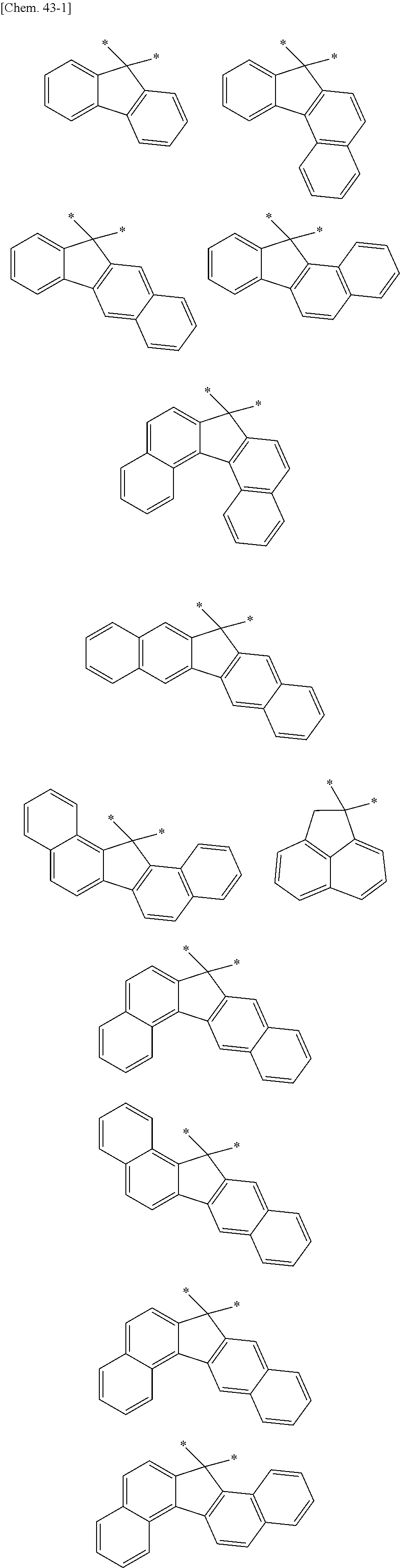

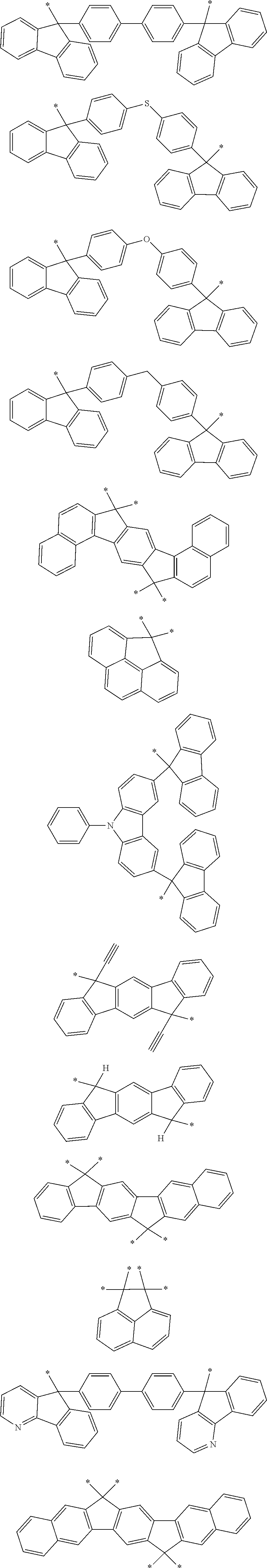

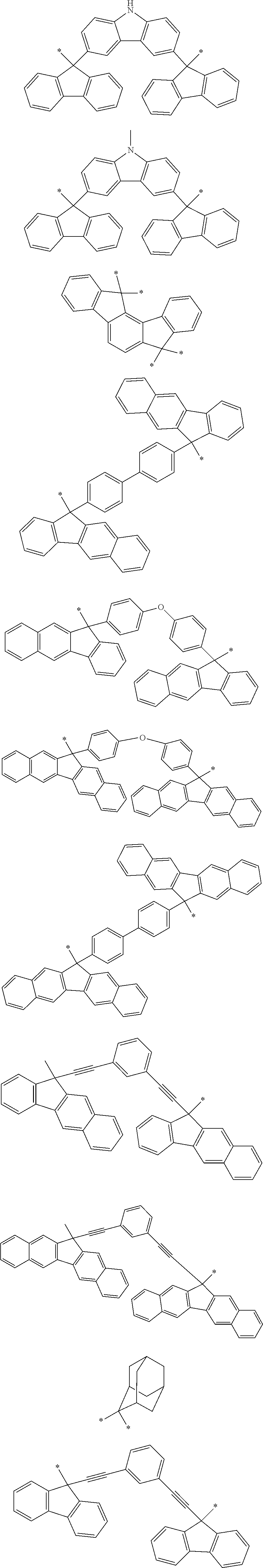

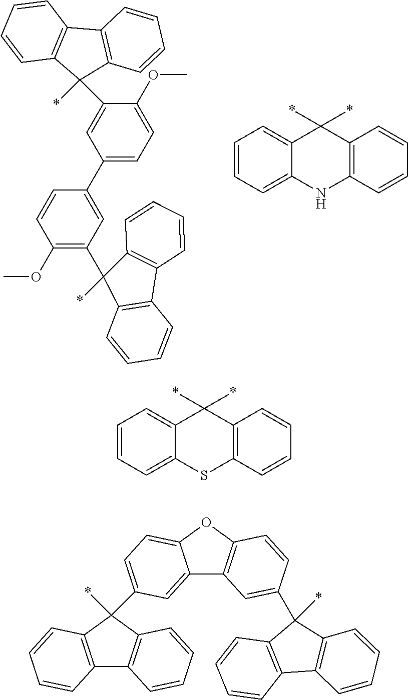

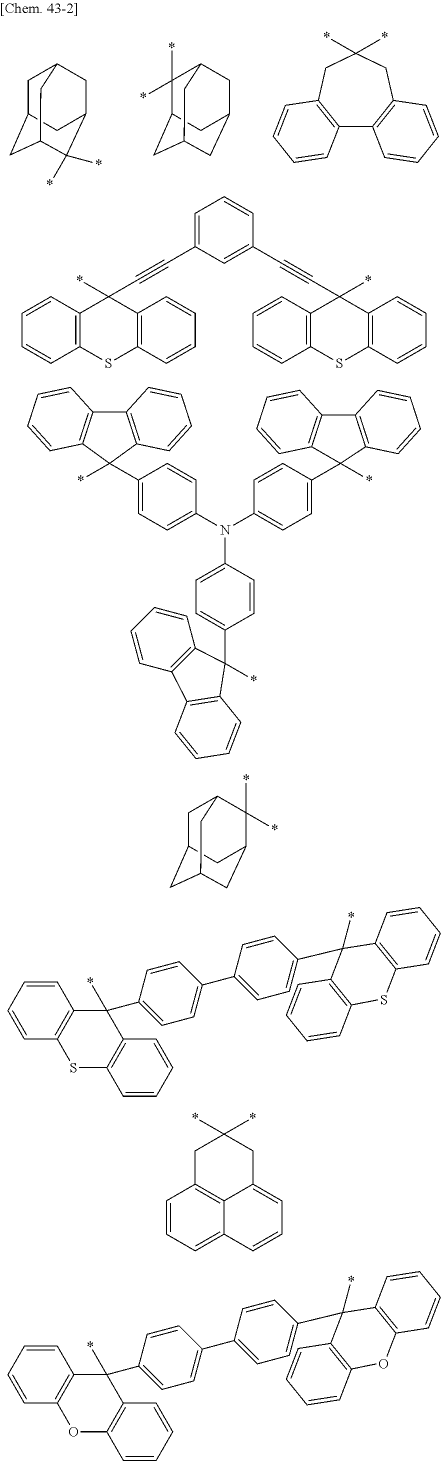

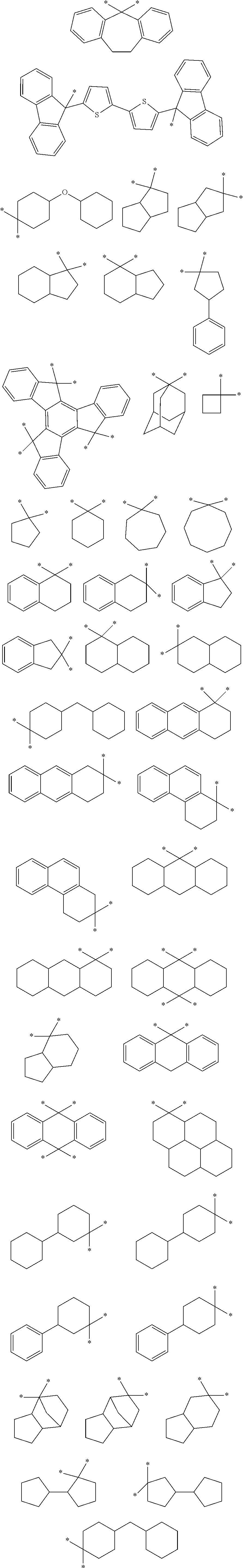

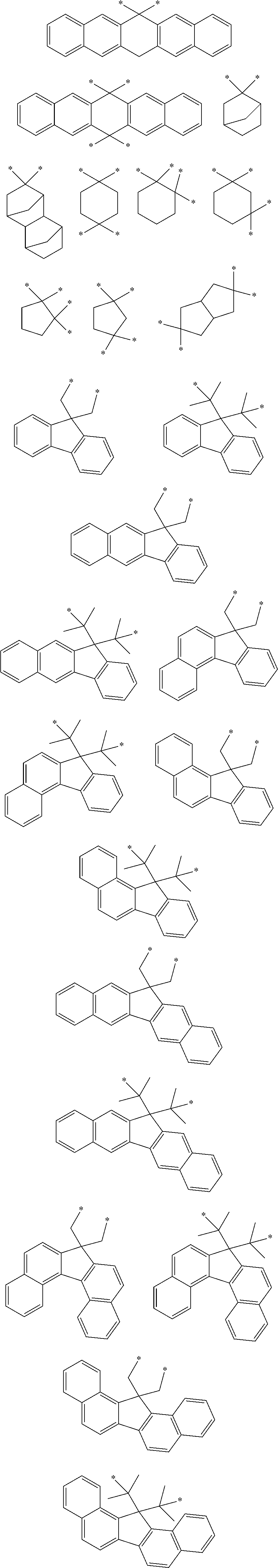

### (IIA-2-4-3)

When Z in the formula (B3) contains an aromatic ring, the aromatic ring [see for example, Ar¹ in formula (B32) below] may be additionally bonded to the other unit structure B.

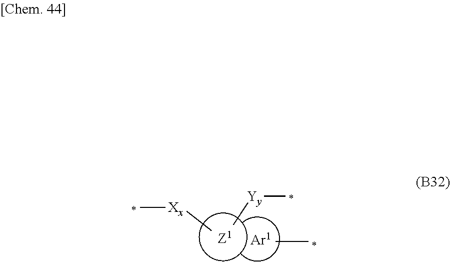

In the formula (B32),
Z¹ denotes at least one non-aromatic monocyclic ring; Ar¹ denotes at least one aromatic monocyclic ring forming a fused ring with the non-aromatic monocyclic ring in Z¹; and the whole of Z and Ar¹ is an optionally substituted C8-C25 bicyclic, tricyclic, tetracyclic, or pentacyclic fused ring. The number of carbon atoms here indicates the number of carbon atoms constituting the ring skeleton of the bicyclic, tricyclic, or tetracyclic fused ring except substituents. When the bicyclic, tricyclic, or tetracyclic fused ring is a heterocyclic ring, the number of carbon atoms does not include the number of heteroatoms constituting the heterocyclic ring.

The bicyclic, tricyclic, tetracyclic, or pentacyclic organic group may be further condensed with one or more aromatic rings to form a hexacyclic or higher ring. The number of carbon atoms in the hexacyclic or higher fused ring is preferably 40 or less. The number of carbon atoms here indicates the number of carbon atoms constituting the ring skeleton of the pentacyclic or higher fused ring except substituents. When the hexacyclic or higher fused ring is a heterocyclic ring, the number of carbon atoms does not include the number of heteroatoms constituting the heterocyclic ring.

In the cyclic organic group, the one, or two or more non-aromatic monocyclic rings in Z¹ may have any permutational positional relationship with the one, or two or more aromatic monocyclic rings in Ar¹. When, for example, Z¹ contains two or more non-aromatic monocyclic rings and Ar¹ contains two or more aromatic monocyclic rings, the non-aromatic monocyclic rings in Z¹ and the aromatic monocyclic rings in Ar¹ may be condensed alternately.

X, Y, x, and y are the same as defined in the formula (B3).

When, in the above case, one valence bond of the linking carbon atom is bonded to a polymer terminal T (such as a hydrogen atom; a functional group, such as a hydroxyl group or an unsaturated aliphatic hydrocarbon group; a terminal unit structure A; or a unit structure A in other polymer chain) as illustrated in formula (C3) below, the unit structure may be regarded as a single unit structure C equivalent to a composite unit structure A-B and may replace at least one composite unit structure A-B.

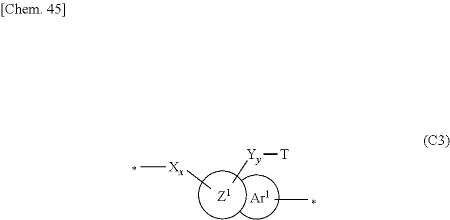

[In the formula (C3),
Z¹, Ar¹, X, Y, x, and y are the same as defined in the formula (B32), and
T denotes the polymer terminal.]
   That is, the aromatic ring in the formula (C3) [Ar¹ in the formula (C3)] may be bonded to the other unit structure B and the remaining valence bond of the linking carbon atom illustrated in the formula (C3) may be bonded to the aromatic ring in the unit structure A, thereby extending the polymer chain.

### (IIA-2-4-4)

More specific examples of the structures of the formula (C3) include formula (C31) below in which T in the formula (C3) is a terminal hydrogen atom. Depending on the valence bonds indicated by p, k₁, and k₂, specifically, when the valence bonds are indicated by p and k₁ or by p and k₂, the unit structure may serve as a single unit structure C equivalent to a composite unit structure A-B.

Incidentally, the unit structure may also function as a unit structure A when the valence bonds are indicated by k₁ and k₂.

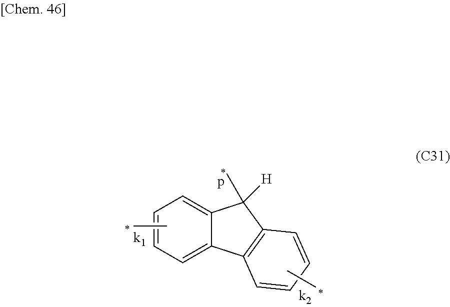

Furthermore, formula (C32) below illustrates a structure of the formula (C3) in which T is a phenyl group. Depending on the valence bonds indicated by p, k₁, k₂, and m, specifically, when the valence bonds are indicated by p and k₁, by p and k₂, or by p and m, this illustrative structure may serve as a single unit structure C equivalent to a composite unit structure A-B.

Incidentally, the unit structure may also function as a unit structure A when the valence bonds are indicated by k₁ and k₂, by k₁ and m, or by k₂ and m.

### [Chem. 47]

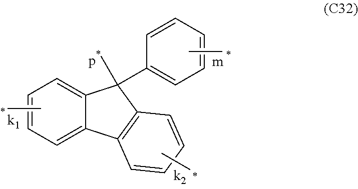

Some specific examples of the unit structures C of the formula (C3) (unit structures equivalent to composite unit structures A-B) are illustrated below. * indicates a bonding site to the unit structure A.

While the unit structures C have, on any of the aromatic rings in the structure, a valence bond that bonds to the unit structure B, the specific examples below omit such a valence bond. It is needless to mention that the illustrated structures may be part of the whole unit structure.

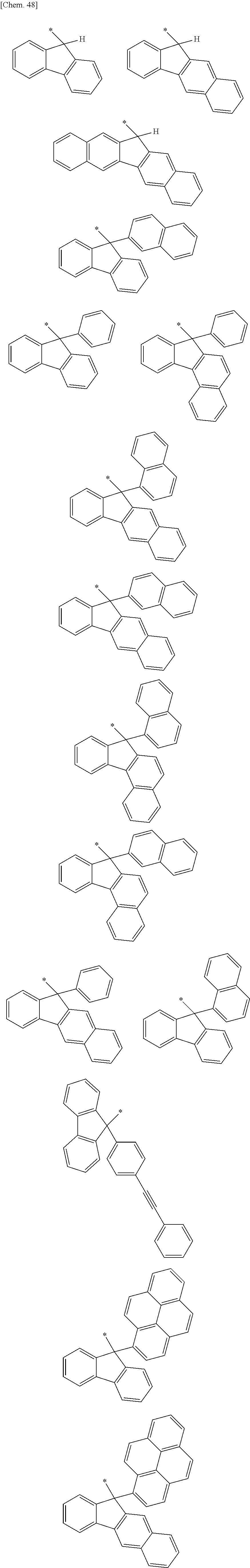

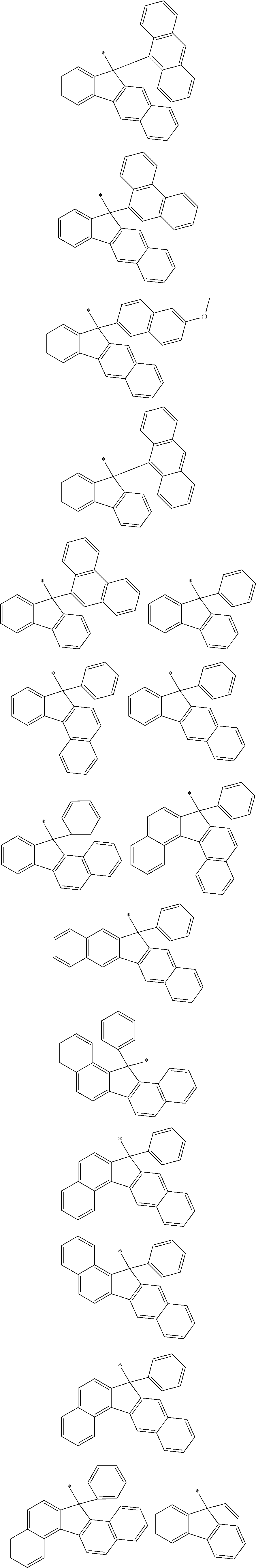

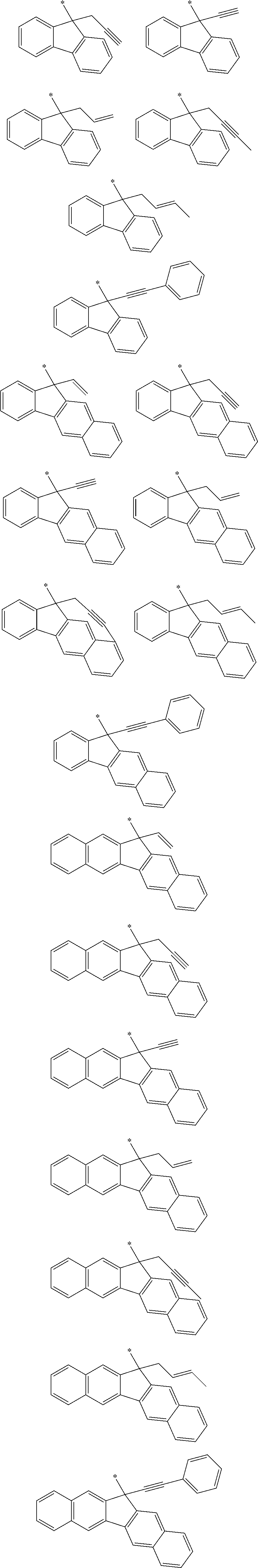

The above specific illustrations without the valence bond on the aromatic ring can serve as specific examples of the polymer terminals.

### (IIA-3)

The novolac resin having a structure represented by the formula (AB) may be prepared by a known method. For example, such a novolac resin may be prepared by condensing a ring-containing compound represented by H-A-H with an oxygen-containing compound represented by, for example, OHC—B, O═C—B, HOB—OH, RO—B—OR, or RO—CH₂—B—CH₂—OR. In the above formulas, A and B are the same as defined hereinabove, and R denotes a halogen or an alkyl group having about 1 to 3 carbon atoms.

The ring-containing compound and the oxygen-containing compound may be each a single compound or a combination of two or more compounds. In the condensation reaction, the oxygen-containing compound may be used in an amount of 0.1 to 10 mol, preferably 0.1 to 2 mol, per mol of the ring-containing compound.

A catalyst may be used in the condensation reaction, with examples including mineral acids, such as sulfuric acid, phosphoric acid, and perchloric acid, organic sulfonic acids, such as p-toluenesulfonic acid, p-toluenesulfonic acid monohydrate, methanesulfonic acid, and trifluoromethanesulfonic acid, and carboxylic acids, such as formic acid and oxalic acid. The amount in which the catalyst is used varies depending on the type of the catalyst used, but is usually 0.001 to 10,000 parts by mass, preferably 0.01 to 1,000 parts by mass, and more preferably 0.05 to 100 parts by mass with respect to 100 parts by mass of the ring-containing compound (when plural, the total of the ring-containing compounds).

The condensation reaction may be carried out without a solvent but is usually performed using a solvent. The solvent is not particularly limited as long as it can dissolve the reaction substrates and does not inhibit the reaction. Examples include 1,2-dimethoxyethane, diethylene glycol dimethyl ether, propylene glycol monomethyl ether, propylene glycol monomethyl ether acetate, tetrahydrofuran, dioxane, 1,2-dichloromethane, 1,2-dichloroethane, toluene, N-methylpyrrolidone, and dimethylformamide. The condensation reaction temperature is usually 40° C. to 200° C., and preferably 100° C. to 180° C. The reaction time varies depending on the reaction temperature but is usually 5 minutes to 50 hours, and preferably 5 minutes to 24 hours.

The weight average molecular weight of the novolac resin according to an aspect of the present invention is usually 500 to 100,000, preferably 600 to 50,000, 700 to 10,000, or 800 to 8,000.

### (IIB) Solvents

The resist underlayer film-forming composition according to an aspect of the present invention includes a solvent.

The solvent is not particularly limited as long as the solvent can dissolve the specific novolac resin and other optional components added as required.

### (IIB-1)

Examples of the solvents include methyl cellosolve acetate, ethyl cellosolve acetate, propylene glycol, propylene glycol monomethyl ether, propylene glycol monoethyl ether, propylene glycol monopropyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol monomethyl ether, diethylene glycol monoethyl ether, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. These solvents may be used singly, or two or more may be used in combination.

### (IIB-2)

Furthermore, the composition may include a combination of a solvent having a boiling point of 160° C. or above and a solvent having a boiling point of below 160° C.

As such a high-boiling solvent, for example, the compound illustrated below that is described in WO 2018/131562 (A1) may be suitably used.

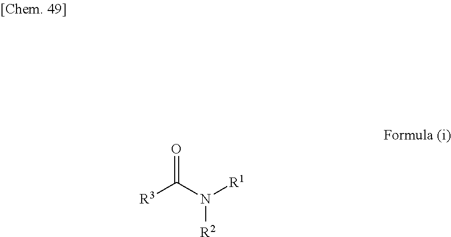

[R¹, R², and R³ in formula (i) each denote a hydrogen atom or a C1-C20 alkyl group optionally interrupted by an oxygen atom, a sulfur atom, or an amide bond, and are the same as or different from one another and are optionally bonded to one another to form a ring structure.]

Alternatively, 1,6-diacetoxyhexane (boiling point: 260° C.) and tripropylene glycol monomethyl ether (boiling point: 242° C.) described in JP 2021-84974 A, and various high-boiling solvents described in paragraph 0082 of the same publication may be suitably used.

Alternatively, dipropylene glycol monomethyl ether acetate (boiling point: 213° C.), diethylene glycol monoethyl ether acetate (boiling point: 217° C.), diethylene glycol monobutyl ether acetate (boiling point: 247° C.), dipropylene glycol dimethyl ether (boiling point: 171° C.), dipropylene glycol monomethyl ether (boiling point: 187° C.), dipropylene glycol monobutyl ether (boiling point: 231° C.), tripropylene glycol monomethyl ether (boiling point: 242° C.), γ-butyrolactone (boiling point: 204° C.), benzyl alcohol (boiling point: 205° C.), propylene carbonate (boiling point: 242° C.), tetraethylene glycol dimethyl ether (boiling point: 275° C.), 1,6-diacetoxyhexane (boiling point: 260° C.), dipropylene glycol (boiling point: 230° C.), and 1,3-butylene glycol diacetate (boiling point: 232° C.) described in JP 2019-20701 A, and various high-boiling solvents described in paragraphs 0023 to 0031 of the same publication may be suitably used.

(IIC) Acids and/or Salts Thereof, and/or Acid Generators

The resist underlayer film-forming composition according to an aspect of the present invention may include an acid and/or a salt thereof, and/or an acid generator.

### (IIC-1)

Examples of the acids include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

The salts may be salts of the acids described above. Examples of the salts that may be suitably used include, but are not limited to, ammonia derivative salts, such as trimethylamine salts and triethylamine salts, pyridine derivative salts, and morpholine derivative salts.

The acids and/or the salts thereof may be used singly, or two or more may be used in combination. The amount thereof is usually 0.0001 to 20 mass %, preferably 0.0005 to 10 mass %, and more preferably 0.01 to 5 mass % relative to the total solid content.

### (IIC-2)

Examples of the acid generators include thermal acid generators and photo acid generators.

### (IIC-2-1)

Examples of the thermal acid generators include 2,4,4,6-tetrabromocyclohexadienone, benzoin tosylate, 2-nitrobenzyl tosylate, K-PURE [registered trademark] series CXC-1612, CXC-1614, TAG-2172, TAG-2179, TAG-2678, TAG2689, and TAG2700 (manufactured by King Industries), SI-45, SI-60, SI-80, SI-100, SI-110, and SI-150 (manufactured by SANSHIN CHEMICAL INDUSTRY CO., LTD.), and other organic sulfonic acid alkyl esters.

### (IIC-2-2)

The photo acid generator generates an acid when a resist is exposed to light, thereby allowing the acidity of the underlayer film to be adjusted. The use of the photo acid generator is an approach to adjusting the acidity of the underlayer film to the acidity of a resist layer that is formed thereon. Furthermore, the shape of a pattern formed in the upper resist layer may be controlled by the adjustment of the acidity of the underlayer film.

Examples of the photo acid generators used in the resist underlayer film-forming composition of the present invention include onium salt compounds, sulfonimide compounds, and disulfonyldiazomethane compounds.

Examples of the onium salt compounds include iodonium salt compounds, such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro-n-butanesulfonate, triphenylsulfonium camphorsulfonate, and triphenylsulfonium trifluoromethanesulfonate.

Examples of the sulfonimide compounds include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

### (IIC-2-3)

The acid generators may be used singly, or two or more may be used in combination.

When the acid generator is used, the amount thereof is 0.01 to 10 parts by mass, or 0.1 to 8 parts by mass, or 0.5 to 5 parts by mass with respect to 100 parts by mass of the solid content in the resist underlayer film-forming composition.

### (IID) Other Optional Components

Where necessary, the resist underlayer film-forming composition according to an aspect of the present invention may include additives, such as crosslinking agents, surfactants, light absorbers, rheology modifiers, and adhesion aids, in addition to the above components.

### (IID-1) Crosslinking Agents

Typical examples of the crosslinking agents include aminoplast crosslinking agents and phenoplast crosslinking agents.

Highly heat-resistant crosslinking agents may be used as the crosslinking agents. Compounds that contain a crosslinking substituent having an aromatic ring (for example, a benzene ring or a naphthalene ring) in the molecule may be preferably used as the highly heat-resistant crosslinking agents.

### (IID-1-1)

Exemplary aminoplast crosslinking agents include highly alkylated, alkoxylated, or alkoxyalkylated melamines, benzoguanamines, glycolurils, ureas, and polymers thereof. Preferably, the crosslinking agents have at least two crosslinking substituents, with examples including methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and methoxymethylated thiourea. Condensates of these compounds may also be used.

Preferably, the crosslinking agent is at least one selected from the group consisting of tetramethoxymethylglycoluril and hexamethoxymethylmelamine.

Some specific examples are illustrated below:

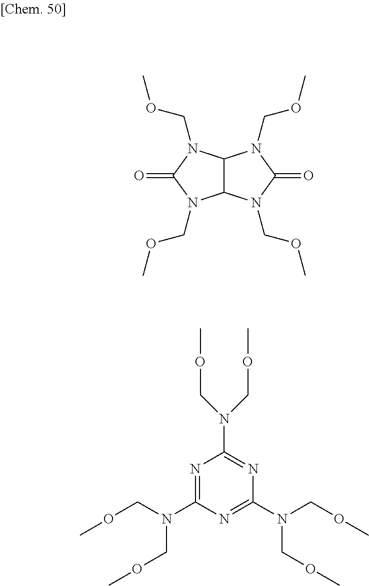

### (IID-1-2)

Exemplary phenoplast crosslinking agents include highly alkylated, alkoxylated, or alkoxyalkylated aromatics, and polymers thereof. Preferably, the crosslinking agents have at least two crosslinking substituents in the molecule, with examples including 2,6-dihydroxymethyl-4-methylphenol, 2,4-dihydroxymethyl-6-methylphenol, bis(2-hydroxy-3-hydroxymethyl-5-methylphenyl)methane, bis(4-hydroxy-3-hydroxymethyl-5-methylphenyl)methane, 2,2-bis(4-hydroxy-3,5-dihydroxymethylphenyl)propane, bis(3-formyl-4-hydroxyphenyl)methane, bis(4-hydroxy-2,5-dimethylphenyl)formylmethane, and α,α-bis(4-hydroxy-2,5-dimethylphenyl)-4-formyltoluene. Condensates of these compounds may also be used.

Examples of such compounds, in addition to those described above, include compounds that have a partial structure of formula (4) below, and polymers or oligomers that have a repeating unit of formula (5) below.

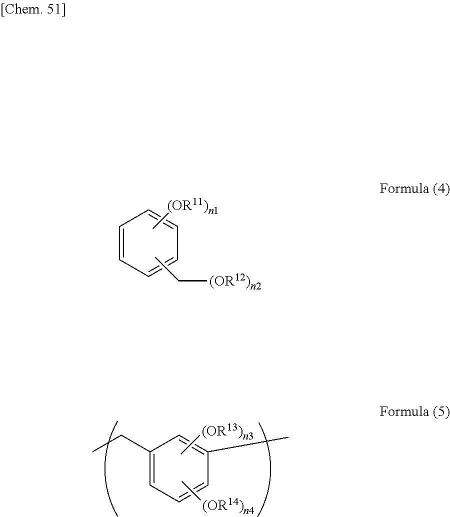

R¹¹, R¹², R¹³, and R¹⁴ are each a hydrogen atom or a C1-C10 alkyl group. Examples of the alkyl groups include those described hereinabove. n1 is an integer of 1 to 4, n2 is an integer of 1 to (5−n1), and (n1+n2) is an integer of 2 to 5. n3 is an integer of 1 to 4, n4 is 0 to (4−n3), and (n3+n4) is an integer of 1 to 4. The number of the repeating unit structures in the oligomers and the polymers may be in the range of 2 to 100, or 2 to 50.

Some specific examples are illustrated below:

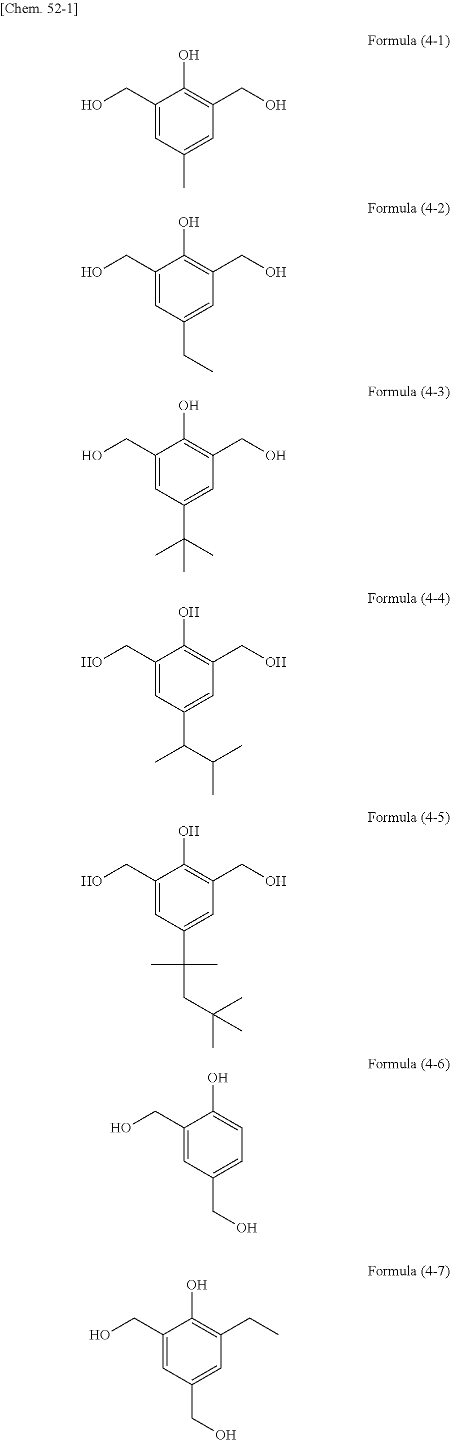

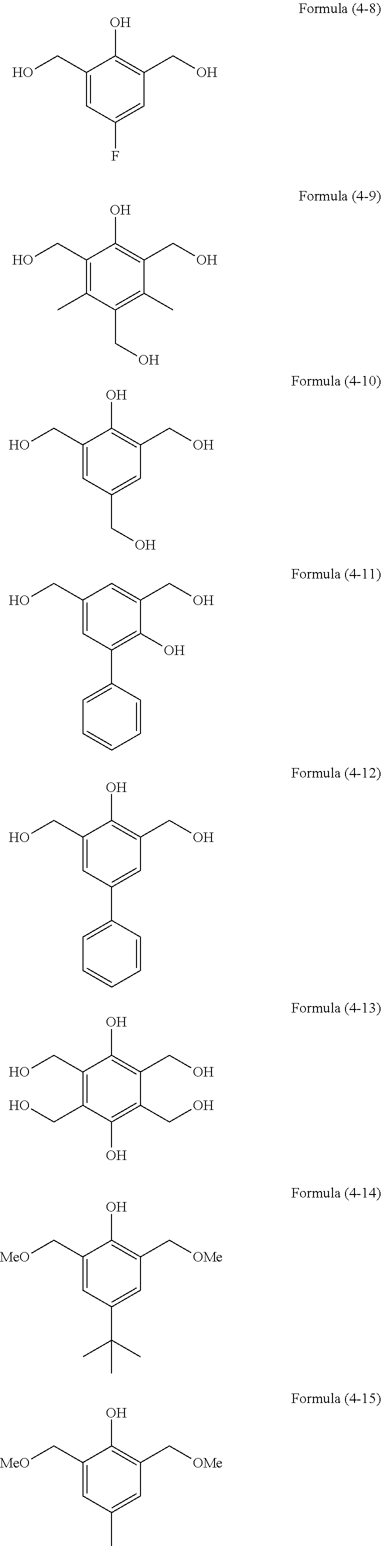

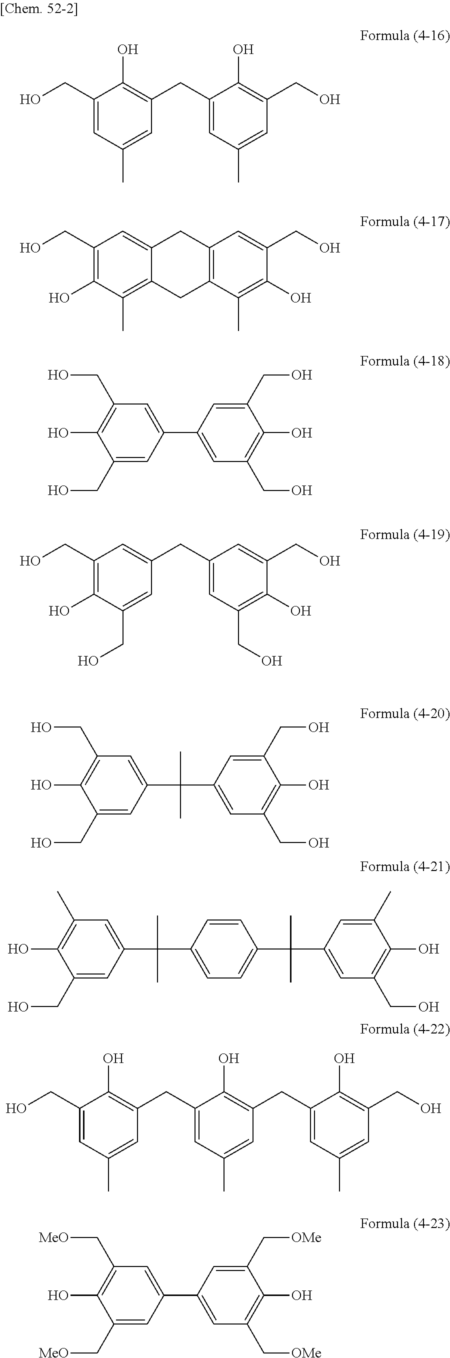

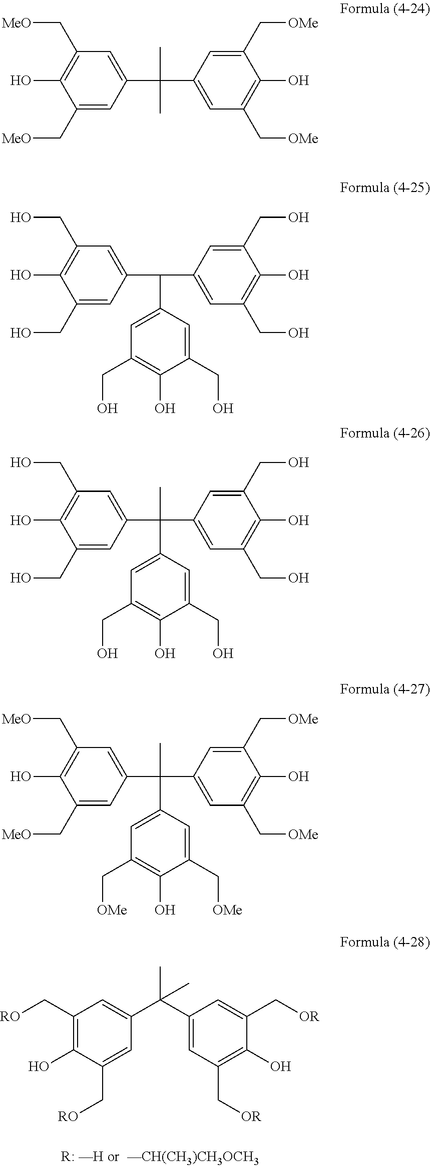

### (IID-1-3)

The crosslinking agents, such as the aminoplast crosslinking agents and the phenoplast crosslinking agents, may be used singly, or two or more may be used in combination. The aminoplast crosslinking agents may be produced by a method known per se or deemed as known or may be purchased from the market.

The amount in which the crosslinking agent, such as the aminoplast crosslinking agent or the phenoplast crosslinking agent, is used varies depending on factors, such as the coating solvent that is used, the base substrate that is used, the solution viscosity that is required, and the film shape that is required, but is 0.001 mass % or more, 0.01 mass % or more, 0.05 mass % or more, 0.5 mass % or more, or 1.0 mass % or more, and is 80 mass % or less, 50 mass % or less, 40 mass % or less, 20 mass % or less, or 10 mass % or less, based on the total solid content in the resist underlayer film-forming composition according to the present invention.

### (IID-2) Surfactants

To reduce the occurrence of defects, such as pinholes or striation, and to further enhance the applicability to surface unevenness, the resist underlayer film-forming composition according to the present invention may include a surfactant.

Examples of the surfactants include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether; polyoxyethylene alkyl aryl ethers, such as polyoxyethylene octyl phenol ether and polyoxyethylene nonyl phenol ether; polyoxyethylene/polyoxypropylene block copolymers; sorbitan fatty acid esters, such as sorbitan monolaurate, sorbitan monopalmitate, sorbitan monostearate, sorbitan monooleate, sorbitan trioleate, and sorbitan tristearate; and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate;
fluorine surfactants, such as EFTOP series EF301, EF303, and EF352 (product names, manufactured by Tohkem Products Corp.), MEGAFACE series F171, F173, R-30, and R-40 (product names, manufactured by DIC CORPORATION), FLUORAD series FC430 and FC431 (product names, manufactured by Sumitomo 3M Ltd.), ASAHI GUARD AG710, and SURFLON series S-382, SC101, SC102, SC103, SC104, SC105, and SC106 (product names, manufactured by AGC Inc.); and
organosiloxane polymer KP341 (manufactured by Shin-Etsu Chemical Co., Ltd.).

The amount in which the surfactant is added is usually 2.0 mass % or less, and preferably 1.0 mass % or less relative to the total solid content in the resist underlayer film-forming composition according to the present invention. The surfactants may be added singly, or two or more may be added in combination.

### (IID-3) Other Additives

Some example light absorbers that may be suitably used include commercially available light absorbers described in “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light absorber is usually added in a proportion of 10 mass % or less, preferably 5 mass % or less relative to the total solid content in the resist underlayer film-forming composition according to the present invention.

A rheology modifier may be added mainly to enhance the fluidity of the resist underlayer film-forming composition and thereby, particularly in the baking step, to enhance the uniformity in thickness of a resist underlayer film and to increase the filling performance of the resist underlayer film-forming composition with respect to the inside of holes. Specific examples thereof include phthalic acid derivatives, such as dimethyl phthalate, diethyl phthalate, diisobutyl phthalate, dihexyl phthalate, and butyl isodecyl phthalate; adipic acid derivatives, such as di-n-butyl adipate, diisobutyl adipate, diisooctyl adipate, and octyl decyl adipate; maleic acid derivatives, such as di(n-butyl) maleate, diethyl maleate, and dinonyl maleate; oleic acid derivatives, such as methyl oleate, butyl oleate, and tetrahydrofurfuryl oleate; and stearic acid derivatives, such as n-butyl stearate and glyceryl stearate. The rheology modifier is usually added in a proportion of less than 30 mass % relative to the total solid content in the resist underlayer film-forming composition according to the present invention.

An adhesion aid may be added mainly to enhance the adhesion between the resist underlayer film-forming composition and a substrate or a resist and thereby to prevent the detachment of the resist particularly during development. Specific examples thereof include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, dimethylvinylethoxysilane, diphenyldimethoxysilane, and phenyltriethoxysilane; silazanes, such as hexamethyldisilazane, N,N′-bis(trimethylsilyl)urea, dimethyltrimethylsilylamine, and trimethylsilylimidazole; silanes, such as vinyltrichlorosilane, γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea. The adhesion aid is usually added in a proportion of less than 5 mass %, preferably less than 2 mass % relative to the total solid content in the resist underlayer film-forming composition according to the present invention.

The solid content in the resist underlayer film-forming composition according to the present invention is 0.1 to 70 mass % or 0.1 to 60 mass %. The solid content is the content of all the components except the solvent in the resist underlayer film-forming composition. The proportion of the crosslinkable resin in the solid content may be 1 to 99.9 mass %, or 50 to 99.9 mass %, or 50 to 95 mass %, or 50 to 90 mass %.

### III: Resist Underlayer Films

For example, a resist underlayer film may be formed as described below using the resist underlayer film-forming composition according to the present invention.

The resist underlayer film-forming composition according to an aspect of the present invention is applied with an appropriate technique, such as a spinner or a coater, onto a semiconductor device substrate (such as, for example, a silicon wafer substrate, a silicon dioxide-coated substrate (a SiO₂ substrate), a silicon nitride substrate (a SiN substrate), a silicon oxynitride substrate (a SiON substrate), a titanium nitride substrate (a TiN substrate), a tungsten substrate (a W substrate), a glass substrate, an ITO substrate, a polyimide substrate, or a low-dielectric constant material (low-k material)-coated substrate), and the coating is baked using a heating device, such as a hot plate, to form a resist underlayer film. The baking conditions are appropriately selected from baking temperatures of 80° C. to 800° C. and amounts of baking time of 0.3 to 60 minutes. The baking temperature is preferably 150° C. to 400° C., and the baking time is preferably 0.5 to 2 minutes. The atmosphere gas at the time of baking may be air or an inert gas, such as nitrogen or argon. In an embodiment, in particular, the oxygen concentration is preferably 1% or less. Here, the film thickness of the underlayer film that is formed is, for example, 10 to 1000 nm, or 20 to 500 nm, or 30 to 400 nm, or 50 to 300 nm. Furthermore, replicas (mold replicas) of a quartz imprinting mold may be produced by using quartz substrates as the substrates.

Furthermore, an adhesion layer and/or a silicon-containing layer containing 99 mass % or less, or 50 mass % or less of Si may be formed on the resist underlayer film according to an aspect of the present invention by application or deposition. For example, an adhesion layer described in JP 2013-202982 A or JP 5827180 B2 may be formed, or a silicon-containing resist underlayer film (inorganic resist underlayer film)-forming composition described in WO 2009/104552 (A1) may be applied by spin coating. Furthermore, a Si-based inorganic material film may be formed by such a method as a CVD method.

The resist underlayer film-forming composition according to an aspect of the present invention may be applied onto a semiconductor substrate having a stepped region and a stepless region (a so-called non-planar substrate) and may be baked to reduce the difference in height between the stepped region and the stepless region.

### IV: Methods for Manufacturing Semiconductor Devices

### (IVA)

(i)

A method for manufacturing a semiconductor device according to an aspect of the present invention includes:
a step of forming on a semiconductor substrate a resist underlayer film from the resist underlayer film-forming composition according to an aspect of the present invention;
a step of forming a resist film on the resist underlayer film;
a step of forming a resist pattern by irradiation of the resist film with light or electron beam followed by development;
a step of etching the resist underlayer film through the resist pattern and thereby patterning the resist underlayer film; and
a step of processing the semiconductor substrate through the resist underlayer film having been patterned.
   (ii)

A method for manufacturing a semiconductor device according to an aspect of the present invention includes:
a step of forming on a semiconductor substrate a resist underlayer film from the resist underlayer film-forming composition according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern and thereby patterning the hard mask;
a step of etching the resist underlayer film through the hard mask having been patterned and thereby patterning the resist underlayer film; and
a step of processing the semiconductor substrate through the resist underlayer film having been patterned.
   (iii)

A method for manufacturing a semiconductor device according to an aspect of the present invention includes:
a step of forming on a semiconductor substrate a resist underlayer film from the resist underlayer film-forming composition according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern and thereby patterning the hard mask;
a step of etching the resist underlayer film through the hard mask having been patterned and thereby patterning the resist underlayer film;
a step of removing the hard mask; and
a step of processing the semiconductor substrate through the resist underlayer film having been patterned.
   (iv)

A method for manufacturing a semiconductor device according to an aspect of the present invention includes:
a step of forming on a semiconductor substrate a resist underlayer film from the resist underlayer film-forming composition according to an aspect of the present invention;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern and thereby patterning the hard mask;
a step of etching the resist underlayer film through the hard mask having been etched and thereby patterning the resist underlayer film;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.

Semiconductor substrates may be processed using the manufacturing methods (i) to (iv) described above.

### (IVB)

The step of forming a resist underlayer film from the resist underlayer film-forming composition according to an aspect of the present invention is as described in [III. Resist underlayer films].

A hard mask, such as a silicon-containing film, may be formed as a second resist underlayer film on the resist underlayer film resulting from the above step, and a resist pattern may be formed thereon [(IVA) (ii) to (iv)].

The hard mask may be a film formed by applying an inorganic substance or the like, or may be a film formed by depositing an inorganic substance or the like by a deposition method, such as CVD or PVD. Examples include SiON film, SiN film, and SiO₂ film.

Furthermore, a bottom anti-reflective coating (BARC), and/or a resist shape correction film having no antireflection function may be formed on the hard mask.

In the step of forming a resist pattern, the exposure is performed through a mask (a reticle) for forming a predetermined pattern or is carried out by direct drawing. For example, g-line, i-line, KrF excimer laser, ArF excimer laser, EUV, or electron beam may be used as the exposure source. After the exposure, post exposure baking is performed as required. Subsequently, the latent image is developed with a developing solution (for example, a 2.38 mass % aqueous tetramethylammonium hydroxide solution, butyl acetate), and the pattern is further rinsed with a rinsing solution or pure water to remove the developing solution used. Subsequently, post-baking is performed to dry the resist pattern and to enhance the adhesion with respect to the substrate.

The etching steps after the resist pattern formation are performed by dry etching.

The processing of the hard mask (the silicon-containing film), the resist underlayer film, and the substrate may be performed using a gas, specifically, CF₄, CHF₃, CH₂F₂, CH₃F, C₄F₆, C₄F₈, O₂, N₂O, NO₂, H₂, or He. These gases may be used singly, or two or more gases may be mixed. Furthermore, argon, nitrogen, carbon dioxide, carbonyl sulfide, sulfur dioxide, neon, or nitrogen trifluoride may be mixed with the above gases.

### (IVC)

The resist film may be patterned by a nanoimprinting method or a self-assembled film method.

In a nanoimprinting method, a resist composition is molded with a patterned mold that is transparent to the irradiation light. In a self-assembled film method, a pattern is formed using a self-assembled film that naturally forms a regular structure on the order of nanometers, for example, a diblock polymer (such as polystyrene-polymethyl methacrylate).

In a nanoimprinting method, a silicon-containing layer (a hard mask layer) may be optionally formed by application or deposition on the resist underlayer film before the application of a curable composition for forming a resist film. An adhesion layer may be formed on the resist underlayer film or the silicon-containing layer (the hard mask layer) by application or deposition, and a curable composition for forming a resist film may be applied onto the adhesion layer.

### (IVD)

Wet etching is sometimes performed for the purposes of simplifying the process step and reducing the damage to the workpiece substrate. This leads to smaller variations in processing dimensions and smaller pattern roughness, and enables processing of substrates with a high yield. Thus, the removal of the hard mask in (IVA) (iii) and (iv) may be performed by either etching or using an alkaline chemical solution. When, in particular, an alkaline chemical solution is used, the components are not particularly limited but the solution preferably includes any of the following alkaline components.

Examples of the alkaline components include tetramethylammonium hydroxide, tetraethylammonium hydroxide, tetrapropylammonium hydroxide, tetrabutylammonium hydroxide, methyltripropylammonium hydroxide, methyltributylammonium hydroxide, ethyltrimethylammonium hydroxide, dimethyldiethylammonium hydroxide, benzyltrimethylammonium hydroxide, hexadecyltrimethylammonium hydroxide, and (2-hydroxyethyl)trimethylammonium hydroxide, monoethanolamine, diethanolamine, triethanolamine, 2-(2-aminoethoxy) ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine, triisopropanolamine, tetrahydrofurfurylamine, N-(2-aminoethyl) piperazine, 1,8-diazabicyclo[5.4.0]undecene-7, 1,4-diazabicyclo[2.2.2]octane, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]nonene-5. From the point of view of handling in particular, tetramethylammonium hydroxide and tetraethylammonium hydroxide are particularly preferable, and an inorganic base may be used in combination with the quaternary ammonium hydroxide. Preferred inorganic bases are alkali metal hydroxides, such as potassium hydroxide, sodium hydroxide, and rubidium hydroxide, with potassium hydroxide being more preferable.

### EXAMPLES

### (1) Synthesis of Polymers

Compounds A, compounds B, compounds C, catalysts D, solvents E, and reprecipitation solvents F described below were used for the synthesis of structural formulas (S1) to (S23) and (S′1) to (S′23) as polymers for use in resist underlayer films and the synthesis of structural formulas (SS1) and (SS2) as Comparative Examples.

### (1-1) Compounds A to C

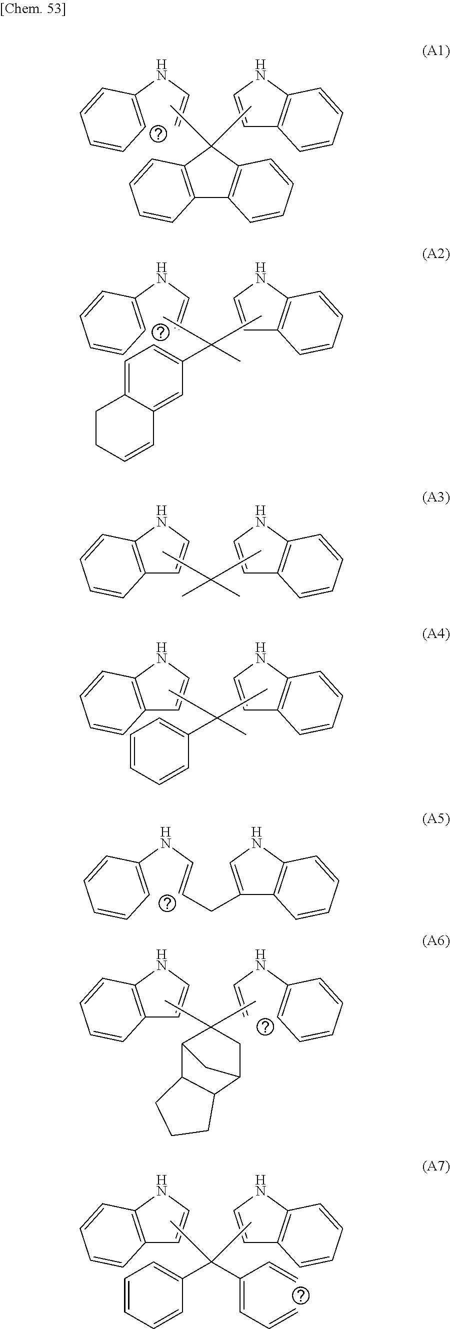

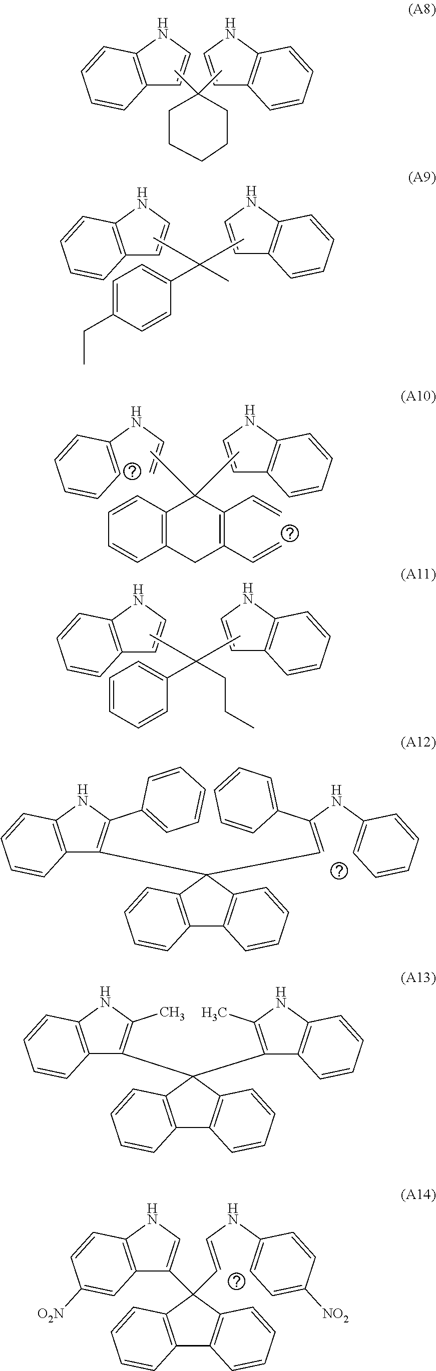

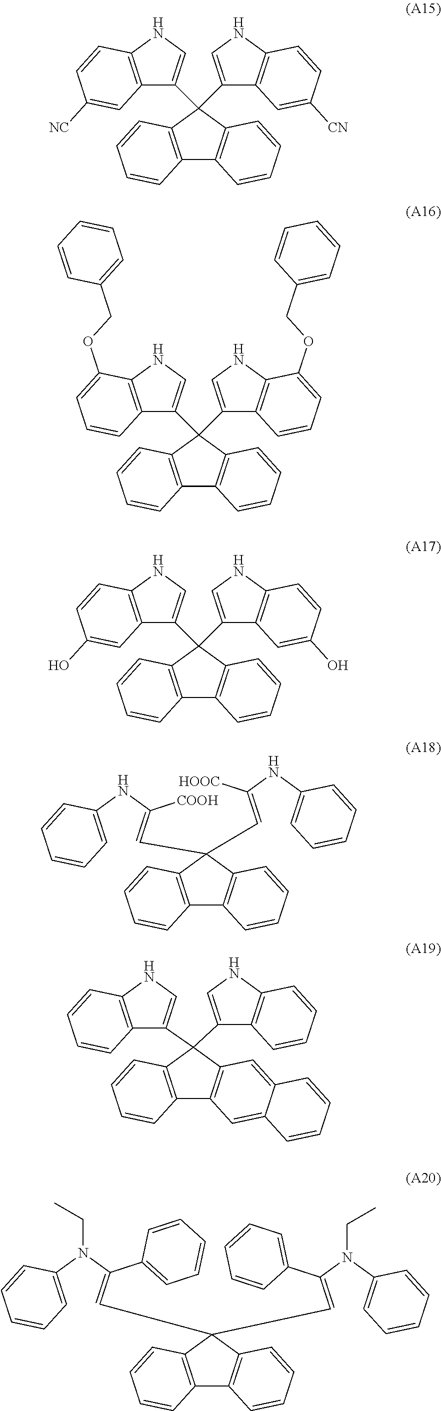

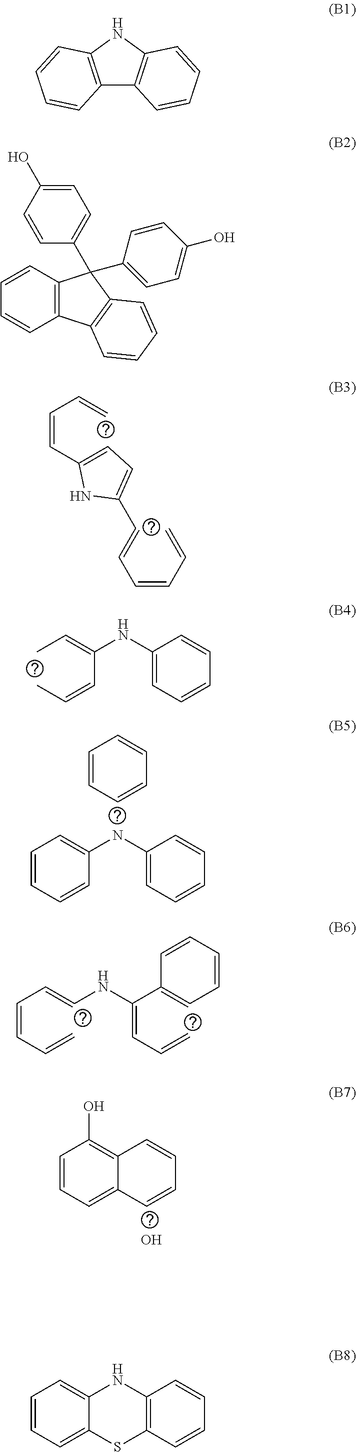

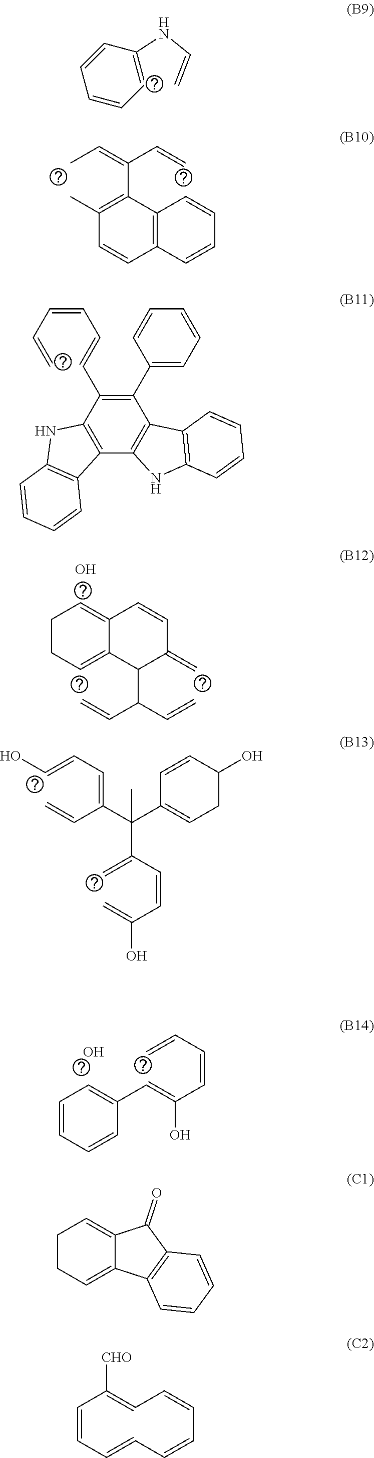

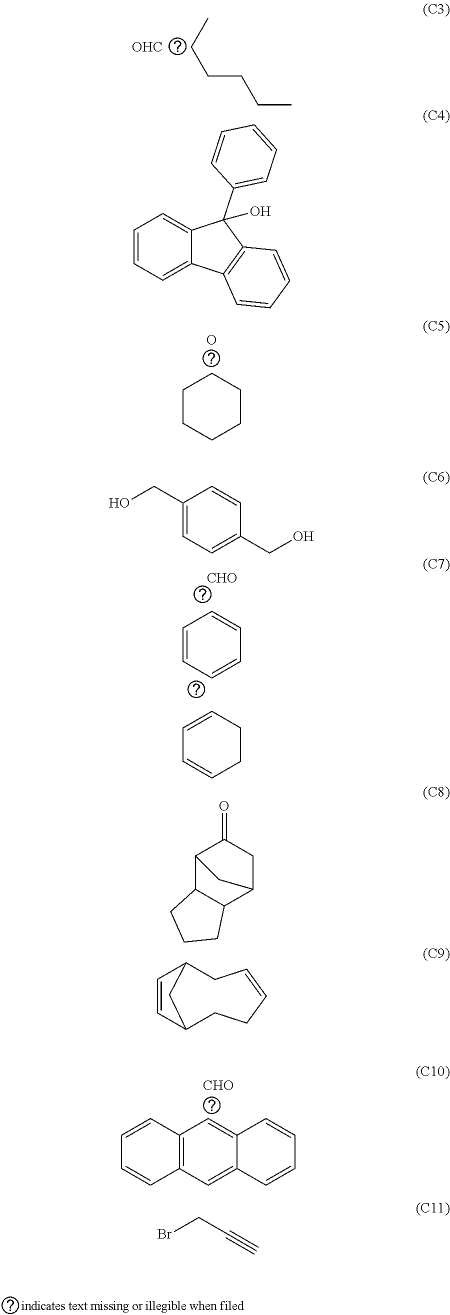

### (1-2) Catalysts D, Solvents E, Reprecipitation Solvents F, and Separation Solvent G

Methanesulfonic acid: D1
Mercaptopropionic acid: D2
Tetrabutylammonium iodide: D3
Propylene glycol monomethyl ether acetate (=PGMEA): E1
N-Methylpyrrolidone (=NMP): E2
Propylene glycol monomethyl ether (=PGME): E3
Tetrahydrofuran (=THF): E4
25% Aqueous sodium hydroxide solution: E5
Methanol: F1
Methanol/ammonia water: F2
Methanol/water: F3
Butyl acetate/water: G1

### Synthesis Example 1

A flask was charged with 17.6 g of A1, 8.0 g of C1, 2.1 g of D1, 1.4 g of D2, 19.4 g of E2, and 45.3 g of E1. Subsequently, the mixture was heated under nitrogen until reflux was achieved, and the reaction was performed for about 16 hours. After the reaction was discontinued, the product was reprecipitated from methanol. The resin was dried to give (S1). The polystyrene-equivalent weight average molecular weight Mw measured by GPC was about 2,000. The resin obtained was dissolved into PGMEA, and ion exchange was performed for 4 hours using a cation exchange resin and an anion exchange resin. A target compound solution was thus obtained.

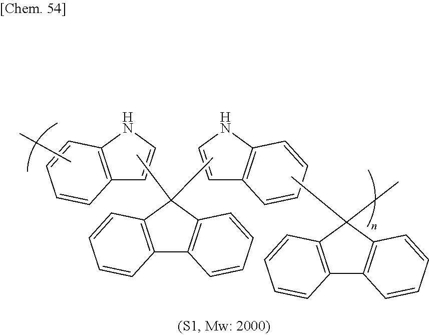

### Synthesis Examples 2 to 23

Resins S2 to S23 were also synthesized in the same manner as in Synthesis Example 1 under the conditions of Synthesis Examples 2 to 23 described in Table 1 below.

TABLE 1

| Syn. | Structural | | | | Temp./ | Re- |
|---|---|---|---|---|---|---|
| Ex. | formula | Compounds | Catalysts | Solvents | time | precipitation |
| 1 | S1 | A1/C1 | D1/D2 | E1/E2 | Reflux/ | F1 |
| | | 17.6 g/8.0 g | 2.1 g/1.4 g | 45.3 g/19.4 g | 16 hr | |
| 2 | S2 | A1/C2 | D1 | E1/E2 | Reflux/ | F1 |
| | | 20.3 g/8.0 g | 2.5 g | 50.3 g/21.5 g | 16 hr | |
| 3 | S3 | A2/C1 | D1/D2 | E1/E3 | Reflux/ | F2 |
| | | 20.0 g/9.3 g | 7.5 g/1.1 g | 38.6 g/16.6 g | 21 hr | |
| 4 | S4 | A3/C1 | D1/D2 | E1/E3 | Reflux/ | F2 |
| | | 20.0 g/13.1 g | 10.5 g/1.5 g | 71.3 g/30.6 g | 21 hr | |
| 5 | S5 | A2/C2 | D1 | E1/E2 | Reflux/ | F3 |
| | | 3.0 g/1.2 g | 0.2 g | 7.3 g/3.1 g | 20 hr | |
| 6 | S6 | A2/B1/B2/C1 | D1/D2 | E1/E2 | 100° C./ | F2 |
| | | 20.0 g/0.9 g/1.8 g/11.2 g | 9.0 g/1.3 g | 79.9 g/20.0 g | 14 hr | |
| 7 | S7 | A2/B3/B4/C1 | D1/D2 | E1/E2 | 100° C./ | F2 |
| | | 20.0 g/2.0 g/0.9 g/12.1 g | 9.7 g/1.4 g | 83.4 g/20.9 g | 14 hr | |
| 8 | S8 | A4/B5/B6/C1 | D1/D2 | E1/E2 | 100° C./ | F2 |
| | | 20.0 g/1.5 g/2.6 g/13.9 g | 11.1 g/1.6 g | 91.7 g/22.9 g | 14 hr | |
| 9 | S9 | A4/B7/B8/C1 | D1/D2 | E1/E2 | 100° C./ | F2 |
| | | 20.0 g/1.0 g/1.2 g/13.9 g | 10.3 g/1.5 g | 84.5 g/21.1 g | 16 hr | |
| 10 | S10 | A4/C1/C3/C4 | D1/D2 | E1/E2 | 100° C./ | F2 |
| | | 20.0 g/13.4 g/1.9 g/1.0 g | 12.9 g/1.9 g | 91.9 g/23.0 g | 16 hr | |
| 11 | S11 | A4/A5/B9/C1 | D1/D2 | E1/E2 | 100° C./ | F2 |
| | | 15.0 g/2.8 g/1.3 g/14.1 g | 14.5 g/2.1 g | 89.0 g/22.3 g | 16 hr | |
| 12 | S12 | A2/A6/B10/C1 | D1/D2 | E1/E2 | 100° C./ | F2 |
| | | 20.0 g/5.7 g/1.1 g/12.1 g | 12.1 g/1.4 g | 90.6 g/22.7 g | 16 hr | |
| 13 | S13 | A2/A7/A8/C1 | D1/D2 | E1/E2 | 100° C./ | F2 |
| | | 20.0 g/6.2 g/1.6 g/12.1 g | 9.7 g/1.4 g | 92.7 g/23.2 g | 16 hr | |
| 14 | S14 | A9/B11/C1/C5 | D1/D2 | E1/E2 | 100° C./ | F2 |
| | | 20.0 g/8.9 g/1.2 g/12.9 g | 10.3 g/1.5 g | 99.5 g/24.9 g | 19 hr | |
| 15 | S15 | A2/B12/B13/C1 | D1/D2 | E1/E2 | 100° C./ | F2 |
| | | 20.0 g/1.2 g/1.7 g/11.9 g | 9.5f/1.4 g | 82.6 g/20.7 g | 19 hr | |
| 16 | S16 | A4/C1/C6/C7 | D1/D2 | E1/E2 | 100° C./ | F2 |
| | | 20.0 g/11.2 g/0.9 g/1.6 g | 10.7 g/1.6 g | 82.0 g/20.5 g | 19 hr | |
| 17 | S17 | A4/C1/C8/C9 | D1/D2 | E1/E2 | 100° C./ | F2 |
| | | 20.0 g/11.0 g/1.8 g/1.6 g | 12.4 g/1.8 g | 93.0 g/23.3 g | 19 hr | |
| 18 | S18 | A3/B14/C1/C10 | D1/D2 | E1/E2 | 100° C./ | F2 |
| | | 20.0 g/4.1 g/11.9 g/2.3 g | 9.5 g/1.4 g | 89.1 g/22.3 g | 19 hr | |
| 19 | S19 | A2/A10/A11/C1 | D1/D2 | E1/E2 | 100° C./ | F2 |
| | | 20.0 g/2.1 g/1.9 g/12.1 g | 9.7 g/1.4 g | 88.6 g/21.4 g | 19 hr | |
| 20 | S20 | A12/A13/A14/C1 | D1/D2 | E1 | 100° C./ | F1 |
| | | 15.0 g/2.5 g/2.9 g/7.0 g | 3.8 g/2.0 g | 46.7 g | 20 hr | |
| 21 | S21 | A12/A15/A16/C1 | D1/D2 | E1 | 100° C./ | F1 |
| | | 15.0 g/2.6 g/3.6 g/7.0 g | 3.8 g/2.1 g | 50.0 g | 20 hr | |
| 22 | S22 | A12/A17/A18/C1 | D1/D2 | E1 | 100° C./ | F1 |
| | | 15.0 g/2.5 g/2.8 g/7.0 g | 3.8 g/2.1 g | 46.7 g | 20 hr | |
| 23 | S23 | A12/A19/A20/C1 | D1/D2 | E1 | 100° C./ | F1 |
| | | 10.0 g/4.1 g/11.0 g/8.2 g | 4.4 g/2.4 g | 56.5 g | 20 hr | |

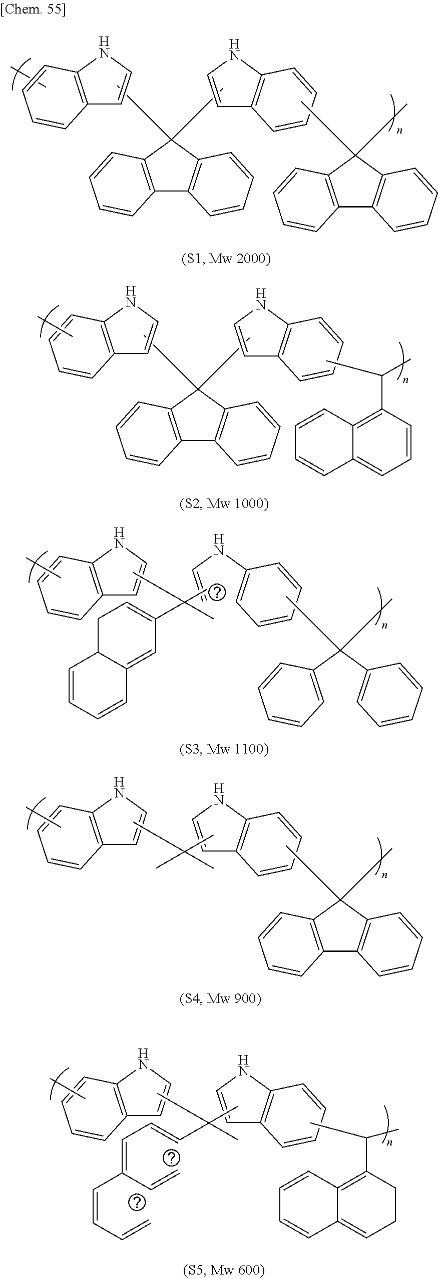

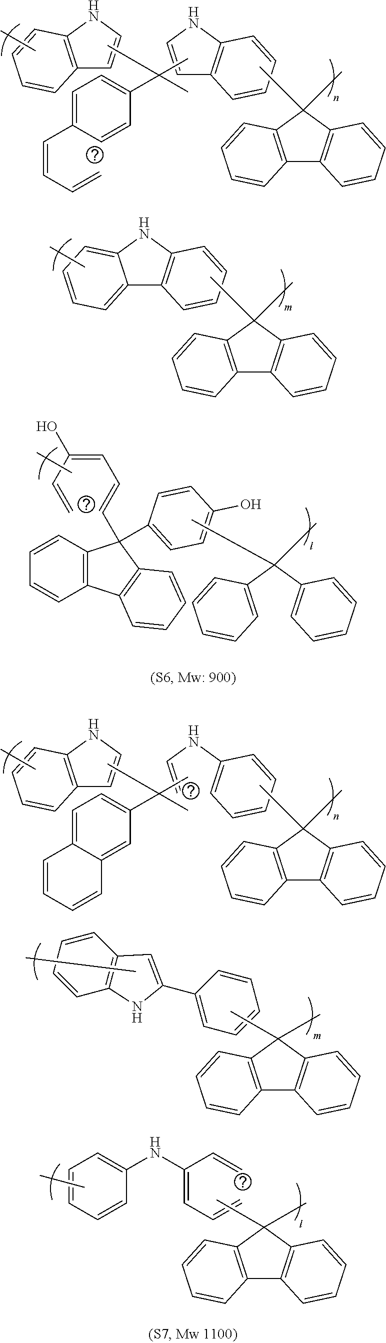

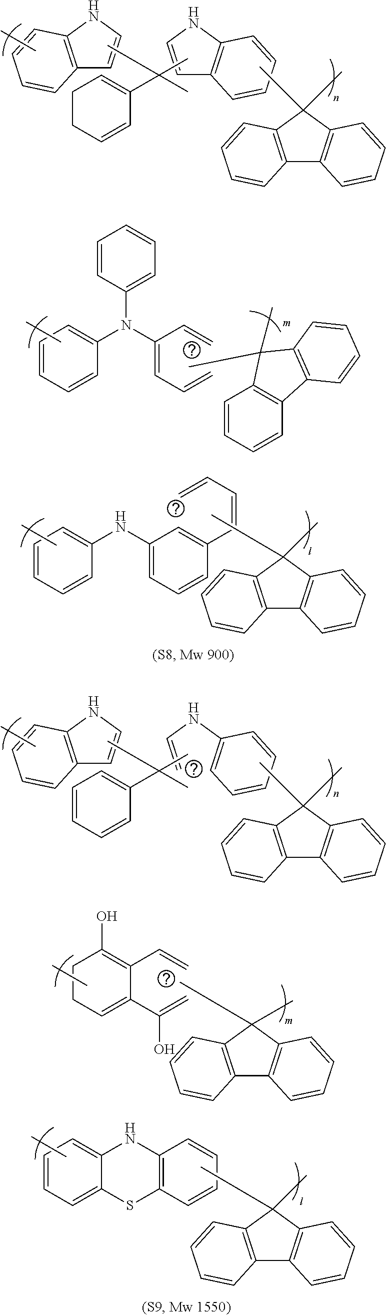

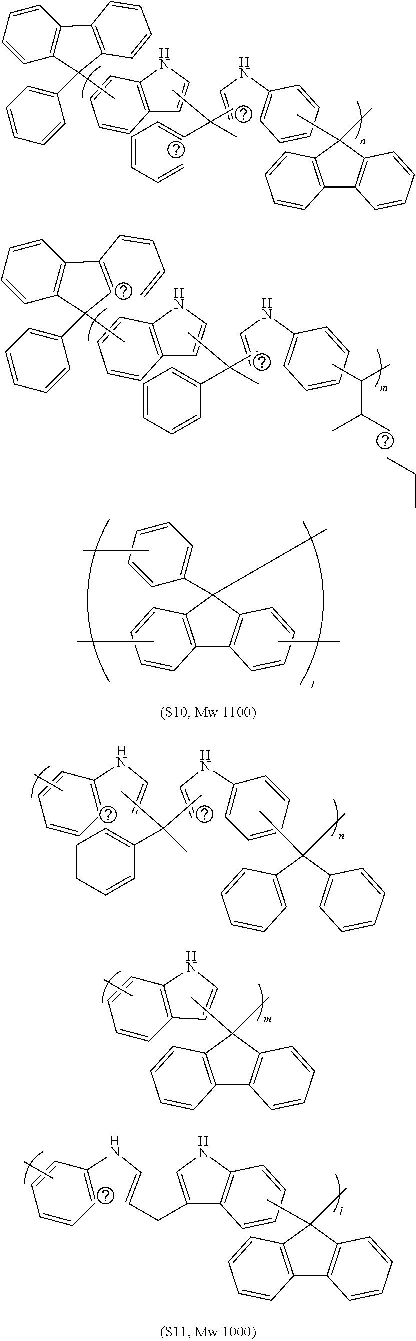

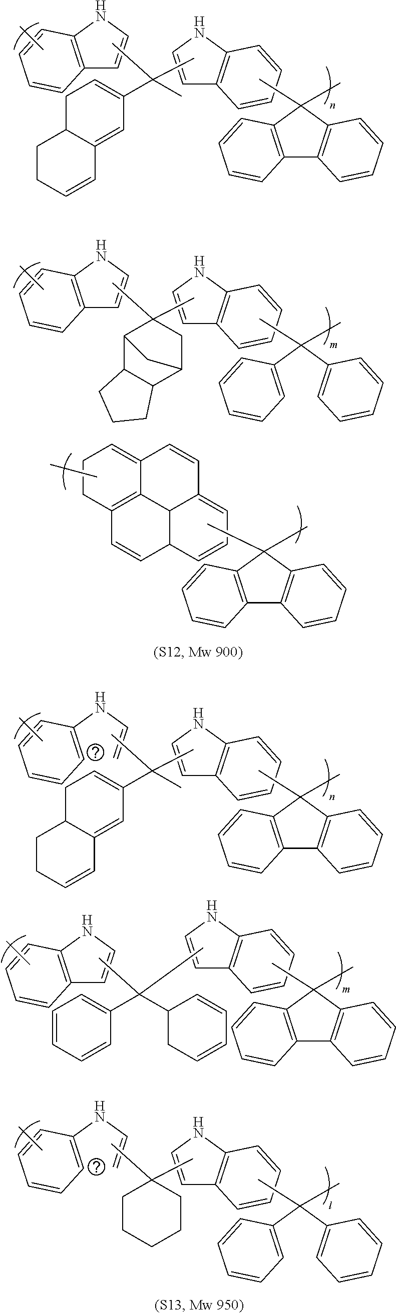

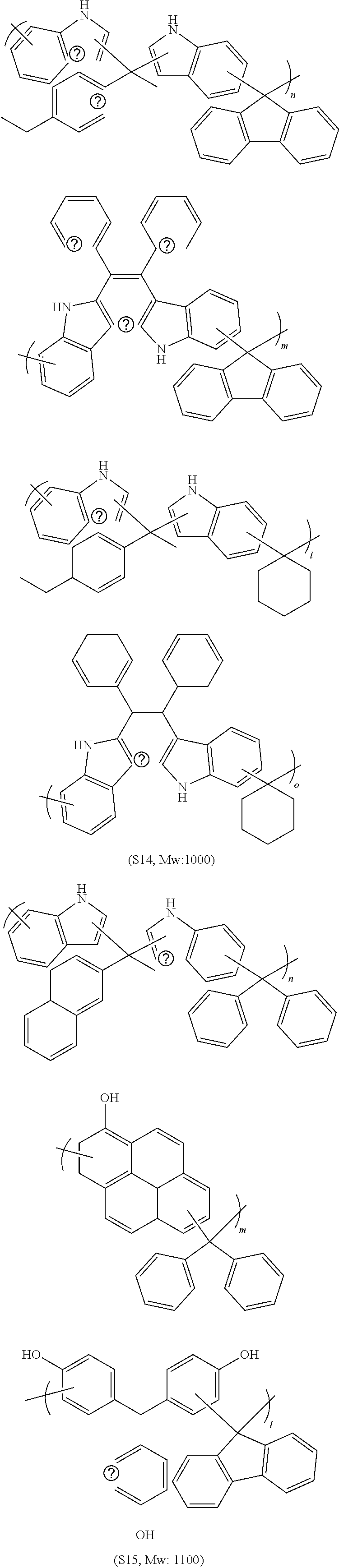

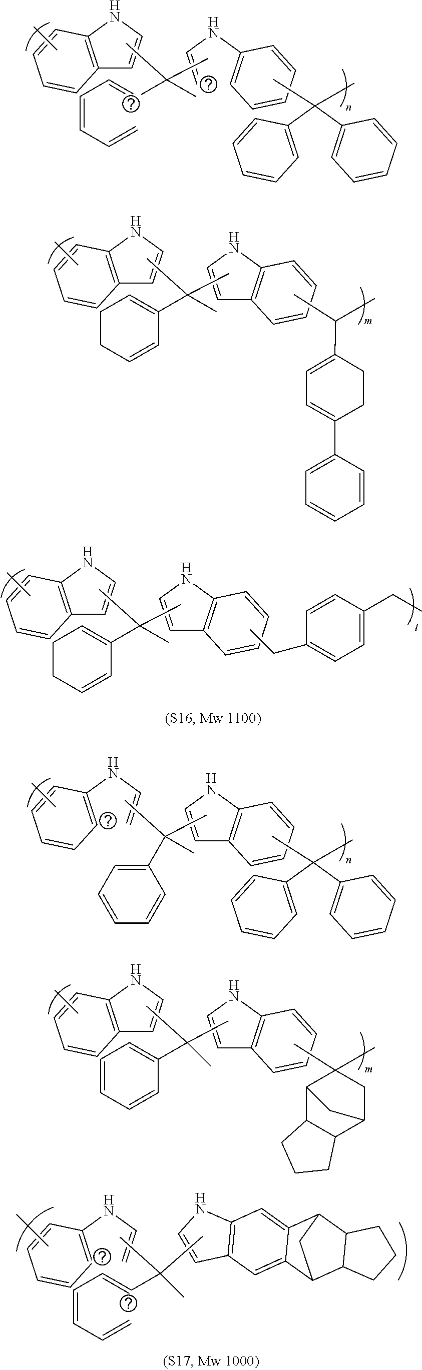

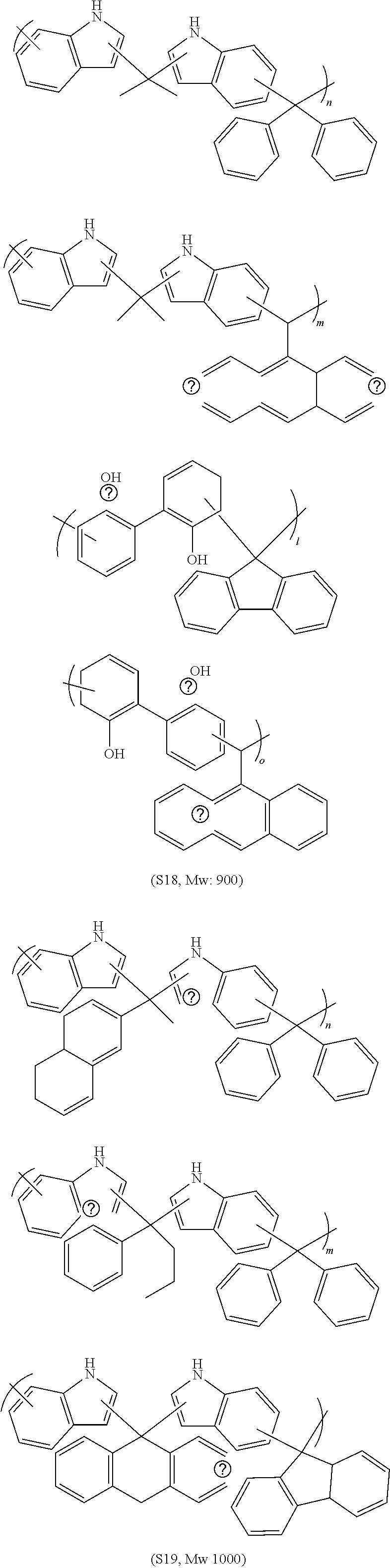

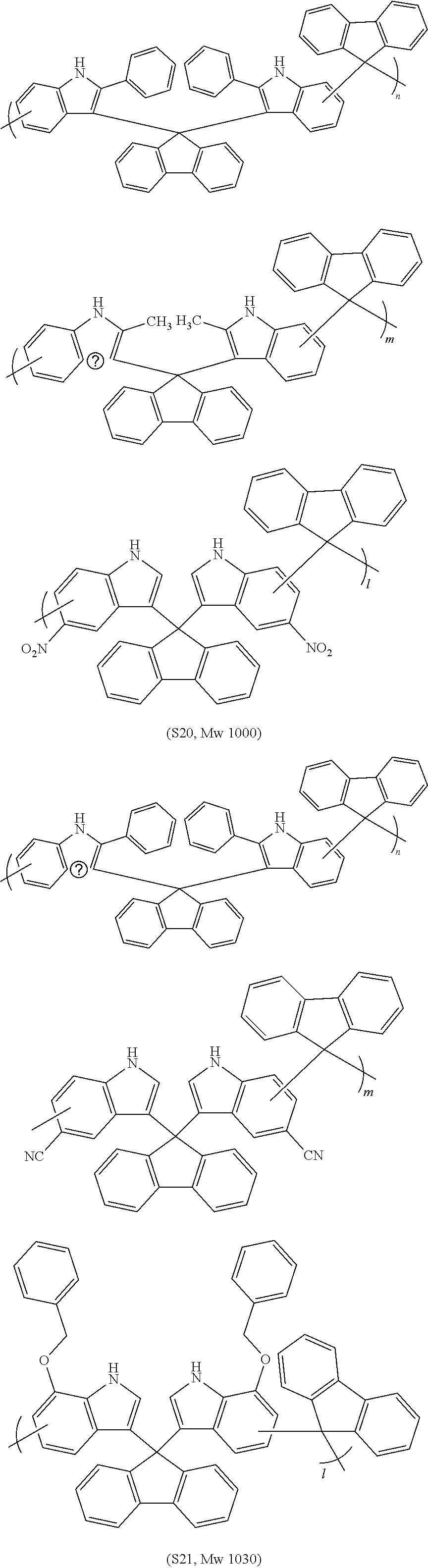

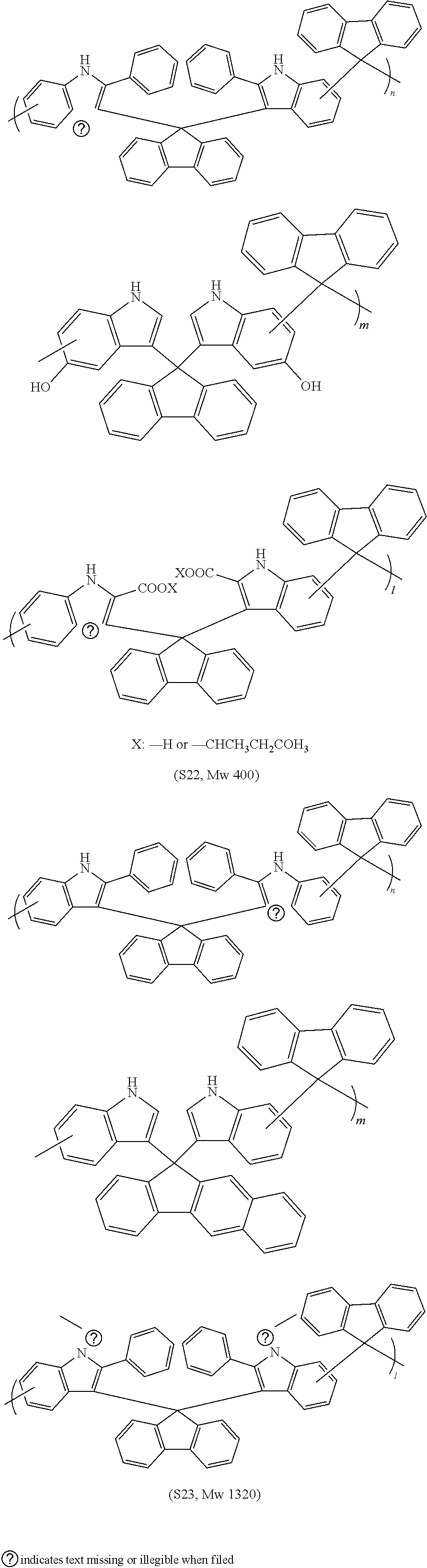

### Synthesis Example 24

A flask was charged with 10.0 g of S1, 6.4 g of C11, 0.3 g of D3, 25.1 g of E4, and 7.5 g of E5. The mixture was heated to 55° C. under nitrogen and was reacted for about 24 hours. After the reaction was discontinued, a separation operation was repeated using butyl acetate and water. The organic layer was concentrated. The product was reprecipitated from methanol and was dried to give resin (S′1). The polystyrene-equivalent weight average molecular weight Mw measured by GPC was about 3,560. The resin obtained was dissolved into PGMEA, and ion exchange was performed for 4 hours using a cation exchange resin and an anion exchange resin. A target compound solution was thus obtained.

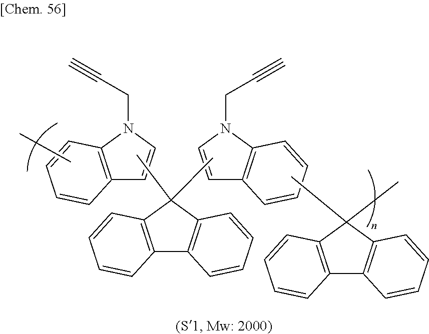

### Synthesis Examples 25 to 46

Resins S′2 to S′23 were also synthesized in the same manner as in Synthesis Example 24 under the conditions of Synthesis Examples 25 to 46 described in Table 2 below.

TABLE 2

| Syn. | Structural | | | | Temp./ | Separation | Re- |
|---|---|---|---|---|---|---|---|
| Ex. | formula | Compounds | Catalyst | Solvents | time | solvent | precipitation |
| 24 | S′1 | S1/C11 | D3 | E4/E5 | 55° C./ | G1 | F1 |
| | | 10.0 g/6.4 g | 0.3 g | 25.1 g/7.5 g | 24 hr | | |
| 25 | S′2 | S2/C11 | D3 | E4/E5 | 55° C./ | G1 | F1 |
| | | 10.0 g/6.7 g | 0.4 g | 25.5 g/7.7 g | 24 hr | | |
| 26 | S′3 | S3/C11 | D3 | E4/E5 | 55° C./ | G1 | F1 |
| | | 10.0 g/6.5 g | 0.3 g | 25.3 g/11.4 g | 24 hr | | |
| 27 | S′4 | S4/C11 | D3 | E4/E5 | 55° C./ | G1 | F1 |
| | | 10.0 g/8.2 g | 0.4 g | 27.9 g/12.3 g | 24 hr | | |
| 28 | S′5 | S5/C11 | D3 | E4/E5 | 55° C./ | G1 | F1 |
| | | 6.5 g/4.4 g | 0.2 g | 16.7 g/7.5 g | 23 hr | | |
| 29 | S′6 | S6/C11 | D3 | E4/E5 | 55° C./ | G1 | F1 |
| | | 10.0 g/10.8 g | 0.6 g | 32.1 g/14.5 g | 20 hr | | |
| 30 | S′7 | S7/C11 | D3 | E4/E5 | 55° C./ | G1 | F1 |
| | | 10.0 g/10.8 g | 0.6 g | 32.0 g/14.4 g | 20 hr | | |
| 31 | S′8 | S8/C11 | D3 | E4/E5 | 55° C./ | G1 | F1 |
| | | 10.0 g/9.4 g | 0.5 g | 29.8 g/13.4 g | 20 hr | | |
| 32 | S′9 | S9/C11 | D3 | E4/E5 | 55° C./ | G1 | F1 |
| | | 10.0 g/9.9 g | 0.5 g | 30.6 g/13.8 g | 21 hr | | |
| 33 | S′10 | S10/C11 | D3 | E4/E5 | 55° C./ | G1 | F1 |
| | | 10.0 g/7.2 g | 0.4 g | 26.3 g/11.8 g | 21 hr | | |
| 34 | S′11 | S11/C11 | D3 | E4/E5 | 55° C./ | G1 | F1 |
| | | 10.0 g/12.8 g | 0.7 g | 35.2 g/15.8 g | 21 hr | | |
| 35 | S′12 | S12/C11 | D3 | E4/E5 | 55° C./ | G1 | F1 |
| | | 10.0 g/6.8 g | 0.4 g | 25.7 g/11.5 g | 24 hr | | |
| 36 | S′13 | S13/C11 | D3 | E4/E5 | 55° C./ | G1 | F1 |
| | | 10.0 g/7.5 g | 0.4 g | 26.8 g/12.1 g | 24 hr | | |
| 37 | S′14 | S14/C11 | D3 | E4/E5 | 55° C./ | G1 | F1 |
| | | 8.0 g/5.4 g | 0.3 g | 20.1 g/9.3 g | 24 hr | | |
| 38 | S′15 | S15/C11 | D3 | E4/E5 | 55° C./ | G1 | F1 |
| | | 10.0 g/6.5 g | 0.3 g | 25.3 g/11.4 g | 20 hr | | |
| 39 | S′16 | S16/C11 | D3 | E4/E5 | 55° C./ | G1 | F1 |
| | | 10.0 g/7.2 g | 0.4 g | 26.3 g/11.8 g | 20 hr | | |
| 40 | S′17 | S17/C11 | D3 | E4/E5 | 55° C./ | G1 | F1 |
| | | 8.0 g/5.7 g | 0.3 g | 21.0 g/9.5 g | 20 hr | | |
| 41 | S′18 | S18/C11 | D3 | E4/E5 | 55° C./ | G1 | F1 |
| | | 7.0 g/5.7 g | 0.3 g | 19.5 g/8.8 g | 20 hr | | |
| 42 | S′19 | S19/C11 | D3 | E4/E5 | 55° C./ | G1 | F1 |
| | | 6.5 g/4.5 g | 0.2 g | 16.8 g/7.6 g | 23 hr | | |
| 43 | S′20 | S20/C11 | D3 | E4/E5 | 55° C./ | G1 | F1 |
| | | 9.0 g/5.7 g | 0.3 g | 22.4 g/10.1 g | 22 hr | | |
| 44 | S′21 | S21/C11 | D3 | E4/E5 | 55° C./ | G1 | F1 |
| | | 9.0 g/5.3 g | 0.3 g | 21.8 g/9.8 g | 22 hr | | |
| 45 | S′22 | S22/C11 | D3 | E4/E5 | 55° C./ | G1 | F1 |
| | | 9.0 g/5.4 g | 0.3 g | 22.1 g/9.9 g | 22 hr | | |
| 46 | S′23 | S23/C11 | D3 | E4/E5 | 55° C./ | G1 | F1 |
| | | 10.0 g/5.9 g | 0.3 g | 24.3 g/10.9 g | 22 hr | | |

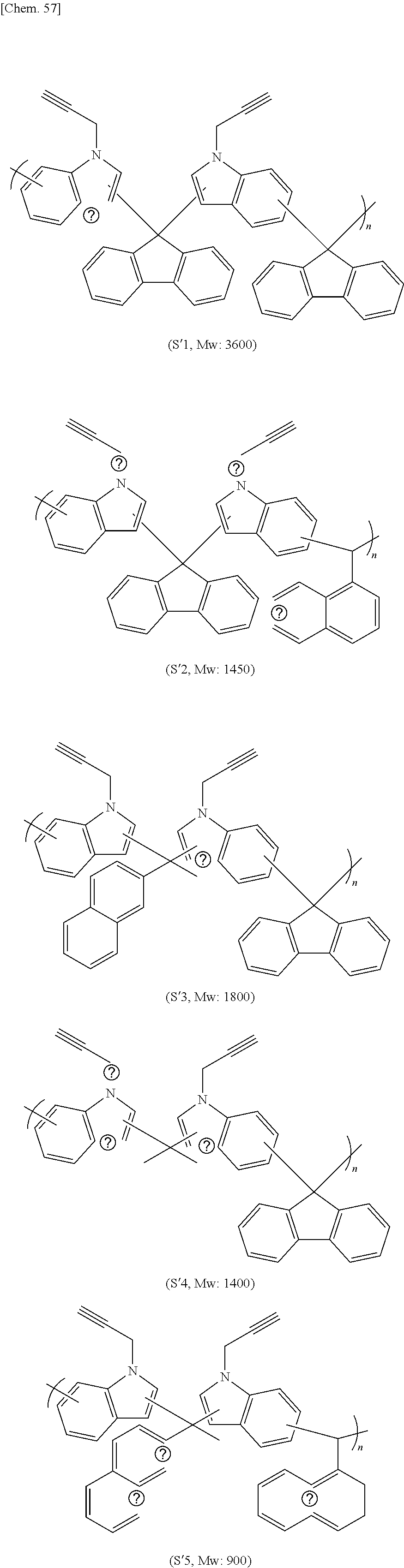

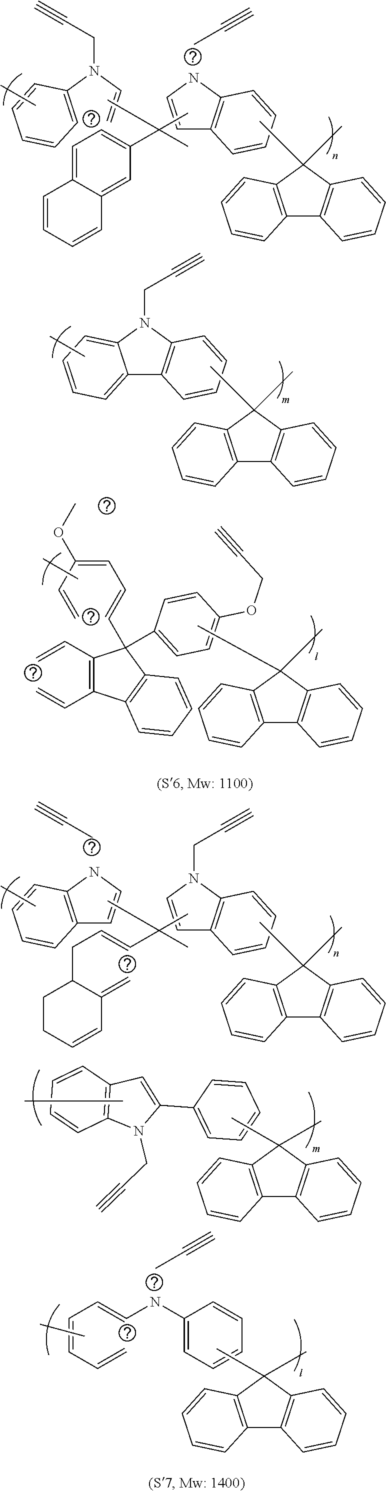

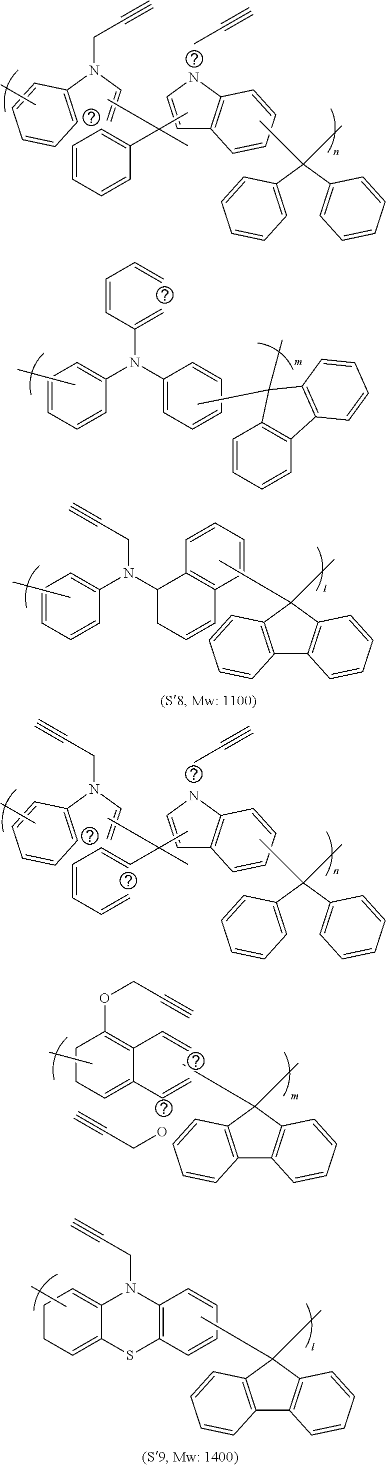

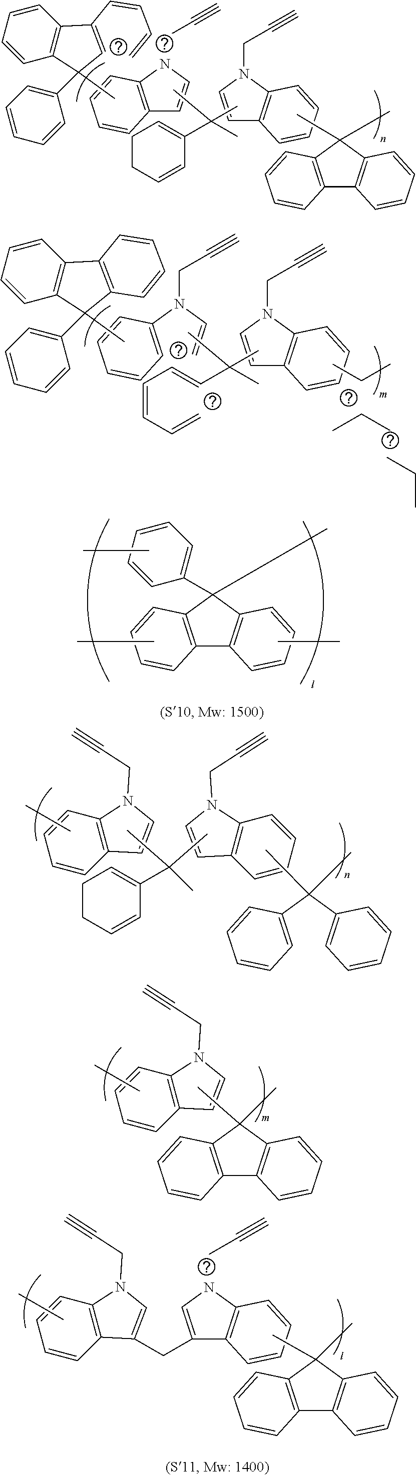

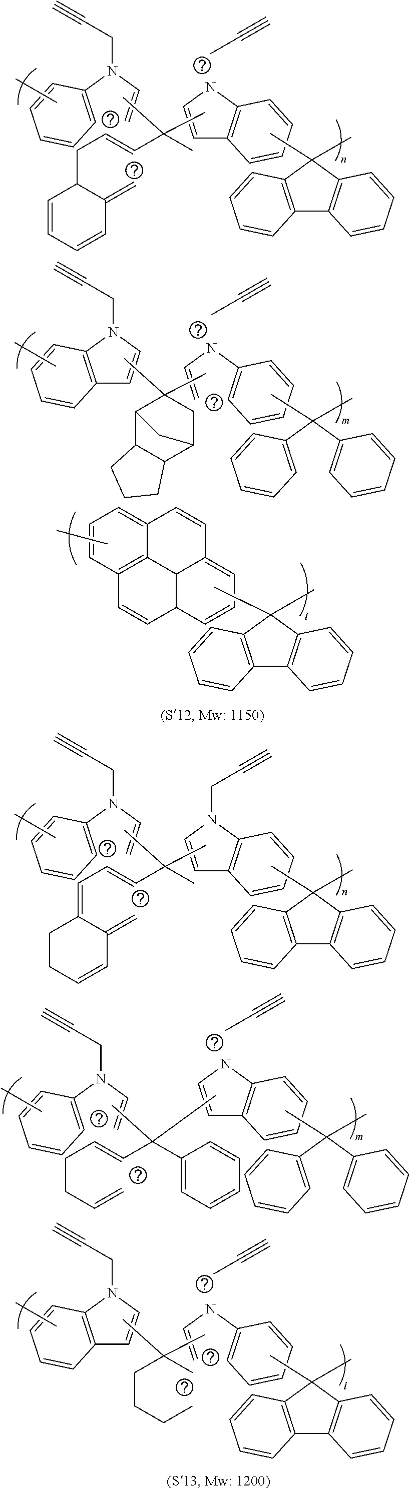

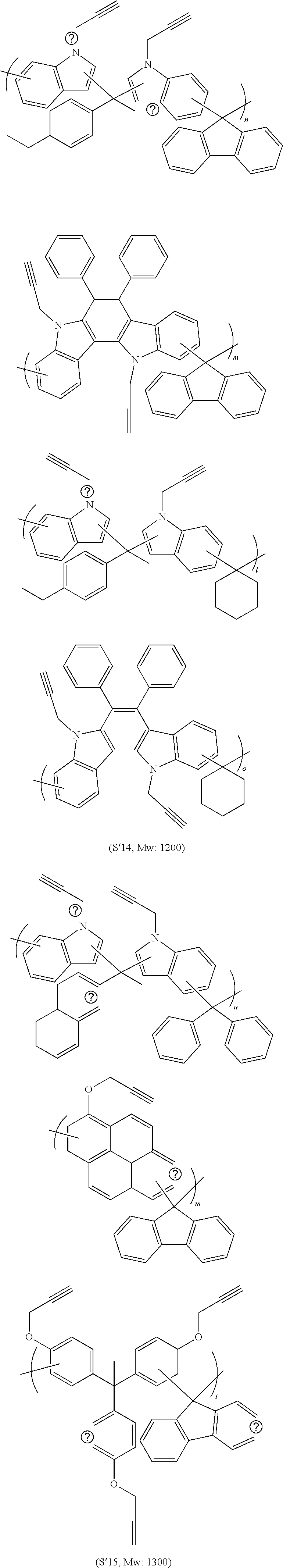

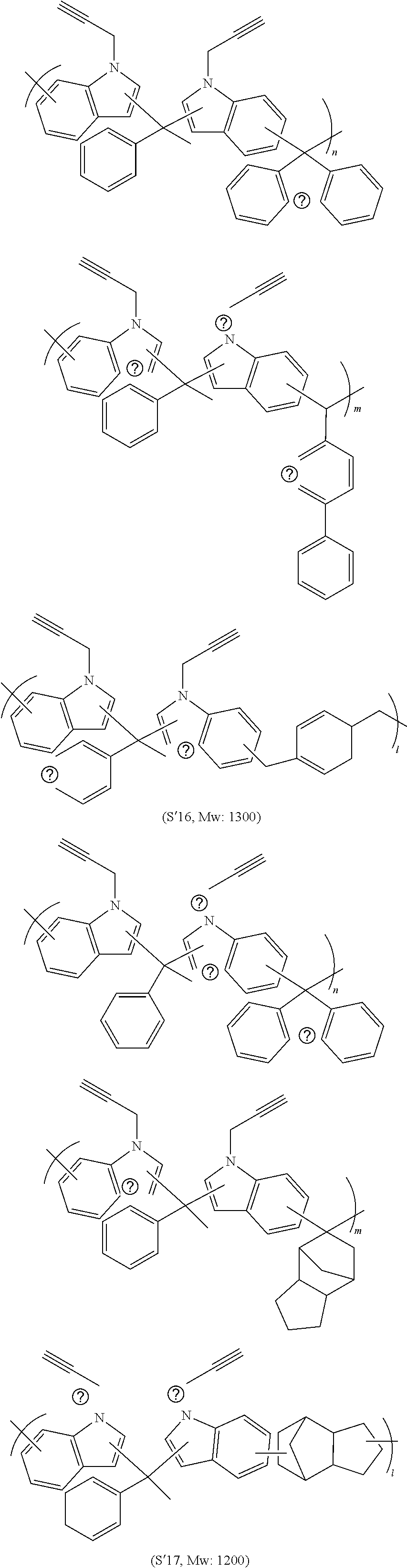

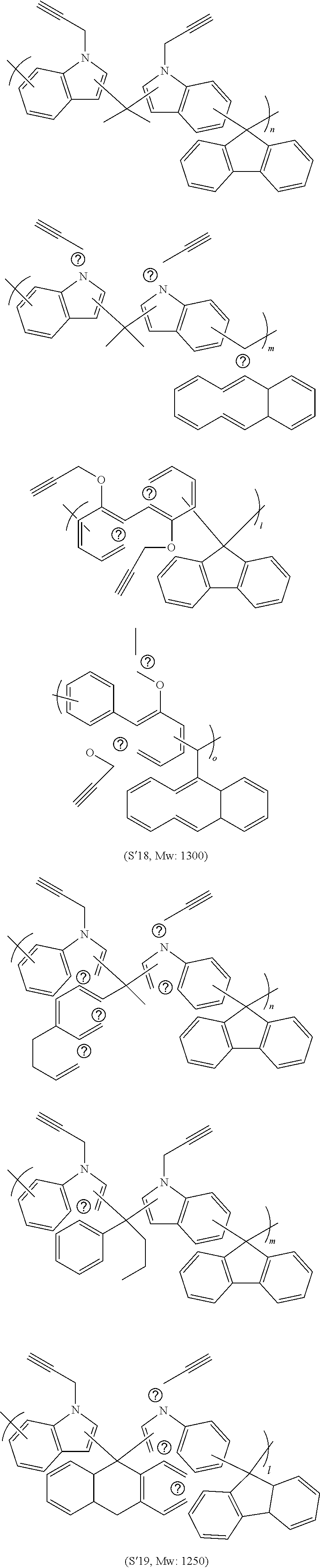

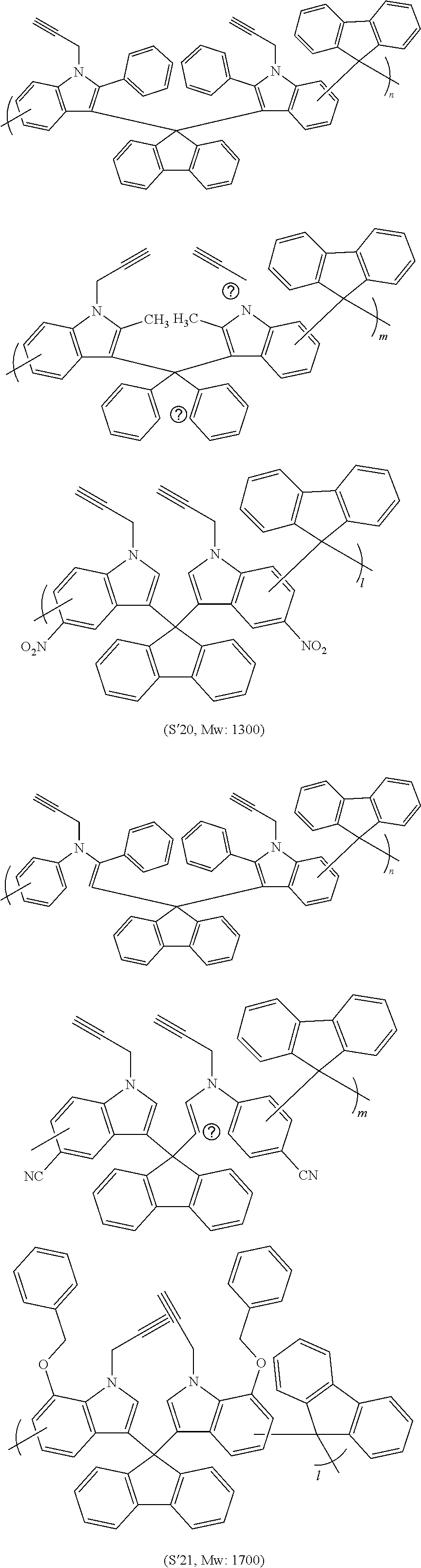

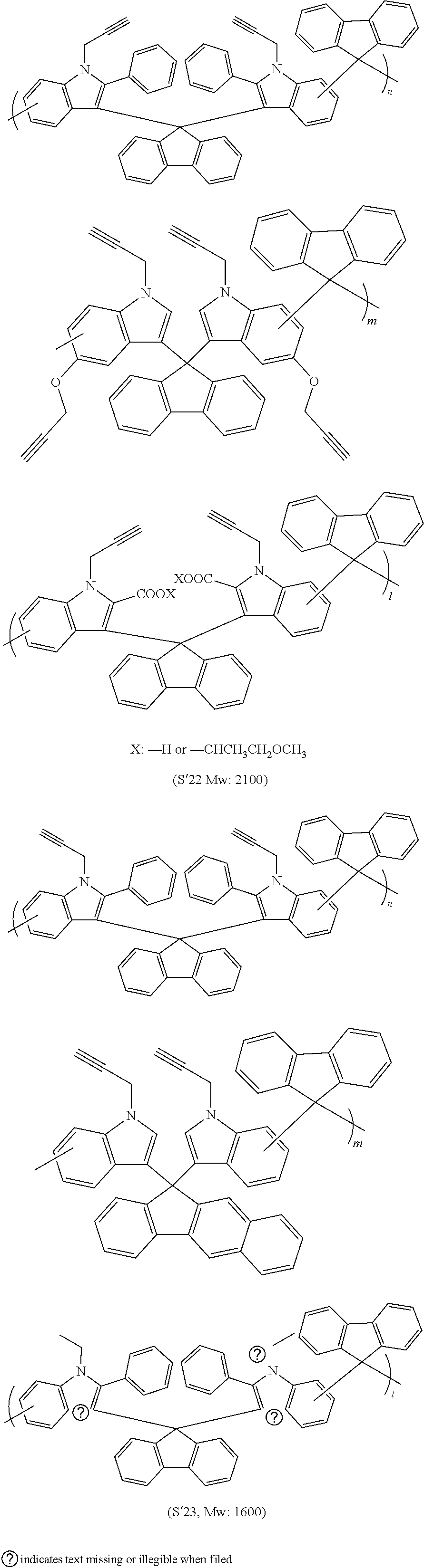

### Comparative Synthesis Examples 1 and 2

Comparative resins SS1 and SS2 were synthesized in the same manner as in Synthesis Example 1 under the conditions of Comparative Synthesis Examples 1 and 2 described in Table 3 below.

TABLE 3

| | | | | | | Re- |
|---|---|---|---|---|---|---|
| Comp. | Structural | Com- | | | Temp./ | precipi- |
| Syn. Ex. | formula | pounds | Catalyst | Solvent | time | tation |
| 1 | SS1 | B3/C2 | D1 | E1 | 120° C./ | F2 |
| | | 15.0 g/ | 1.5 g | 42.9 g | 5 hr | |
| | | 12.1 g | | | | |
| 2 | SS2 | B9/C2 | D1 | E1 | 120° C./ | F2 |
| | | 15.0 g/ | 3.7 g | 62.7 g | 5 hr | |
| | | 23.1 g | | | | |

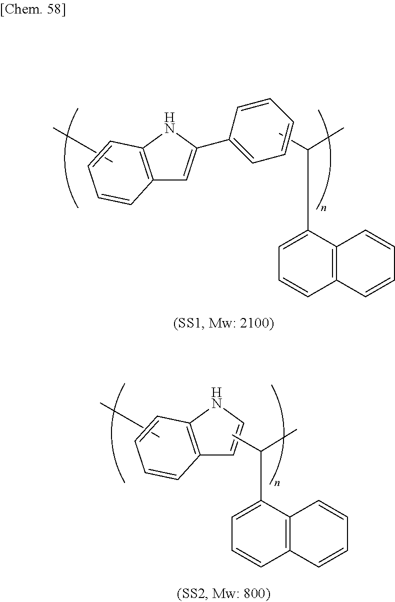

### (2) Preparation of Resist Underlayer Films

The polymers (S1) to (S23) and (S′1) to (S′23), crosslinking agents (CL1 and CL2), acid generators (Ad1 and Ad2), solvents [propylene glycol monomethyl ether acetate (PGMEA), propylene glycol monomethyl ether (PGME), cyclohexanone (CYH)], and MEGAFACE R-40 (manufactured by DIC CORPORATION, G1) as a surfactant were mixed in weight proportions described in Tables 4-1 to 4-4 below (the amounts of the crosslinking agent, the acid generator, and the surfactant are shown as weight proportions relative to the weight of the polymer taken as 100; the amounts of the respective solvents are shown as weight proportions relative to the weight of the whole solvent taken as 100). The mixtures were filtered through a 0.1 μm polytetrafluoroethylene microfilter. Resist underlayer film materials (M1 to M48 and Comparative M1 to Comparative M3) were thus prepared.

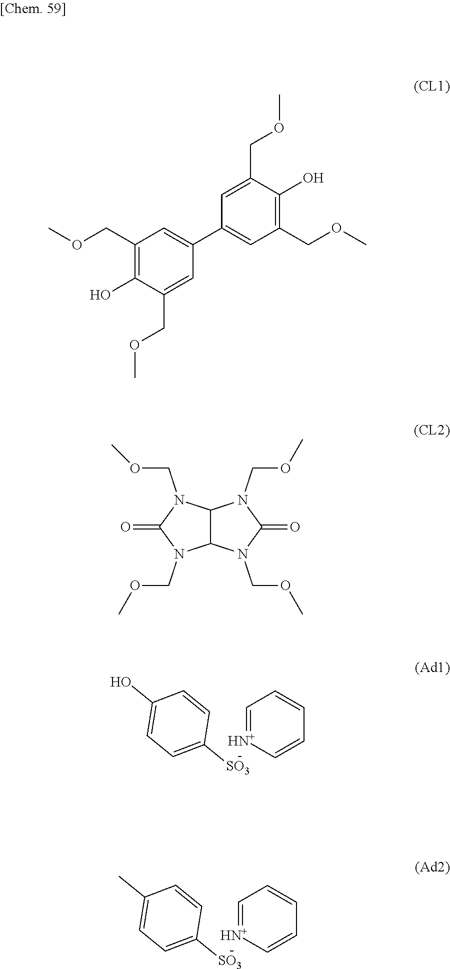

TABLE 4

| | | Crosslinking | Acid | | Solvents | | |
|---|---|---|---|---|---|---|---|
| Composition | Polymer | agent | generator | Surfactant | (100 in total) | | |
| M1 | S1 | CL1 | Ad1 | G1 | PGMEA | PGME | CYH |
| | 100 | 20 | 3.0 | 0.1 | 70 | 30 | 0 |
| M2 | S2 | CL1 | Ad1 | G1 | PGMEA | PGME | CYH |
| | 100 | 20 | 3.0 | 0.1 | 70 | 30 | 0 |
| M3 | S3 | CL1 | Ad1 | G1 | PGMEA | PGME | CYH |
| | 100 | 20 | 3.0 | 0.1 | 70 | 30 | 0 |
| M4 | S4 | CL1 | Ad1 | G1 | PGMEA | PGME | CYH |
| | 100 | 20 | 3.0 | 0.1 | 70 | 30 | 0 |
| M5 | S5 | CL1 | Ad1 | G1 | PGMEA | PGME | CYH |
| | 100 | 20 | 3.0 | 0.1 | 70 | 30 | 0 |
| M6 | S6 | CL1 | Ad1 | G1 | PGMEA | PGME | CYH |
| | 100 | 20 | 3.0 | 0.1 | 70 | 30 | 0 |
| M7 | S7 | CL1 | Ad1 | G1 | PGMEA | PGME | CYH |
| | 100 | 20 | 3.0 | 0.1 | 70 | 30 | 0 |
| M8 | S8 | CL1 | Ad1 | G1 | PGMEA | PGME | CYH |
| | 100 | 20 | 3.0 | 0.1 | 70 | 30 | 0 |
| M9 | S9 | CL1 | Ad1 | G1 | PGMEA | PGME | CYH |
| | 100 | 20 | 3.0 | 0.1 | 70 | 30 | 0 |
| M10 | S10 | CL1 | Ad1 | G1 | PGMEA | PGME | CYH |
| | 100 | 20 | 3.0 | 0.1 | 70 | 30 | 0 |
| M11 | S11 | CL1 | Ad1 | G1 | PGMEA | PGME | CYH |
| | 100 | 20 | 3.0 | 0.1 | 70 | 30 | 0 |
| M12 | S12 | CL1 | Ad1 | G1 | PGMEA | PGME | CYH |
| | 100 | 20 | 3.0 | 0.1 | 70 | 30 | 0 |
| M13 | S13 | CL1 | Ad1 | G1 | PGMEA | PGME | CYH |
| | 100 | 20 | 3.0 | 0.1 | 70 | 30 | 0 |
| M14 | S14 | CL1 | Ad1 | G1 | PGMEA | PGME | CYH |
| | 100 | 20 | 3.0 | 0.1 | 70 | 30 | 0 |
| M15 | S15 | CL1 | Ad1 | G1 | PGMEA | PGME | CYH |
| | 100 | 20 | 3.0 | 0.1 | 70 | 30 | 0 |
| M16 | S16 | CL1 | Ad1 | G1 | PGMEA | PGME | CYH |
| | 100 | 20 | 3.0 | 0.1 | 70 | 30 | 0 |
| M17 | S17 | CL1 | Ad1 | G1 | PGMEA | PGME | CYH |
| | 100 | 20 | 3.0 | 0.1 | 70 | 30 | 0 |
| M18 | S18 | CL1 | Ad1 | G1 | PGMEA | PGME | CYH |
| | 100 | 20 | 3.0 | 0.1 | 70 | 30 | 0 |
| M19 | S19 | CL1 | Ad1 | G1 | PGMEA | PGME | CYH |
| | 100 | 20 | 3.0 | 0.1 | 70 | 30 | 0 |
| M20 | S20 | CL1 | Ad1 | G1 | PGMEA | PGME | CYH |
| | 100 | 20 | 3.0 | 0.1 | 70 | 30 | 0 |
| M21 | S21 | CL1 | Ad1 | G1 | PGMEA | PGME | CYH |
| | 100 | 20 | 3.0 | 0.1 | 70 | 30 | 0 |
| M22 | S22 | CL1 | Ad1 | G1 | PGMEA | PGME | CYH |
| | 100 | 20 | 3.0 | 0.1 | 70 | 30 | 0 |
| M23 | S23 | CL1 | Ad1 | G1 | PGMEA | PGME | CYH |
| | 100 | 20 | 3.0 | 0.1 | 70 | 30 | 0 |
| M24 | S′1 | — | — | G1 | PGMEA | PGME | CYH |
| | 100 | — | — | 0.1 | 70 | 30 | 0 |
| M25 | S′2 | — | — | G1 | PGMEA | PGME | CYH |
| | 100 | — | — | 0.1 | 70 | 30 | 0 |
| M26 | S′3 | — | — | G1 | PGMEA | PGME | CYH |
| | 100 | — | — | 0.1 | 70 | 30 | 0 |
| M27 | S′4 | — | — | G1 | PGMEA | PGME | CYH |
| | 100 | — | — | 0.1 | 70 | 30 | 0 |
| M28 | S′5 | — | — | G1 | PGMEA | PGME | CYH |
| | 100 | — | — | 0.1 | 70 | 30 | 0 |
| M29 | S′6 | — | — | G1 | PGMEA | PGME | CYH |
| | 100 | — | — | 0.1 | 70 | 30 | 0 |
| M30 | S′7 | — | — | G1 | PGMEA | PGME | CYH |
| | 100 | — | — | 0.1 | 70 | 30 | 0 |
| M31 | S′8 | — | — | G1 | PGMEA | PGME | CYH |
| | 100 | — | — | 0.1 | 70 | 30 | 0 |
| M32 | S′9 | — | — | G1 | PGMEA | PGME | CYH |
| | 100 | — | — | 0.1 | 70 | 30 | 0 |
| M33 | S′10 | — | — | G1 | PGMEA | PGME | CYH |
| | 100 | — | — | 0.1 | 70 | 30 | 0 |
| M34 | S′11 | — | — | G1 | PGMEA | PGME | CYH |
| | 100 | — | — | 0.1 | 70 | 30 | 0 |
| M35 | S′12 | — | — | G1 | PGMEA | PGME | CYH |
| | 100 | — | — | 0.1 | 70 | 30 | 0 |
| M36 | S′13 | — | — | G1 | PGMEA | PGME | CYH |
| | 100 | — | — | 0.1 | 70 | 30 | 0 |
| M37 | S′14 | — | — | G1 | PGMEA | PGME | CYH |
| | 100 | — | — | 0.1 | 70 | 30 | 0 |
| M38 | S′15 | — | — | G1 | PGMEA | PGME | CYH |
| | 100 | — | — | 0.1 | 70 | 30 | 0 |
| M39 | S′16 | — | — | G1 | PGMEA | PGME | CYH |
| | 100 | — | — | 0.1 | 70 | 30 | 0 |
| M40 | S′17 | — | — | G1 | PGMEA | PGME | CYH |
| | 100 | — | — | 0.1 | 70 | 30 | 0 |
| M41 | S′18 | — | — | G1 | PGMEA | PGME | CYH |
| | 100 | — | — | 0.1 | 70 | 30 | 0 |
| M42 | S′19 | — | — | G1 | PGMEA | PGME | CYH |
| | 100 | — | — | 0.1 | 70 | 30 | 0 |
| M43 | S′20 | — | — | G1 | PGMEA | PGME | CYH |
| | 100 | — | — | 0.1 | 70 | 30 | 0 |
| M44 | S′21 | — | — | G1 | PGMEA | PGME | CYH |
| | 100 | — | — | 0.1 | 70 | 30 | 0 |
| M45 | S′22 | — | — | G1 | PGMEA | PGME | CYH |
| | 100 | — | — | 0.1 | 70 | 30 | 0 |
| M46 | S′23 | — | — | G1 | PGMEA | PGME | CYH |
| | 100 | — | — | 0.1 | 70 | 30 | 0 |
| M47 | S′1 | CL1 | Ad1 | G1 | PGMEA | PGME | CYH |
| | 100 | 20 | 3.0 | 0.1 | 70 | 30 | 0 |
| M48 | S′2 | CL1 | Ad1 | G1 | PGMEA | PGME | CYH |
| | 100 | 20 | 3.0 | 0.1 | 60 | 30 | 10 |
| Comp. M1 | SS1 | — | — | — | PGMEA | PGME | CYH |
| | 100 | — | — | — | 70 | 30 | 0 |
| Comp. M2 | SS2 | — | — | — | PGMEA | PGME | CYH |
| | 100 | — | — | — | 70 | 30 | 0 |
| Comp. M3 | SS1 | CL2 | Ad2 | G1 | PGMEA | PGME | CYH |
| | 100 | 30 | 3.0 | 0.1 | 70 | 30 | 0 |

TABLE 4-2

| M17 | S17 | CL1 | Ad1 | G1 | PGMEA | PGME | CYH |
|---|---|---|---|---|---|---|---|
| | 100 | 20 | 3.0 | 0.1 | 70 | 30 | 0 |
| M18 | S18 | CL1 | Ad1 | G1 | PGMEA | PGME | CYH |
| | 100 | 20 | 3.0 | 0.1 | 70 | 30 | 0 |
| M19 | S19 | CL1 | Ad1 | G1 | PGMEA | PGME | CYH |
| | 100 | 20 | 3.0 | 0.1 | 70 | 30 | 0 |
| M20 | S20 | CL1 | Ad1 | G1 | PGMEA | PGME | CYH |
| | 100 | 20 | 3.0 | 0.1 | 70 | 30 | 0 |
| M21 | S21 | CL1 | Ad1 | G1 | PGMEA | PGME | CYH |
| | 100 | 20 | 3.0 | 0.1 | 70 | 30 | 0 |
| M22 | S22 | CL1 | Ad1 | G1 | PGMEA | PGME | CYH |
| | 100 | 20 | 3.0 | 0.1 | 70 | 30 | 0 |
| M23 | S23 | CL1 | Ad1 | G1 | PGMEA | PGME | CYH |
| | 100 | 20 | 3.0 | 0.1 | 70 | 30 | 0 |
| M24 | S'1 | — | — | G1 | PGMEA | PGME | CYH |
| | 100 | — | — | 0.1 | 70 | 30 | 0 |
| M25 | S'2 | — | — | G1 | PGMEA | PGME | CYH |
| | 100 | — | — | 0.1 | 70 | 30 | 0 |
| M26 | S'3 | — | — | G1 | PGMEA | PGME | CYH |
| | 100 | — | — | 0.1 | 70 | 30 | 0 |
| M27 | S'4 | — | — | G1 | PGMEA | PGME | CYH |
| | 100 | — | — | 0.1 | 70 | 30 | 0 |
| M28 | S'5 | — | — | G1 | PGMEA | PGME | CYH |
| | 100 | — | — | 0.1 | 70 | 30 | 0 |
| M29 | S'6 | — | — | G1 | PGMEA | PGME | CYH |
| | 100 | — | — | 0.1 | 70 | 30 | 0 |
| M30 | S'7 | — | — | G1 | PGMEA | PGME | CYH |
| | 100 | — | — | 0.1 | 70 | 30 | 0 |
| M31 | S'8 | — | — | G1 | PGMEA | PGME | CYH |
| | 100 | — | — | 0.1 | 70 | 30 | 0 |
| M32 | S'9 | — | — | G1 | PGMEA | PGME | CYH |
| | 100 | — | — | 0.1 | 70 | 30 | 0 |
| M33 | S'10 | — | — | G1 | PGMEA | PGME | CYH |
| | 100 | — | — | 0.1 | 70 | 30 | 0 |

TABLE 4-3

| M34 | S'11 | — | — | G1 | PGMEA | PGME | CYH |
|---|---|---|---|---|---|---|---|
| | 100 | — | — | 0.1 | 70 | 30 | 0 |
| M35 | S'12 | — | — | G1 | PGMEA | PGME | CYH |
| | 100 | — | — | 0.1 | 70 | 30 | 0 |
| M36 | S'13 | — | — | G1 | PGMEA | PGME | CYH |
| | 100 | — | — | 0.1 | 70 | 30 | 0 |
| M37 | S'14 | — | — | G1 | PGMEA | PGME | CYH |
| | 100 | — | — | 0.1 | 70 | 30 | 0 |
| M38 | S'15 | — | — | G1 | PGMEA | PGME | CYH |
| | 100 | — | — | 0.1 | 70 | 30 | 0 |
| M39 | S'16 | — | — | G1 | PGMEA | PGME | CYH |
| | 100 | — | — | 0.1 | 70 | 30 | 0 |
| M40 | S'17 | — | — | G1 | PGMEA | PGME | CYH |
| | 100 | — | — | 0.1 | 70 | 30 | 0 |
| M41 | S'18 | — | — | G1 | PGMEA | PGME | CYH |
| | 100 | — | — | 0.1 | 70 | 30 | 0 |
| M42 | S'19 | — | — | G1 | PGMEA | PGME | CYH |
| | 100 | — | — | 0.1 | 70 | 30 | 0 |
| M43 | S'20 | — | — | G1 | PGMEA | PGME | CYH |
| | 100 | — | — | 0.1 | 70 | 30 | 0 |
| M44 | S'21 | — | — | G1 | PGMEA | PGME | CYH |
| | 100 | — | — | 0.1 | 70 | 30 | 0 |
| M45 | S'22 | — | — | G1 | PGMEA | PGME | CYH |
| | 100 | — | — | 0.1 | 70 | 30 | 0 |
| M46 | S'23 | — | — | G1 | PGMEA | PGME | CYH |
| | 100 | — | — | 0.1 | 70 | 30 | 0 |
| M47 | S'1 | CL1 | Ad1 | G1 | PGMEA | PGME | CYH |
| | 100 | 20 | 3.0 | 0.1 | 70 | 30 | 0 |
| M48 | S'2 | CL1 | Ad1 | G1 | PGMEA | PGME | CYH |
| | 100 | 20 | 3.0 | 0.1 | 60 | 30 | 10 |
| Comp. | SS1 | - | - | - | PGMEA | PGME | CYH |
| M1 | 100 | - | - | - | 70 | 30 | 0 |
| Comp. | SS2 | - | - | - | PGMEA | PGME | CYH |
| M2 | 100 | - | - | - | 70 | 30 | 0 |

TABLE 4-4

| Comp. M3 | SS1 | CL2 | Ad2 | G1 | PGMEA | PGME | CYH |
|---|---|---|---|---|---|---|---|
| | 100 | 30 | 3.0 | 0.1 | 70 | 30 | 0 |

(3) Test of Dissolution into Resist Solvent

The resist underlayer film materials Comp. M1 to Comp. M3 and M1 to M48 were each applied onto a silicon wafer using a spin coater, and the coatings were each baked in air atmosphere at a predetermined temperature for a predetermined time described in Table 5 to form a resist underlayer film with a film thickness of about 130 nm. The resist underlayer films formed were soaked in a general-purpose thinner, specifically, PGME/PGMEA=7/3 for 60 seconds to test the resistance to the solvent. The solvent resistance was rated as ◯ when the loss in film thickness after the thinner immersion was 1% or less (Tables 5-1 and 5-2).

Furthermore, the underlayer film materials were each applied onto a silicon wafer using ACT-8 manufactured by Tokyo Electron Ltd., and the coatings were each baked under nitrogen at a predetermined temperature for a predetermined time described in the table to form a 130 nm resist underlayer film. The resist underlayer films were similarly soaked in PGME/PGMEA=7/3 for 60 seconds to test the resistance to the solvent. The solvent resistance was rated as ◯ when the loss in film thickness after the thinner immersion was smaller than Comparative Examples (Tables 5-1 and 5-2).

In Table 5-2, the loss in film thickness is written in parentheses.

TABLE 5

| | | | Solvent | | | Solvent | |
|---|---|---|---|---|---|---|---|
| Ex./ | | | resistance | | | resistance under | |
| Comp. Ex. | Composition | Baking temp. | in air | | Baking temp. | nitrogen | |
| Ex. 1 | M1 | 400° C./60 sec | ∘ | | 400° C./60 sec | ∘ | |
| Ex. 2 | M2 | 400° C./60 sec | ∘ | | 400° C./60 sec | ∘ | |
| Ex. 3 | M3 | 400° C./60 sec | ∘ | | 400° C./60 sec | ∘ | |
| Ex. 4 | M4 | 400° C./60 sec | ∘ | | 400° C./60 sec | ∘ | |
| Ex. 5 | M5 | 400° C./60 sec | ∘ | | 400° C./60 sec | ∘ | |
| Ex. 6 | M6 | 400° C./60 sec | ∘ | | 400° C./60 sec | ∘ | |
| Ex. 7 | M7 | 400° C./60 sec | ∘ | | 400° C./60 sec | ∘ | |
| Ex. 8 | M8 | 400° C./60 sec | ∘ | | 400° C./60 sec | ∘ | |
| Ex. 9 | M9 | 400° C./60 sec | ∘ | | 400° C./60 sec | ∘ | |
| Ex. 10 | M10 | 400° C./60 sec | ∘ | | 400° C./60 sec | ∘ | |
| Ex. 11 | M11 | 400° C./60 sec | ∘ | | 400° C./60 sec | ∘ | |
| Ex. 12 | M12 | 400° C./60 sec | ∘ | | 400° C./60 sec | ∘ | |
| Ex. 13 | M13 | 400° C./60 sec | ∘ | | 400° C./60 sec | ∘ | |
| Ex. 14 | M14 | 400° C./60 sec | ∘ | | 400° C./60 sec | ∘ | |
| Ex. 15 | M15 | 400° C./60 sec | ∘ | | 400° C./60 sec | ∘ | |
| Ex. 16 | M16 | 400° C./60 sec | ∘ | | 400° C./60 sec | ∘ | |
| Ex. 17 | M17 | 400° C./60 sec | ∘ | | 400° C./60 sec | ∘ | |
| Ex. 18 | M18 | 400° C./60 sec | ∘ | | 400° C./60 sec | ∘ | |
| Ex. 19 | M19 | 400° C./60 sec | ∘ | | 400° C./60 sec | ∘ | |
| Ex. 20 | M20 | 400° C./60 sec | ∘ | | 400° C./60 sec | ∘ | |
| Ex. 21 | M21 | 400° C./60 sec | ∘ | | 400° C./60 sec | ∘ | |
| Ex. 22 | M22 | 400° C./60 sec | ∘ | | 400° C./60 sec | ∘ | |
| Ex. 23 | M23 | 400° C./60 sec | ∘ | | 400° C./60 sec | ∘ | |
| Ex. 24 | M24 | 400° C./60 sec | ∘ | | 400° C./60 sec | ∘ | |
| Ex. 25 | M25 | 400° C./60 sec | ∘ | | 400° C./60 sec | ∘ | |
| Ex. 26 | M26 | 400° C./60 sec | ∘ | | 400° C./60 sec | ∘ | |
| Ex. 27 | M27 | 400° C./60 sec | ∘ | | 400° C./60 sec | ∘ | |
| Ex. 28 | M28 | 400° C./60 sec | ∘ | | 400° C./60 sec | ∘ | |
| Ex. 29 | M29 | 400° C./60 sec | ∘ | | 400° C./60 sec | ∘ | |
| Ex. 30 | M30 | 400° C./60 sec | ∘ | | 400° C./60 sec | ∘ | |
| Ex. 31 | M31 | 400° C./60 sec | ∘ | | 400° C./60 sec | ∘ | |
| Ex. 32 | M32 | 400° C./60 sec | ∘ | | 400° C./60 sec | ∘ | |
| Ex. 33 | M33 | 400° C./60 sec | ∘ | | 400° C./60 sec | ∘ | |
| Ex. 34 | M34 | 400° C./60 sec | ∘ | | 400° C./60 sec | ∘ | |
| Ex. 35 | M35 | 400° C./60 sec | ∘ | | 400° C./60 sec | ∘ | |
| Ex. 36 | M36 | 400° C./60 sec | ∘ | | 400° C./60 sec | ∘ | |
| Ex. 37 | M37 | 400° C./60 sec | ∘ | | 400° C./60 sec | ∘ | |
| Ex. 38 | M38 | 400° C./60 sec | ∘ | | 400° C./60 sec | ∘ | |
| Ex. 39 | M39 | 400° C./60 sec | ∘ | | 400° C./60 sec | ∘ | |
| Ex. 40 | M40 | 400° C./60 sec | ∘ | | 400° C./60 sec | ∘ | |
| Ex. 41 | M41 | 400° C./60 sec | ∘ | | 400° C./60 sec | ∘ | |
| Ex. 42 | M42 | 400° C./60 sec | ∘ | | 400° C./60 sec | ∘ | |
| Ex. 43 | M43 | 400° C./60 sec | ∘ | | 400° C./60 sec | ∘ | |
| Ex. 44 | M44 | 400° C./60 sec | ∘ | | 400° C./60 sec | ∘ | |
| Ex. 45 | M45 | 400° C./60 sec | ∘ | | 400° C./60 sec | ∘ | |
| Ex. 46 | M46 | 400° C./60 sec | ∘ | | 400° C./60 sec | ∘ | |
| Ex. 47 | M47 | 400° C./60 sec | ∘ | | 400° C./60 sec | ∘ | |
| Ex. 48 | M48 | 400° C./60 sec | ∘ | | 400° C./60 sec | ∘ | |
| Comp. Ex. 1 | Comp. M1 | 400° C./60 sec | ∘ | (<1%) | 400° C./60 sec | x | (100%) |
| Comp. Ex. 2 | Comp. M2 | 400° C./60 sec | x | (45%) | 400° C./60 sec | x | (100%) |
| Comp. Ex. 3 | Comp. M3 | 400° C./60 sec | ∘ | (<1%) | 400° C./60 sec | ∘ | (<1%) |

TABLE 5-2

| | | | | | |
|---|---|---|---|---|---|
| Ex. 32 | M32 | 400° C./60sec | O | 400° C./60sec | O |
| Ex. 33 | M33 | 400°C/60sec | O | 400°C/60sec | C |
| Ex. 34 | M34 | 400° C./60sec | O | 400° C./60sec | O |
| Ex. 35 | M35 | 400° C./60sec | O | 400° C./60sec | |
| Ex. 36 | M36 | 400°C/60sec | O | 400°C/60sec | C |
| Ex. 37 | M37 | 400°C/60sec | O | 400°C/60sec | |
| Ex. 38 | M38 | 400° C./60sec | O | 400° C./60sec | |
| Ex. 39 | M39 | 400°C/60sec | | 400° C./60sec | |
| Ex. 40 | M40 | 400°C/60sec | O | 400° C./60sec | |
| Ex. 41 | M41 | 400°C/60sec | | 400° C./60sec | |
| Ex. 42 | M42 | 400°C/60sec | O | 400° C./60sec | |
| Ex. 43 | M43 | 400°C/60sec | O | 400°C/60sec | O |
| Ex. 44 | M44 | 400° C./60sec | O | 400°C/60sec | |
| Ex. 45 | M45 | 400° C./60sec | O | 400°C/60sec | |
| Ex. 46 | M46 | 400° C./60sec | | 400° C./60sec | |
| Ex. 47 | M47 | 400° C./60sec | O | 400°C/60sec | |
| Ex. 48 | M48 | 400° C./60sec | C | 400° C./60sec | |
| Comp. Ex. 1 | Comp. M1 | 400°C/60sec | O(<1%) | 400°C/60sec | × (100%) |
| Comp. Ex. 2 | Comp. M2 | 400° C./60sec | × (45%) | 400°C/60sec | ×(100%) |
| Comp. Ex. 3 | Comp. M3 | 400° C./60sec | O(<1%) | 400° C./60sec | O(<1%) |

It has been shown that usual resist underlayer films that did not contain a crosslinking agent or a curing catalyst (Comparative Examples 1 and 2) failed to exhibit solvent resistance when baked in nitrogen atmosphere. In contrast, the resist underlayer films in which propargyl groups had been introduced into the bis(azaaryl fused ring) structures (Examples 24 to 46) had self-crosslinkability and, without containing a crosslinking agent or a curing catalyst, attained solvent resistance when baked not only in air atmosphere but also in nitrogen atmosphere. As a matter of course, such resist underlayer films that further contained a crosslinking agent and a curing catalyst (Examples 47 and 48) were successfully cured in both atmospheres similarly to a general resist underlayer film (Comparative Example 3). By the use of a crosslinking agent and a curing catalyst, even the resist underlayer films from polymers that did not contain propargyl groups (Examples 1 to 23) were successfully cured in both atmospheres similarly to a usual resist underlayer film (Comparative Example 3). Comparative M2 failed to attain solvent resistance when baked in air atmosphere that is adopted in general baking conditions and thus cannot serve as a resist underlayer film. This material was therefore excluded from the subsequent evaluations.

### (4) Measurement of Etching Rates

The resist underlayer film materials Comparative M1, Comparative M3, and M1 to M48 were each applied onto a silicon wafer using a spin coater. The coatings were each baked on a hot plate at a predetermined temperature for a predetermined time described in the table to form a 130 nm resist underlayer film. The dry etching rate was measured using O₂/N₂ gas or CF₄ gas as the etching gas.

In the etching resistance data in Tables 6-1 and 6-2, the values written in parentheses are the dry etching rate ratios calculated by (resist underlayer film)/(phenol novolac resin film). The etching resistance was evaluated as ◯ when the etching rate was lower than those of both Comparative Examples 1 and 3 (Comparative M1 and Comparative M3) (Tables 6-1 and 6-2).

The etcher and the etching gases used in the etching measurement are as follows:
RIE-200NL (manufactured by Samco Inc.); CF₄ 50 sccm
RIE-200NL (manufactured by Samco Inc.); O₂/N₂ 10 sccm/200 sccm

### (5) Measurement of Optical Constants

The resist underlayer film materials Comparative M1, Comparative M3, and M1 to M48 were each applied onto a silicon wafer using a spin coater. The coatings were each baked on a hot plate at a predetermined temperature for a predetermined time described in the table to form a resist underlayer film (film thickness: 50 nm). These resist underlayer films were analyzed with a spectroscopic ellipsometer to measure the refractive index (n value) and the optical absorption coefficient (k value, also called the attenuation coefficient) at a wavelength of 193 nm (Tables 6-1 and 6-2).

### (6) Evaluation of Applicability

The resist underlayer film materials Comparative M1, Comparative M3, and M1 to M48 were each applied onto a silicon wafer using a 12-inch coater manufactured by Tokyo Electron Ltd. The coatings were each baked in air atmosphere at a predetermined temperature for a predetermined time described in the table to form a 130 nm resist underlayer film. Subsequently, the film thickness was measured with respect to 49 points on circles over the entirety of the wafer to evaluate the uniformity of film thickness in the plane of the wafer. The uniformity was evaluated as ◯ when the ratio of the variation in film thickness (maximum film thickness−minimum film thickness) to the average film thickness was smaller than the values of both Comparative Examples 1 and 3 (Comparative M1 and Comparative M3). A smaller ratio of the variation in film thickness means a higher uniformity in film thickness in the plane of the wafer (Tables 6-1 and 6-2).

In the results of film thickness uniformity in Tables 6-1 and 6-2, the values in parentheses indicate the ratio of the variation in film thickness (maximum film thickness−minimum film thickness) to the average film thickness.

TABLE 6

| Ex./ | | | | | | Film |
|---|---|---|---|---|---|---|
| Comp. | | Baking | Etching resistance | | n/k | thickness |
| Ex. | Composition | temp. | CF₄ | O₂/N₂ | @193 nm | uniformity |
| Ex. 1 | M1 | 400° C./60 sec | ∘ | ∘ | 1.42/0.51 | ∘ |
| Ex. 2 | M2 | 400° C./60 sec | ∘ | ∘ | 1.36/0.48 | ∘ |
| Ex. 3 | M3 | 400° C./60 sec | ∘ | ∘ | 1.36/0.47 | ∘ |
| Ex. 4 | M4 | 400° C./60 sec | ∘ | ∘ | 1.41/0.47 | ∘ |
| Ex. 5 | M5 | 400° C./60 sec | ∘ | ∘ | 1.32/0.42 | ∘ |
| Ex. 6 | M6 | 400° C./60 sec | ∘ | ∘ | 1.37/0.47 | ∘ |
| Ex. 7 | M7 | 400° C./60 sec | ∘ | ∘ | 1.38/0.47 | ∘ |
| Ex. 8 | M8 | 400° C./60 sec | ∘ | ∘ | 1.46/0.58 | ∘ |
| Ex. 9 | M9 | 400° C./60 sec | ∘ | ∘ | 1.46/0.57 | ∘ |
| Ex. 10 | M10 | 400° C./60 sec | ∘ | ∘ | 1.47/0.59 | ∘ |
| Ex. 11 | M11 | 400° C./60 sec | ∘ | ∘ | 1.45/0.59 | ∘ |
| Ex. 12 | M12 | 400° C./60 sec | ∘ | ∘ | 1.37/0.46 | ∘ |
| Ex. 13 | M13 | 400° C./60 sec | ∘ | ∘ | 1.37/0.47 | ∘ |
| Ex. 14 | M14 | 400° C./60 sec | ∘ | ∘ | 1.44/0.55 | ∘ |
| Ex. 15 | M15 | 400° C./60 sec | ∘ | ∘ | 1.36/0.47 | ∘ |
| Ex. 16 | M16 | 400° C./60 sec | ∘ | ∘ | 1.45/0.59 | ∘ |
| Ex. 17 | M17 | 400° C./60 sec | ∘ | ∘ | 1.47/0.58 | ∘ |
| Ex. 18 | M18 | 400° C./60 sec | ∘ | ∘ | 1.42/0.50 | ∘ |
| Ex. 19 | M19 | 400° C./60 sec | ∘ | ∘ | 1.36/0.48 | ∘ |
| Ex. 20 | M20 | 400° C./60 sec | ∘ | ∘ | 1.45/0.54 | ∘ |
| Ex. 21 | M21 | 400° C./60 sec | ∘ | ∘ | 1.45/0.54 | ∘ |
| Ex. 22 | M22 | 400° C./60 sec | ∘ | ∘ | 1.44/0.54 | ∘ |
| Ex. 23 | M23 | 400° C./60 sec | ∘ | ∘ | 1.45/0.54 | ∘ |
| Ex. 24 | M24 | 400° C./60 sec | ∘ | ∘ | 1.42/0.53 | ∘ |
| Ex. 25 | M25 | 400° C./60 sec | ∘ | ∘ | 1.37/0.48 | ∘ |
| Ex. 26 | M26 | 400° C./60 sec | ∘ | ∘ | 1.40/0.46 | ∘ |
| Ex. 27 | M27 | 400° C./60 sec | ∘ | ∘ | 1.43/0.46 | ∘ |
| Ex. 28 | M28 | 400° C./60 sec | ∘ | ∘ | 1.32/0.43 | ∘ |
| Ex. 29 | M29 | 400° C./60 sec | ∘ | ∘ | 1.37/0.47 | ∘ |
| Ex. 30 | M30 | 400° C./60 sec | ∘ | ∘ | 1.38/0.49 | ∘ |
| Ex. 31 | M31 | 400° C./60 sec | ∘ | ∘ | 1.46/0.60 | ∘ |
| Ex. 32 | M32 | 400° C./60 sec | ∘ | ∘ | 1.46/0.60 | ∘ |
| Ex. 33 | M33 | 400° C./60 sec | ∘ | ∘ | 1.47/0.60 | ∘ |
| Ex. 34 | M34 | 400° C./60 sec | ∘ | ∘ | 1.45/0.58 | ∘ |
| Ex. 35 | M35 | 400° C./60 sec | ∘ | ∘ | 1.39/0.47 | ∘ |
| Ex. 36 | M36 | 400° C./60 sec | ∘ | ∘ | 1.38/0.49 | ∘ |
| Ex. 37 | M37 | 400° C./60 sec | ∘ | ∘ | 1.45/0.54 | ∘ |
| Ex. 38 | M38 | 400° C./60 sec | ∘ | ∘ | 1.37/0.48 | ∘ |
| Ex. 39 | M39 | 400° C./60 sec | ∘ | ∘ | 1.47/0.60 | ∘ |
| Ex. 40 | M40 | 400° C./60 sec | ∘ | ∘ | 1.47/0.59 | ∘ |
| Ex. 41 | M41 | 400° C./60 sec | ∘ | ∘ | 1.43/0.49 | ∘ |
| Ex. 42 | M42 | 400° C./60 sec | ∘ | ∘ | 1.37/0.48 | ∘ |
| Ex. 43 | M43 | 400° C./60 sec | ∘ | ∘ | 1.45/0.54 | ∘ |
| Ex. 44 | M44 | 400° C./60 sec | ∘ | ∘ | 1.45/0.54 | ∘ |
| Ex. 45 | M45 | 400° C./60 sec | ∘ | ∘ | 1.46/0.54 | ∘ |
| Ex. 46 | M46 | 400° C./60 sec | ∘ | ∘ | 1.45/0.55 | ∘ |
| Ex. 47 | M47 | 400° C./60 sec | ∘ | ∘ | 1.42/0.50 | ∘ |
| Ex. 48 | M48 | 400° C./60 sec | ∘ | ∘ | 1.37/0.46 | ∘ |
| Comp. | Comp. | 400° C./60 sec | x | x | 1.42/0.50 | x |
| Ex. 1 | M1 | | (0.85) | (0.75) | | (4.1%) |
| Comp. | Comp. | 400° C./60 sec | x | x | 1.46/0.49 | x |
| Ex. 3 | M3 | | (0.88) | (0.78) | | (4.4%) |

TABLE 6-2

| | | | | | | |
|---|---|---|---|---|---|---|
| Ex. 33 | M33 | 400°C/60sec | O | O | 1.47/0.60 | O |
| Ex. 34 | M34 | 400°C/60sec | C | C | 1.45/0.58 | 0 |
| Ex. 35 | M35 | 400° C./60sec | | C | 1.39/0.47 | C |
| Ex. 36 | M36 | 400° C./60sec | | C | 1.38/0.49 | 0 |
| Ex. 37 | M37 | 400°C/60sec | | ( | 1.45/0.54 | O |
| Ex. 38 | M38 | 400° C./60sec | | | 1.37/0.48 | O |
| Ex. 39 | M39 | 400° C./60sec | | C | 1.47/0.60 | 0 |
| Ex. 40 | M40 | 400° C./60sec | | C | 1.47/0.59 | 0 |
| Ex. 41 | M41 | 400°C/60sec | | C | 1.43/0.49 | O |
| Ex. 42 | M42 | 400° C./60sec | | C | 1.37/0.48 | O |
| Ex. 43 | M43 | 400°C/60sec | | ( | 1.45/0.54 | O |
| Ex. 44 | M44 | 400° C./60sec | | C | 1.45/0.54 | O |
| Ex. 45 | M45 | 400°C/60sec | | O | 1.46/0.54 | O |
| Ex. 46 | M46 | 400° C./60sec | C | O | 1.45/0.55 | |
| Ex. 47 | M47 | 400° C./60sec | C | | 1.42/0.50 | O |
| Ex. 48 | M48 | 400° C./60sec | | C | 1.37/0.46 | 0 |
| Comp. Ex. 1 | Comp. | 400° C./60sec | × | X | 1.42/0.50 | × |
| | M1 | | (0.85) | (0.75) | | (4.1%) |
| Comp. Ex. 3 | Comp. | 400° C./60sec | X | × | 1.46/0.49 | X |
| | M3 | | (0.88) | (0.78) | | (4.4%) |

### (7) Measurement of Amount of Sublimates)

The amount of sublimates was measured using the sublimate amount measuring apparatus described in WO 2007/111147 A1. The resist underlayer film-forming compositions Comparative M1, Comparative M3, and M1 to M48 were prepared so that the film thickness after baking at 400° C. for 60 seconds would be 130 nm. The compositions were each applied to a silicon wafer, and the coatings were baked at 300° C. while measuring the amount of sublimates. The rating was ◯ when the amount of sublimates was smaller than the amounts of both Comparative Examples 1 and 3 (Comparative M1 and Comparative M3) (Tables 7-1 and 7-2).

The values in parentheses indicate the amounts of sublimates actually measured.

TABLE 7

| Ex./Comp. Ex. | Composition | Baking temp. | Amount of sublimates |
|---|---|---|---|
| Ex. 1 | M1 | 300° C./60 sec | ∘ |
| Ex. 2 | M2 | 300° C./60 sec | ∘ |
| Ex. 3 | M3 | 300° C./60 sec | ∘ |
| Ex. 4 | M4 | 300° C./60 sec | ∘ |
| Ex. 5 | M5 | 300° C./60 sec | ∘ |
| Ex. 6 | M6 | 300° C./60 sec | ∘ |
| Ex. 7 | M7 | 300° C./60 sec | ∘ |
| Ex. 8 | M8 | 300° C./60 sec | ∘ |
| Ex. 9 | M2 | 300° C./60 sec | ∘ |
| Ex. 10 | M10 | 300° C./60 sec | ∘ |
| Ex. 11 | M11 | 300° C./60 sec | ∘ |
| Ex. 12 | M12 | 300° C./60 sec | ∘ |
| Ex. 13 | M13 | 300° C./60 sec | ∘ |
| Ex. 14 | M14 | 300° C./60 sec | ∘ |
| Ex. 15 | M15 | 300° C./60 sec | ∘ |
| Ex. 16 | M16 | 300° C./60 sec | ∘ |
| Ex. 17 | M17 | 300° C./60 sec | ∘ |
| Ex. 18 | M18 | 300° C./60 sec | ∘ |
| Ex. 19 | M19 | 300° C./60 sec | ∘ |
| Ex. 20 | M20 | 300° C./60 sec | ∘ |
| Ex. 21 | M21 | 300° C./60 sec | ∘ |
| Ex. 22 | M22 | 300° C./60 sec | ∘ |
| Ex. 23 | M23 | 300° C./60 sec | ∘ |
| Ex. 24 | M24 | 300° C./60 sec | ∘ |
| Ex. 25 | M25 | 300° C./60 sec | ∘ |
| Ex. 26 | M26 | 300° C./60 sec | ∘ |
| Ex. 27 | M27 | 300° C./60 sec | ∘ |
| Ex. 28 | M28 | 300° C./60 sec | ∘ |
| Ex. 29 | M29 | 300° C./60 sec | ∘ |
| Ex. 30 | M30 | 300° C./60 sec | ∘ |
| Ex. 31 | M31 | 300° C./60 sec | ∘ |
| Ex. 32 | M32 | 300° C./60 sec | ∘ |
| Ex. 33 | M33 | 300° C./60 sec | ∘ |
| Ex. 34 | M34 | 300° C./60 sec | ∘ |
| Ex. 35 | M35 | 300° C./60 sec | ∘ |
| Ex. 36 | M36 | 300° C./60 sec | ∘ |
| Ex. 37 | M37 | 300° C./60 sec | ∘ |
| Ex. 38 | M38 | 300° C./60 sec | ∘ |
| Ex. 39 | M39 | 300° C./60 sec | ∘ |
| Ex. 40 | M40 | 300° C./60 sec | ∘ |
| Ex. 41 | M41 | 300° C./60 sec | ∘ |
| Ex. 42 | M42 | 300° C./60 sec | ∘ |
| Ex. 43 | M43 | 300° C./60 sec | ∘ |
| Ex. 44 | M44 | 300° C./60 sec | ∘ |
| Ex. 45 | M45 | 300° C./60 sec | ∘ |
| Ex. 46 | M46 | 300° C./60 sec | ∘ |
| Ex. 47 | M47 | 300° C./60 sec | ∘ |
| Ex. 48 | M48 | 300° C./60 sec | ∘ |
| Comp. Ex. 1 | Comp. M1 | 300° C./60 sec | x (3500 ng) |
| Comp. Ex. 3 | Comp. M3 | 300° C./60 sec | x (3100 ng) |

TABLE 7-2

| | | | |
|---|---|---|---|
| Ex. 32 | M32 | 300°C/60sec | O |
| Ex. 33 | M33 | 300°C/60sec | O |
| Ex. 34 | M34 | 300° C./60sec | ) |
| Ex. 35 | M35 | 300°C/60sec | O |
| Ex. 36 | M36 | 300° C./60sec | O |
| Ex. 37 | M37 | 300°C/60sec | O |
| Ex. 38 | M38 | 300°C/60sec | |
| Ex. 39 | M39 | 300° C./60sec | |
| Ex. 40 | M40 | 300°C/60sec | O |
| Ex. 41 | M41 | 300° C./60sec | |
| Ex. 42 | M42 | 300° C./60sec | |
| Ex. 43 | M43 | 300° C./60sec | |
| Ex. 44 | M44 | 300°C/60sec | 0 |
| Ex. 45 | M45 | 300°C/60sec | 0 |
| Ex. 46 | M46 | 300°C/60sec | 0 |
| Ex. 47 | M47 | 300°C/60sec | O |
| Ex. 48 | M48 | 300° C./60sec | |
| Comp. Ex. 1 | Comp. M1 | 300°C/60sec | X (3500ng) |
| Comp. Ex. 3 | Comp. M3 | 300° C./60sec | × (3100ng) |

### (8) Test 1 of Applicability and Covering Performance on Non-Planar Substrates

The covering performance on non-planar substrates was tested using SiO₂ substrates, SiN substrates, and TiN substrates each having a thickness of 200 nm. Resist underlayer films may exhibit poor applicability on non-planar substrates as compared to planar silicon wafers. Thus, the ability of being applied uniformly on non-planar substrates was examined. The rating was ◯ when visual observation confirmed uniform application. Flattening properties were evaluated with respect to a trenched area (a dense pattern area) present on the substrate that consisted of 50 nm wide trenches at 100 nm pitches. The coating film thickness was compared between at the dense area and at a pattern-free area (an open area). The resist underlayer film-forming compositions, Comparative M1 and M1 to M48, were each applied to the substrate, and the coatings were each baked on a hot plate at a predetermined temperature for a predetermined time described in Table 8 to form a 130 nm resist underlayer film. The flatness of the substrates was observed using a scanning electron microscope (S-4800) manufactured by Hitachi High-Tech Corporation. Flattening properties were evaluated by measuring the difference in film thickness between on the trenched area (the patterned area) and on the open area (the pattern-free area) of the non-planar substrate (the step height created on the coating film between the trenched area and the open area, called a bias). Here, flattening properties mean how small the difference (an iso-dense bias) is in the film thickness of the coating film between on the region with the pattern (the trenched area (the patterned area)) and on the region without patterns (the open area (the pattern-free area)). Flattening properties were rated as ◯ when the bias was improved compared to Comparative Example 1 (Comparative M1) (Tables 8-1 and 8-2).

TABLE 8-1

| | | | | | | |
|---|---|---|---|---|---|---|
| Ex./Comp. Ex. | Composition | Film | Baking temp. | Type of | Applicability | Flattening |
| | | thickness | | substrate | on non-planar | properties |
| | | | | | substrate | |
| Ex. 1 | M1 | 130nm | 400° C./60sec | SiO2 | | |
| Ex. 2 | M2 | 130nm | 400°C/60sec | SiO2 | | |
| Ex. 3 | M3 | 130nm | 400°C/60sec | SiO2 | O | O |
| Ex. 4 | M4 | 130nm | 400°C/60sec | SiO2 | | O |
| Ex. 5 | M5 | 130nm | 400° C./60sec | SiO2 | | |
| Ex. 6 | M6 | 130nm | 400°C/60sec | SiO2 | 0 | 0 |
| Ex. 7 | M7 | 130nm | 400° C./60sec | SiO2 | | |
| Ex. 8 | M8 | 130nm | 400° C./60sec | SiO2 | | C |
| | | 130nm | 400° C./60sec | TIN | | C |
| | | 130nm | 400°C/60sec | SIN | C | C |
| Ex. 9 | M9 | 130nm | 400°C/60sec | SiO2 | | |
| Ex. 10 | M10 | 130nm | 400°C/60sec | SiO2 | | |
| Ex. 11 | M11 | 130nm | 400°C/60sec | SiO2 | C | C |
| | | 130nm | 400° C./60sec | TIN | C | C |
| | | 130nm | 400°C/60sec | SIN | C | |
| Ex. 12 | M12 | 130nm | 400°C/60sec | SiO2 | C | |
| Ex. 13 | M13 | 130nm | 400°C/60sec | SiO2 | 0 | ( |
| Ex. 14 | M14 | 130nm | 400°C/60sec | SiO2 | 0 | |
| Ex. 15 | M15 | 130nm | 400°C/60sec | SiO2 | 0 | 0 |
| Ex. 16 | M16 | 130nm | 400° C./60sec | SiO2 | | |
| Ex. 17 | M17 | 130nm | 400°C/60sec | SiO2 | | |
| Ex. 18 | M18 | 130nm | 400° C./60sec | SiO2 | | O |
| Ex. 19 | M19 | 130nm | 400° C./60sec | SiO2 | | C |
| Ex. 20 | M20 | 130nm | 400°C/60sec | SiO2 | | C |
| Ex. 21 | M21 | 130nm | 400°C/60sec | SiO2 | C | C |
| Ex. 22 | M22 | 130nm | 400°C/60sec | SiO2 | C | C |
| Ex. 23 | M23 | 130nm | 400°C/60sec | SiO2 | | |
| Ex. 24 | M24 | 130nm | 400°C/60sec | SiO2 | C | C |
| Ex. 25 | M25 | 130nm | 400° C./60sec | SiO2 | O | C |
| Ex. 26 | M26 | 130nm | 400°C/60sec | SiO2 | 0 | |
| Ex. 27 | M27 | 130nm | 400°C/60sec | SiO2 | C | |
| Ex. 28 | M28 | 130nm | 400°C/60sec | SiO2 | | |

TABLE 8-2

| | | | | | | |
|---|---|---|---|---|---|---|
| Ex. 29 | M29 | 130nm | 400°C/60sec | SiO2 | O | O |
| Ex. 30 | M30 | 130nm | 400°C/60sec | SiO2 | | 0 |
| Ex. 31 | M31 | 130nm | 400°C/60sec | SiO2 | | |
| | | 130nm | 400° C./60sec | TIN | O | |
| | | 130nm | 400°C/60sec | SIN | O | |
| Ex. 32 | M32 | 130nm | 400°C/60sec | SiO2 | 0 | |
| Ex. 33 | M33 | 130nm | 400°C/60sec | SiO2 | C | |
| Ex. 34 | M34 | 130nm | 400°C/60sec | SiO2 | C | |
| Ex. 35 | M35 | 130nm | 400°C/60sec | SiO2 | O | |
| Ex. 36 | M36 | 130nm | 400° C./60sec | SiO2 | C | C |
| Ex. 37 | M37 | 130nm | 400°C/60sec | SiO2 | 0 | |
| Ex. 38 | M38 | 130nm | 400°° C./60sec | SiO2 | 0 | |
| Ex. 39 | M39 | 130nm | 400° C./60sec | SiO2 | | |
| | | 130nm | 400°° C./60sec | TIN | | |
| | | 130nm | 400°C/60sec | SIN | 0 | O |
| Ex. 40 | M40 | 130nm | 400°C/60sec | SiO2 | O | O |
| Ex. 41 | M41 | 130nm | 400° C./60sec | SiO2 | 0 | |
| Ex. 42 | M42 | 130nm | 400° C./60sec | SiO2 | C | |
| | | 130nm | 400° C./60sec | TIN | | |
| | | 130nm | 400°C/60sec | SIN | | |
| Ex. 43 | M43 | 130nm | 400°C/60sec | SiO2 | 0 | |
| Ex. 44 | M44 | 130nm | 400° C./60sec | SiO2 | O | 0 |
| Ex. 45 | M45 | 130nm | 400°C/60sec | SiO2 | O | C |
| Ex. 46 | M46 | 130nm | 400° C./60sec | SiO2 | O | |
| Ex. 47 | M47 | 130nm | 400°C/60sec | SiO2 | C | 2 |
| Ex. 48 | M48 | 130nm | 400°C/60sec | SiO2 | | C |
| Comp. Ex. 1 | Comp. M1 | 130nm | 400° C./60sec | SiO2 | | × |

### (9) Test 2 of Applicability and Covering Performance on Non-Planar Substrates

The covering performance on non-planar substrates was tested using SiO₂ substrates, SiN substrates, and TiN substrates each having a thickness of 200 nm. Resist underlayer films may exhibit poor applicability on non-planar substrates as compared to planar silicon wafers. Thus, the ability of being applied uniformly on non-planar substrates was examined. The rating was ◯ when visual observation confirmed uniform application. Flattening properties were evaluated with respect to a wide trenched area present on the substrate that had a trench width of 800 nm. The coating film thickness was compared between at the wide trenched area and at a pattern-free area (an open area). The resist underlayer film-forming compositions, Comparative M3 and M1 to M48, were each applied to the substrate, and the coatings were each baked on a hot plate at a predetermined temperature for a predetermined time described in the table to form a 130 nm resist underlayer film. Flattening properties were evaluated in the same manner as “Test 1 of applicability and covering performance on non-planar substrates” (Tables 9-1 and 9-2). Flattening properties were rated as ◯ when the bias was improved compared to Comparative Example 3 (Comparative M3) (Tables 9-1 and 9-2).

TABLE 9

| Ex./ | | | | | Applicability | |
|---|---|---|---|---|---|---|
| Comp. | | Film | Baking | Type of | on non-planar | Flattening |
| Ex. | Composition | thickness | temp. | substrate | substrate | properties |
| Ex. 1 | M1 | 130 nm | 400° C./60 sec | SiO₂ | ∘ | ∘ |
| Ex. 2 | M2 | 130 nm | 400° C./60 sec | SiO₂ | ∘ | ∘ |
| Ex. 3 | M3 | 130 nm | 400° C./60 sec | SiO₂ | ∘ | ∘ |
| Ex. 4 | M4 | 130 nm | 400° C./60 sec | SiO₂ | ∘ | ∘ |
| Ex. 5 | M5 | 130 nm | 400° C./60 sec | SiO₂ | ∘ | ∘ |
| Ex. 6 | M6 | 130 nm | 400° C./60 sec | SiO₂ | ∘ | ∘ |
| Ex. 7 | M7 | 130 nm | 400° C./60 sec | SiO₂ | ∘ | ∘ |
| Ex. 8 | M8 | 130 nm | 400° C./60 sec | SiO₂ | ∘ | ∘ |
| | | 130 nm | 400° C./60 sec | TiN | ∘ | ∘ |
| | | 130 nm | 400° C./60 sec | SiN | ∘ | ∘ |
| Ex. 9 | M9 | 130 nm | 400° C./60 sec | SiO₂ | ∘ | ∘ |
| Ex. 10 | M10 | 130 nm | 400° C./60 sec | SiO₂ | ∘ | ∘ |
| Ex. 11 | M11 | 130 nm | 400° C./60 sec | SiO₂ | ∘ | ∘ |
| | | 130 nm | 400° C./60 sec | SiO₂ | ∘ | ∘ |
| | | 130 nm | 400° C./60 sec | TiN | ∘ | ∘ |
| Ex. 12 | M12 | 130 nm | 400° C./60 sec | SiN | ∘ | ∘ |
| Ex. 13 | M13 | 130 nm | 400° C./60 sec | SiO₂ | ∘ | ∘ |
| Ex. 14 | M14 | 130 nm | 400° C./60 sec | SiO₂ | ∘ | ∘ |
| Ex. 15 | M15 | 130 nm | 400° C./60 sec | SiO₂ | ∘ | ∘ |
| Ex. 16 | M16 | 130 nm | 400° C./60 sec | SiO₂ | ∘ | ∘ |
| Ex. 17 | M17 | 130 nm | 400° C./60 sec | SiO₂ | ∘ | ∘ |
| Ex. 18 | M18 | 130 nm | 400° C./60 sec | SiO₂ | ∘ | ∘ |
| Ex. 19 | M19 | 130 nm | 400° C./60 sec | SiO₂ | ∘ | ∘ |
| Ex. 20 | M20 | 130 nm | 400° C./60 sec | SiO₂ | ∘ | ∘ |
| Ex. 21 | M21 | 130 nm | 400° C./60 sec | SiO₂ | ∘ | ∘ |
| Ex. 22 | M22 | 130 nm | 400° C./60 sec | SiO₂ | ∘ | ∘ |
| Ex. 23 | M23 | 130 nm | 400° C./60 sec | SiO₂ | ∘ | ∘ |
| Ex. 24 | M24 | 130 nm | 400° C./60 sec | SiO₂ | ∘ | ∘ |
| Ex. 25 | M25 | 130 nm | 400° C./60 sec | SiO₂ | ∘ | ∘ |
| Ex. 26 | M26 | 130 nm | 400° C./60 sec | SiO₂ | ∘ | ∘ |
| Ex. 27 | M27 | 130 nm | 400° C./60 sec | SiO₂ | ∘ | ∘ |
| Ex. 28 | M28 | 130 nm | 400° C./60 sec | SiO₂ | ∘ | ∘ |

TABLE 9-2

| Ex. 29 | M29 | 130nm | 400°C/60sec | SiO2 | O | O |
|---|---|---|---|---|---|---|
| Ex. 30 | M30 | 130nm | 400° C./60sec | SiO2 | 0 | O |
| Ex. 31 | M31 | 130nm | 400°C/60sec | SiO2 | C | O |
| | | 130nm | 400°C/60sec | TIN | O | C |
| | | 130nm | 400° C./60sec | SIN | C | O |
| Ex. 32 | M32 | 130nm | 400°C/60sec | SiO2 | C | C |
| Ex. 33 | M33 | 130nm | 400°C/60sec | SiO2 | 0 | C |
| Ex. 34 | M34 | 130nm | 400°C/60sec | SiO2 | | C |
| Ex. 35 | M35 | 130nm | 400°C/60sec | SiO2 | | C |
| Ex. 36 | M36 | 130nm | 400° C./60sec | SiO2 | 0 | C |
| Ex. 37 | M37 | 130nm | 400°C/60sec | SiO2 | O | O |
| Ex. 38 | M38 | 130nm | 400°C/60sec | SiO2 | 0 | |
| Ex. 39 | M39 | 130nm | 400°C/60sec | SiO2 | C | C |
| | | 130nm | 400° C./60sec | TIN | C | C |
| | | 130nm | 400°C/60sec | SIN | | |
| Ex. 40 | M40 | 130nm | 400°C/60sec | SIN | C | O |
| Ex. 41 | M41 | 130nm | 400°C/60sec | SiO2 | O | C |
| Ex. 42 | M42 | 130nm | 400° C./60sec | SiO2 | | C |
| | | 130nm | 400° C./60sec | TIN | | C |
| | | 130nm | 400°C/60sec | SIN | | |
| Ex. 43 | M43 | 130nm | 400°C/60sec | SIN | | C |
| Ex. 44 | M44 | 130nm | 400°C/60sec | SiO2 | 0 | C |
| Ex. 45 | M45 | 130nm | 400°C/60sec | SiO2 | C | O |
| Ex. 46 | M46 | 130nm | 400° C./60sec | SiO2 | C | O |
| Ex. 47 | M47 | 130nm | 400°C/60sec | SiO2 | 0 | O |
| Ex. 48 | M48 | 130nm | 400° C./60sec | SiO2 | | C |
| Comp. Ex. 3 | Comp. M3 | 130nm | 400°C/60sec | SiO2 | 0 | X |

### (10) Test of Gap-Filling Properties on Non-Planar Substrates

The covering performance on non-planar substrates was tested using SiO₂ substrates, SiN substrates, and TiN substrates each having a thickness of 200 nm. Gap-filling properties were evaluated with respect to a trenched area (a dense pattern area) present on the substrate that consisted of 50 nm wide trenches at 100 nm pitches. The resist underlayer film-forming compositions, M5, M28 to M36, M38 to M40, and Comparative M3, were each applied to the substrate, and the coatings were each baked on a hot plate at a predetermined temperature for a predetermined time described in the table to form a 130 nm resist underlayer film. Gap-filling properties on the substrates were observed using a scanning electron microscope (S-4800) manufactured by Hitachi High-Tech Corporation. Gap-filling properties were rated as ◯ when the resist underlayer film had filled to the bottom of the trenches (Table 10).

TABLE 10

| | | Film | | | Gap- |
|---|---|---|---|---|---|
| Ex./ | Compo- | thick- | | Type of | filling |
| Comp. Ex. | sition | ness | Baking temp. | substrate | properties |
| Ex. 5 | M5 | 130 nm | 400° C./60 sec | SiO₂ | ∘ |
| Ex. 28 | M28 | 130 nm | 400° C./60 sec | SiO₂ | ∘ |
| Ex. 29 | M29 | 130 nm | 400° C./60 sec | SiO₂ | ∘ |
| Ex. 30 | M30 | 130 nm | 400° C./60 sec | SiO₂ | ∘ |
| Ex. 31 | M31 | 130 nm | 400° C./60 sec | SiO₂ | ∘ |
| Ex. 32 | M32 | 130 nm | 400° C./60 sec | SiO₂ | ∘ |
| Ex. 33 | M33 | 130 nm | 400° C./60 sec | SiO₂ | ∘ |
| Ex. 34 | M34 | 130 nm | 400° C./60 sec | SiO₂ | ∘ |
| Ex. 35 | M35 | 130 nm | 400° C./60 sec | SiO₂ | ∘ |
| Ex. 36 | M36 | 130 nm | 400° C./60 sec | SiO₂ | ∘ |
| Ex. 38 | M38 | 130 nm | 400° C./60 sec | SiO₂ | ∘ |
| Ex. 39 | M39 | 130 nm | 400° C./60 sec | SiO₂ | ∘ |
| | | 130 nm | 400° C./60 sec | TiN | ∘ |
| | | 130 nm | 400° C./60 sec | SiN | ∘ |
| Ex. 40 | M40 | 130 nm | 400° C./60 sec | SiO₂ | ∘ |
| Comp. | Comp. | 130 nm | 400° C./60 sec | SiO₂ | x |
| Ex. 3 | M3 | | | | |

As demonstrated above, the novolac resins from a bis(azaaryl fused ring) compound have high heat resistance and thus generate less sublimates during baking, thus causing no or little device contamination. It can therefore be said that such novolac resins are materials with low process load. Furthermore, the novolac resins attain very high in-plane uniformity of film thickness when applied to planar silicon wafers and also exhibit good applicability to various non-planar substrates having deposited films.

Furthermore, the novolac resins have high etching resistance, good flattening properties, and good gap-filling properties, and monomer selection at the time of synthesis enables control of optical constants appropriately so that reflection during exposure will be eliminated or reduced depending on the type of a device. Self-crosslinking groups, such as propargyl groups, can be introduced into the bis(azaaryl fused ring) compound. This introduction allows the resin to form a resist underlayer film in air atmosphere and in nitrogen atmosphere without requiring a crosslinking agent or a curing catalyst. Thus, the material can be applied to a wider range of processes than heretofore possible. As a matter of course, the introduction of propargyl groups does not impair the above-described characteristics of the bis(azaaryl fused ring). Thus, the novolac resins are expected to serve as materials applicable to a wide range of diverse semiconductor manufacturing processes.

1. A resist underlayer film-forming composition comprising a novolac resin and a solvent, wherein
the novolac resin comprises a unit structure A having an aromatic ring, and the unit structure A includes one, or two or more kinds of bis(azaaryl fused ring) structural units represented by formula (A) below in which two azaaryl fused rings are connected to each other by a linking group L, 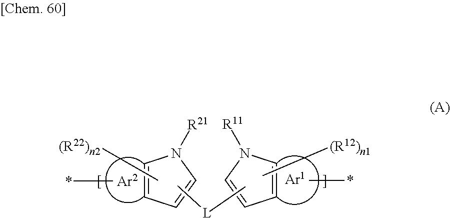
in the formula (A),
L denotes a divalent linking group between two carbon atoms each constituting the respective azaaryl fused rings and is not a single bond,
R¹¹ and R²¹ are the same as or different from each other and each independently denote:
(i) a hydrogen atom or a methylol group,
(ii) a C6-C30 aryl group, or
(iii) a C2-C20 linear, branched, or cyclic alkoxymethyl group; a C1-C20 linear, branched, or cyclic alkyl group; a C2-C10 alkenyl group; or a C2-C10 alkynyl group;
R¹² and R²² are the same as or different from each other and each independently denote an optional substituent on a carbon atom constituting the azaaryl fused ring,
the groups mentioned in (ii) and (iii) are optionally further substituted with an oxygen atom-containing substituent, a sulfur atom-containing substituent, a nitrogen atom-containing substituent, an aryl group, or a halo group, and the groups mentioned in (iii) optionally further have a hydrocarbon chain moiety interrupted by an oxygen atom-containing substituent, a sulfur atom-containing substituent, a nitrogen atom-containing substituent, or an arylene group,
n1 and n2 are the same as or different from each other and independently indicate the number of the substituents R¹² and the number of the substituents R²², respectively, each being optionally 0,
Ar¹ and Ar² are the same as or different from each other, and each independently denote a benzene ring or a fused ring composed of 2 or 3 benzene rings and each independently form a fused ring with the pyrrole ring moiety in the formula (A), and
* denotes a valence bond.

2. The resist underlayer film-forming composition according to claim 1, wherein the novolac resin comprises composite unit structures A-B represented by formula (AB) below: 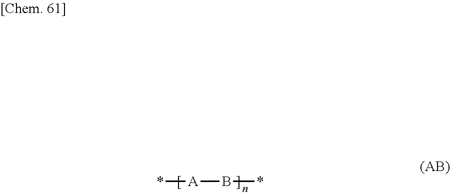
in the formula (AB)
n indicates the number of the composite unit structures A-B,
the unit structures A are represented by the formula (A) described in claim 1,
the unit structures B indicate one, or two or more kinds of unit structures including a structure represented by formula (B1), (B2), or (B3) below, and
* denotes a valence bond, 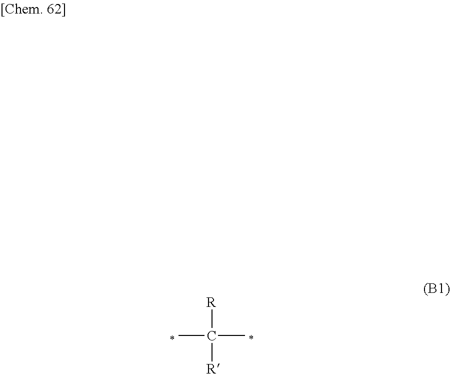
[in the formula (B1),
R and R′ each independently denote a hydrogen atom, an optionally substituted C6-C30 aromatic ring residue, an optionally substituted C3-C30 heterocyclic ring residue, or an optionally substituted C10 or lower linear, branched, or cyclic alkyl group, and
* denotes a valence bond] 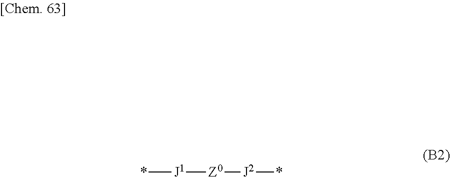
[in the formula (B2),
Z⁰ denotes an optionally substituted C6-C30 aromatic ring residue, aliphatic ring residue, or organic group including two aromatic ring residues or aliphatic ring residues connected to each other via a single bond,
J¹ and J² each independently denote a direct bond or an optionally substituted divalent organic group, and
* denotes a valence bond] 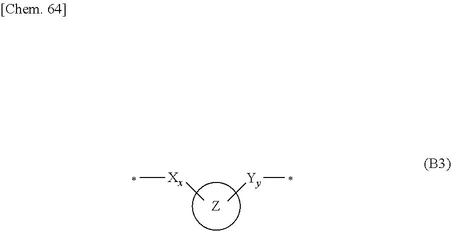
[in the formula (B3),
Z is an optionally substituted C4-C25 monocyclic ring or bicyclic, tricyclic, or tetracyclic fused ring, wherein the monocyclic ring is a non-aromatic monocyclic ring; at least one of the monocyclic rings constituting the bicyclic, tricyclic, or tetracyclic ring is a non-aromatic monocyclic ring, and the remaining monocyclic ring or rings are optionally aromatic monocyclic rings or non-aromatic monocyclic rings; and the monocyclic ring or the bicyclic, tricyclic, or tetracyclic fused ring is optionally further condensed with one or more aromatic rings to form a pentacyclic or higher fused ring,
X and Y denote identical or different —CR³¹R³²— groups, R³¹ and R³² are the same as or different from each other and each denote a hydrogen atom or a C1-C6 hydrocarbon group,
x and y indicate the numbers of X and Y, respectively, and are each independently 0 or 1, 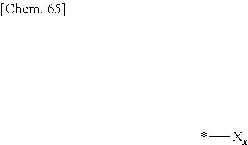
is bonded to any carbon atom (referred to as “carbon atom 1”) constituting any of the non-aromatic monocyclic rings in Z (when x=1) or extends from the carbon atom 1 (when x=0), 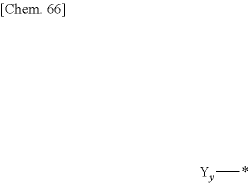
is bonded to any carbon atom (referred to as “carbon atom 2”) constituting any of the non-aromatic monocyclic rings in Z (when y=1) or extends from the carbon atom 2 (when y=0),
the carbon atom 1 and the carbon atom 2 are the same as or different from each other, and when the carbon atom 1 and the carbon atom 2 are different from each other, they belong to the same non-aromatic monocyclic ring or to different non-aromatic monocyclic rings, and
* indicates a valence bond].

3. The resist underlayer film-forming composition according to claim 1, wherein the linking group L is selected from the group consisting of —O—, —S—, —SO₂—, —CO—, —CONH—, —COO—, —NH—, —(CR¹R²)m¹-, —(Ar)m²-, —CH₂—(Ar)m²-CH₂—, and -(cyclo-R)—,
R¹ and R² are the same as or different from each other and each independently denote a hydrogen atom, a C1-C5 hydrocarbon group, or a C6-C30 aryl group, m¹ denotes an integer of 1 to 10,
Ar denotes a C6-C30 arylene group, m² denotes an integer of 1 to 3 and indicates the number of aromatic ring(s) bonded to one another through a single bond, and
cyclo-R denotes a 5- to 8-membered divalent alicyclic hydrocarbon group optionally forming a fused ring with one or two benzene rings or naphthalene rings.

4. The resist underlayer film-forming composition according to claim 3, wherein cyclo-R denotes a 6- to 8-membered divalent alicyclic hydrocarbon group optionally forming a fused ring with one or two benzene rings or naphthalene rings.

5. The resist underlayer film-forming composition according to claim 1, wherein at least part of the occurrences of R¹¹ and R²¹ denotes a substituent: 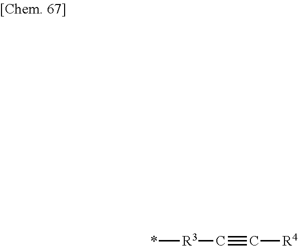
[wherein
* denotes a valence bond,
R³ is a single bond or a C1-C20 divalent organic group, and
R⁴ is a hydrogen atom or a C1-C20 monovalent organic group].

6. The resist underlayer film-forming composition according to claim 1, wherein the solvent comprises a solvent having a boiling point of 160° C. or above.

7. The resist underlayer film-forming composition according to claim 1, further comprising an acid and/or a salt thereof, and/or an acid generator.

8. The resist underlayer film-forming composition according to claim 1, further comprising a crosslinking agent.

9. The resist underlayer film-forming composition according to claim 8, wherein the crosslinking agent is an aminoplast crosslinking agent or a phenoplast crosslinking agent.

10. The resist underlayer film-forming composition according to claim 1, further comprising a surfactant.

11. A resist underlayer film on a semiconductor substrate, comprising a baked product of a coating film comprising the resist underlayer film-forming composition described in claim 1.

12. A method for forming a resist pattern used in semiconductor manufacturing, the method comprising a step of applying the resist underlayer film-forming composition described in claim 1 onto a semiconductor substrate, and baking the resist underlayer film-forming composition to form a resist underlayer film.

13. A method for manufacturing a semiconductor device, comprising:
a step of forming on a semiconductor substrate a resist underlayer film from the resist underlayer film-forming composition described in claim 1;
a step of forming a resist film on the resist underlayer film;
a step of forming a resist pattern by irradiation of the resist film with light or electron beam followed by development;
a step of etching the resist underlayer film through the resist pattern; and
a step of processing the semiconductor substrate through the resist underlayer film having been patterned.

14. A method for manufacturing a semiconductor device, comprising:
a step of forming on a semiconductor substrate a resist underlayer film from the resist underlayer film-forming composition described in claim 1;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned; and
a step of processing the semiconductor substrate through the resist underlayer film having been patterned.

15. A method for manufacturing a semiconductor device, comprising:
a step of forming on a semiconductor substrate a resist underlayer film from the resist underlayer film-forming composition described in claim 1;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been patterned;
a step of removing the hard mask; and
a step of processing the semiconductor substrate through the resist underlayer film having been patterned.

16. A method for manufacturing a semiconductor device, comprising:
a step of forming on a semiconductor substrate a resist underlayer film from the resist underlayer film-forming composition described in claim 1;
a step of forming a hard mask on the resist underlayer film;
a step of forming a resist film on the hard mask;
a step of forming a resist pattern by irradiation of the resist film with light or electron beam followed by development;
a step of etching the hard mask through the resist pattern;
a step of etching the resist underlayer film through the hard mask having been etched;
a step of removing the hard mask;
a step of forming a deposited film (a spacer) on the resist underlayer film cleaned of the hard mask;
a step of processing the deposited film (the spacer) by etching;
a step of removing the resist underlayer film having been patterned while leaving the deposited film (the spacer) having been patterned; and
a step of processing the semiconductor substrate through the deposited film (the spacer) having been patterned.

17. The method for manufacturing a semiconductor device according to claim 14, wherein the hard mask is formed by applying a composition comprising an inorganic substance or by depositing an inorganic substance.

18. The method for manufacturing a semiconductor device according to claim 13, wherein the resist film is patterned by a nanoimprinting method or by using a self-assembled film.

19. The method for manufacturing a semiconductor device according to claim 15, wherein the hard mask is removed by etching or with an alkaline chemical solution.
